(19) United States
(12) Patent Application Publication
(10) Pub. No.: US 2019/0393426 A1
(43) Pub. Date: Dec. 26, 2019

(54) ORGANIC ELECTROLUMINESCENT ELEMENT AND ELECTRONIC DEVICE

(71) Applicant: IDEMITSU KOSAN CO., LTD., Chiyoda-ku (JP)

(72) Inventors: Tetsuya MASUDA, Chiba-shi (JP); Takushi SHIOMI, Chiba-shi (JP); Masayuki MITSUYA, Chengdu (CN)

(73) Assignee: IDEMITSU KOSAN CO., LTD., Chiyoda-ku (JP)

(21) Appl. No.: 16/481,178

(22) PCT Filed: Jan. 30, 2018
(86) PCT No.: PCT/JP2018/002858

§ 371 Date: Jul. 26, 2019

(30) Foreign Application Priority Data
Jan. 30, 2017 (JP) 2017-014626

(51) Int. Cl. H01L 51/00; H01L 51/50; C09K 11/06

(52) U.S. Cl. CPC H01L 51/0072; H01L 51/0054; H01L 51/0067; H01L 51/5076; C09K 2211/182; C09K 11/06; C09K 2211/1029; C09K 2211/181; H01L 51/5092

(57) ABSTRACT

An organic electroluminescence device including a light emitting layer, a first electron transporting layer, and a second electron transporting layer from an anode toward a cathode, wherein the first electron transporting layer comprises a compound represented by formula (1) and the second electron transporting layer comprises a compound represented by formula (2) has a good organic electroluminescence device performance:

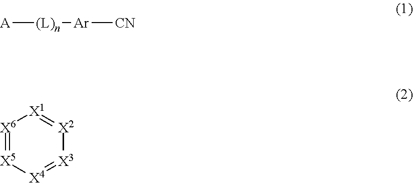

wherein A, L, Ar, n, and X¹ to X⁶ are as defined in the specification.

### TECHNICAL FIELD

The present invention relates to organic electroluminescence devices and electronic devices.

### BACKGROUND ART

One of the method for improving the performance of organic electroluminescence device (organic EL device) now studied is the development of the electron transporting layer material. As another method for improving the performance of organic EL device, it has been known to make the electron transporting layer into two-layered structure and provide the electron transporting layer at the light emitting layer side with a function such as a hole blocking ability and a triplet blocking ability.

However, since the performance of the organic EL device having two-layered electron transporting layers has been insufficient, it has been demanded to further improve the performance. In particular, since the improvement in the emission efficiency is an important problem relating to the power consumption of the product for practical use, an organic EL device having an emission efficiency more improved than known organic EL devices has been demanded.

Patent Document 1 describes an organic EL device comprising a light emitting layer, a blocking layer, and an electron injecting layer in this order from the anode toward the cathode. The blocking layer comprising a compound having a cyano group and a biscarbazole structure is combined with an electron injecting layer comprising a compound having a benzimidazole structure.

Patent Document 2 discloses the use of a compound having a cyano group and a fused aromatic hydrocarbon ring as the electron transporting layer material.

Patent Document 3 discloses the use of a compound having a cyano group and an indolocarbazole structure as the co-host of the light emitting layer, but fails to disclose the use of the compound in the electron transporting layer.

Patent Document 4 describes an organic EL device comprising a light emitting layer, a blocking layer, and an electron injecting layer in this order from the anode toward the cathode. An aromatic heterocyclic compound comprising an azine ring is described as the material for blocking layer.

### CITATION LIST

### Patent Literature

Patent Literature 1: WO2013/084881A1

Patent Literature 2: WO2012/017680A1

Patent Literature 3: WO2013/180097A1

Patent Literature 4: WO2012/070233A1

### SUMMARY OF INVENTION

### Technical Problem

The present invention has been made to solve the above problems and an object thereof is to provide organic EL devices having a good emission efficiency.

### Solution to Problem

As a result of extensive research, the inventors have found that the above object is achieved by an organic EL device comprising a light emitting layer, a first electron transporting layer, and a second electron transporting layer in this order from an anode toward a cathode, wherein the first electron transporting layer comprises a compound having a cyano group which is represented by formula (1) below and the second electron transporting layer comprises a compound having a nitrogen-comprising six-membered ring which is represented by formula (2) below. Namely, the inventors have found that the emission efficiency of organic EL devices are improved by the combination of the first electron transporting layer comprising a compound having a specific structure and the second electron transporting layer comprising a compound having another specific structure.

Thus, in an aspect of the invention, provided is an organic electroluminescence device comprising a cathode, an anode, and an organic layer between the cathode and the anode, wherein:

the organic layer comprises a light emitting layer, a first electron transporting layer, and second electron transporting layer in this order from the anode toward the cathode;

the first electron transporting layer comprises a compound represented by formula (1); and

the second electron transporting layer comprises a compound represented by formula (2):

A-(L)ₙ-Ar—CN (1)

wherein

A is a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 30 ring atoms, or a substituted or unsubstituted non-fused heteroaryl group having 5 to 30 ring atoms;

L is a substituted or unsubstituted fused arylene group having 10 to 30 ring carbon atoms, a substituted or unsubstituted non-fused arylene group having 6 to 30 ring carbon atoms, a substituted or unsubstituted fused heteroarylene group having 9 to 30 ring atoms, or a substituted or unsubstituted non-fused heteroarylene group having 5 to 30 ring atoms;

n is an integer of 0 to 2;

when n is 0, L is a single bond;

when n is 2, two L's may be the same or different; and

Ar is a substituted or unsubstituted fused arylene group having 10 to 30 ring carbon atoms, a substituted or unsubstituted non-fused arylene group having 6 to 30 ring carbon atoms, a substituted or unsubstituted fused heteroarylene group having 9 to 30 ring atoms, or a substituted or unsubstituted non-fused heteroarylene group having 5 to 30 ring atoms;

provided that at least one of A and Ar is a group comprising a fused ring;

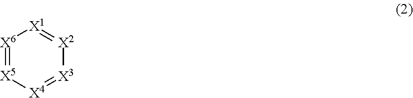

wherein

X¹ is a nitrogen atom or CR¹;

X² is a nitrogen atom or CR²;

X³ is a nitrogen atom or CR³;

X⁴ is a nitrogen atom or CR⁴;

X⁵ is a nitrogen atom or CR⁵;

X⁶ is a nitrogen atom or CR⁶;

at least one of X¹ to X⁶ is a nitrogen atom;

each of one to three selected from R¹ to R⁶ is independently a group represented by any of formulae (3) to (6), and the others are each independently a hydrogen atom or a substituent;

adjacent two selected from R¹ to R⁶ are optionally bonded to each other to form a ring together with two ring carbon atoms to which the adjacent two are bonded, wherein the ring is a substituted or unsubstituted fused aromatic hydrocarbon ring having 10 to 30 ring carbon atoms, a substituted or unsubstituted non-fused aromatic hydrocarbon ring, a substituted or unsubstituted fused aromatic heterocyclic ring having 9 to 30 ring atoms, or a substituted or unsubstituted non-fused aromatic heterocyclic ring having 5 or 6 ring atoms;

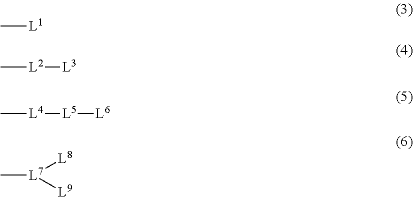

wherein

each of L¹, L³, L⁶, L⁸, and L⁹ is independently a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 32 ring atoms, or a substituted or unsubstituted non-fused heteroaryl group having 5 to 30 ring atoms;

each of L², L⁴, and L⁵ is independently a substituted or unsubstituted fused arylene group having 10 to 30 ring carbon atoms, a substituted or unsubstituted non-fused arylene group having 6 to 30 ring carbon atoms, a substituted or unsubstituted fused heteroarylene group having 9 to 30 ring atoms, or a substituted or unsubstituted non-fused heteroarylene group having 5 to 30 ring atoms;

L⁷ is a trivalent residue of a ring selected from a fused aromatic hydrocarbon ring having 10 to 30 ring carbon atoms, a non-fused aromatic hydrocarbon ring, a fused aromatic heterocyclic ring having 9 to 30 ring atoms, and a non-fused aromatic heterocyclic ring having 5 or 6 ring atoms, the trivalent residue being unsubstituted or having a substituent.

In another aspect of the invention, an electronic device comprising the organic electroluminescence device mentioned above is provided.

### Advantageous Effects of Invention

The present invention realizes an organic EL device having an improved emission efficiency.

### BRIEF DESCRIPTION OF DRAWINGS

FIG. 1 is a schematic view showing the structure of an organic EL device in an aspect of the invention.

### DESCRIPTION OF EMBODIMENTS

The term of “XX to YY carbon atoms” referred to by “a substituted or unsubstituted group ZZ having XX to YY carbon atoms” used herein is the number of carbon atoms of the unsubstituted group ZZ and does not include any carbon atom in the substituent of the substituted group ZZ.

The term of “XX to YY atoms” referred to by “a substituted or unsubstituted group ZZ having XX to YY atoms” used herein is the number of atoms of the unsubstituted group ZZ and does not include any atom in the substituent of the substituted group ZZ.

The term of “unsubstituted group ZZ” referred to by “substituted or unsubstituted group ZZ” used herein means that no hydrogen atom in the group ZZ is substituted by a substituent.

The definition of “hydrogen atom” used herein includes isotopes different in the neutron numbers, i.e., light hydrogen (protium), heavy hydrogen (deuterium), and tritium.

The number of “ring carbon atoms” referred to herein means the number of the carbon atoms included in the atoms which are members forming the ring itself of a compound in which a series of atoms is bonded to form a ring (for example, a monocyclic compound, a fused ring compound, a cross-linked compound, a carbocyclic compound, and a heterocyclic compound). If the ring has a substituent, the carbon atom in the substituent is not included in the ring carbon atom. The same applies to the number of “ring carbon atom” described below, unless otherwise noted. For example, a benzene ring has 6 ring carbon atoms, a naphthalene ring has 10 ring carbon atoms, a pyridine ring has 5 ring carbon atoms, and a furan ring has 4 ring carbon atoms. If a benzene ring or a naphthalene ring has, for example, an alkyl substituent, the carbon atom in the alkyl substituent is not counted as the ring carbon atom of the benzene or naphthalene ring. In case of a fluorene ring to which a fluorene substituent is bonded (inclusive of a spirofluorene ring), the carbon atom in the fluorene substituent is not counted as the ring carbon atom of the fluorene ring.

The number of “ring atom” referred to herein means the number of the atoms which are members forming the ring itself (for example, a monocyclic ring, a fused ring, and a ring assembly) of a compound in which a series of atoms is bonded to form the ring (for example, a monocyclic compound, a fused ring compound, a cross-linked compound, a carbocyclic compound, and a heterocyclic compound). The atom not forming the ring (for example, hydrogen atom(s) for saturating the valence of the atom which forms the ring) and the atom in a substituent, if the ring is substituted, are not counted as the ring atom. The same applies to the number of “ring atoms” described below, unless otherwise noted. For example, a pyridine ring has 6 ring atoms, a quinazoline ring has 10 ring atoms, and a furan ring has 5 ring atoms. The hydrogen atom on the ring carbon atom of a pyridine ring or a quinazoline ring and the atom in a substituent are not counted as the ring atom. In case of a fluorene ring to which a fluorene substituent is bonded (inclusive of a spirofluorene ring), the atom in the fluorene substituent is not counted as the ring atom of the fluorene ring.

The organic EL device in an aspect of the invention comprises a cathode, an anode, and an organic layer between the cathode and the anode. The organic layer comprises a light emitting layer, a first electron transporting layer, and a second electron transporting layer in this order from the anode toward the cathode. The first electron transporting layer comprises a compound represented by formula (1) mentioned below (also referred to as “compound 1”) and the second electron transporting layer comprises a compound represented by formula (2) mentioned below (also referred to as “compound 2”).

The compound 1 is represented by formula (1):

A-(L)ₙ-Ar—CN (1).

In formula (1), A is a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 30 ring atoms, or a substituted or unsubstituted non-fused heteroaryl group having 5 to 30 ring atoms.

In a preferred embodiment of the invention, A is a substituted or unsubstituted fused aryl group having 10 to 30 ring carbon atoms or a substituted or unsubstituted fused heteroaryl group having 9 to 30 ring atoms.

In another preferred embodiment of the invention, A is a substituted or unsubstituted fused aryl group having 10 to 30 ring carbon atoms.

In another preferred embodiment of the invention, A is a substituted or unsubstituted fused heteroaryl group having 9 to 30 ring atoms.

The fused aryl group of the substituted or unsubstituted fused aryl group having 10 to 30 ring carbon atoms for A comprises 2 to 6, preferably 4 to 6 fused rings, for example, a monovalent residue of a fused aromatic hydrocarbon ring selected from naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, benzofluoranthene, triphenylene, benzotriphenylene, and spirofluorene.

The fused aryl group is preferably a monovalent residue of a fused aromatic hydrocarbon ring selected from triphenylene, benzochrysene, fluoranthene, pyrene, fluorene, spirofluorene, 9,9-dimethylfluorene, and 9,9-diphenylfluorene.

In a preferred embodiment of the invention, the fused aryl group is represented by any of the following formulae:

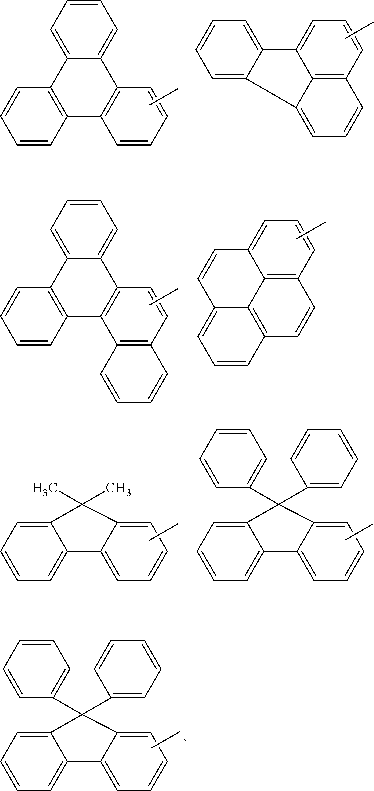

preferably by any of the following formulae:

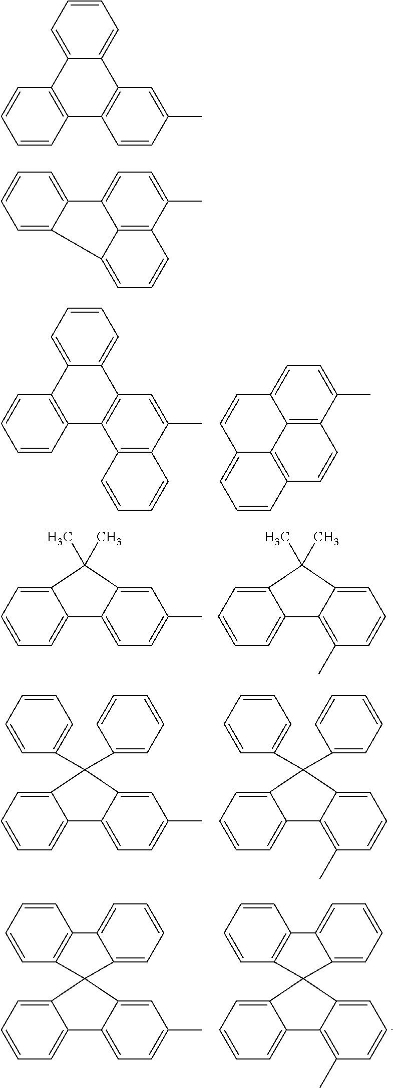

In another preferred embodiment of the invention the fused aryl group is represented by any of the following formulae:

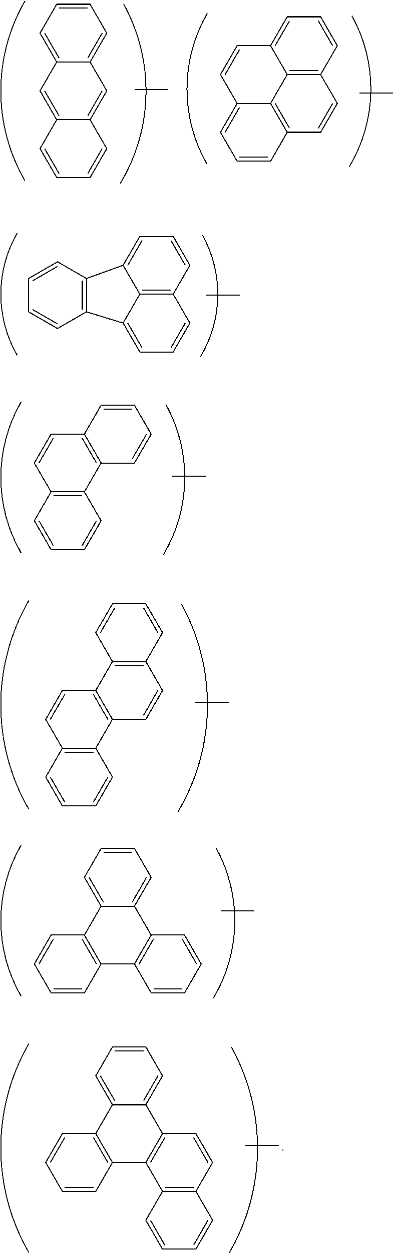

The non-fused aryl group of the substituted or unsubstituted non-fused aryl group having 6 to 30, preferably 6 to 18 ring carbon atoms for A is a monovalent residue of a single ring or a ring assembly, for example, selected from benzene, biphenyl, terphenyl (inclusive of isomers), and quaterphenyl (inclusive of isomers).

The non-fused aryl group is preferably a phenyl group, a biphenylyl group, or a terphenylyl group, and more preferably a phenyl group or a biphenylyl group.

The fused heteroaryl group of the substituted or unsubstituted fused heteroaryl group having 9 to 30 ring atoms for A comprises 2 to 6, preferably 3 to 5 fused rings and 1 to 5, preferably 1 to 3, and more preferably 1 to 2 ring heteroatoms, such as a nitrogen atom, a sulfur atom, and an oxygen atom.

The fused heteroaryl group is a monovalent residue derived from a fused aromatic heterocyclic ring by removing one hydrogen atom on a ring carbon atom or a ring nitrogen atom. The fused aromatic heterocyclic ring is, for example, selected from indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, xanthene, di(benzimidazo)benzo[1,3,5]triazepine, (benzimidazo)benzimidazole, (benzimidazo)phenanthridine, and (benzindolo)benzoazepine. Another ring, for example, benzene, naphthalene, indole, indene, 1,1-dimethylindene, benzofuran, benzothiophene, etc. may further fuse to the fused heteroaryl group.

The non-fused heteroaryl group of the substituted or unsubstituted non-fused heteroaryl group having 5 to 30, preferably 5 to 18 ring atoms for A comprises 1 to 5, preferably 1 to 3, and more preferably 1 to 2 ring heteroatoms, such as a nitrogen atom, a sulfur atom, and an oxygen atom.

The non-fused heteroaryl group is a monovalent residue derived from a single ring or a ring assembly by removing one hydrogen atom on a carbon atom or a nitrogen atom, wherein the single ring and the ring assembly is, for example, selected from pyrrole, imidazole, pyrazole, triazole, furan, thiophene, thiazole, isothiazole, oxazole, isoxazole, oxadiazole, thiadiazole, pyridine, pyrazine, pyridazine, pyrimidine, triazine, bipyrrole, terpyrrole, bithiophene, terthiophene, bipyridine, and terpyridine.

In a preferred embodiment of the invention, the fused heteroaryl group of the substituted or unsubstituted fused heteroaryl group having 9 to 30 ring atoms for A preferably comprises at least one selected from a ring nitrogen atom, a ring oxygen atom, and a ring sulfur atom. The non-fused heteroaryl group of the substituted or unsubstituted non-fused heteroaryl group having 5 to 30, preferably 5 to 18 ring atoms for A preferably comprises at least one selected from a ring nitrogen atom, a ring oxygen atom, and a ring sulfur atom.

The fused heteroaryl group and the non-fused heteroaryl group are selected from the fused heteroaryl group and the non-fused heteroaryl group each mentioned above, respectively.

In a preferred embodiment of the invention, the fused heteroaryl group of the substituted or unsubstituted fused heteroaryl group having 9 to 30 ring atoms for A preferably comprises at least one ring nitrogen atom. The non-fused heteroaryl group of the substituted or unsubstituted non-fused heteroaryl group having 5 to 30, preferably 5 to 18 ring atoms for A preferably comprises at least one nitrogen atom.

The fused heteroaryl group and the non-fused heteroaryl group are selected from the fused heteroaryl group and the non-fused heteroaryl group each mentioned above, respectively.

In a preferred embodiment of the invention, the non-fused heteroaryl group comprising at least one ring nitrogen atom is selected from pyridine, pyrazine, pyridazine, pyrimidine, bipyridine, and triazine.

In a preferred embodiment of the invention, the fused heteroaryl group comprising at least one ring nitrogen atom is a monovalent residue derived from a compound by removing one hydrogen atom on a carbon atom or a nitrogen atom, wherein the compound is selected from indole, carbazole, imidazole, benzimidazole, di(benzimidazo)benzo[1,3,5]triazepine, (benzimidazo)benzimidazole, (benzimidazo)phenanthridine, (benzindolo)benzoazepine, dibenzofuran, and dibenzothiophene.

The monovalent residues of di(benzimidazo)benzo[1,3,5]triazepine, (benzimidazo)benzimidazole, (benzimidazo)phenanthridine, and (benzindolo)benzoazepine are preferably the following groups:

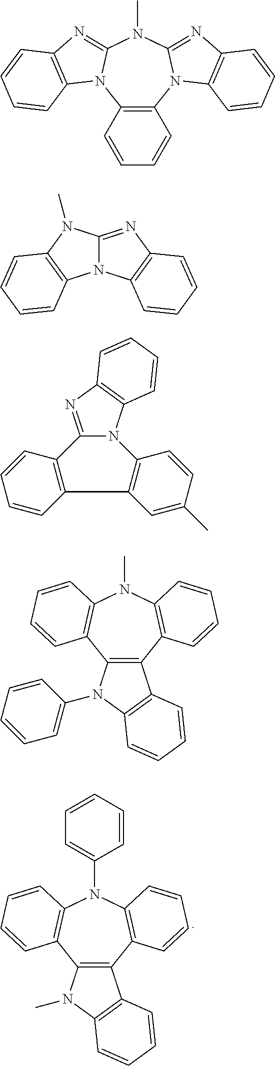

In another preferred embodiment of the invention, the fused heteroaryl group comprising at least one ring nitrogen atom is a monovalent residue derived from indole or carbazole by removing one hydrogen atom on a carbon atom or a nitrogen atom.

In a preferred embodiment of the invention, the fused heteroaryl group comprising at least one ring nitrogen atom for A comprises a carbazole structure. The carbazole structure is preferably a biscarbazole structure or a fused carbazole structure (a carbazole structure to which a ring is further fused).

The fused heteroaryl group comprising the biscarbazole structure is represented by formula (7):

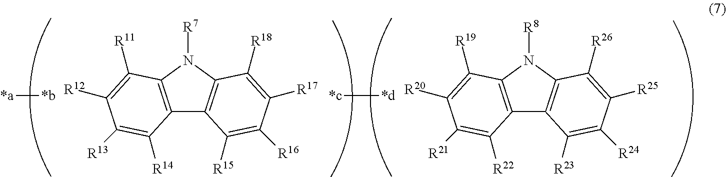

wherein

*a is bonded to L of formula (1);

one selected from R⁷ and R¹¹ to R¹⁴, preferably R⁷ is a single bond bonded to *b;

one selected from R¹¹ to R¹⁸ is a single bond bonded to *c;

R⁷ not a single bond bonded to *b is a substituted or unsubstituted fused aryl group having 10 to 30 ring carbon atoms, preferably a naphthyl group, an anthracenyl group, a phenanthryl group, a fluoranthenyl group, a pyrenyl group, a chrysenyl group, a triphenylenyl group, or a fluorenyl group; a substituted or unsubstituted non-fused aryl group having 6 to 30, preferably 6 to 18 ring carbon atoms, more preferably a phenyl group or a biphenylyl group; a substituted or unsubstituted fused heteroaryl group having 9 to 30 ring atoms, preferably a dibenzofuranyl group or a dibenzothiophenyl group (dibenzothienyl group); or a substituted or unsubstituted non-fused heteroaryl group having 5 to 30, preferably 5 to 18 ring atoms, more preferably a pyrrolyl group, an imidazolyl group, a pyrazolyl group, a furanyl group, a thienyl group, a pyridinyl group, a pyrazinyl group, a pyridazinyl group, a pyrimidinyl group, or a triazinyl group;

R¹¹ to R¹⁴ not a single bond bonded to *b and not a single bond bonded to *c, and R¹⁵ to R¹⁸ not a single bond bonded to *c are each independently a hydrogen atom or a substituent, preferably a hydrogen atom;

one selected from R⁸ and R¹⁹ to R²⁶ is a single bond bonded to *d;

R⁸ not a single bond bonded to *d is a substituted or unsubstituted fused aryl group having 10 to 30 ring carbon atoms, preferably a naphthyl group, an anthracenyl group, a phenanthryl group, a fluoranthenyl group, a pyrenyl group, a chrysenyl group, a triphenylenyl group, or a fluorenyl group; a substituted or unsubstituted non-fused aryl group having 6 to 30, preferably 6 to 18 ring carbon atoms, more preferably a phenyl group or a biphenylyl group; a substituted or unsubstituted fused heteroaryl group having 9 to 30 ring atoms, preferably a dibenzofuranyl group or a dibenzothiophenyl group (dibenzothienyl group); or a substituted or unsubstituted non-fused heteroaryl group having 5 to 30, preferably 5 to 18 ring carbon atoms, more preferably a pyrrolyl group, an imidazolyl group, a pyrazolyl group, a furanyl group, a thienyl group, a pyridinyl group, a pyrazinyl group, a pyridazinyl group, a pyrimidinyl group, or a triazinyl group; and

R¹⁹ to R²² not a single bond bonded to *d are each independently a hydrogen atom or a substituent, preferably a hydrogen atom;

provided that when R¹⁶ is a single bond bonded to *c and R²¹ is a single bond bonded to *d, R¹⁵ and R²² together may represent an oxygen atom or a sulfur atom that crosslinks two carbazole structures.

The fused heteroaryl group comprising the biscarbazole structure is preferably represented by formula (7-1), wherein R⁷ of formula (7) is a single bond bonded to *b:

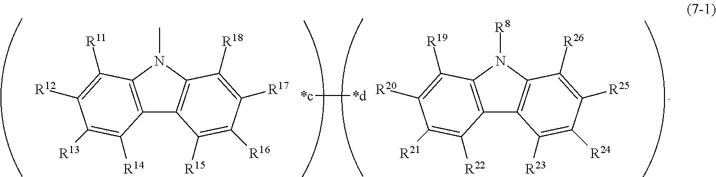

Preferred examples of the biscarbazole structure represented by formula (7) are shown below, wherein R¹¹ to R²⁶ are omitted.

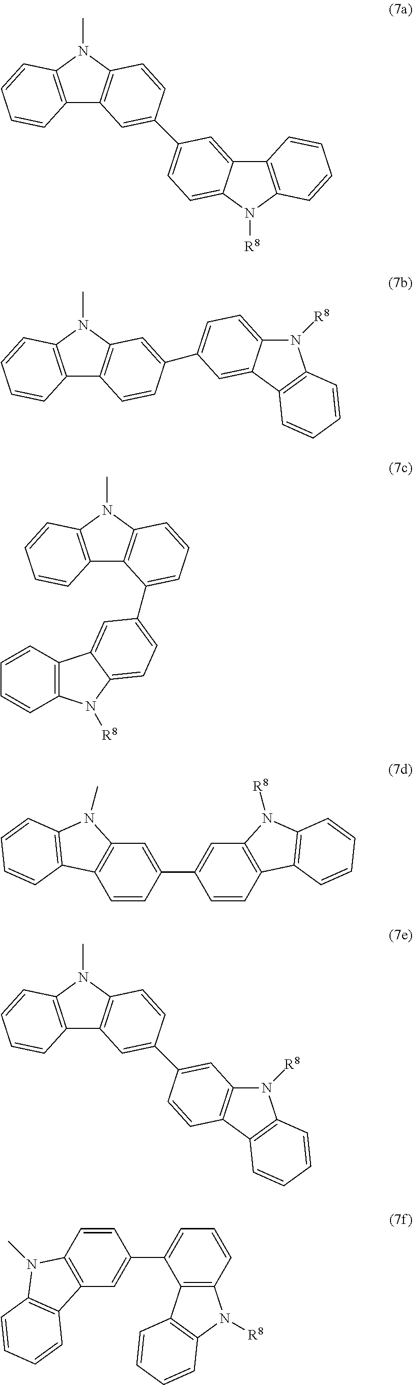

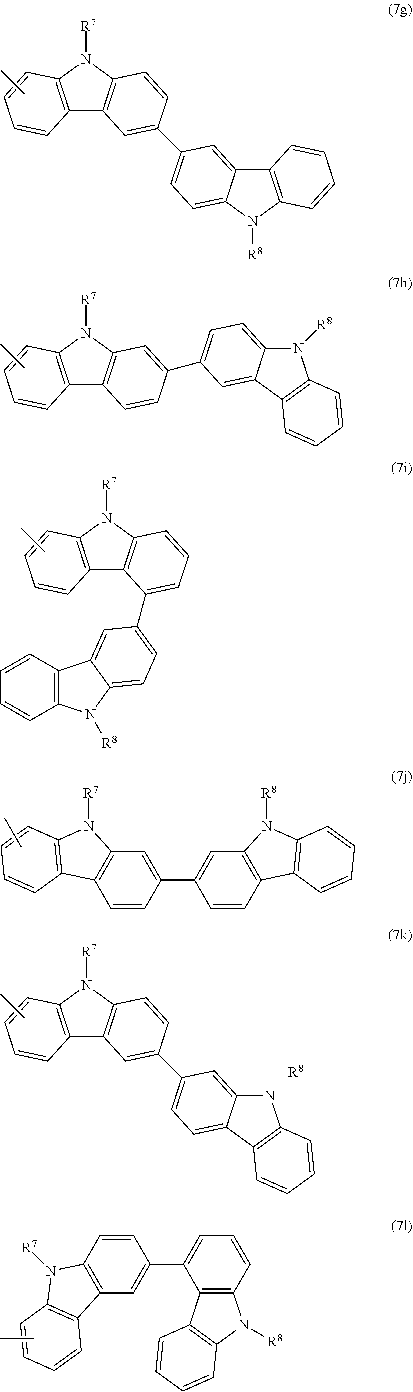

The biscarbazole structure is preferably represented by formula (7a), (7b), (7c), (7d), (7e), or (7f) and more preferably represented by formula (7b).

The fused carbazole structure (a carbazole structure to which a ring is further fused) is represented by formula (8):

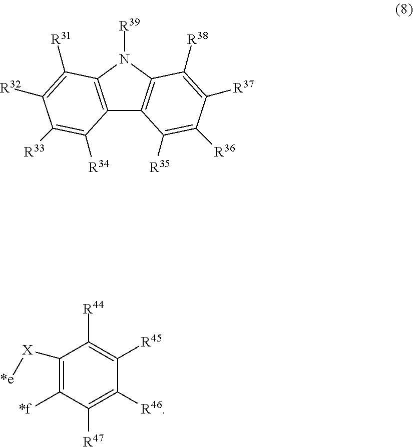

In formula (8),

one selected from R³⁹, R³¹ to R³⁸, and R⁴⁴ to R⁴⁷, preferably R³⁹ is a single bond bonded to L of formula (1);

in at least one, preferably one to three, more preferably one to two, and still more preferably one selected from R³¹ and R³², R³² and R³³, R³³ and R³⁴, R³⁵ and R³⁶, R³⁶ and R³⁷, and R³⁷ and R³⁸, one is a single bond bonded to *e and the other is a single bond bonded to *f,

R³⁹ not a single bond bonded to L of formula (1) is a substituted or unsubstituted non-fused aryl group having 6 to 30, preferably 6 to 18 ring carbon atoms, preferably a phenyl group or a biphenylyl group; or a substituted or unsubstituted fused heteroaryl group having 5 to 30 ring atoms, preferably a dibenzofuranyl group or a dibenzothiophenyl group (dibenzothienyl group);

R³¹ to R³⁸ not a single bond bonded to L of formula (1), *e or *f is a hydrogen atom or a substituent, preferably a hydrogen atom;

X is an oxygen atom, a sulfur atom, NR⁴¹, or CR⁴²R⁴³;

R⁴¹ is a substituted or unsubstituted non-fused aryl group having 6 to 30, preferably 6 to 18 ring carbon atoms, more preferably a phenyl group or a biphenylyl group; or a substituted or unsubstituted fused heteroaryl group having 5 to 30 ring atoms, preferably a dibenzofuranyl group or a dibenzothiophenyl group(dibenzothienyl group);

each of R⁴² and R⁴³ is independently a hydrogen atom or a substituent, preferably a substituted or unsubstituted alkyl group having 1 to 30 carbon atoms or a substituted or unsubstituted fused or non-fused aryl group having 6 to 30 ring carbon atoms, more preferably a methyl group or a phenyl group; and

R⁴⁴ to R⁴⁷ not a single bond bonded to L of formula (1) are each independently a hydrogen atom or a substituent, preferably a hydrogen atom; or

In formula (8),

at least one, preferably one to three, more preferably one to two, and still more preferably one selected from R³¹ and R³², R³² and R³³, R³³ and R³⁴, R³⁵ and R³⁶, R³⁶ and R³⁷, and R³⁷ and R³⁸, together with two ring carbon atoms to which they are bonded, form a substituted or unsubstituted fused or non-fused aromatic hydrocarbon ring having 6 to 30 ring carbon atoms, preferably a benzene ring or a naphthalene ring;

one selected from R³⁹ and R³¹ to R³⁸ not forming the fused or non-fused aromatic hydrocarbon ring, preferably R³⁹ is a single bond bonded to L of formula (1), or one ring carbon atom of the fused or non-fused aromatic hydrocarbon ring is bonded to L of formula (1);

R³⁹ not a single bond bonded to L of formula (1) is a substituent, preferably a substituted or unsubstituted fused or non-fused aryl group having 6 to 30 ring carbon atoms, more preferably a phenyl group or a biphenylyl group; and

R³¹ to R³⁸ not a single bond bonded to L of formula (1), and, not forming the ring are each a hydrogen atom or a substituent, preferably a hydrogen atom.

Preferred examples of the fused carbazole structure represented by formula (8) are shown below, wherein R³⁴ to R³⁸ and R⁴⁴ to R⁴⁷ are omitted.

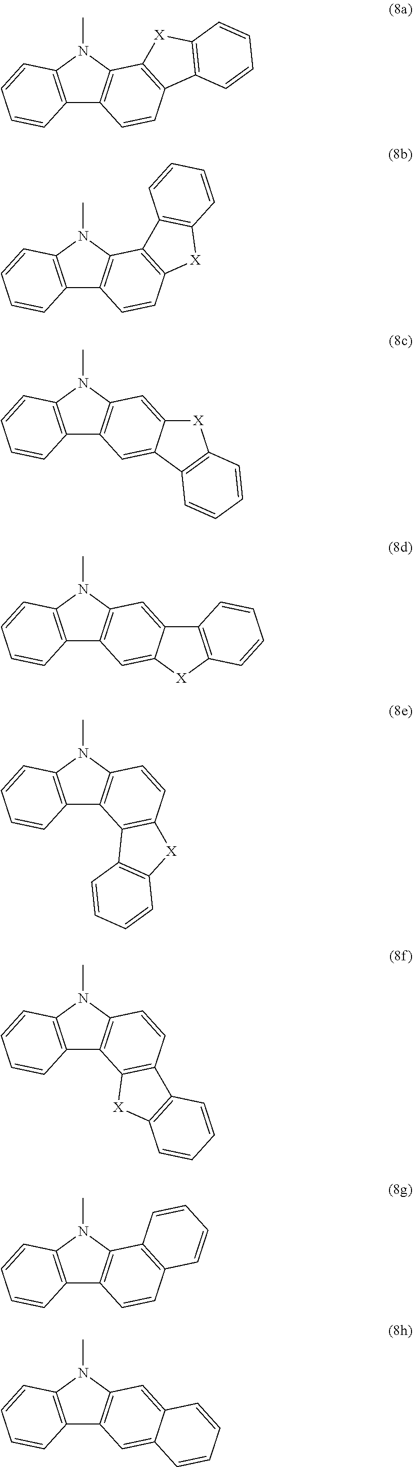

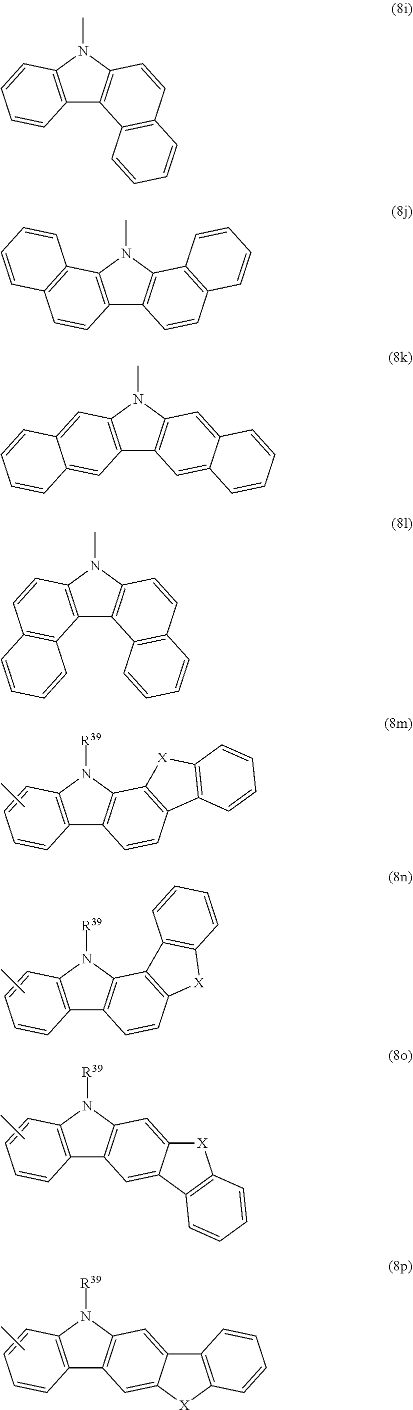

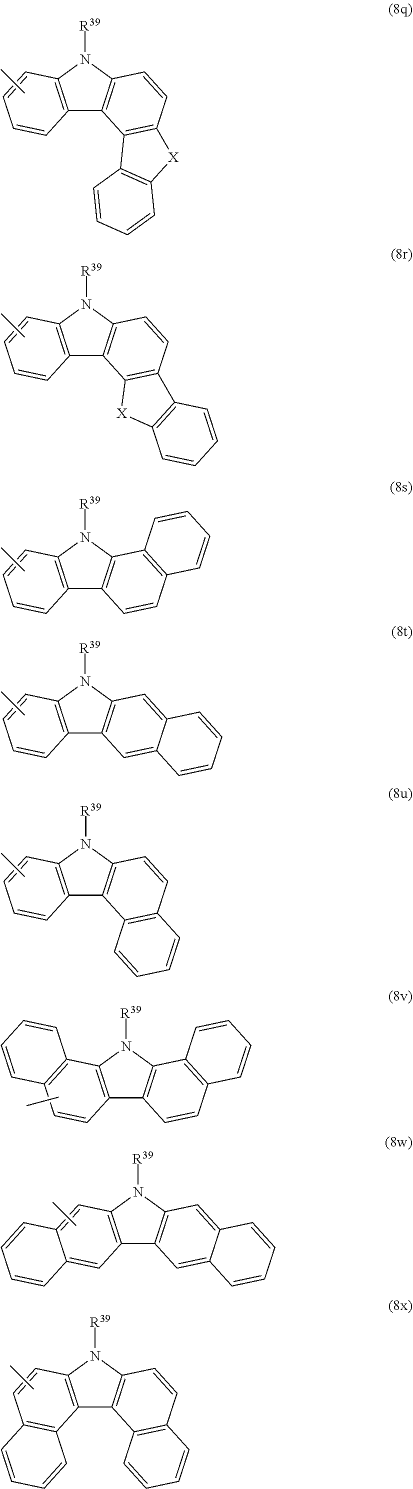

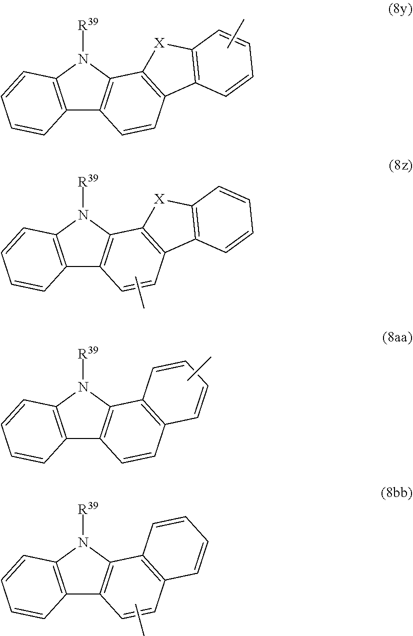

The fused carbazole structure is preferably represented by formula (8a), (8b), (8c), (8d), (8e), or (8f).

In formula (1), L is a substituted or unsubstituted fused arylene group having 10 to 30 ring carbon atoms, a substituted or unsubstituted non-fused arylene group having 6 to 30, preferably 6 to 18 ring carbon atoms, a substituted or unsubstituted fused heteroarylene group having 9 to 30 ring atoms, or a substituted or unsubstituted non-fused heteroarylene group having 5 to 30, preferably 5 to 18 ring atoms.

In a preferred embodiment of the invention, L is a substituted or unsubstituted fused arylene group having 10 to 30 ring carbon atoms or a substituted or unsubstituted non-fused arylene group having 6 to 30, preferably 6 to 18 ring carbon atoms.

The fused arylene group of the substituted or unsubstituted fused arylene group having 10 to 30 ring carbon atoms for L comprises 2 to 6, preferably 2 to 4, more preferably 2 fused rings and examples thereof include a divalent residue of a fused aromatic ring selected from naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, triphenylene, benzotriphenylene, spirofluorene, benzofluoranthene, and benzochrysene.

In a preferred embodiment of the invention, the fused arylene group is a divalent residue of a fused aromatic ring selected from naphthalene, triphenylene, phenanthrene, and fluorene.

In another preferred embodiment of the invention, the fused arylene group is, for example, a 2,7-naphthalenediyl group.

The non-fused arylene group of the substituted or unsubstituted non-fused arylene group having 6 to 30, preferably 6 to 18 ring carbon atoms for L is a divalent residue of single ring or ring assembly selected from, for example, benzene, biphenyl, terphenyl (inclusive of isomers), and quaterphenyl (inclusive of isomers).

In a preferred embodiment of the invention, the non-fused arylene group is represented by any of the following formulae, wherein one of two free bonds is boned to A and the other is bonded to L or Ar:

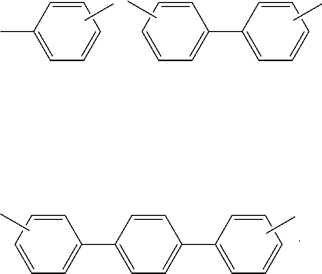

The fused heteroarylene group of the substituted or unsubstituted fused heteroarylene group having 9 to 30 ring atoms for L comprises 2 to 6, preferably 3 to 5 fused rings and 1 to 5, preferably 1 to 3, and more preferably 1 to 2 ring heteroatoms, such as a nitrogen atom, a sulfur atom, and an oxygen atom.

Examples of the fused heteroarylene group include a divalent residue derived from a fused heterocyclic ring by removing two hydrogen atoms on a ring carbon atom and/or a ring nitrogen atom, wherein the fused heterocyclic ring is selected from, for example, indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene.

In a preferred embodiment of the invention, the fused heteroarylene group is a divalent residue of a fused heterocyclic ring selected from dibenzofuran and dibenzothiophene.

The non-fused heteroarylene group of the substituted or unsubstituted non-fused heteroarylene group having 5 to 30, preferably 5 to 18 ring atoms comprises 1 to 5, preferably 1 to 3, and more preferably 1 to 2 ring heteroatoms, such as a nitrogen atom, a sulfur atom, and an oxygen atom.

Examples of the non-fused heteroarylene group include a divalent residue derived from a single ring or a ring assembly by removing two hydrogen atoms on a carbon atom and/or a nitrogen atom, wherein the single ring and the ring assembly are selected from pyrrole, imidazole, pyrazole, triazole, furan, thiophene, thiazole, isothiazole, oxazole, oxazoline, isoxazole, oxadiazole, thiadiazole, pyridine, pyrazine, pyridazine, pyrimidine, triazine, bipyrrole, terpyrrole, bithiophene, terthiophene, bipyridine, and terpyridine.

In a preferred embodiment of the invention, the non-fused heteroarylene group is a divalent residue of a non-fused heterocyclic ring selected from pyridine, pyrimidine, and triazine.

n is an integer of 0 to 2, preferably 0 or 1, more preferably 0. When n is 2, two L's may be the same or different. When n is 0, L is a single bond.

In formula (1), Ar is a substituted or unsubstituted fused arylene group having 10 to 30 ring carbon atoms, a substituted or unsubstituted non-fused arylene group having 6 to 30, preferably 6 to 18 ring carbon atoms, a substituted or unsubstituted fused heteroarylene group having 9 to 30 ring atoms, or a substituted or unsubstituted non-fused heteroarylene group having 5 to 30, preferably 5 to 18 ring atoms.

In a preferred embodiment of the invention, Ar is a substituted or unsubstituted fused arylene group having 10 to 30 ring carbon atoms, a substituted or unsubstituted non-fused arylene group having 6 to 30, preferably 6 to 18 ring carbon atoms, or a substituted or unsubstituted fused heteroarylene group having 9 to 30 ring atoms.

In another preferred embodiment of the invention, Ar is a substituted or unsubstituted fused arylene group having 10 to 30 ring carbon atoms or a substituted or unsubstituted fused heteroarylene group having 9 to 30 ring atoms.

The fused arylene group of the substituted or unsubstituted fused arylene group having 10 to 30 ring carbon atoms for Ar comprises 2 to 6, preferably 2 to 4 fused rings and may include, for example, a divalent residue of a fused aromatic ring selected from naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, triphenylene, 9,9-dimethylfluorene, 9,9-diphenylfluorene, spirofluorene, benzofluoranthene, and benzochrysene, preferably a divalent residue of a fused aromatic ring selected from naphthalene, phenanthrene, fluoranthene, pyrene, triphenylene, benzochrysene, 9,9-dimethylfluorene, 9,9-diphenylfluorene, and spirofluorene.

In a preferred embodiment of the invention, the fused arylene group includes the following groups, wherein one of two free bonds is bonded to L or A and the other is bonded to CN:

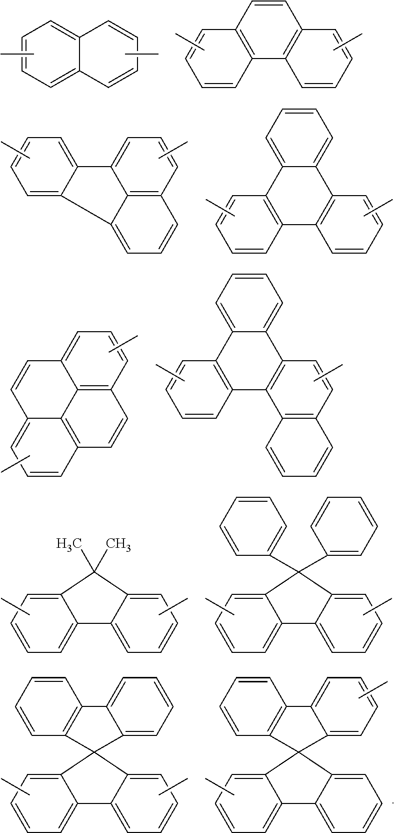

The fused arylene groups above are preferably represented by the following formulae:

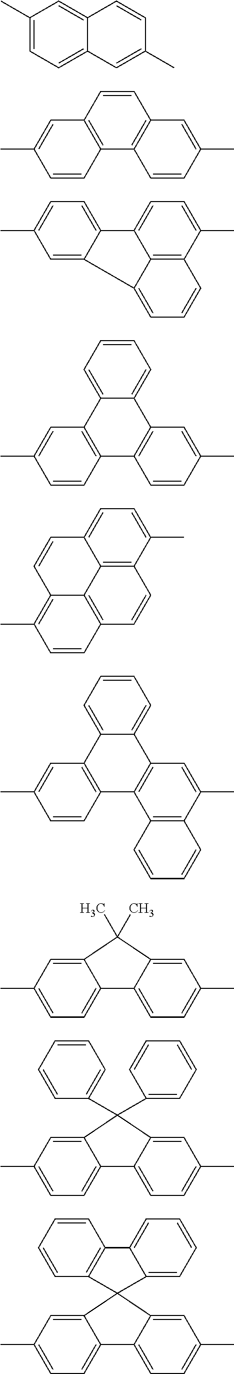

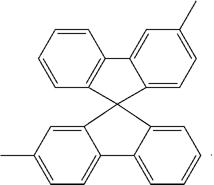 [SMILES: Cc1ccc2c(c1)-c1ccccc1C21c2ccccc2-c2ccc(C)cc21]

The non-fused arylene group of the substituted or unsubstituted non-fused arylene group having 6 to 30, preferably 6 to 18 ring carbon atoms for Ar is a divalent residue of a single ring or a ring assembly, for example, selected from benzene, biphenyl, terphenyl (inclusive of isomers), and quaterphenyl (inclusive of isomers).

In a preferred embodiment of the invention, the non-fused arylene group is represented by any of the following formulae, wherein one of two free bonds is bonded to L or A and the other is bonded to CN:

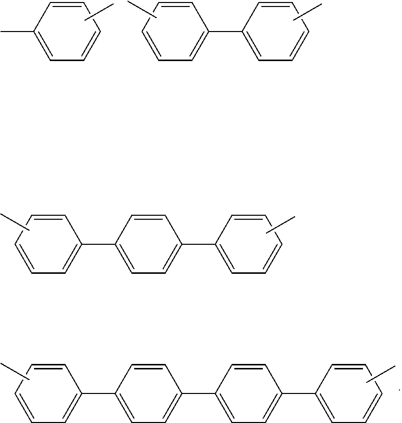

The non-fused arylene groups above are preferably represented by the following formulae:

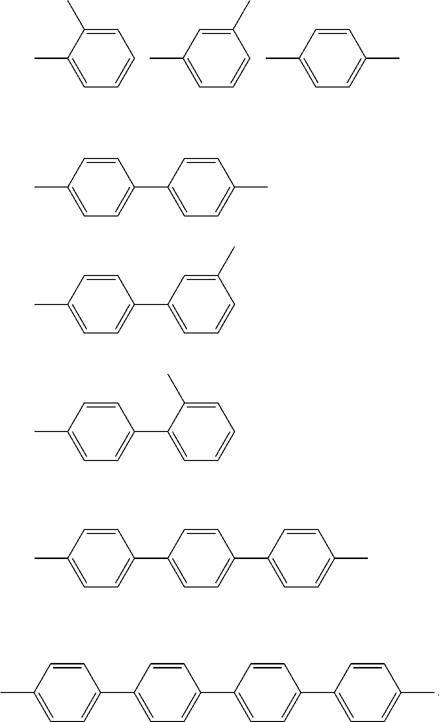

The fused heteroarylene group of the substituted or unsubstituted fused heteroarylene group having 9 to 30 ring atoms for Ar comprises 2 to 6, preferably 3 to 5 fused rings and comprises 1 to 5, preferably 1 to 3, and more preferably 1 to 2 ring heteroatoms, such as a nitrogen atom, a sulfur atom, and an oxygen atom.

Examples of the fused heteroarylene group include a divalent residue derived from a fused heterocyclic ring by removing two hydrogen atoms on a ring carbon atom and/or a ring nitrogen atom, wherein the fused heterocyclic ring is selected from indole, isoindole, benzofuran, isobenzofuran, benzothiophene, indolizine, quinolizine, quinoline, isoquinoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene, preferably selected from dibenzofuran, dibenzothiophene, and carbazole.

In a preferred embodiment of the invention, the divalent residue of the fused aromatic ring is represented by any of the following formulae, wherein one of the free bonds is bonded to L or A and the other is bonded to CN:

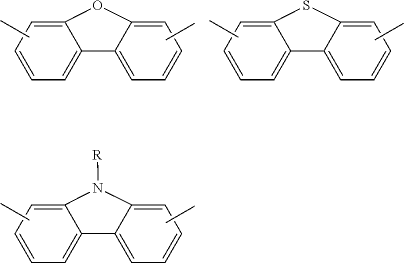

wherein R is a non-fused aryl group having 6 to 30, preferably 6 to 18 ring carbon atoms or a fused aryl group having 10 to 30 ring carbon atoms, and the details thereof are as described above with respect to A.

The divalent residue of the fused aromatic ring is preferably represented by any of the following formulae:

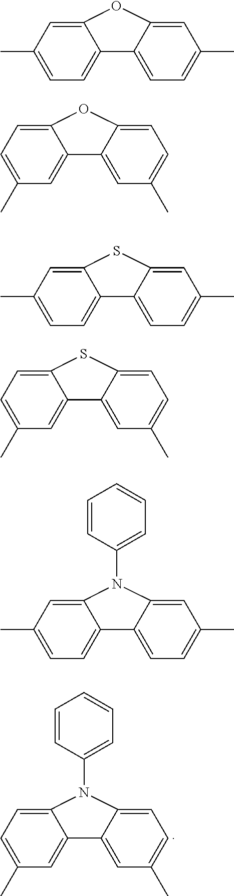

The non-fused heteroarylene group of the substituted or unsubstituted non-fused heteroarylene group having 5 to 30, preferably 5 to 18 ring atoms for Ar comprises 1 to 5, preferably 1 to 3, and more preferably 1 to 2 ring heteroatoms, such as a nitrogen atom, a sulfur atom, and an oxygen atom.

The non-fused heteroarylene group is a divalent residue derived from a single ring or a ring assembly by removing two hydrogen atoms on a carbon atom and/or a nitrogen atom, wherein the single ring or the ring assembly is, for example, selected from pyrrole, imidazole, pyrazole, triazole, furan, thiophene, thiazole, isothiazole, oxazole, oxazoline, isoxazole, oxadiazole, thiadiazole, pyridine, pyrazine, pyridazine, pyrimidine, triazine, bipyrrole, terpyrrole, bithiophene, terthiophene, bipyridine, and terpyridine.

In a preferred embodiment of the invention, the non-fused heteroarylene group is a divalent residue of the non-fused heterocyclic ring selected from pyridine, pyrimidine, and triazine.

In a preferred embodiment of the invention, Ar of —Ar—CN or -L-Ar—CN in formula (1) comprises a benzene ring as a single ring; a benzene ring included in a ring assembly, such as biphenyl; a benzene ring included in an aromatic hydrocarbon ring, such as naphthalene, phenanthrene, fluoranthene, benzofluoranthene, triphenylene, benzochrysene, pyrene, 9,9-dimethylfluorene, 9,9-diphenylfluorene, and spirofluorene; or a benzene ring included in a fused aromatic heterocyclic ring, such as dibenzofuran, dibenzothiophene, and carbazole, and the carbon atom forming the benzene ring is bonded to CN. The benzene ring may have an optional substituent or not.

In another preferred embodiment of the invention, the structure (—Ar—CN or -L-Ar—CN) wherein Ar comprises the benzene ring mentioned above and the carbon atom forming the benzene ring is bonded to CN is represented by, for example, any of the following formulae:

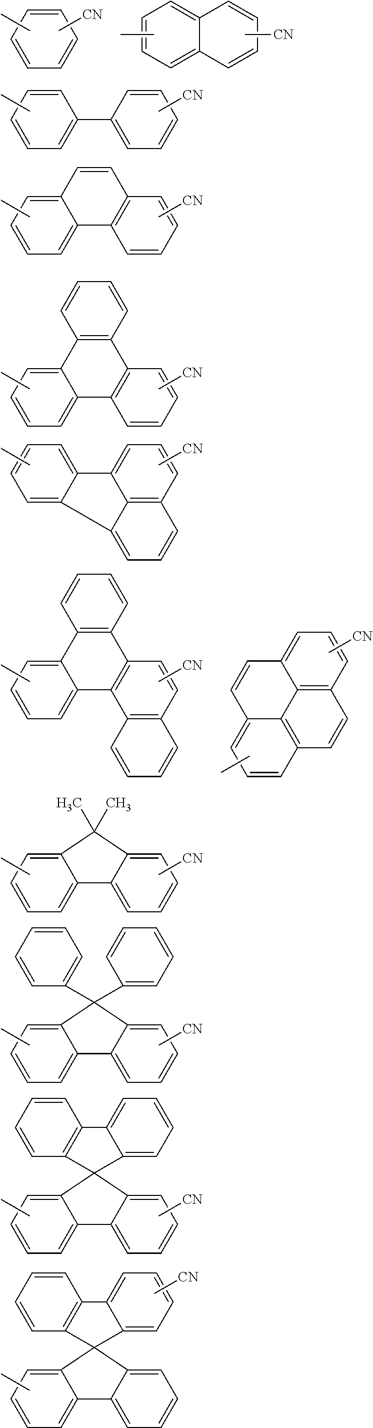

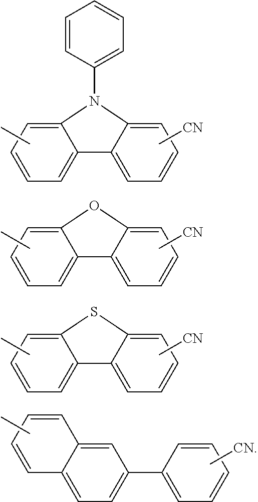

In another preferred embodiment of the invention, —Ar—CN and -L-Ar—CN comprises a p-biphenylylcyano structure as shown below, wherein an optional substituent is omitted:

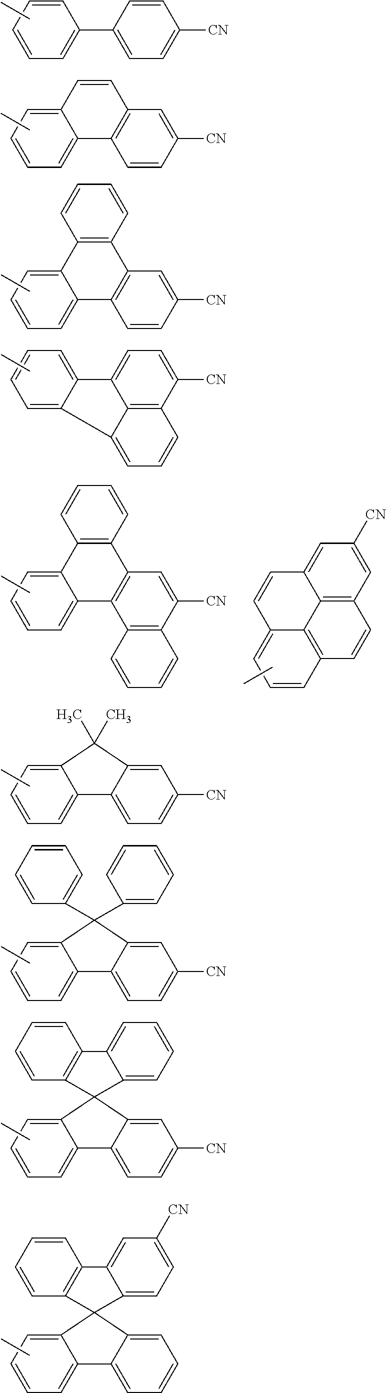

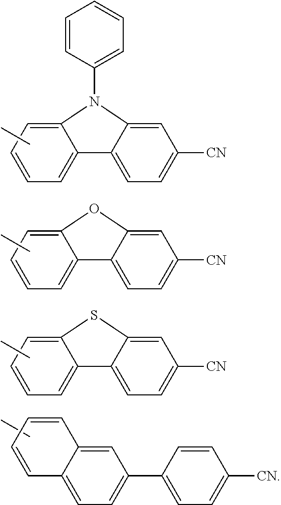

In another preferred embodiment of the invention, —Ar—CN and -L-Ar—CN comprises a p-biphenylylcyano structure containing no heteroatom.

Examples of the compound 1 are shown below, although not limited thereto.

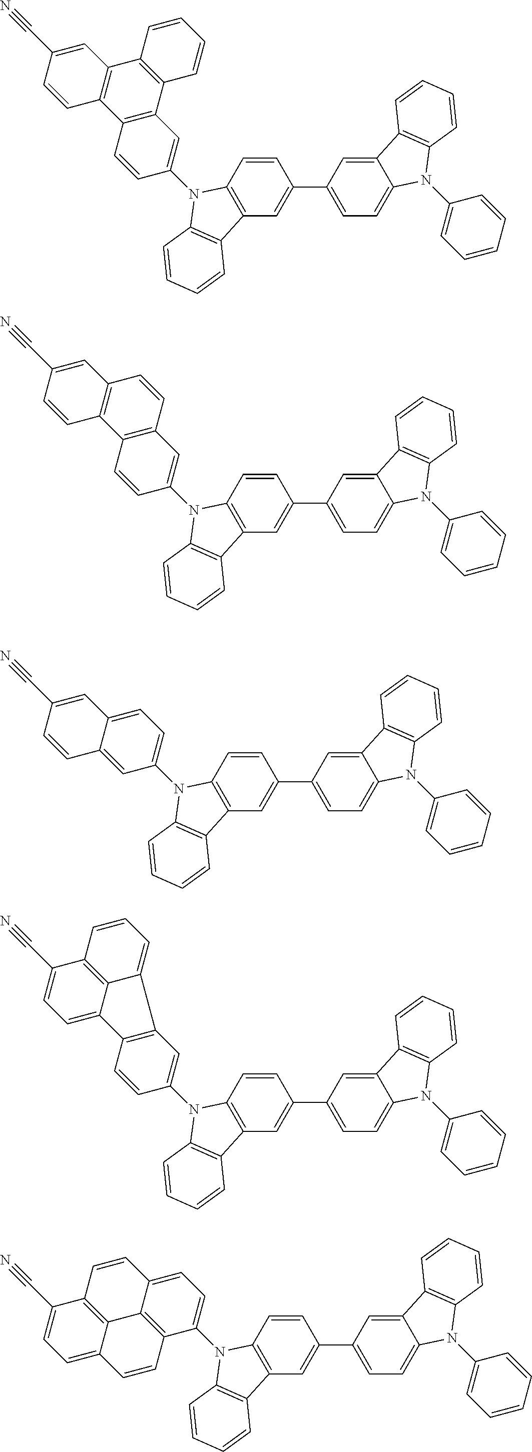 [SMILES: N#Cc1ccc2c3ccc(-n4c5ccccc5c5cc(-c6ccc7c(c6)c6ccccc6n7-c6ccccc6)ccc54)cc3c3ccccc3c2c1 ; N#Cc1ccc2c(ccc3cc(-n4c5ccccc5c5cc(-c6ccc7c(c6)c6ccccc6n7-c6ccccc6)ccc54)ccc32)c1 ; N#Cc1ccc2cc(-n3c4ccccc4c4cc(-c5ccc6c(c5)c5ccccc5n6-c5ccccc5)ccc43)ccc2c1 ; N#Cc1ccc2c3c(cccc13)-c1cc(-n3c4ccccc4c4cc(-c5ccc6c(c5)c5ccccc5n6-c5ccccc5)ccc43)ccc1-2 ; N#Cc1ccc2ccc3c(-n4c5ccccc5c5cc(-c6ccc7c(c6)c6ccccc6n7-c6ccccc6)ccc54)ccc4ccc1c2c43]

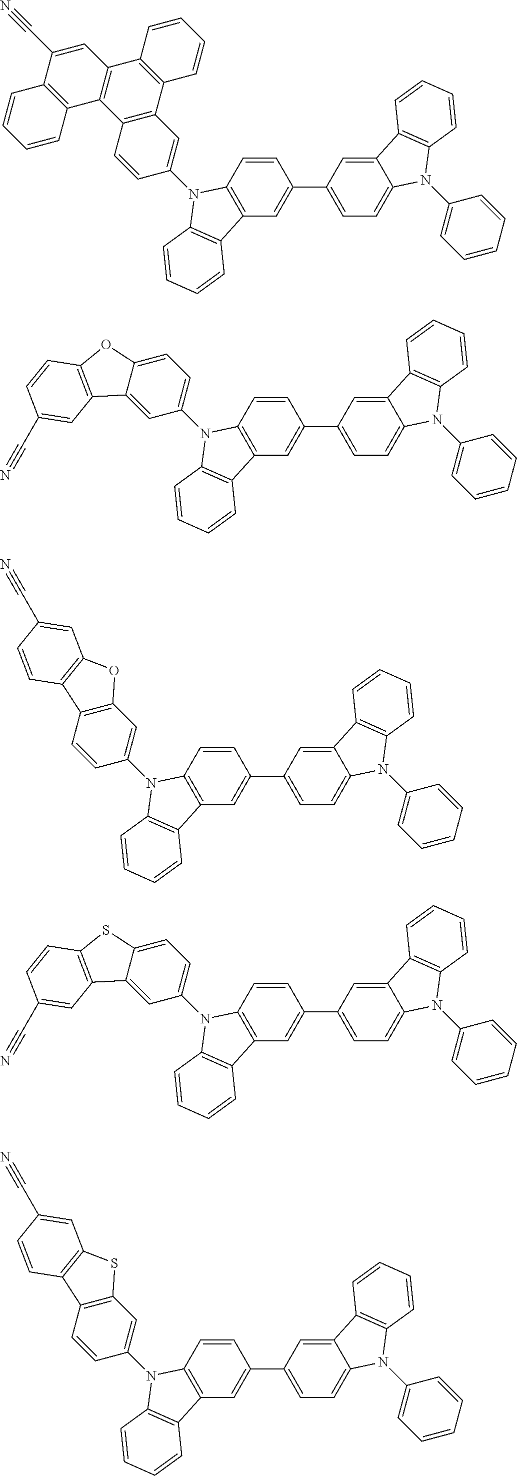 [SMILES: N#Cc1cc2c3ccccc3c3cc(-n4c5ccccc5c5cc(-c6ccc7c(c6)c6ccccc6n7-c6ccccc6)ccc54)ccc3c2c2ccccc12 ; N#Cc1ccc2oc3ccc(-n4c5ccccc5c5cc(-c6ccc7c(c6)c6ccccc6n7-c6ccccc6)ccc54)cc3c2c1 ; N#Cc1ccc2c(c1)oc1cc(-n3c4ccccc4c4cc(-c5ccc6c(c5)c5ccccc5n6-c5ccccc5)ccc43)ccc12 ; N#Cc1ccc2sc3ccc(-n4c5ccccc5c5cc(-c6ccc7c(c6)c6ccccc6n7-c6ccccc6)ccc54)cc3c2c1 ; N#Cc1ccc2c(c1)sc1cc(-n3c4ccccc4c4cc(-c5ccc6c(c5)c5ccccc5n6-c5ccccc5)ccc43)ccc12]

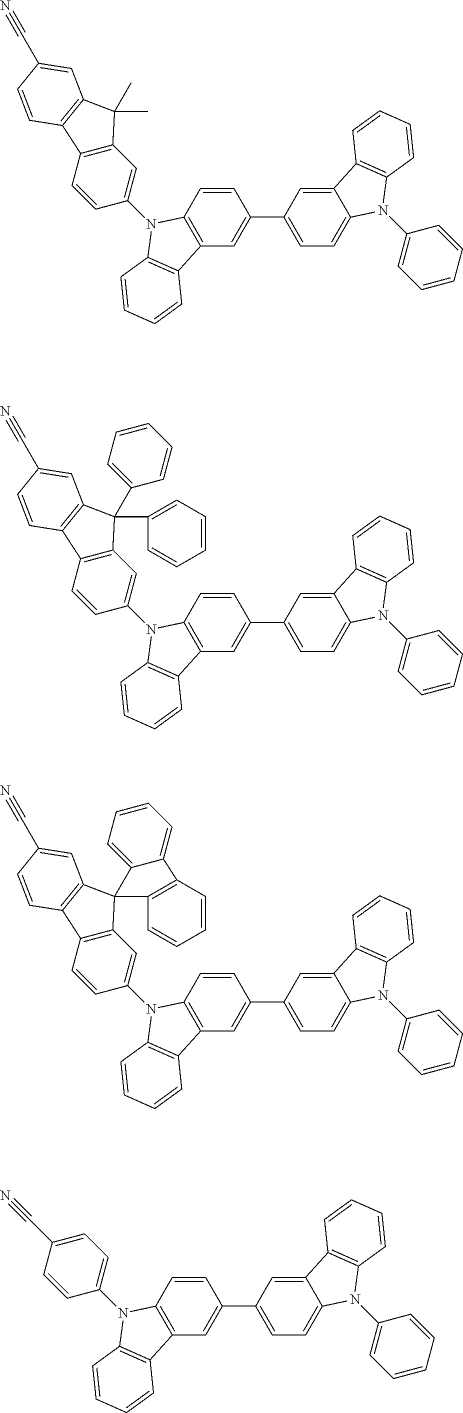 [SMILES: CC1(C)c2cc(C#N)ccc2-c2ccc(-n3c4ccccc4c4cc(-c5ccc6c(c5)c5ccccc5n6-c5ccccc5)ccc43)cc21 ; N#Cc1ccc2c(c1)C(c1ccccc1)(c1ccccc1)c1cc(-n3c4ccccc4c4cc(-c5ccc6c(c5)c5ccccc5n6-c5ccccc5)ccc43)ccc1-2 ; N#Cc1ccc2c(c1)C1(c3ccccc3-c3ccccc31)c1cc(-n3c4ccccc4c4cc(-c5ccc6c(c5)c5ccccc5n6-c5ccccc5)ccc43)ccc1-2 ; N#Cc1ccc(-n2c3ccccc3c3cc(-c4ccc5c(c4)c4ccccc4n5-c4ccccc4)ccc32)cc1]

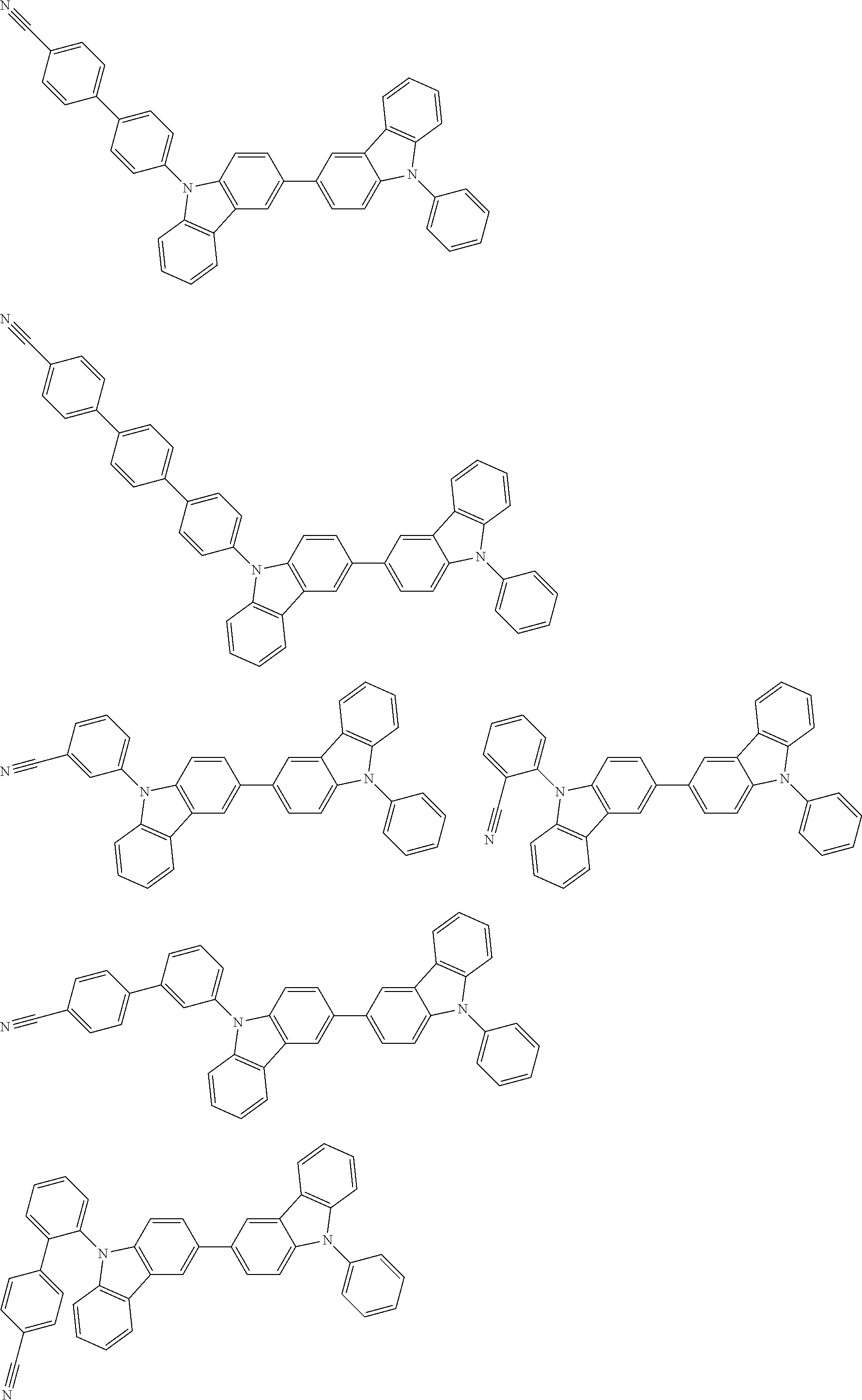 [SMILES: N#Cc1ccc(-c2ccc(-n3c4ccccc4c4cc(-c5ccc6c(c5)c5ccccc5n6-c5ccccc5)ccc43)cc2)cc1 ; N#Cc1ccc(-c2ccc(-c3ccc(-n4c5ccccc5c5cc(-c6ccc7c(c6)c6ccccc6n7-c6ccccc6)ccc54)cc3)cc2)cc1 ; N#Cc1cccc(-n2c3ccccc3c3cc(-c4ccc5c(c4)c4ccccc4n5-c4ccccc4)ccc32)c1 ; N#Cc1ccccc1-n1c2ccccc2c2cc(-c3ccc4c(c3)c3ccccc3n4-c3ccccc3)ccc21 ; N#Cc1ccc(-c2cccc(-n3c4ccccc4c4cc(-c5ccc6c(c5)c5ccccc5n6-c5ccccc5)ccc43)c2)cc1 ; N#Cc1ccc(-c2ccccc2-n2c3ccccc3c3cc(-c4ccc5c(c4)c4ccccc4n5-c4ccccc4)ccc32)cc1]

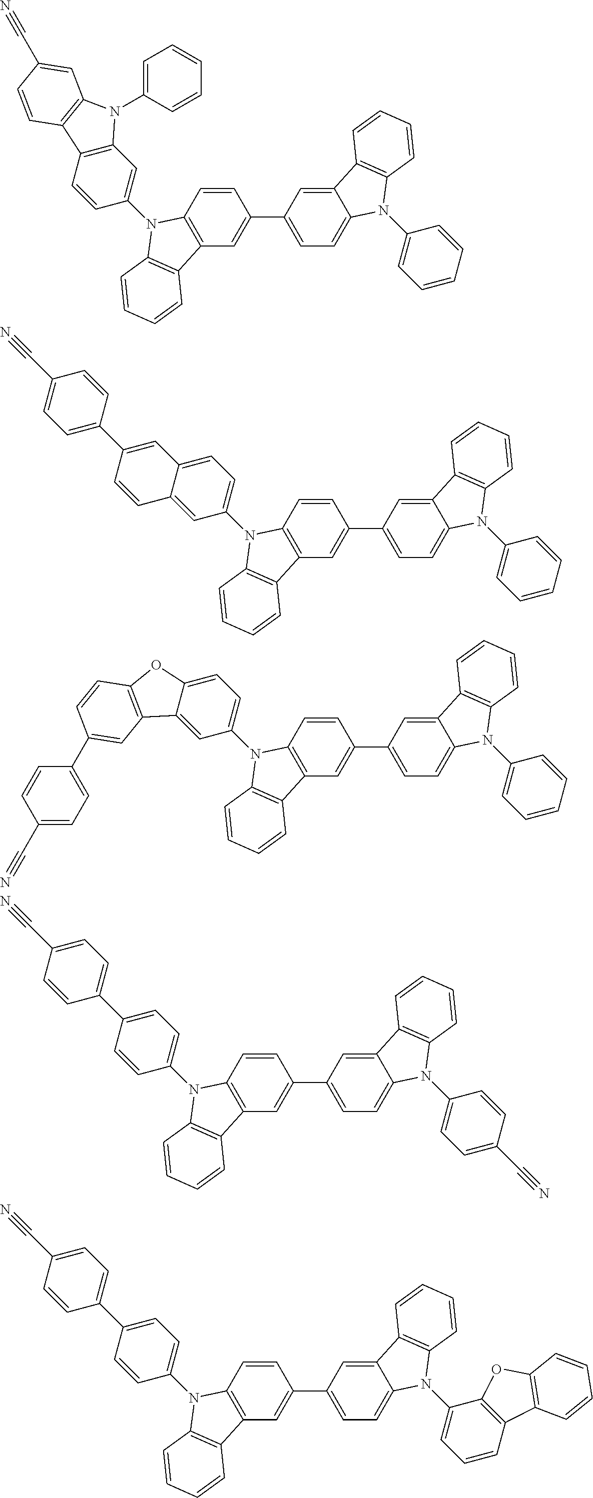

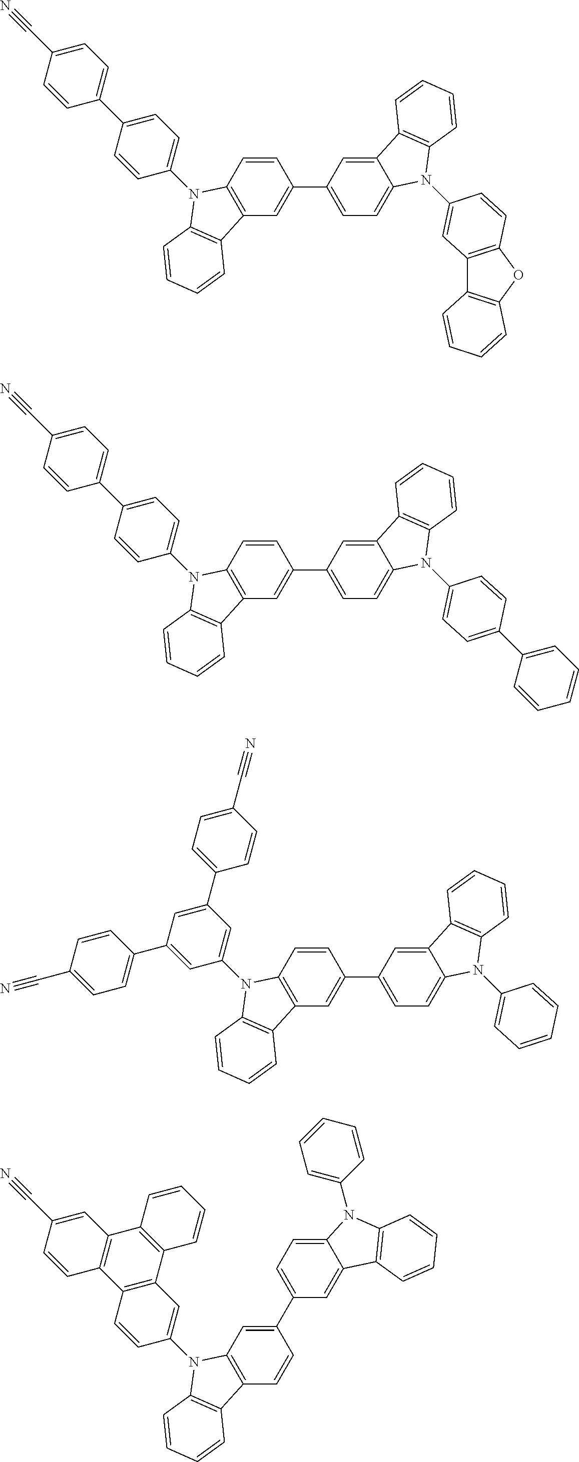 [SMILES: N#Cc1ccc(-c2ccc(-n3c4ccccc4c4cc(-c5ccc6c(c5)c5ccccc5n6-c5ccc6oc7ccccc7c6c5)ccc43)cc2)cc1 ; N#Cc1ccc(-c2ccc(-n3c4ccccc4c4cc(-c5ccc6c(c5)c5ccccc5n6-c5ccc(-c6ccccc6)cc5)ccc43)cc2)cc1 ; N#Cc1ccc(-c2cc(-c3ccc(C#N)cc3)cc(-n3c4ccccc4c4cc(-c5ccc6c(c5)c5ccccc5n6-c5ccccc5)ccc43)c2)cc1 ; N#Cc1ccc2c3ccc(-n4c5ccccc5c5ccc(-c6ccc7c(c6)c6ccccc6n7-c6ccccc6)cc54)cc3c3ccccc3c2c1]

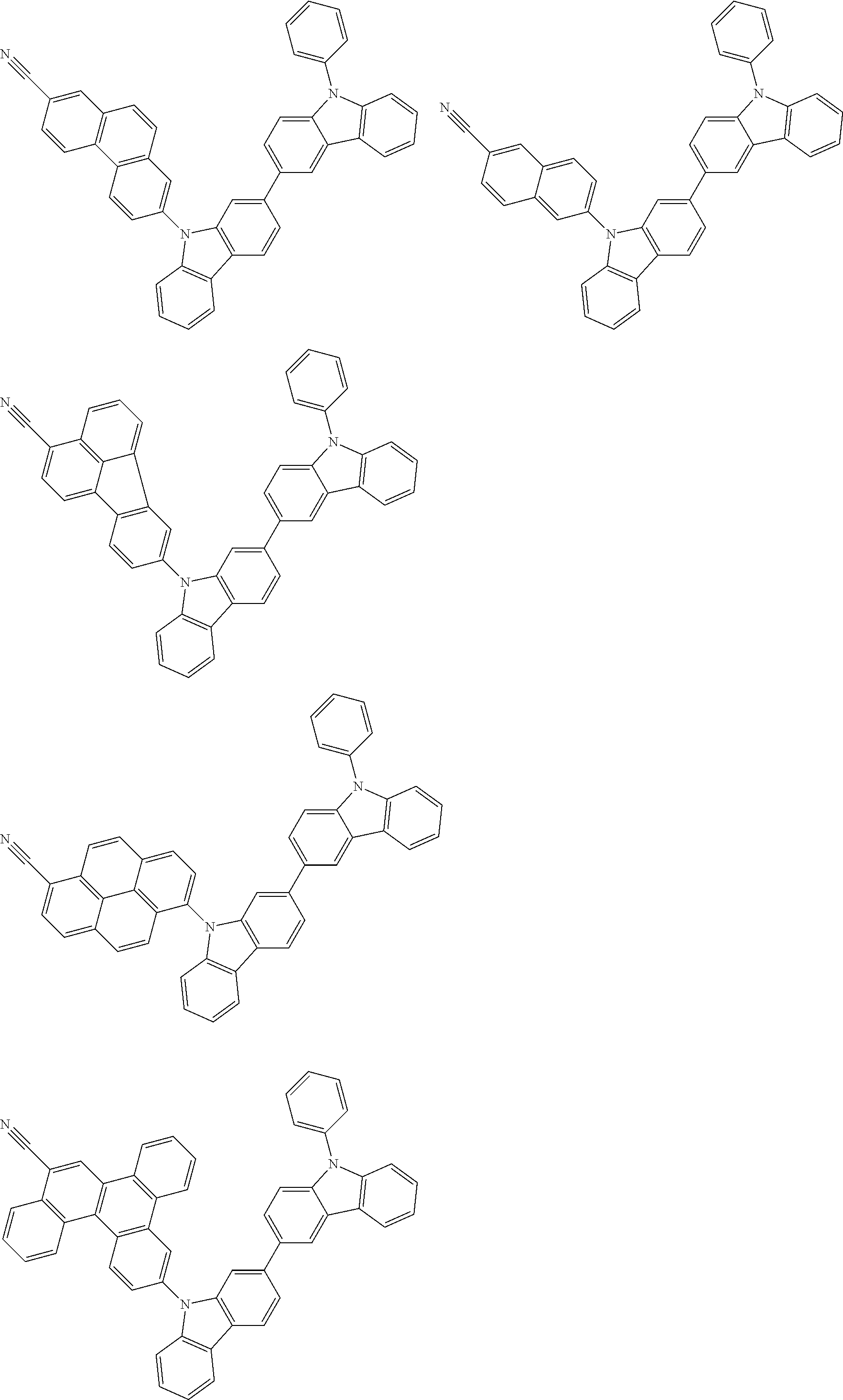

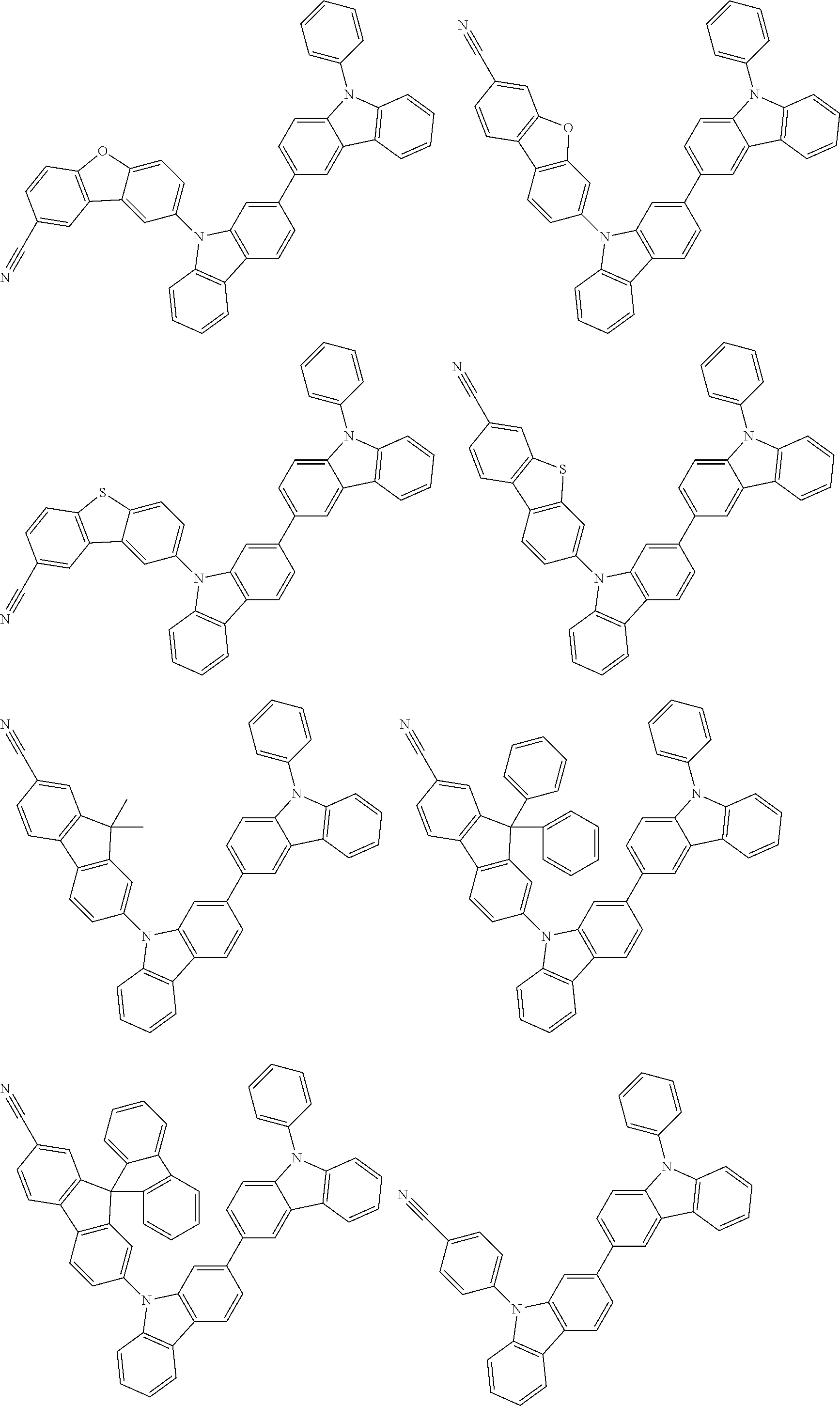

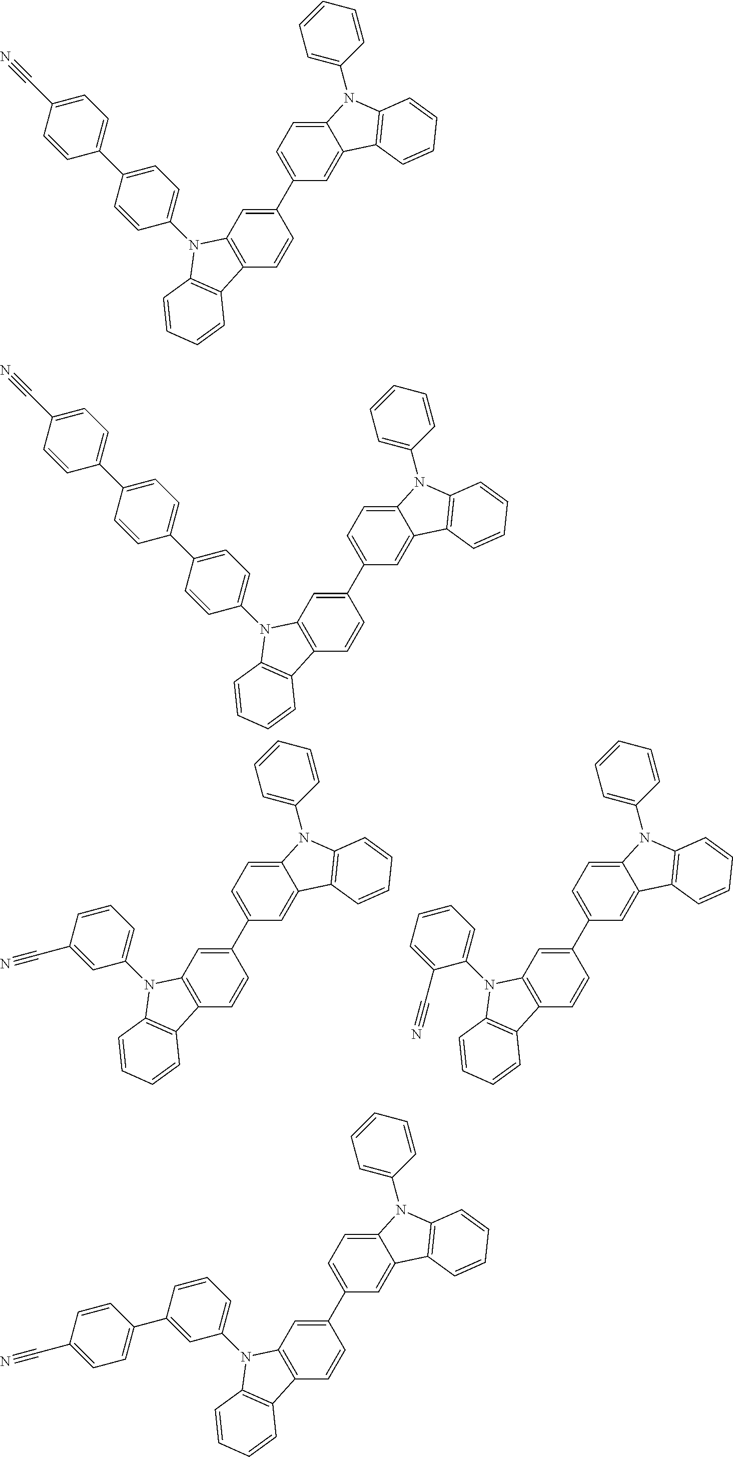

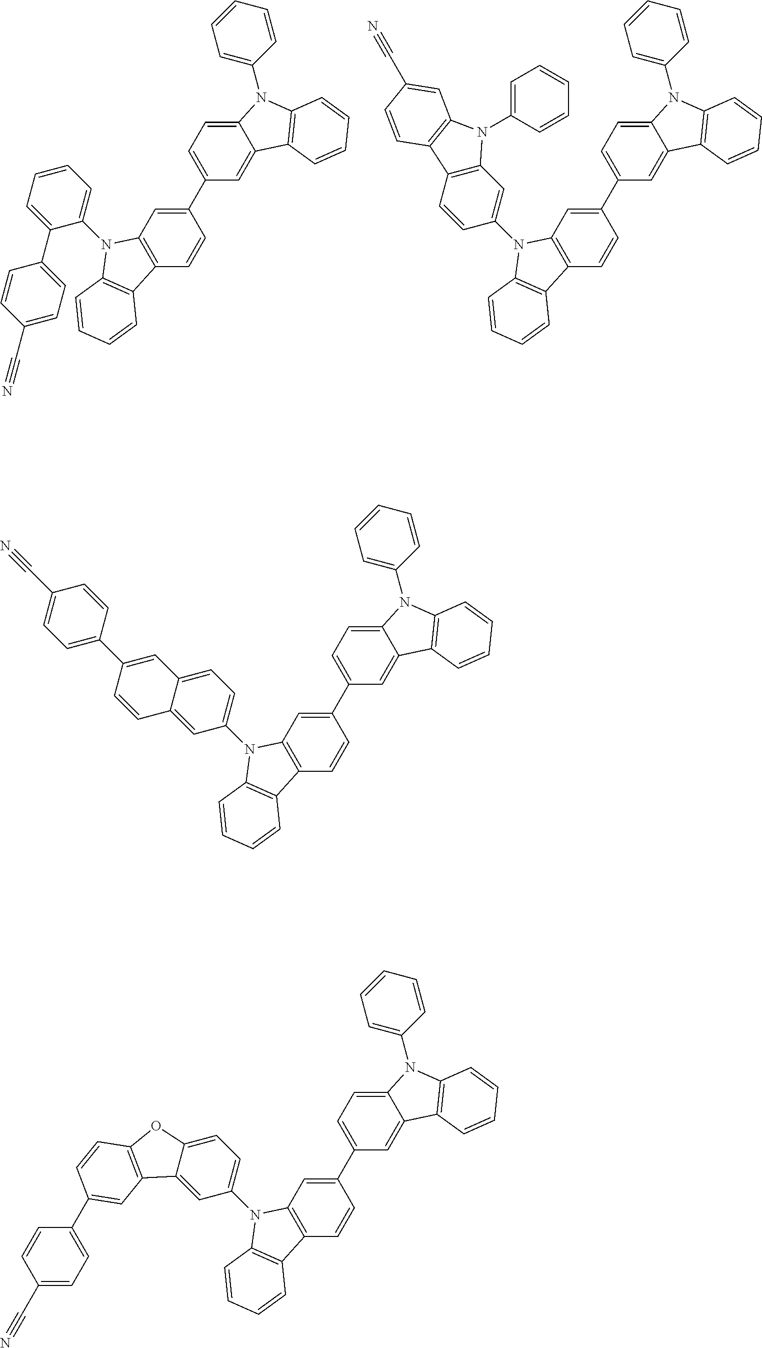

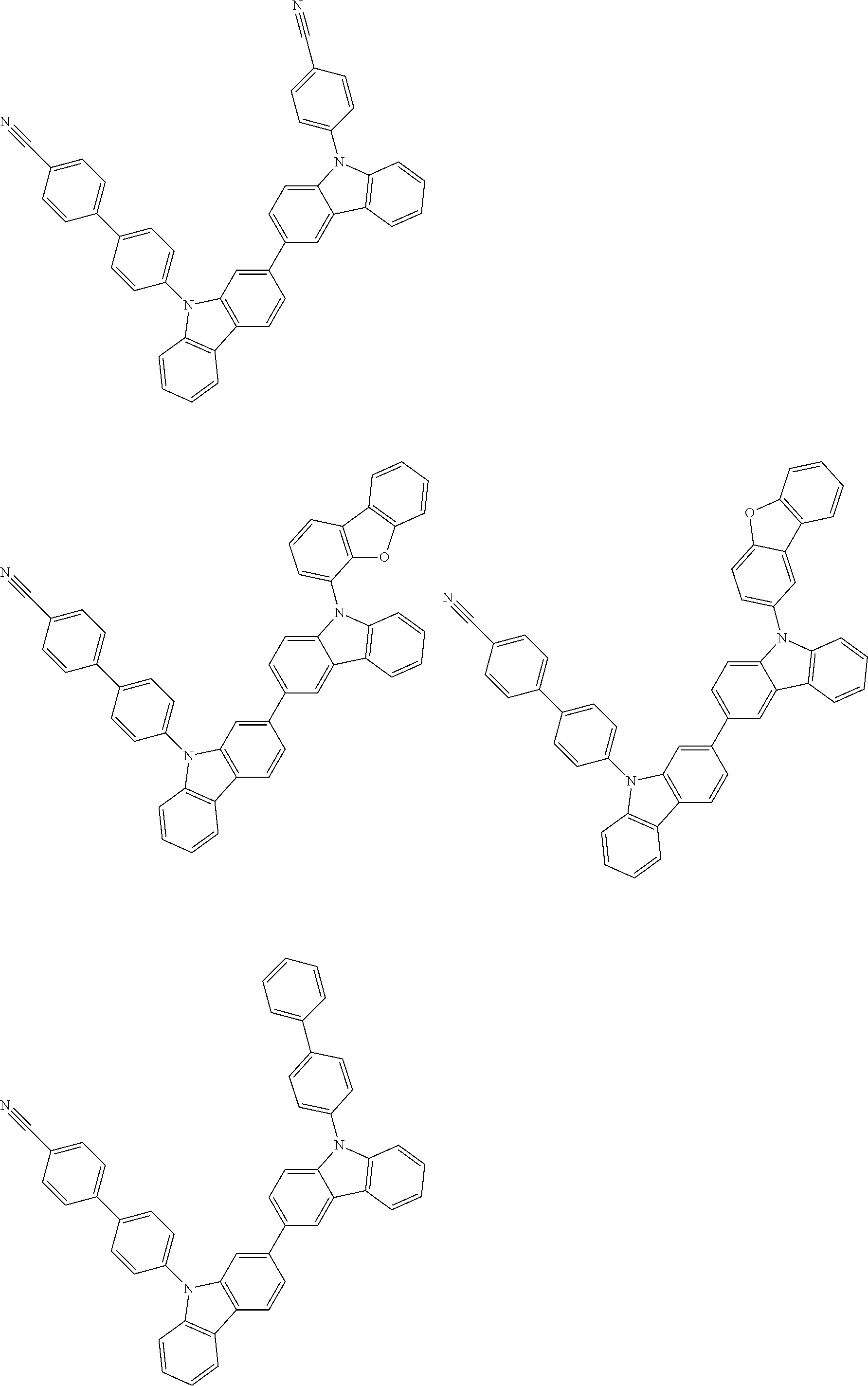

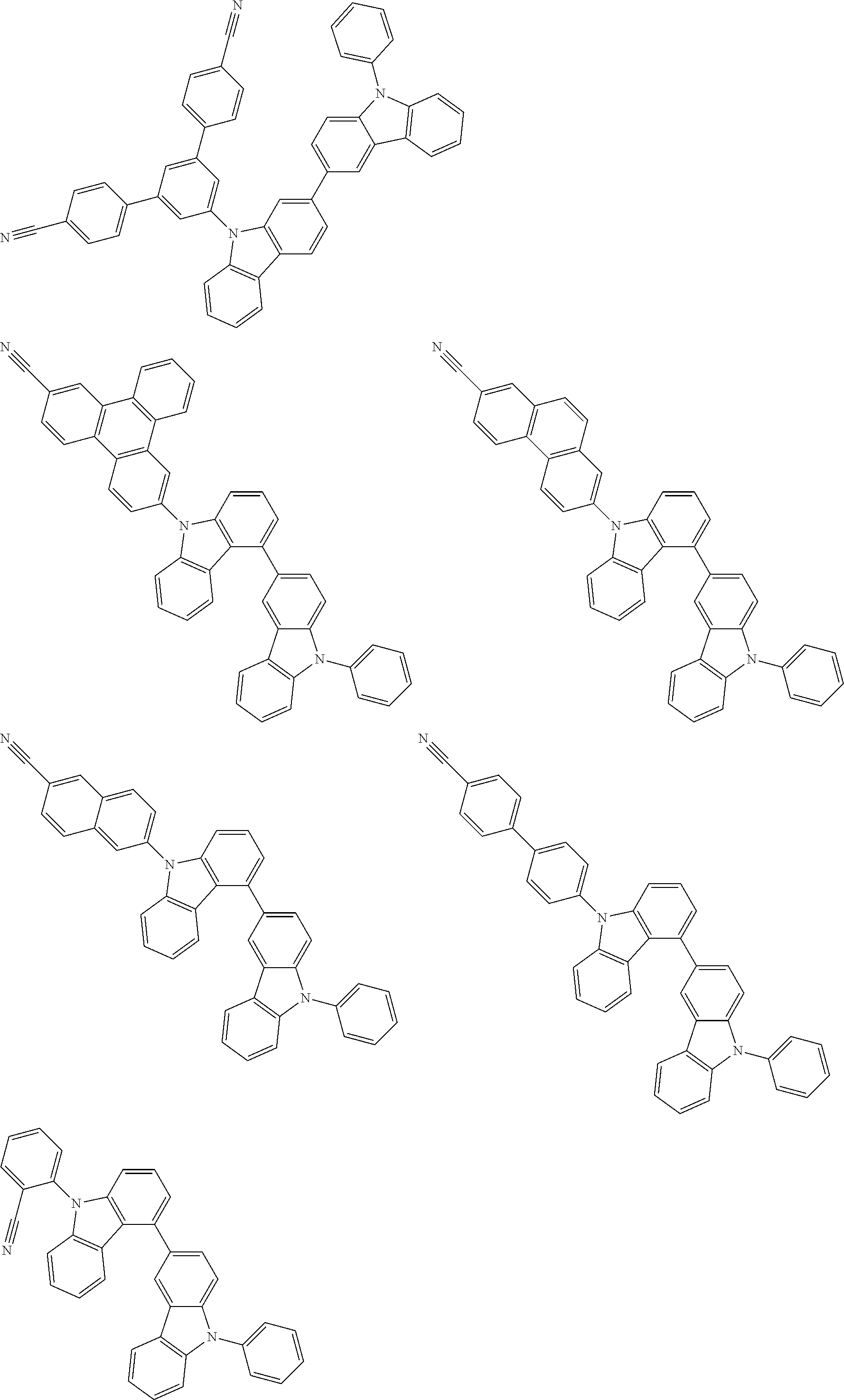 [SMILES: N#Cc1ccc(-c2cc(-c3ccc(C#N)cc3)cc(-n3c4ccccc4c4ccc(-c5ccc6c(c5)c5ccccc5n6-c5ccccc5)cc43)c2)cc1 ; N#Cc1ccc2c3ccc(-n4c5ccccc5c5c(-c6ccc7c(c6)c6ccccc6n7-c6ccccc6)cccc54)cc3c3ccccc3c2c1 ; N#Cc1ccc2c(ccc3cc(-n4c5ccccc5c5c(-c6ccc7c(c6)c6ccccc6n7-c6ccccc6)cccc54)ccc32)c1 ; N#Cc1ccc2cc(-n3c4ccccc4c4c(-c5ccc6c(c5)c5ccccc5n6-c5ccccc5)cccc43)ccc2c1 ; N#Cc1ccc(-c2ccc(-n3c4ccccc4c4c(-c5ccc6c(c5)c5ccccc5n6-c5ccccc5)cccc43)cc2)cc1 ; N#Cc1ccccc1-n1c2ccccc2c2c(-c3ccc4c(c3)c3ccccc3n4-c3ccccc3)cccc21]

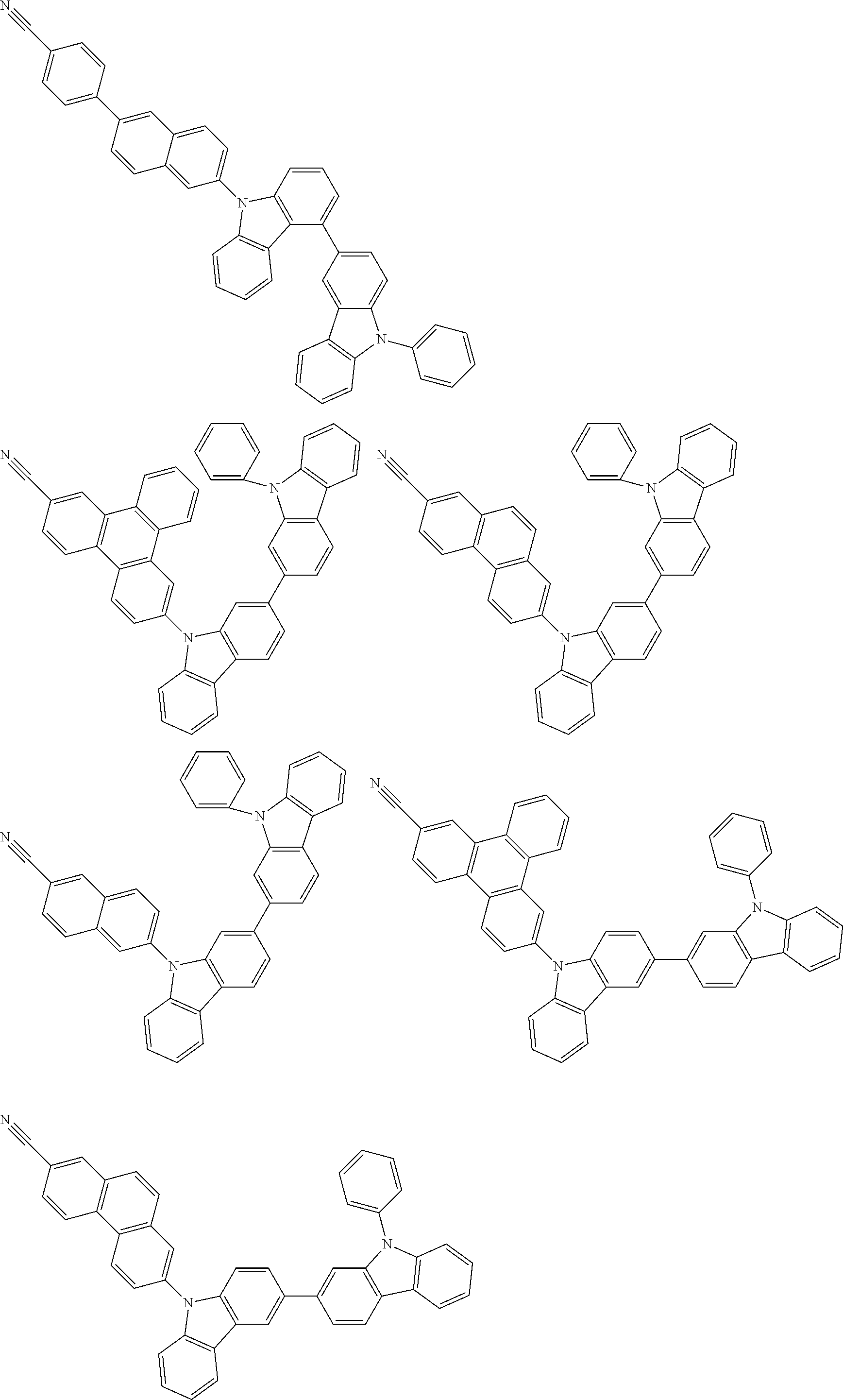

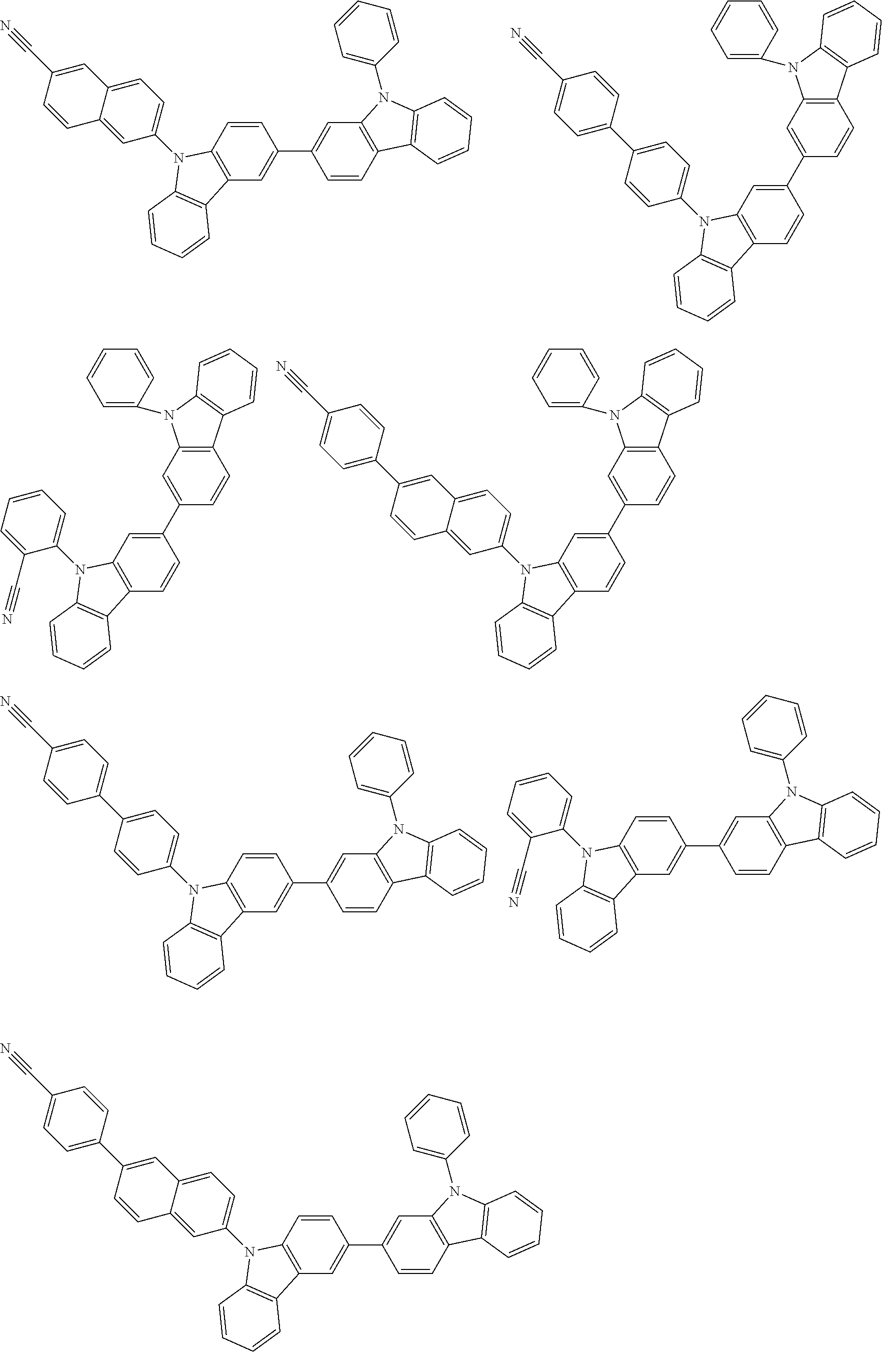

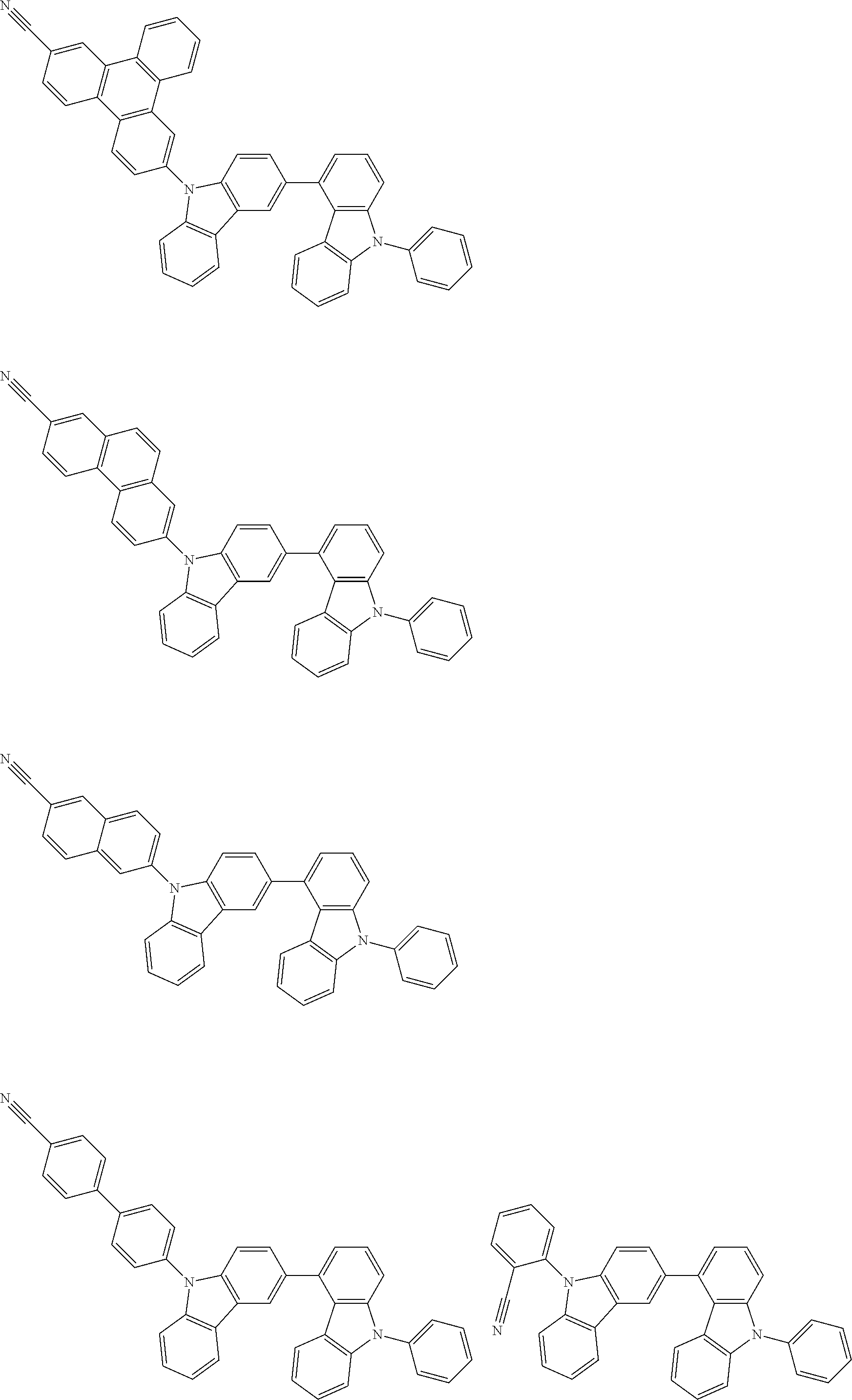

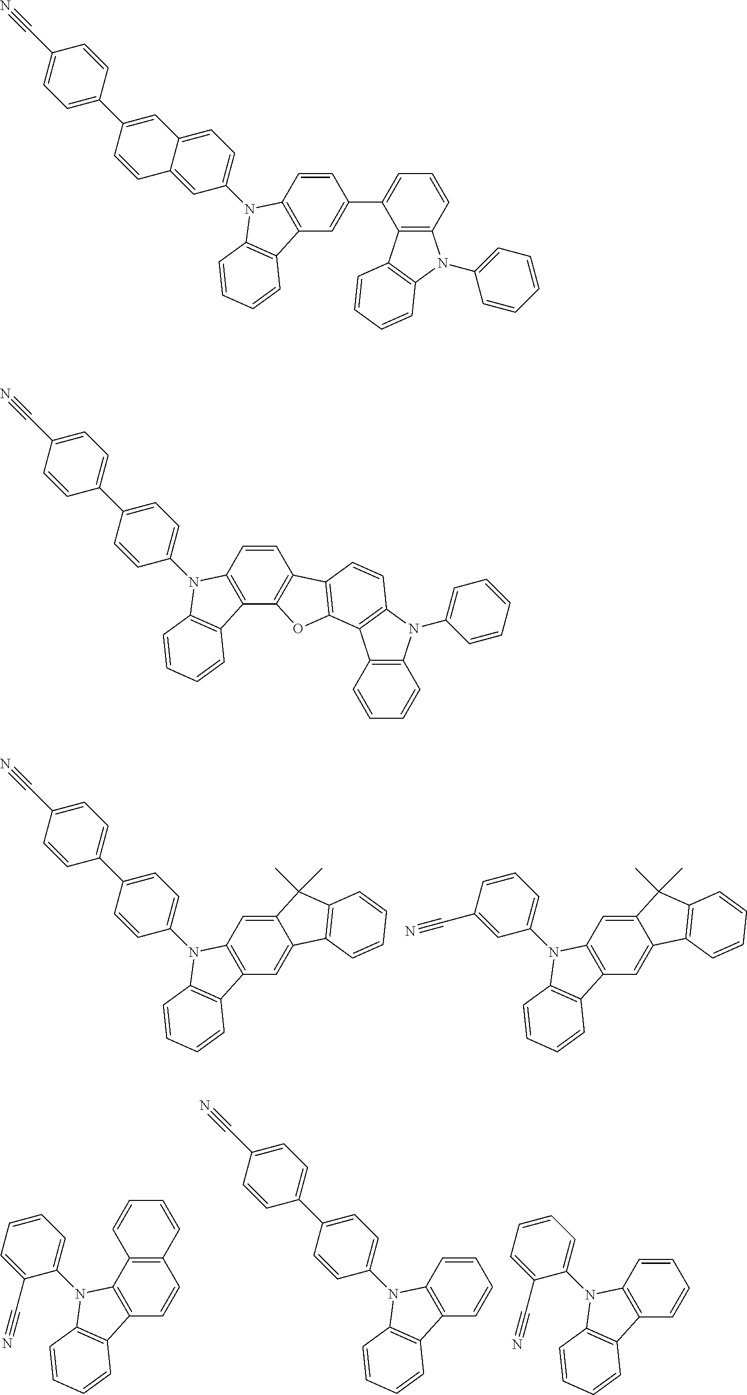

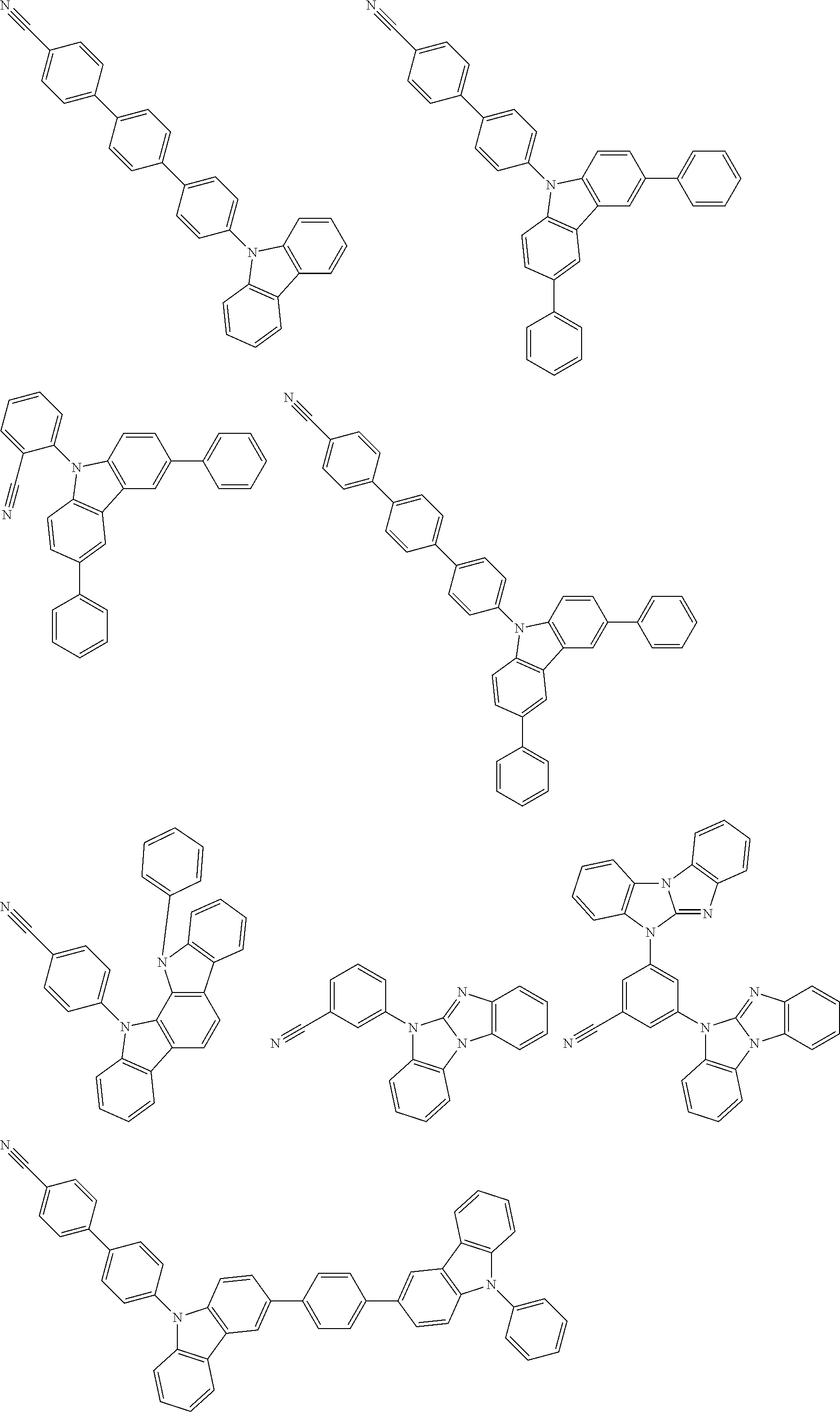

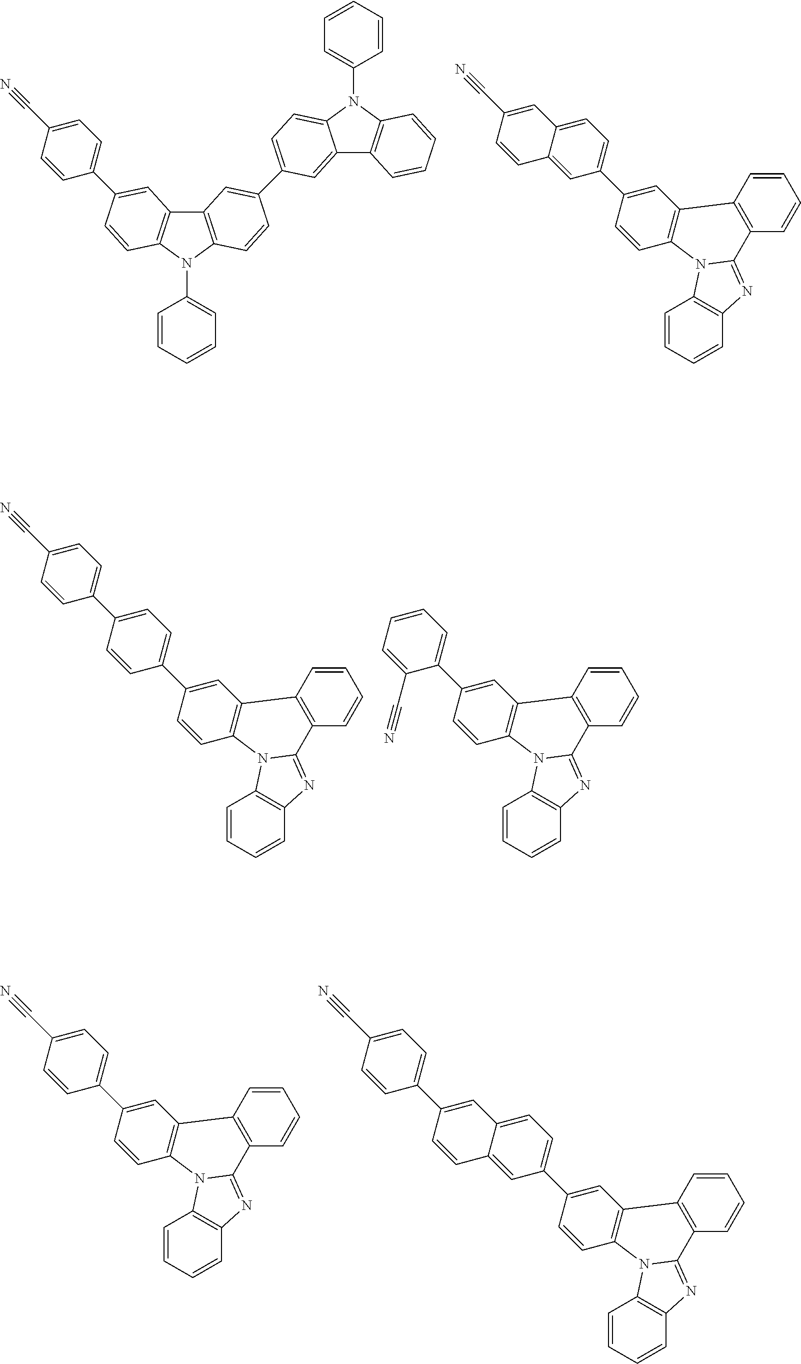

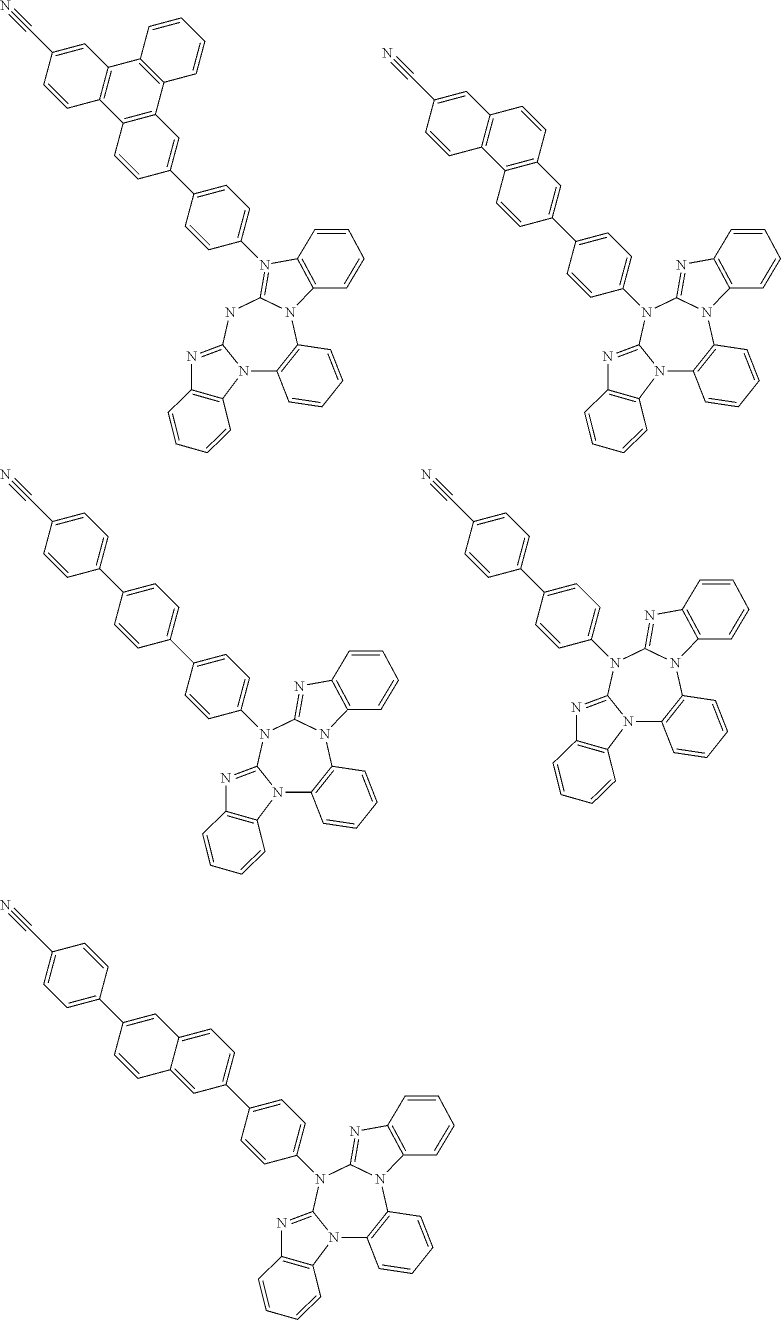

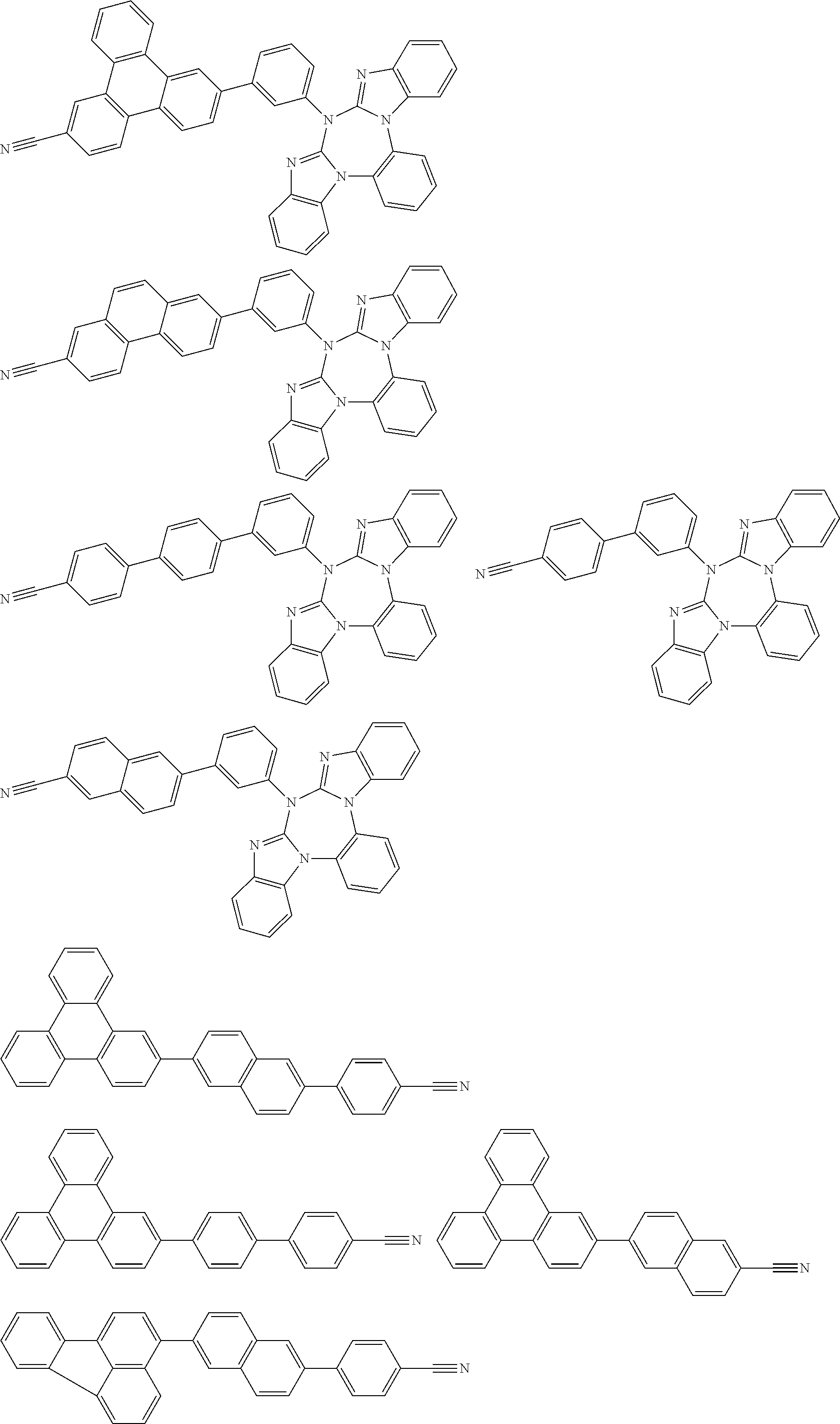

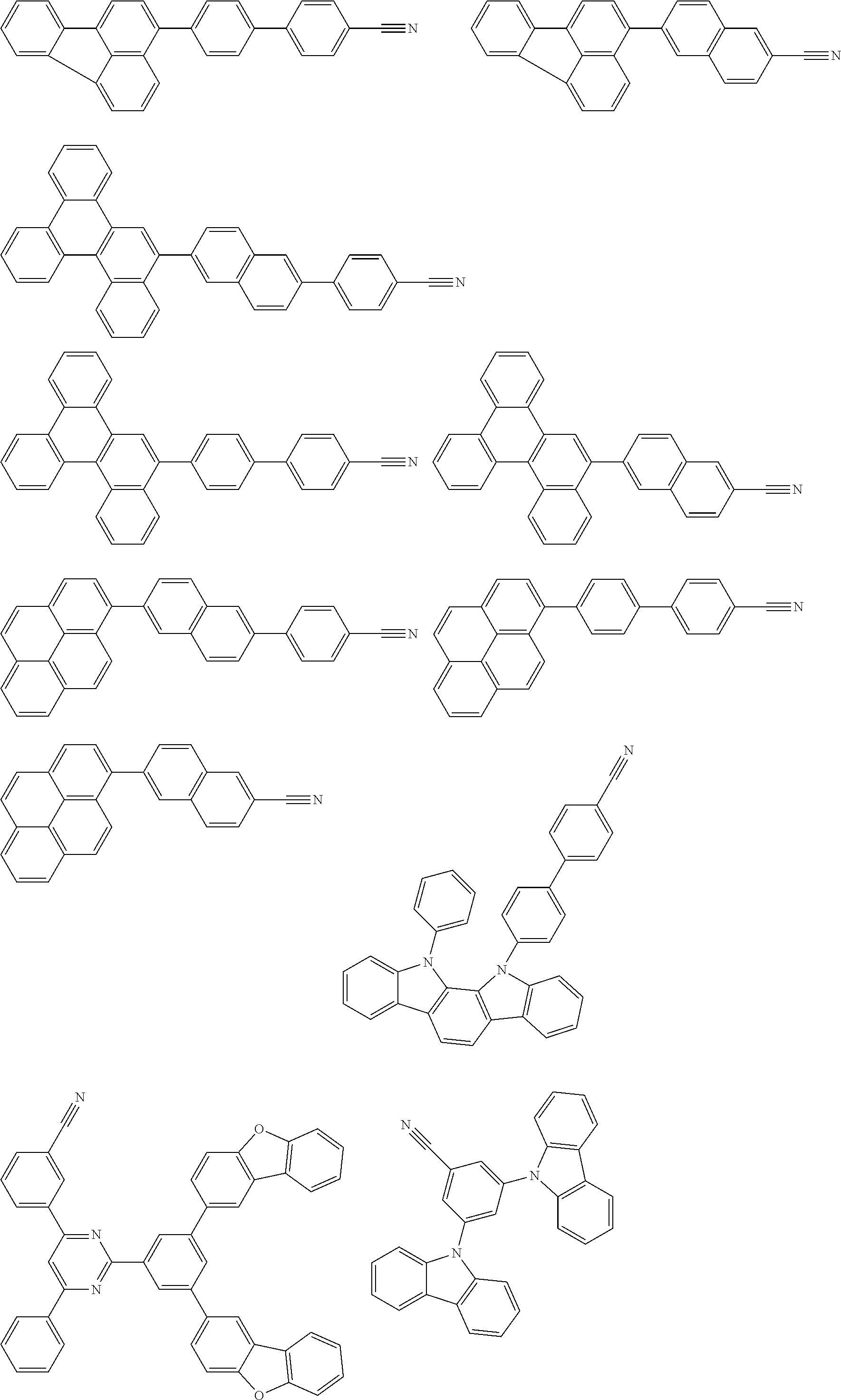

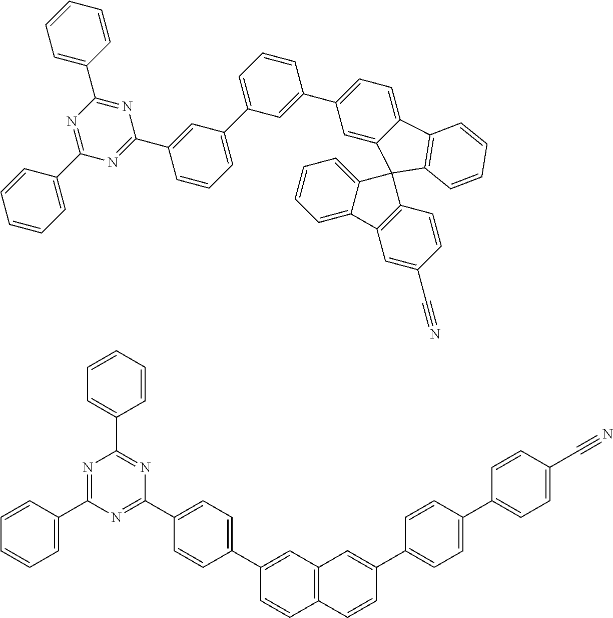 [SMILES: N#Cc1ccc2c(c1)-c1ccccc1C21c2ccccc2-c2ccc(-c3cccc(-c4cccc(-c5nc(-c6ccccc6)nc(-c6ccccc6)n5)c4)c3)cc21 ; N#Cc1ccc(-c2ccc(-c3ccc4ccc(-c5ccc(-c6nc(-c7ccccc7)nc(-c7ccccc7)n6)cc5)cc4c3)cc2)cc1]

The compound 2 is represented by formula (2):

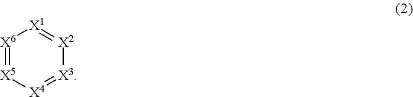

In formula (2),

X¹ is a nitrogen atom or CR¹;

X² is a nitrogen atom or CR²;

X³ is a nitrogen atom or CR³;

X⁴ is a nitrogen atom or CR⁴;

X⁵ is a nitrogen atom or CR⁵; and

X⁶ is a nitrogen atom or CR⁶;

provided that at least one of X¹ to X⁶ is a nitrogen atom.

Formula (2) is preferably represented by formula (2′):

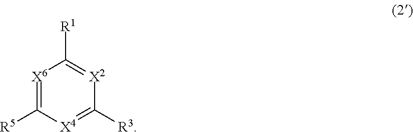

In a preferred embodiment of the invention, one of X², X⁴, and X⁶ is a nitrogen atom. In another preferred embodiment of the invention, two of X², X⁴, and X⁶ are nitrogen atoms. In another preferred embodiment of the invention, X², X⁴, and X⁶ are all nitrogen atoms.

Thus, formula (2′) is represented by, for example, any of formulae (2a) to (2c);

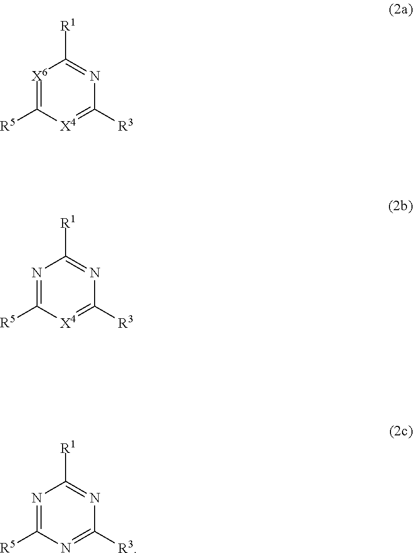

In a preferred embodiment of the invention, formula (2′) is represented by any of formulae (2a′), (2b′), and (20;

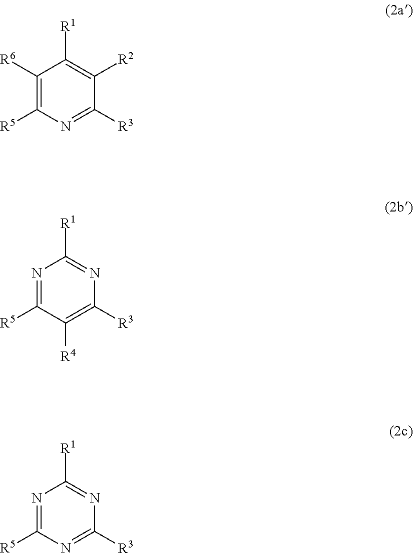

In formula (2), one to three selected from R¹ to R⁶ are each independently a group represented by any of formulae (3) to (6) and the others of R¹ to R⁶ are each independently a hydrogen atom or a substituent, preferably a hydrogen atom.

Adjacent two selected from R¹ to R⁶ are optionally bonded to each other to form a ring together with two ring carbon atoms to which the adjacent two are bonded, wherein the ring is a substituted or unsubstituted fused aromatic hydrocarbon ring having 10 to 30 ring carbon atoms, a substituted or unsubstituted non-fused aromatic hydrocarbon ring, a substituted or unsubstituted fused aromatic heterocyclic ring having 9 to 30 ring atoms, or a substituted or unsubstituted non-fused aromatic heterocyclic ring having 5 or 6 ring atoms.

Examples of the fused aromatic hydrocarbon ring include an indene ring, a naphthalene ring, and an anthracene ring; example of the non-fused aromatic hydrocarbon ring includes a benzene ring; examples of the fused aromatic heterocyclic ring include a quinoline ring, a benzofuran ring, a benzothiophene ring, an azabenzofuran ring, an azabenzothiophene ring, and an azaindene ring; and examples of the non-fused aromatic heterocyclic ring include a pyrrole ring, an imidazole ring, a pyrazole ring, a triazole ring, a furan ring, a thiophene ring, a thiazole ring, an isothiazole ring, an oxazole ring, an isoxazole ring, an oxadiazole ring, a thiadiazole ring, a pyridine ring, a pyrazine ring, a pyridazine ring, a pyrimidine ring, and a triazine ring.

In a preferred embodiment of the invention, the compound of formula (2) wherein adjacent two selected from R¹ to R⁶ are bonded to each other to form a ring together with two ring carbon atoms to which the adjacent two are bonded, i.e., a fused azine compound, is represented by, for example, any of the following formulae:

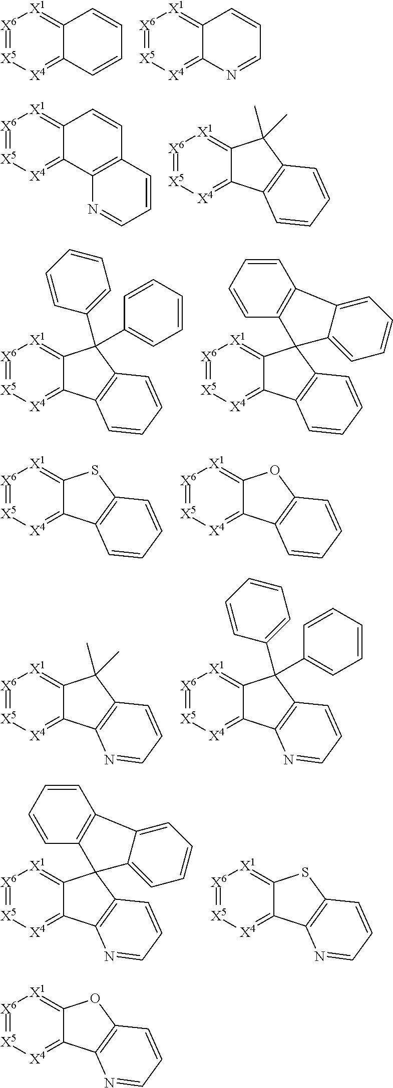

wherein the ring formed by the adjacent two selected from R¹ to R⁶ which are bonded to each other and two ring carbon atoms to which the adjacent two are bonded may have a substituent.

In another preferred embodiment of the invention, the fused azine compound is represented by, for example, any of the following formulae.

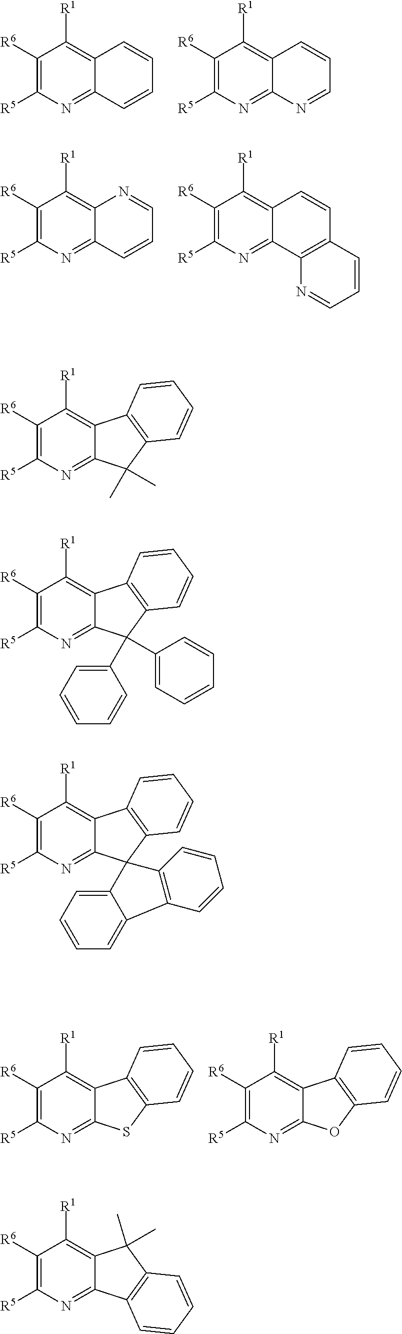

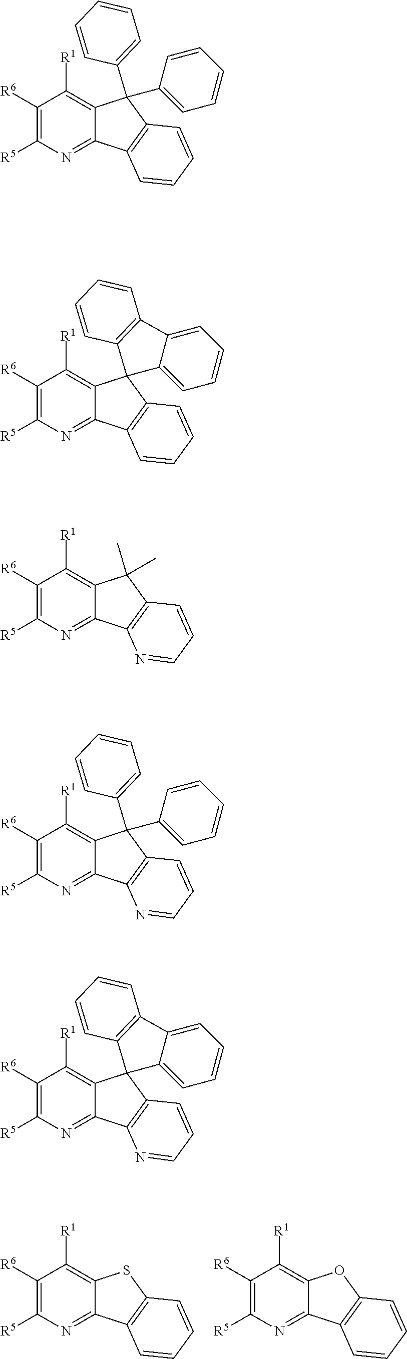

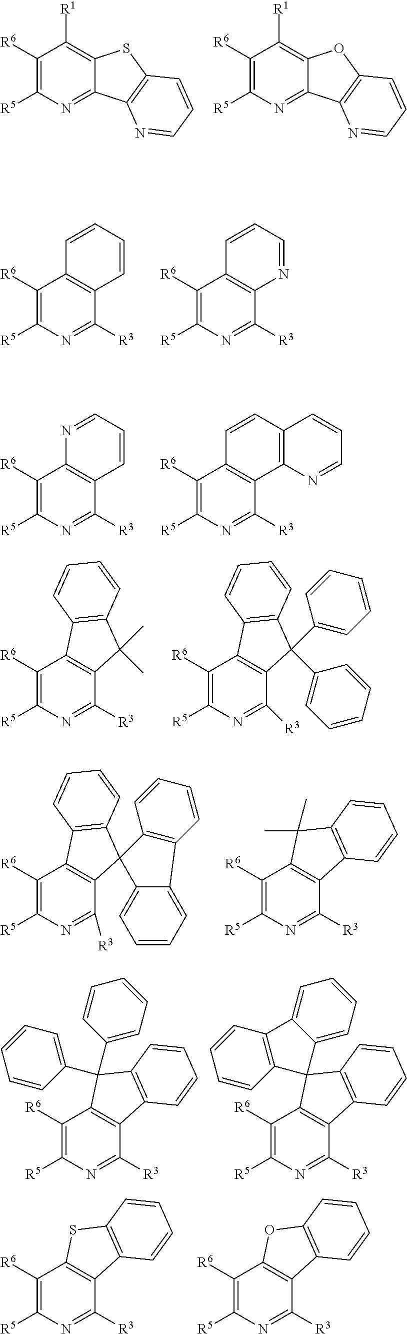

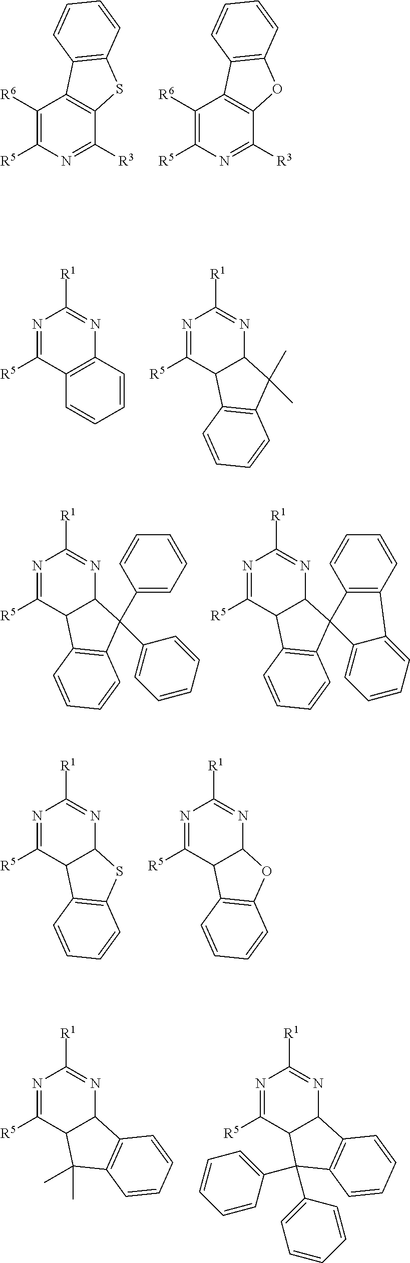

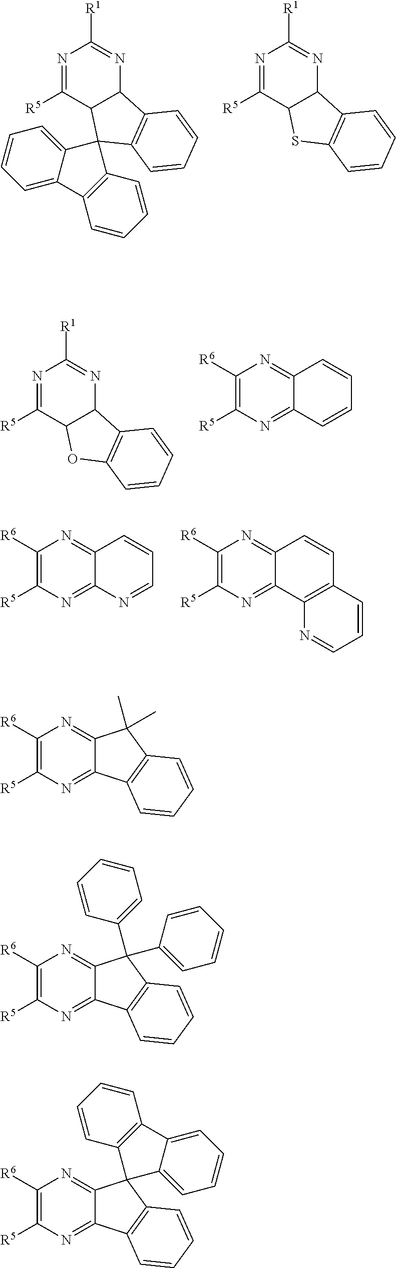

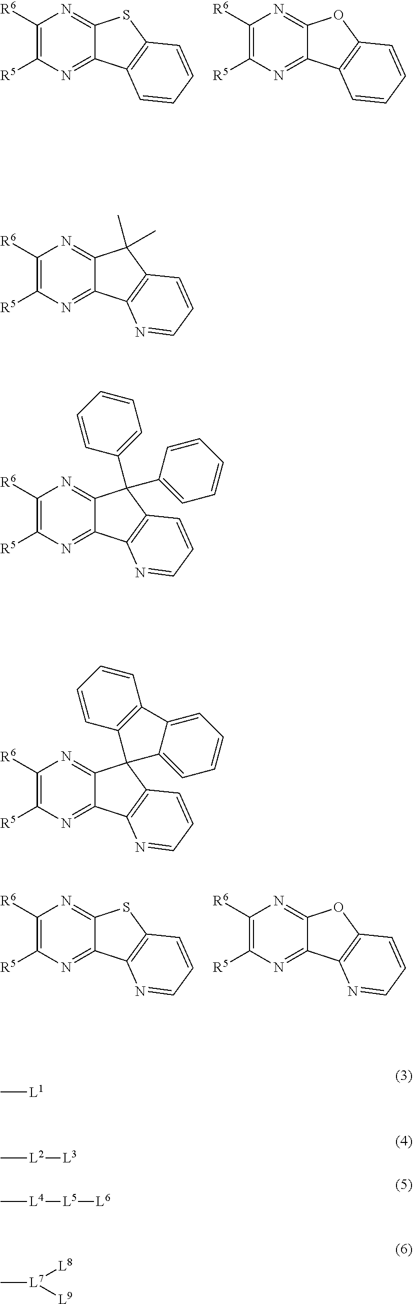

In formulae (3) to (6),

each of L¹, L³, L⁶, L⁸, and L⁹ is independently a substituted or unsubstituted fused aryl group having 10 to 30 ring carbon atoms, a substituted or unsubstituted non-fused aryl group having 6 to 30, preferably 6 to 18 ring carbon atoms, a substituted or unsubstituted fused heteroaryl group having 9 to 32, preferably 9 to 30 ring atoms, or a substituted or unsubstituted non-fused heteroaryl group having 5 to 30, preferably 5 to 18 ring carbon atoms.

The fused aryl group of the substituted or unsubstituted fused aryl group having 10 to 30 ring carbon atoms comprises 2 to 6, preferably 4 to 6 fused rings and is a monovalent residue of a fused aromatic ring selected from, for example, naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, benzofluoranthene, perylene, triphenylene, benzotriphenylene, and spirofluorene.

In a preferred embodiment of the invention, the fused aryl group is a monovalent residue of a fused aromatic ring selected from naphthalene, phenanthrene, triphenylene, benzochrysene, fluoranthene, pyrene, fluorene, spirofluorene, 9,9-dimethylfluorene, and 9,9-diphenylfluorene.

In another preferred embodiment of the invention, the substituted or unsubstituted fused aryl group having 10 to 30 ring carbon atoms is represented by any of the following formulae:

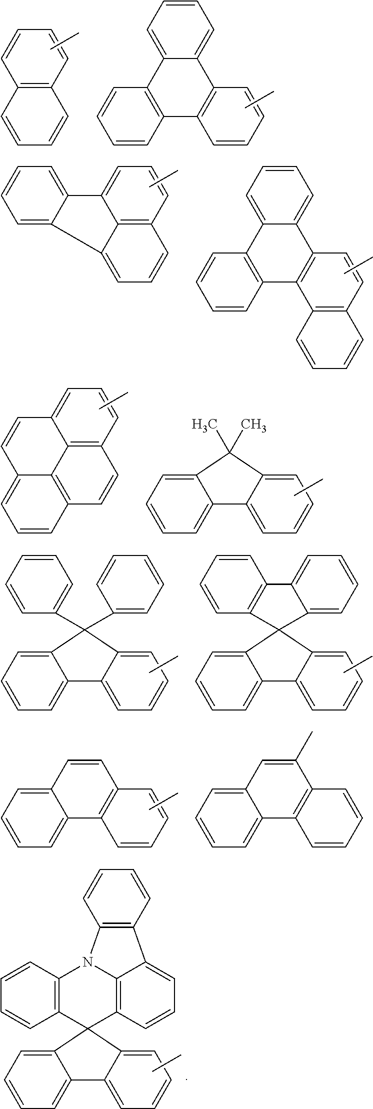

In another preferred embodiment of the invention, the substituted or unsubstituted fused aryl group having 10 to 30 ring carbon atoms is represented by any of the following formulae:

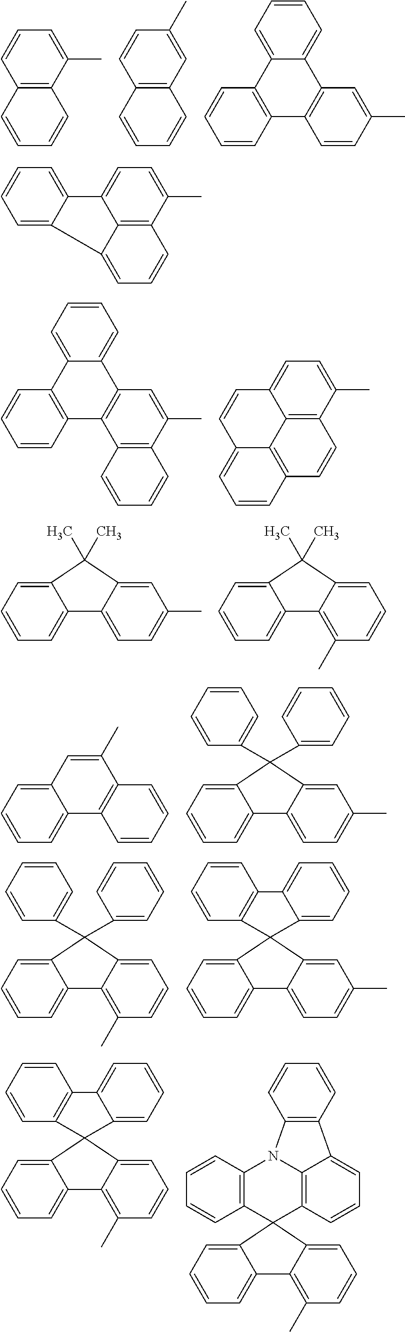

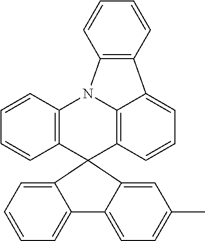 [SMILES: Cc1ccc2c(c1)C1(c3ccccc3-2)c2ccccc2-n2c3ccccc3c3cccc1c32]

The non-fused aryl group of the substituted or unsubstituted non-fused aryl group having 6 to 30, preferably 6 to 18 ring carbon atoms is a monovalent residue of a single ring or a ring assembly which are selected from, for example, benzene, biphenyl, terphenyl (inclusive of isomers), and quaterphenyl (inclusive of isomers).

The non-fused aryl group is preferably a phenyl group, a biphenylyl group, or a terphenylyl group and more preferably a phenyl group.

The fused heteroaryl group of the substituted or unsubstituted fused heteroaryl group having 9 to 32, preferably 9 to 30 ring atoms comprises 2 to 6, preferably 3 to 5 fused rings and 1 to 5, preferably 1 to 3, and more preferably 1 to 2 ring heteroatoms, such as a nitrogen atom, a sulfur atom, and an oxygen atom.

The fused heteroaryl group is a monovalent residue derived from a fused heterocyclic ring by removing one hydrogen atom on a ring carbon atom or a ring nitrogen atom, wherein the fused heterocyclic ring is selected from indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene.

In a preferred embodiment of the invention, the fused heteroaryl group is selected from a N-carbazolyl group, a C-carbazolyl group, a dibenzofuranyl group, a dibenzothiophenyl group (dibenzothienyl group), a xanthenyl group, a phenanthrolinyl group, and a quinolinyl group.

In another preferred embodiment of the invention, the fused heteroaryl group is represented by any of the following formulae:

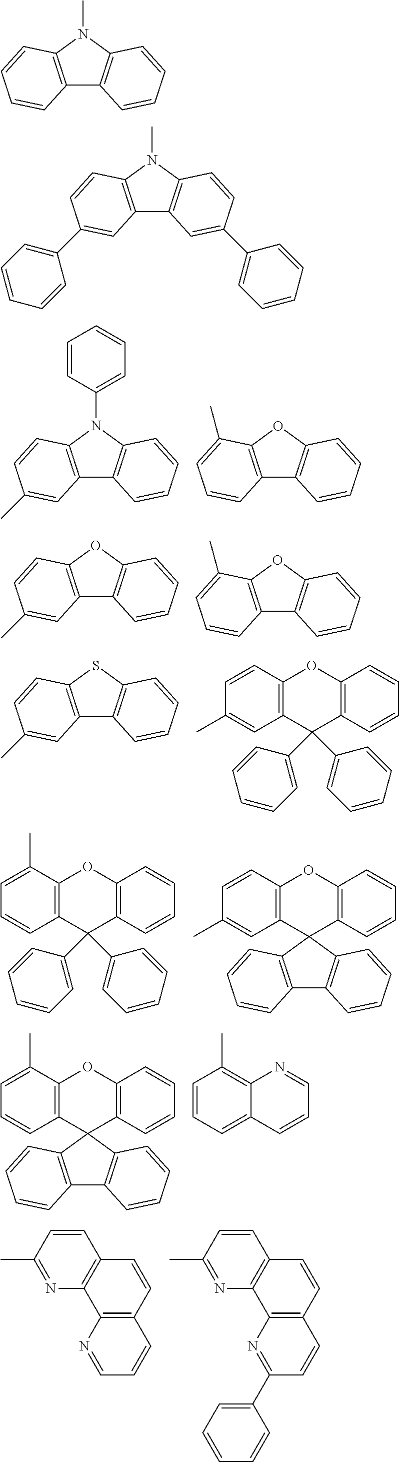

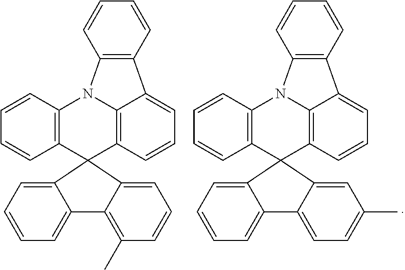

The non-fused heteroaryl group of the substituted or unsubstituted non-fused heteroaryl group having 5 to 30, preferably 5 to 18 ring carbon atoms comprises 1 to 5, preferably 1 to 3, and more preferably 1 to 2 ring heteroatoms, such as a nitrogen atom, a sulfur atom, and an oxygen atom.

The non-fused heteroaryl group is a monovalent residue derived from a single ring or a ring assembly by removing one hydrogen atom on a carbon atom or a nitrogen atom, wherein the single ring and the ring assembly are selected from, for example, pyrrole, imidazole, imidazoline, pyrazole, triazole, furan, thiophene, thiazole, isothiazole, oxazole, isoxazole, oxadiazole, thiadiazole, pyridine, pyrazine, pyridazine, pyrimidine, triazine, bipyrrole, terpyrrole, bithiophene, terthiophene, bipyridine, and terpyridine.

In a preferred embodiment of the invention, the non-fused heteroaryl group is a residue of pyridine, pyrazine, pyridazine, pyrimidine, triazine, or bipyridine.

In another preferred embodiment of the invention, the non-fused heteroaryl group is, for example, a 2-, 3-, or 4-pyridyl group.

Each of L², L⁴, and L⁵ of formulae (4) and (5) is independently a substituted or unsubstituted fused arylene group having 10 to 30 ring carbon atoms, a substituted or unsubstituted non-fused arylene group having 6 to 30, preferably 6 to 18 ring carbon atoms, a substituted or unsubstituted fused heteroarylene group having 9 to 30 ring atoms, or a substituted or unsubstituted non-fused heteroarylene group having 5 to 30, preferably 5 to 18 ring carbon atoms.

The fused arylene group of the substituted or unsubstituted fused arylene group having 10 to 30 ring carbon atoms comprises 2 to 6, preferably 2 to 4, and more preferably 2 fused rings and is a divalent residue of a fused aromatic ring which is selected from, for example, naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, triphenylene, 9,9-dimethylfluorene, 9,9-diphenylfluorene, spirofluorene, and benzofluoranthene.

In a preferred embodiment of the invention, the fused arylene group is a divalent residue of a fused aromatic ring selected from naphthalene, 9,9-dimethylfluorene, 9,9-diphenylfluorene, spirofluorene, and anthracene.

The non-fused arylene group of the substituted or unsubstituted non-fused arylene group having 6 to 30 ring carbon atoms is a divalent residue of a single ring or a ring assembly which is selected from, for example, benzene, biphenyl, terphenyl (inclusive of isomers), and quaterphenyl (inclusive of isomers).

In a preferred embodiment of the invention, the divalent residue is represented by any of the following formulae:

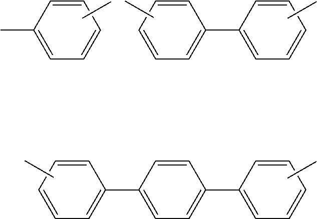

wherein one of two free bonds is bonded to a ring carbon atom of formula (2) and the other is bonded to L³, L⁵, or L⁶.

The fused heteroarylene group of the substituted or unsubstituted fused heteroarylene group having 9 to 30 ring atoms comprises 2 to 6, preferably 3 to 5 fused rings and 1 to 5, preferably 1 to 3, and more preferably 1 to 2 ring heteroatoms, such as a nitrogen atom, a sulfur atom, and an oxygen atom.

Example of the fused heteroarylene group include a divalent residue derived from a fused heterocyclic ring by removing two hydrogen atoms on a ring carbon atom and/or a ring nitrogen atom, wherein the fused heterocyclic ring is selected from, for example, indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene.

In a preferred embodiment of the invention, the fused heteroarylene group is a divalent residue of a fused heterocyclic ring selected from dibenzofuran, dibenzothiophene, and carbazole.

The non-fused heteroarylene group of the substituted or unsubstituted non-fused heteroarylene group having 5 to 30, preferably 5 to 18 ring carbon atoms comprises 1 to 5, preferably 1 to 3, and more preferably 1 to 2 ring heteroatoms, such as a nitrogen atom, a sulfur atom, and an oxygen atom.

The non-fused heteroarylene group is a divalent residue derived from a single ring or a ring assembly by removing two hydrogen atoms on a carbon atom and/or nitrogen atom, wherein the single ring or the ring assembly is selected from, for example, pyrrole, imidazole, pyrazole, triazole, furan, thiophene, thiazole, isothiazole, oxazole, oxazoline, isoxazole, oxadiazole, thiadiazole, pyridine, pyrazine, pyridazine, pyrimidine, triazine, bipyrrole, terpyrrole, bithiophene, terthiophene, bipyridine, and terpyridine.

In a preferred embodiment of the invention, the non-fused heteroarylene group is a divalent residue of pyridine.

In a preferred embodiment of the invention, each of L², L⁴, and L⁵ is selected from a phenylene group, a biphenylene group, a carbazole-N,2-diyl group, or a carbazole-N,3-diyl group.

L⁷ of formula (6) is a trivalent residue of a fused aromatic hydrocarbon ring having 10 to 30 ring carbon atoms, a non-fused aromatic hydrocarbon ring, a fused aromatic heterocyclic ring having 9 to 30 ring atoms, or a non-fused aromatic heterocyclic ring having 5 or 6 ring atoms. The trivalent residue may have a substituent other than L⁸ and L⁹ or not.

In a preferred embodiment of the invention, the fused aromatic hydrocarbon ring is an indene ring, a naphthalene ring, or an anthracene ring; the non-fused aromatic hydrocarbon ring is a benzene ring; the fused aromatic heterocyclic ring is a quinoline ring, a benzofuran ring, or a benzothiophene ring; and the non-fused aromatic heterocyclic ring is a pyridine ring, a pyrazine ring, a pyridazine ring, a pyrimidine ring, or a triazine ring.

L⁷ of formula (6) is preferably a trivalent residue of benzene and more preferably a benzene-1,3,5-triyl group.

Examples of the compound 2 are shown below, although not limited thereto.

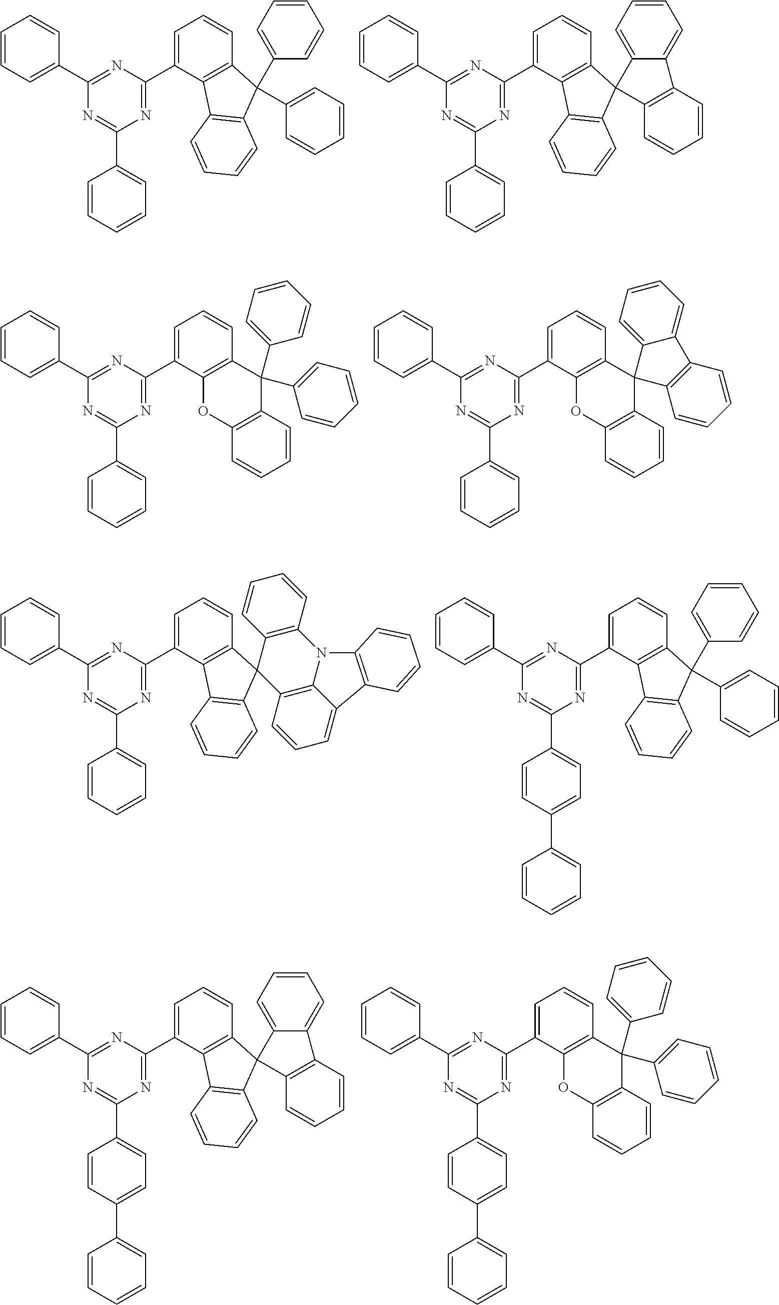

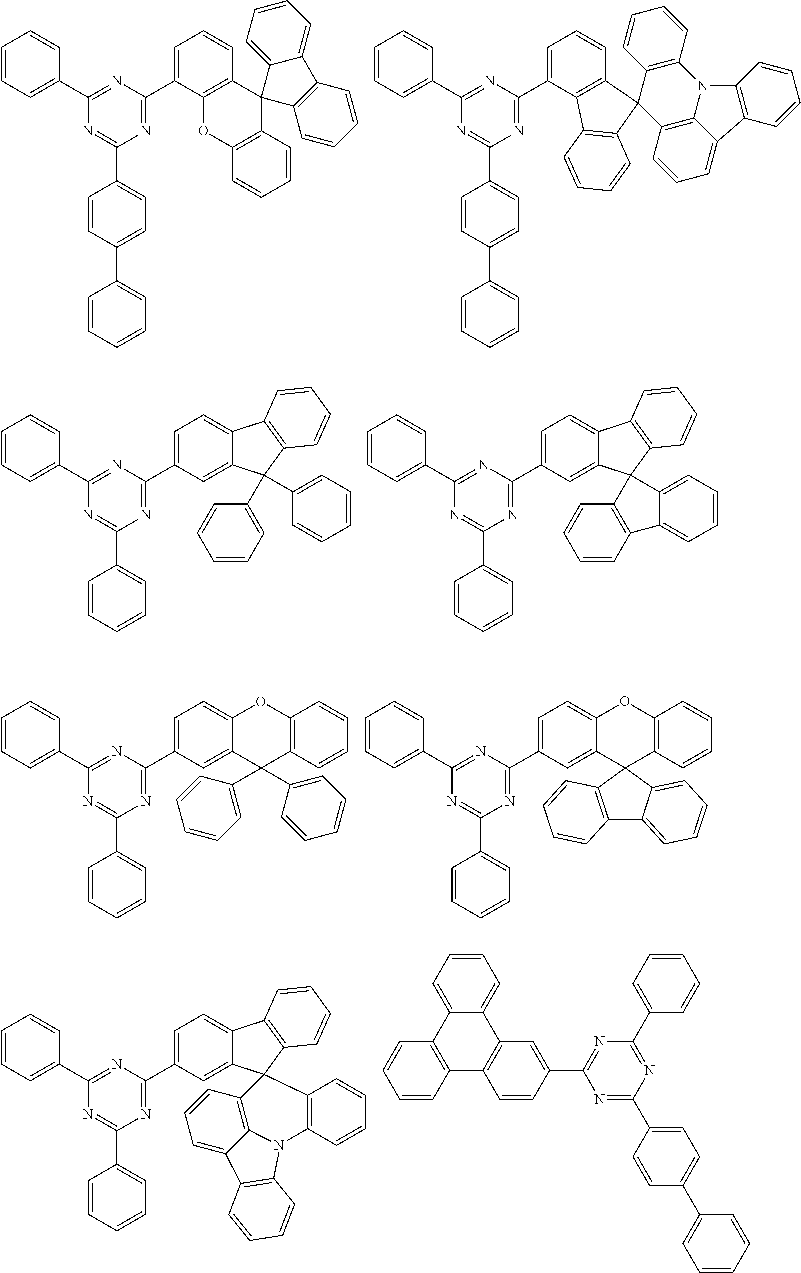

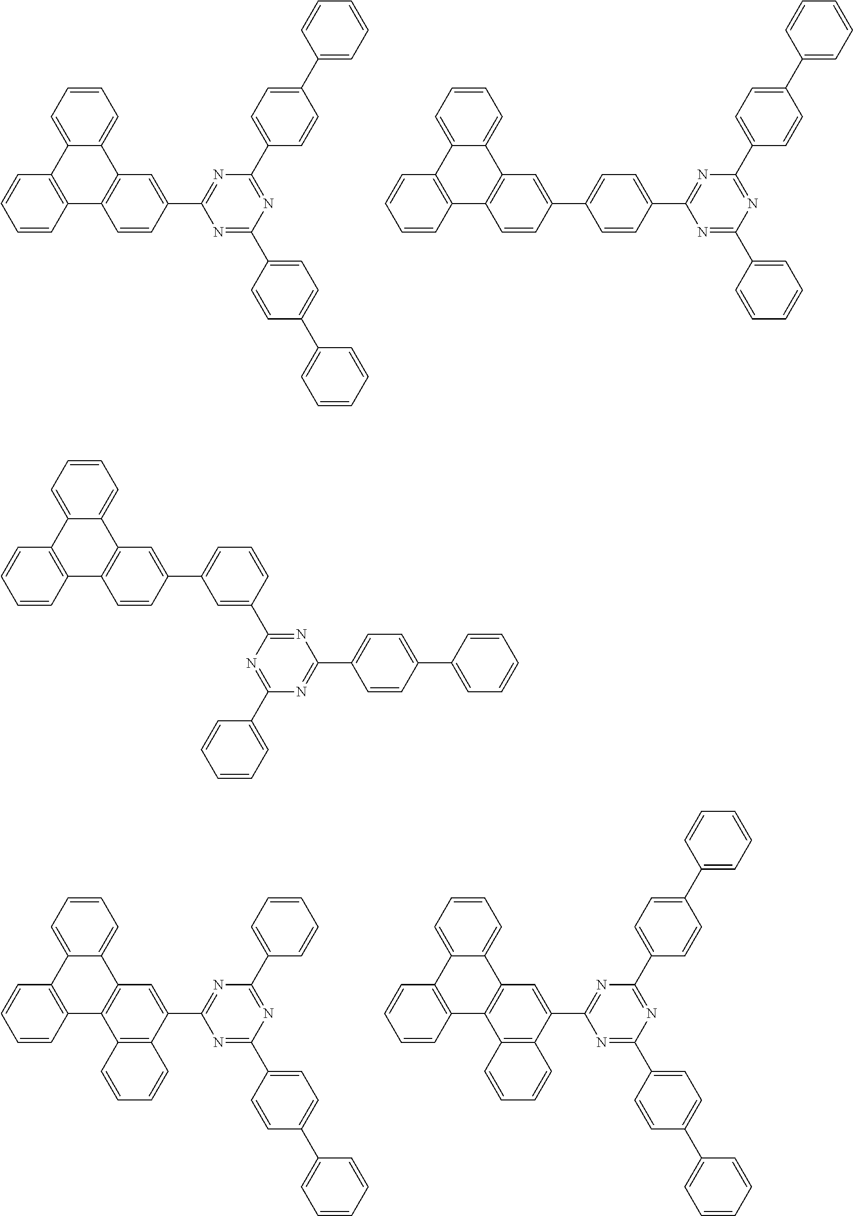 [SMILES: c1ccc(-c2ccc(-c3nc(-c4ccc(-c5ccccc5)cc4)nc(-c4ccc5c6ccccc6c6ccccc6c5c4)n3)cc2)cc1 ; c1ccc(-c2ccc(-c3nc(-c4ccccc4)nc(-c4ccc(-c5ccc6c7ccccc7c7ccccc7c6c5)cc4)n3)cc2)cc1 ; c1ccc(-c2ccc(-c3nc(-c4ccccc4)nc(-c4cccc(-c5ccc6c7ccccc7c7ccccc7c6c5)c4)n3)cc2)cc1 ; c1ccc(-c2ccc(-c3nc(-c4ccccc4)nc(-c4cc5c6ccccc6c6ccccc6c5c5ccccc45)n3)cc2)cc1 ; c1ccc(-c2ccc(-c3nc(-c4ccc(-c5ccccc5)cc4)nc(-c4cc5c6ccccc6c6ccccc6c5c5ccccc45)n3)cc2)cc1]

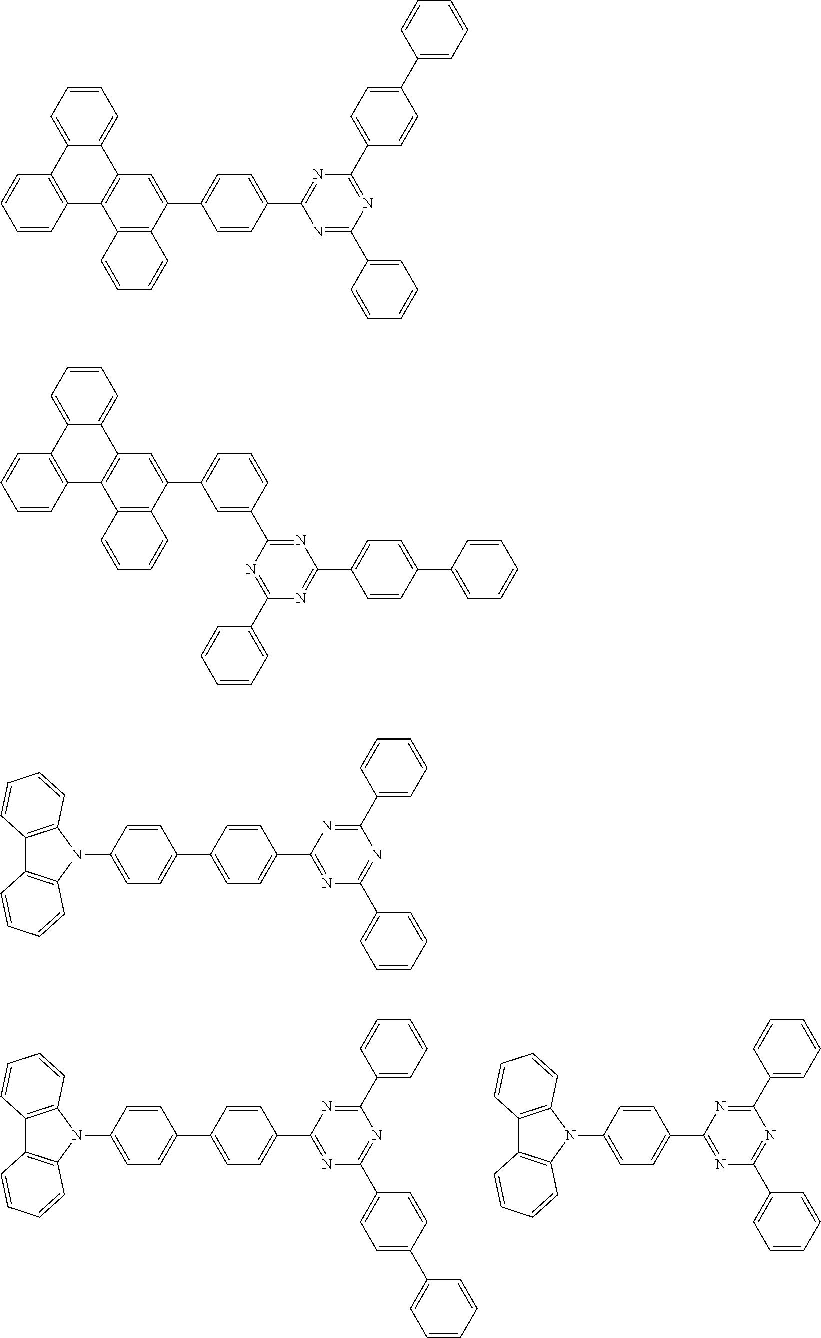 [SMILES: c1ccc(-c2ccc(-c3nc(-c4ccccc4)nc(-c4ccc(-c5cc6c7ccccc7c7ccccc7c6c6ccccc56)cc4)n3)cc2)cc1 ; c1ccc(-c2ccc(-c3nc(-c4ccccc4)nc(-c4cccc(-c5cc6c7ccccc7c7ccccc7c6c6ccccc56)c4)n3)cc2)cc1 ; c1ccc(-c2nc(-c3ccccc3)nc(-c3ccc(-c4ccc(-n5c6ccccc6c6ccccc65)cc4)cc3)n2)cc1 ; c1ccc(-c2ccc(-c3nc(-c4ccccc4)nc(-c4ccc(-c5ccc(-n6c7ccccc7c7ccccc76)cc5)cc4)n3)cc2)cc1 ; c1ccc(-c2nc(-c3ccccc3)nc(-c3ccc(-n4c5ccccc5c5ccccc54)cc3)n2)cc1]

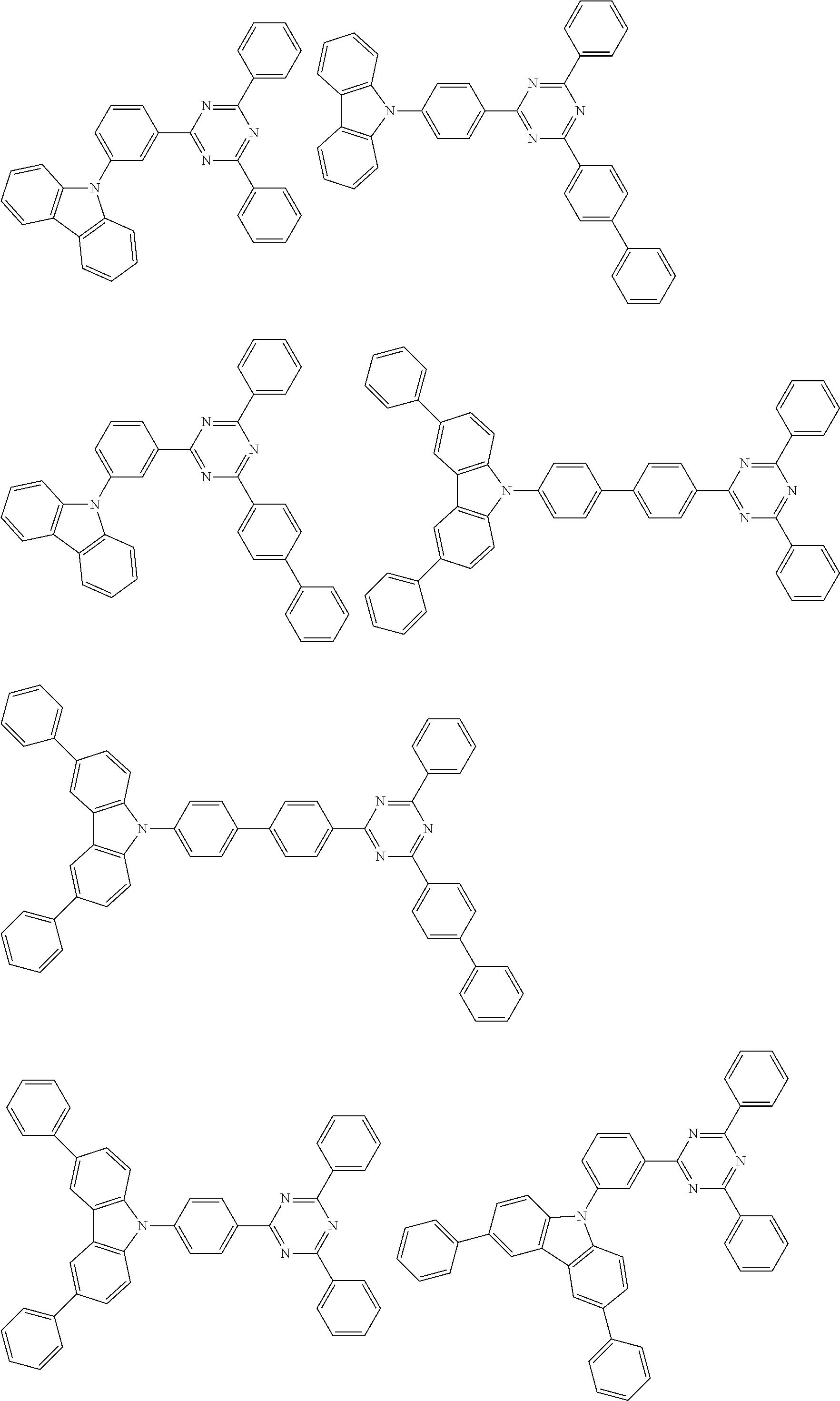

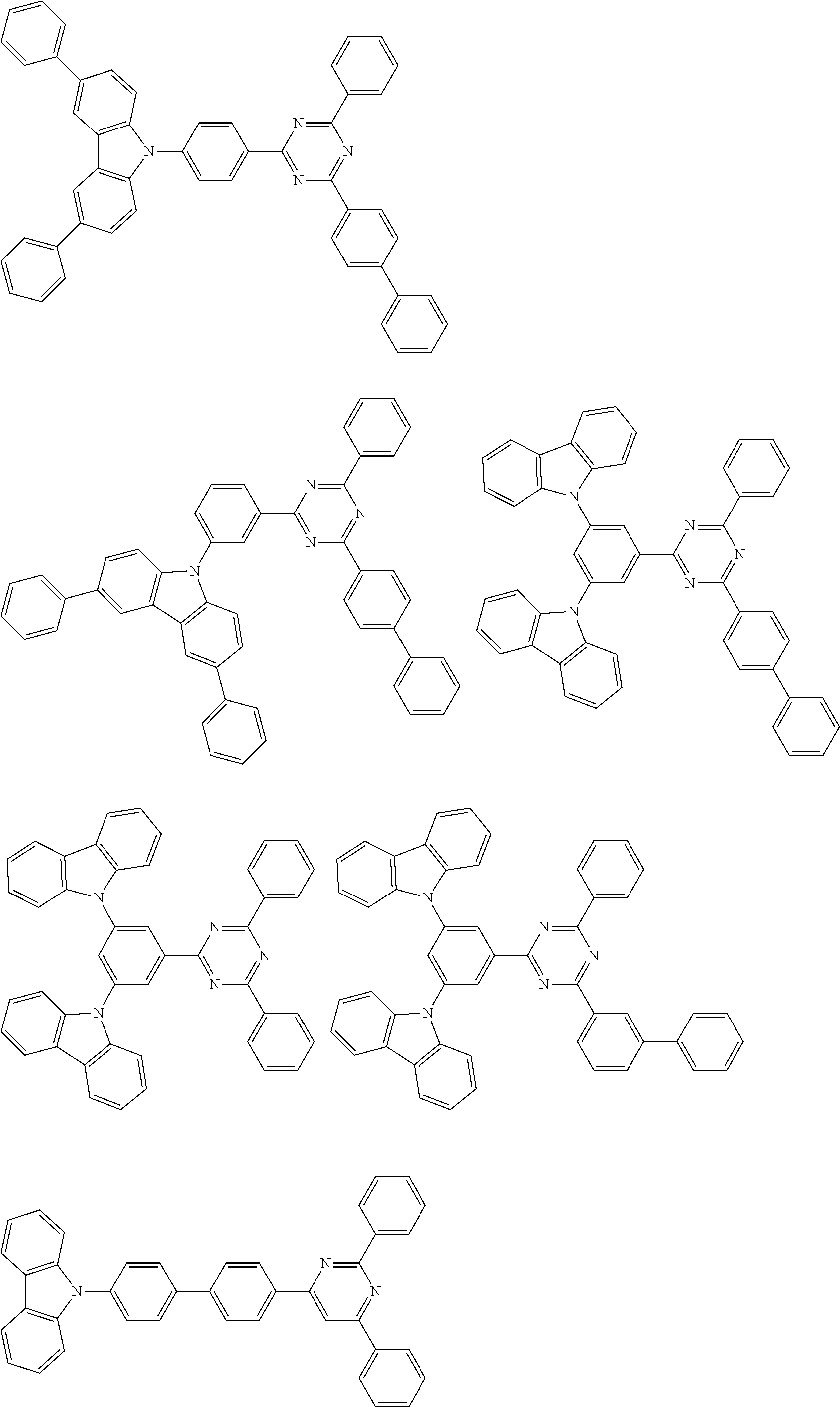

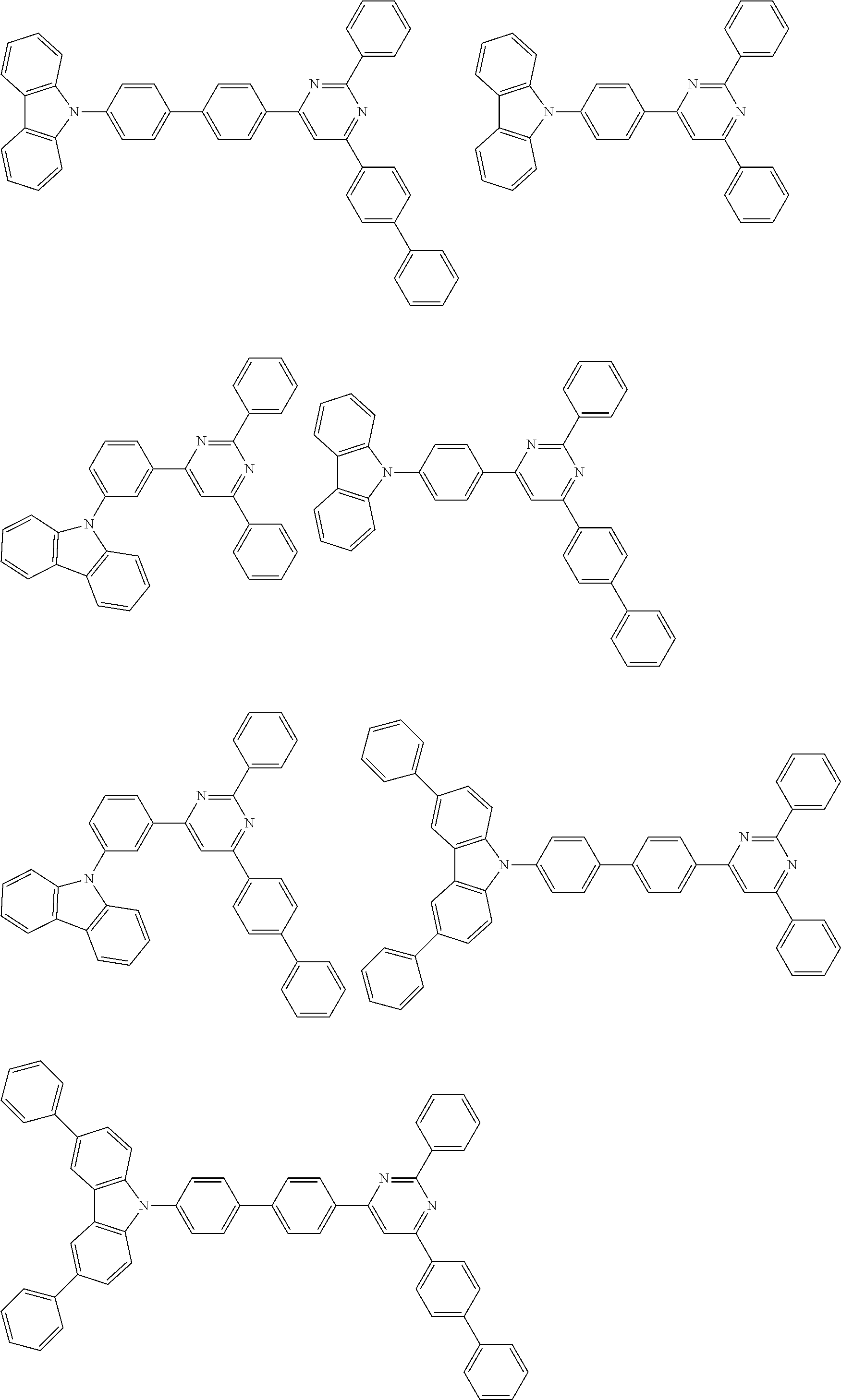

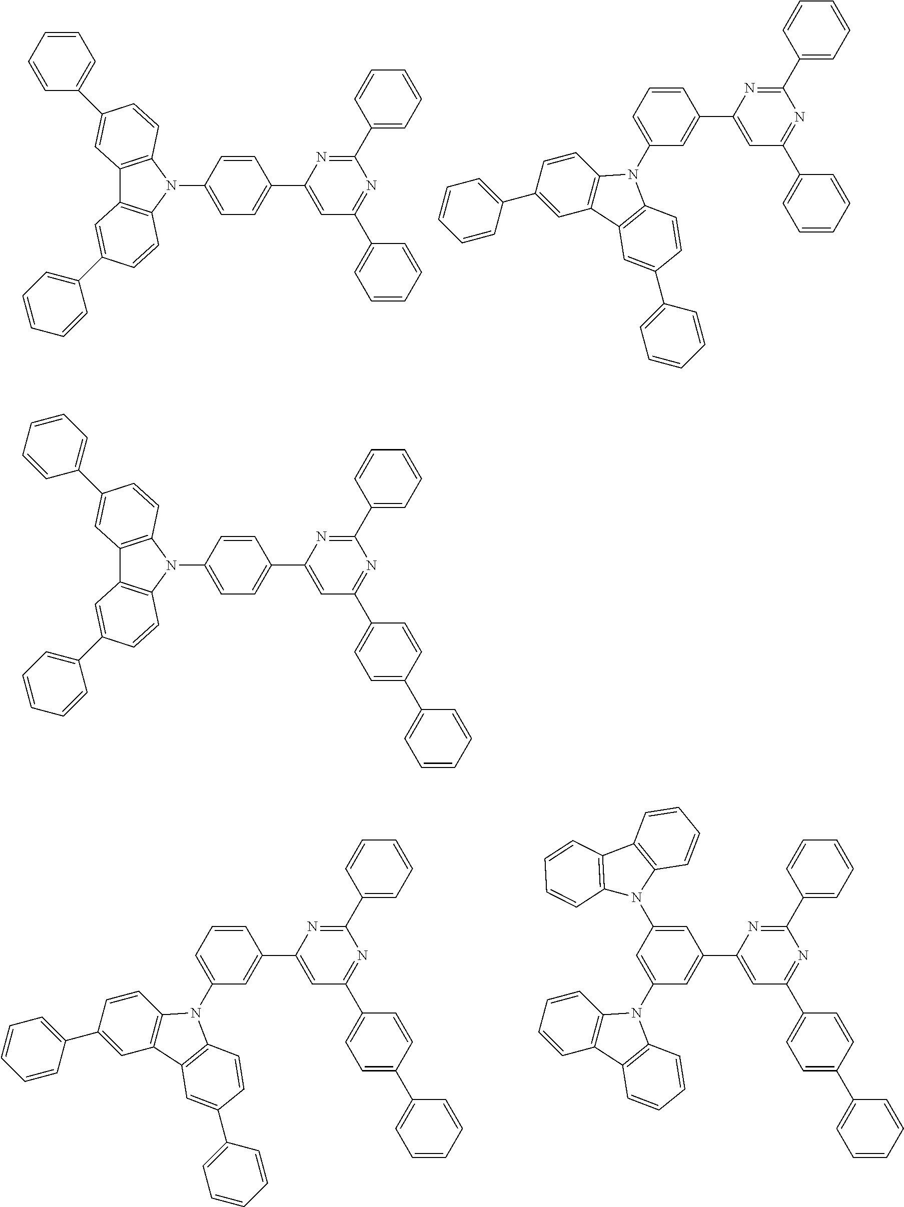

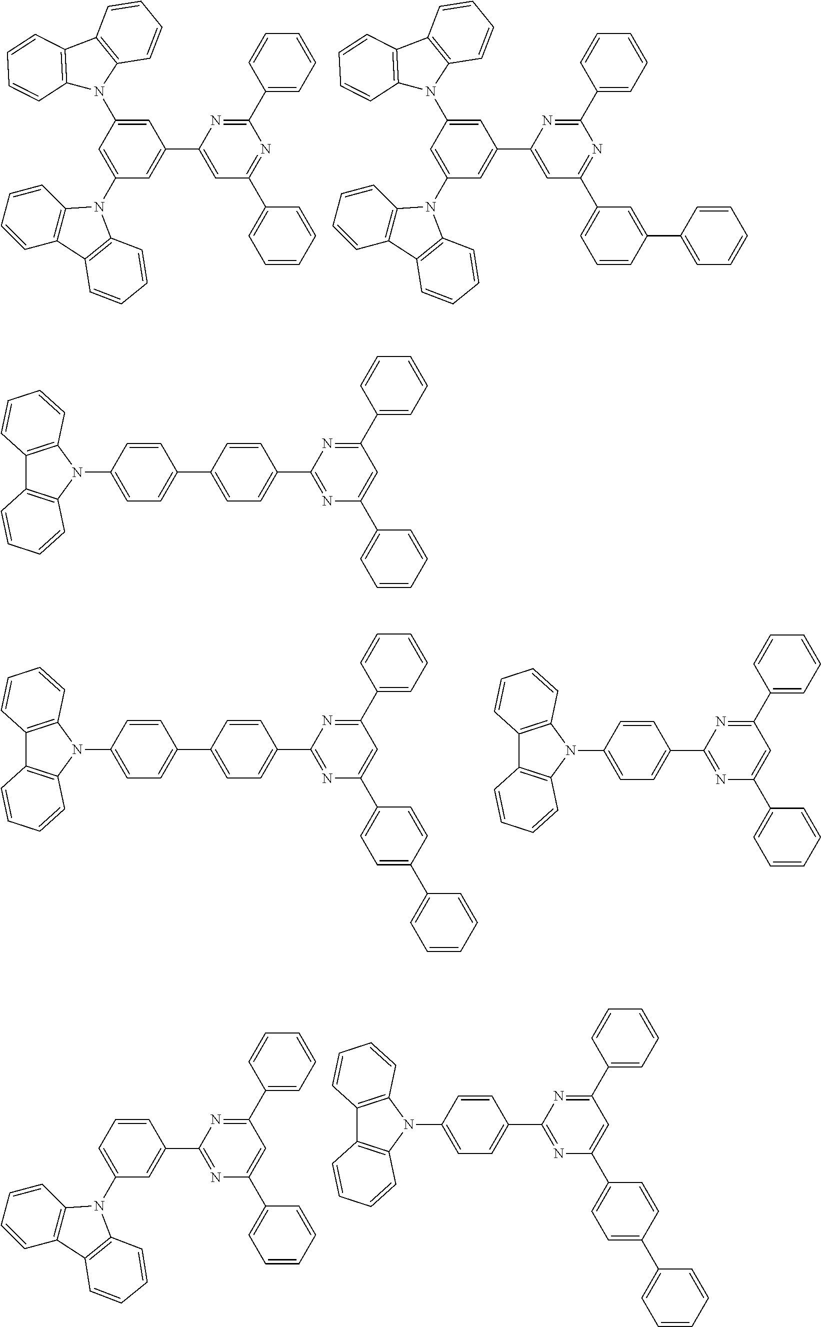

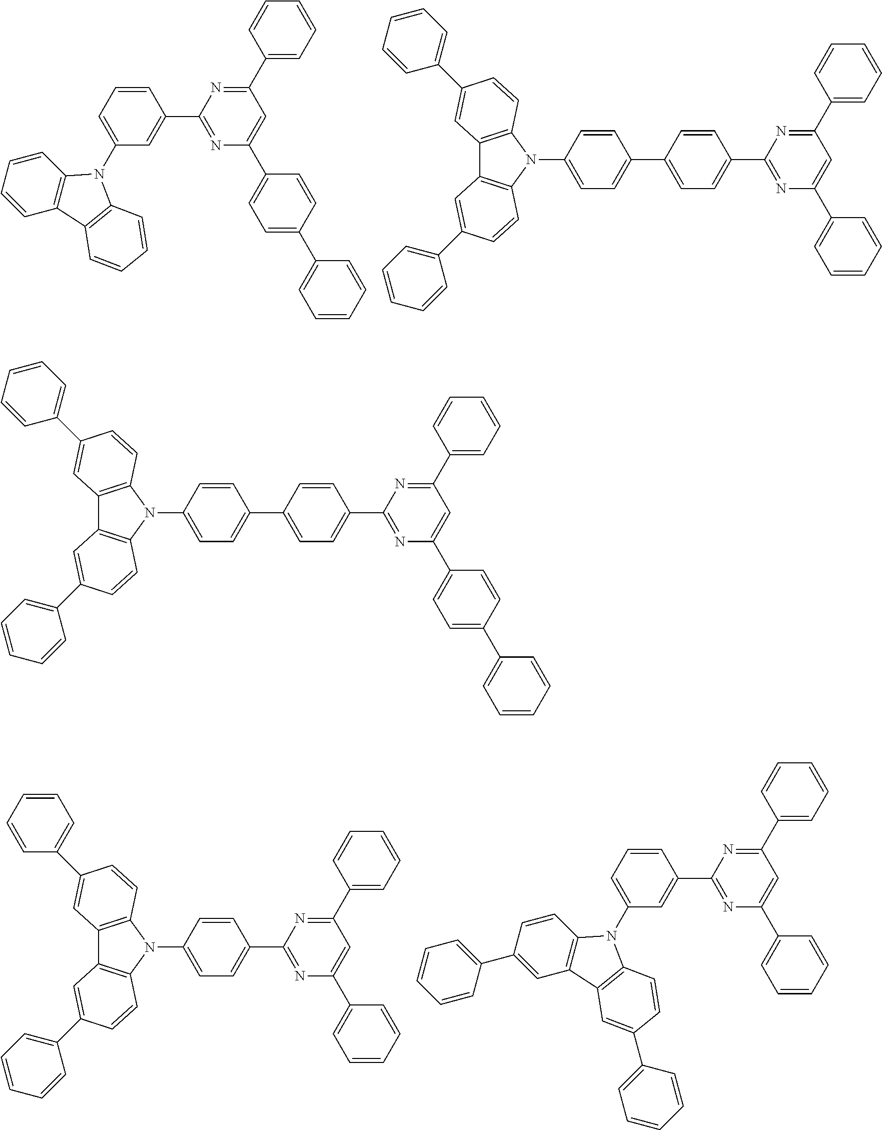

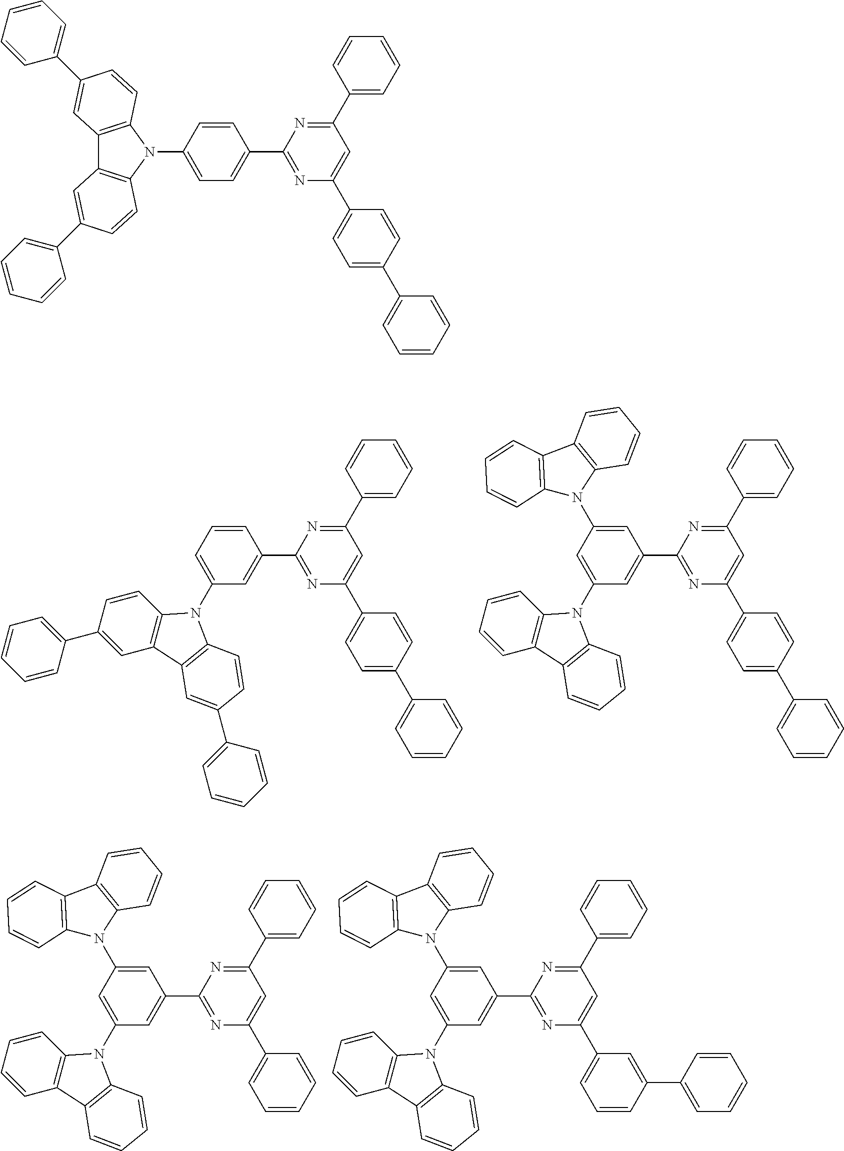

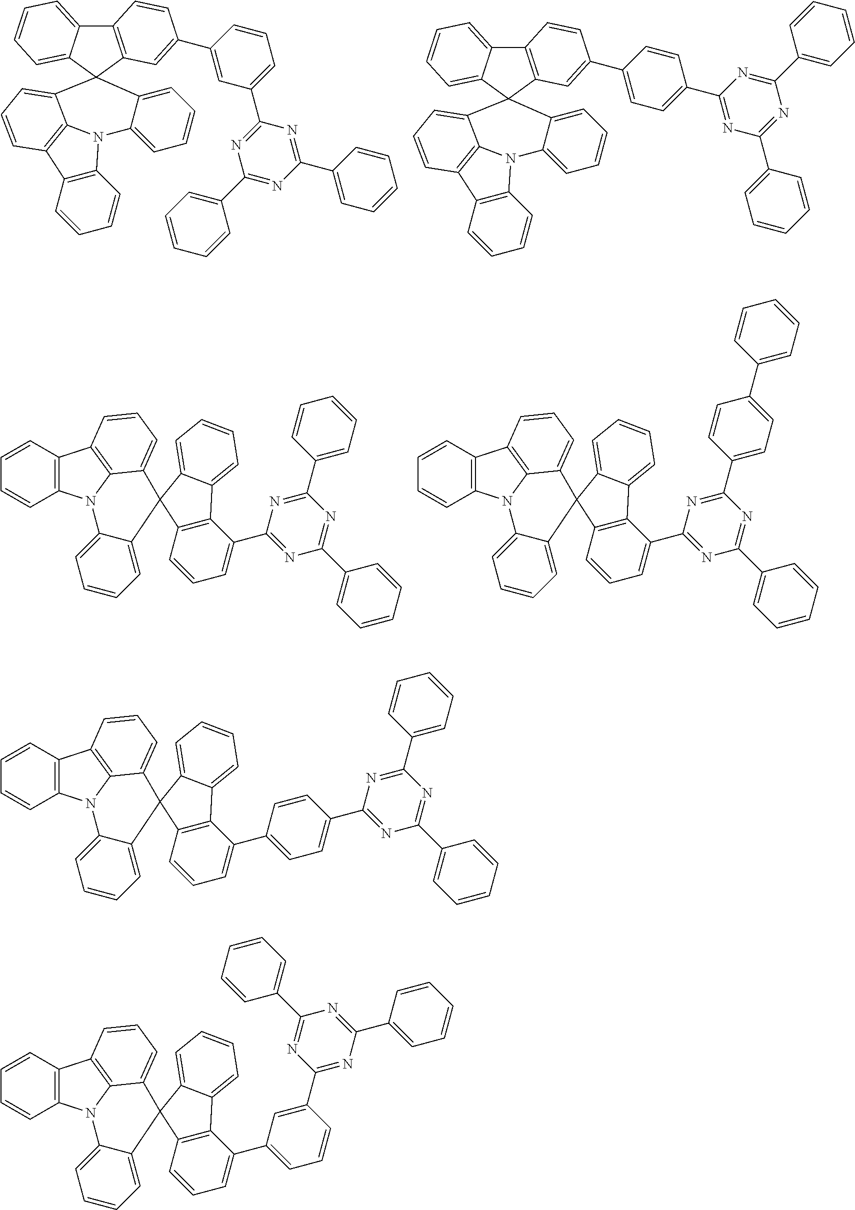

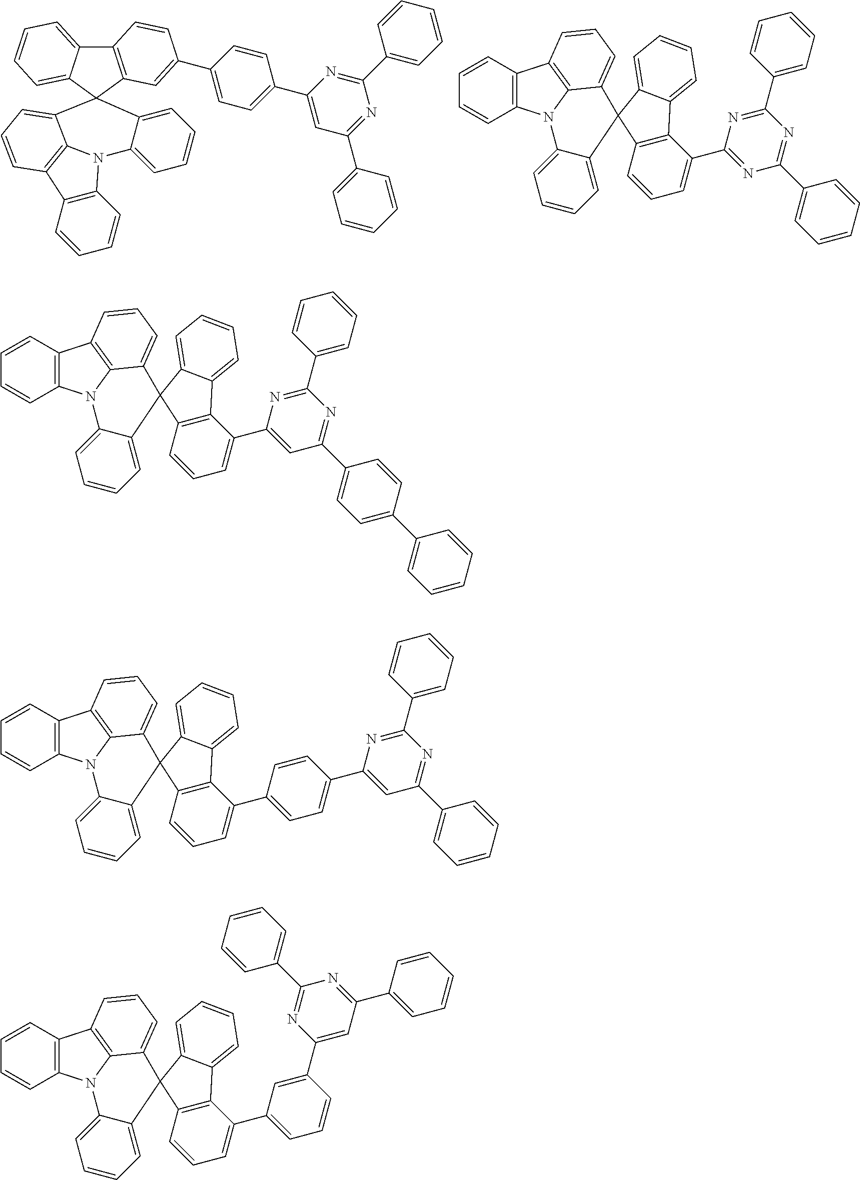

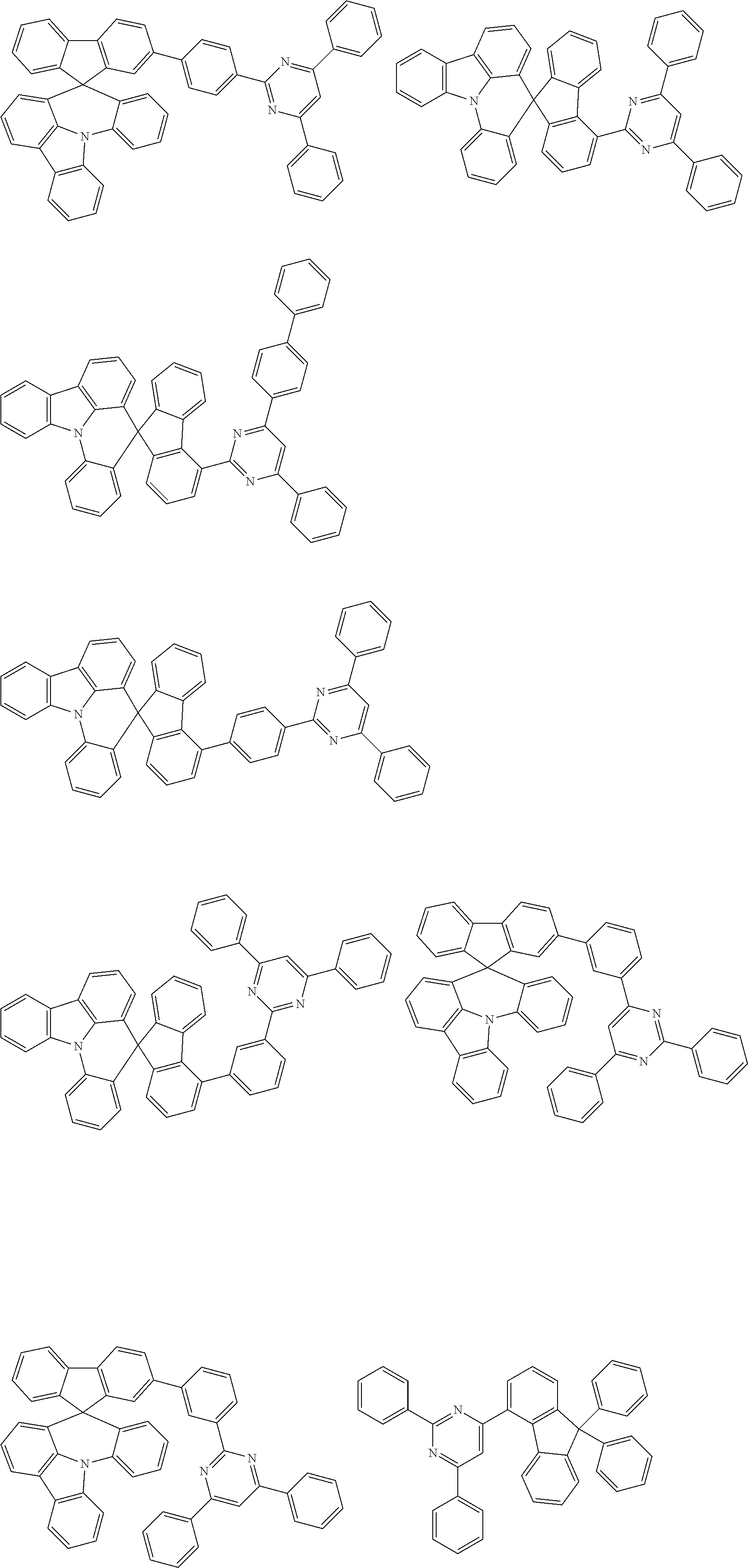

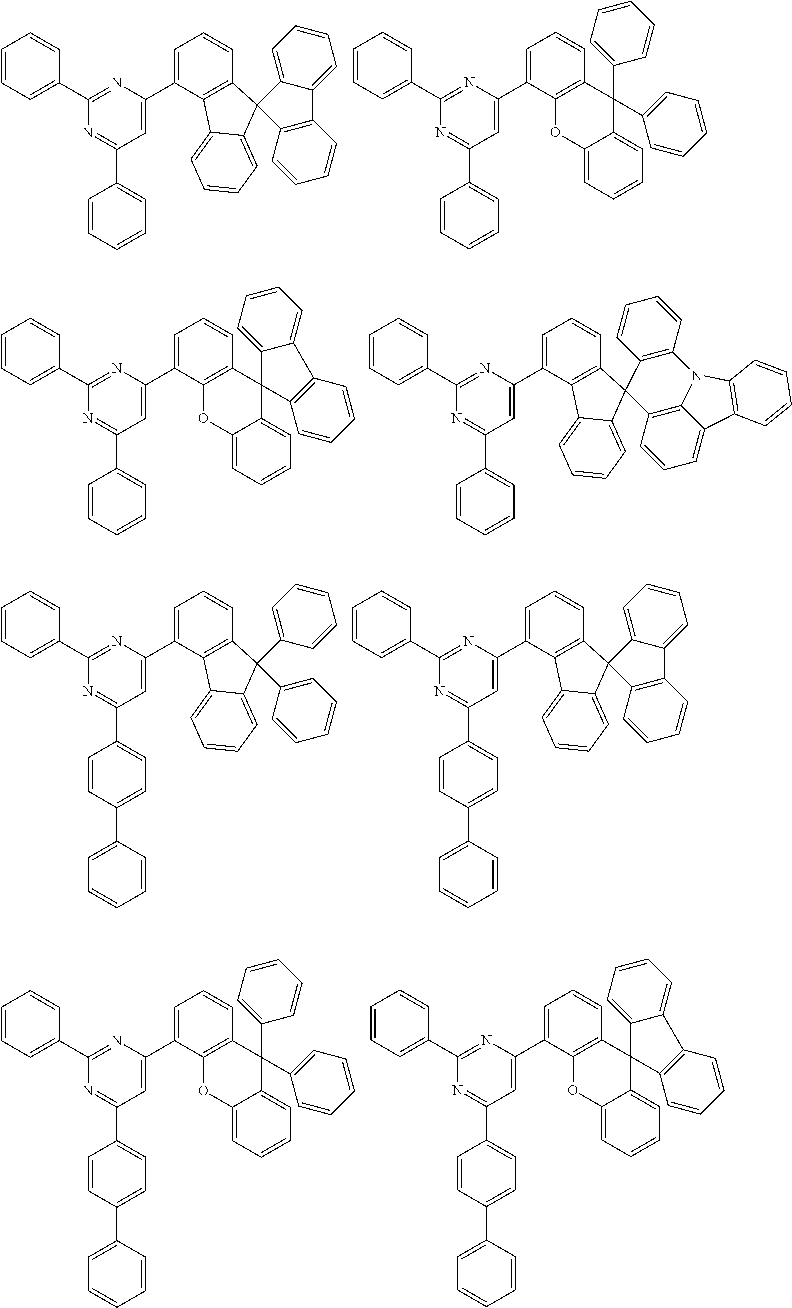

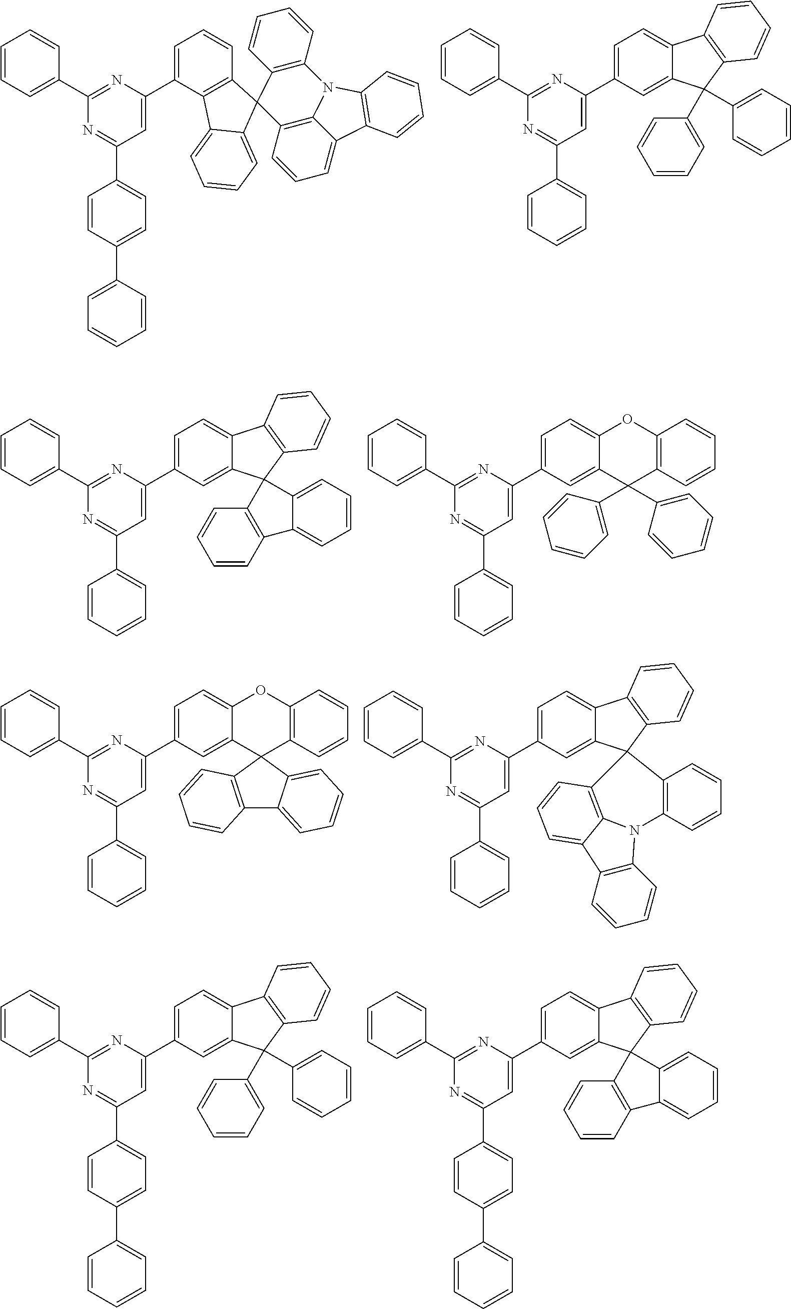

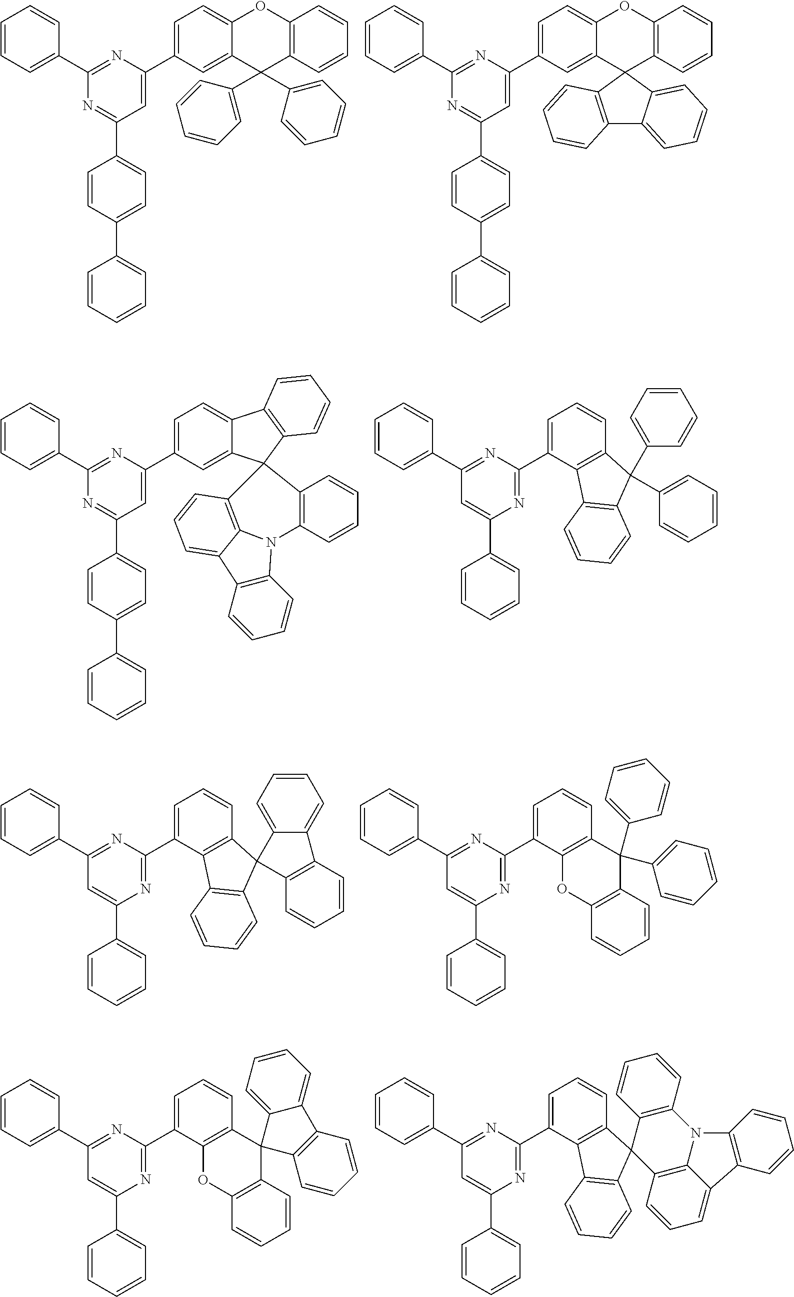

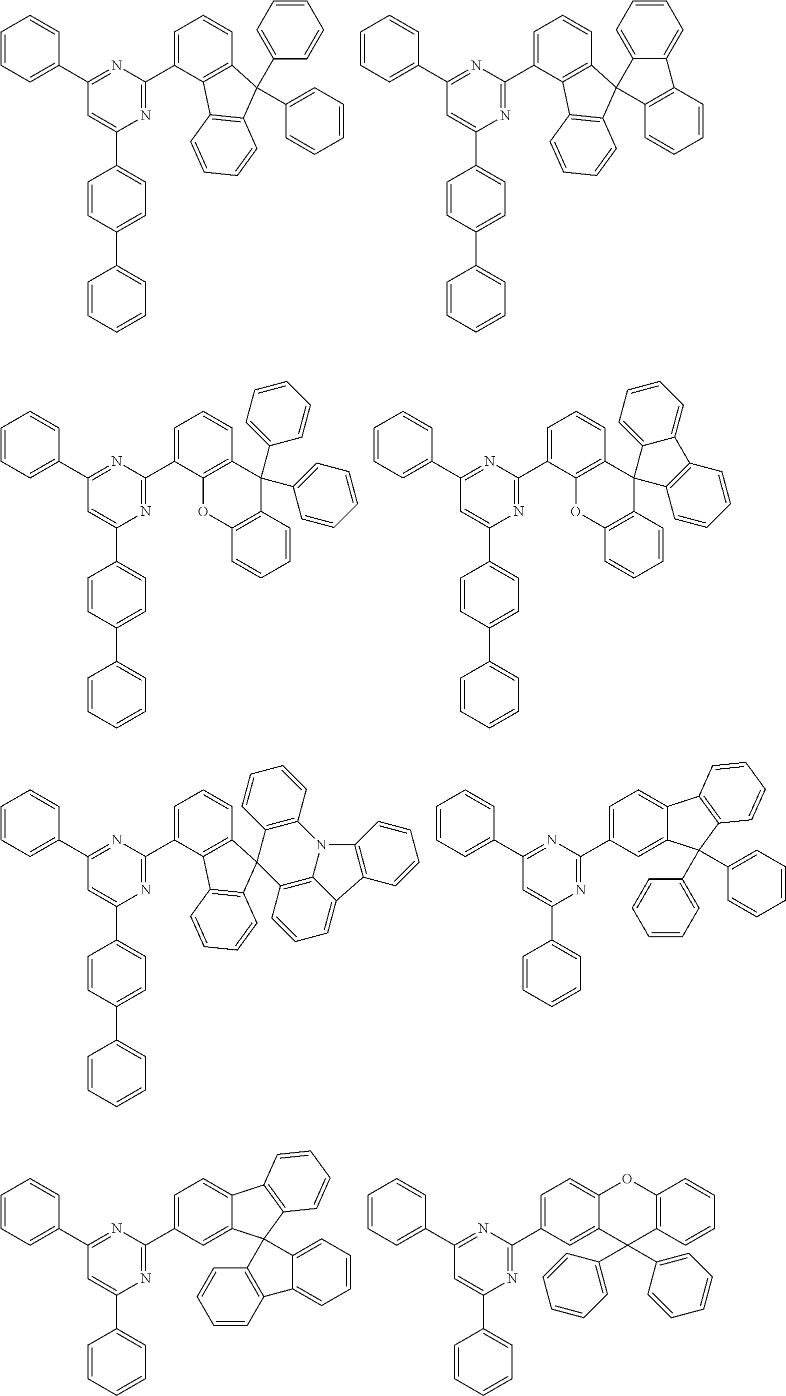

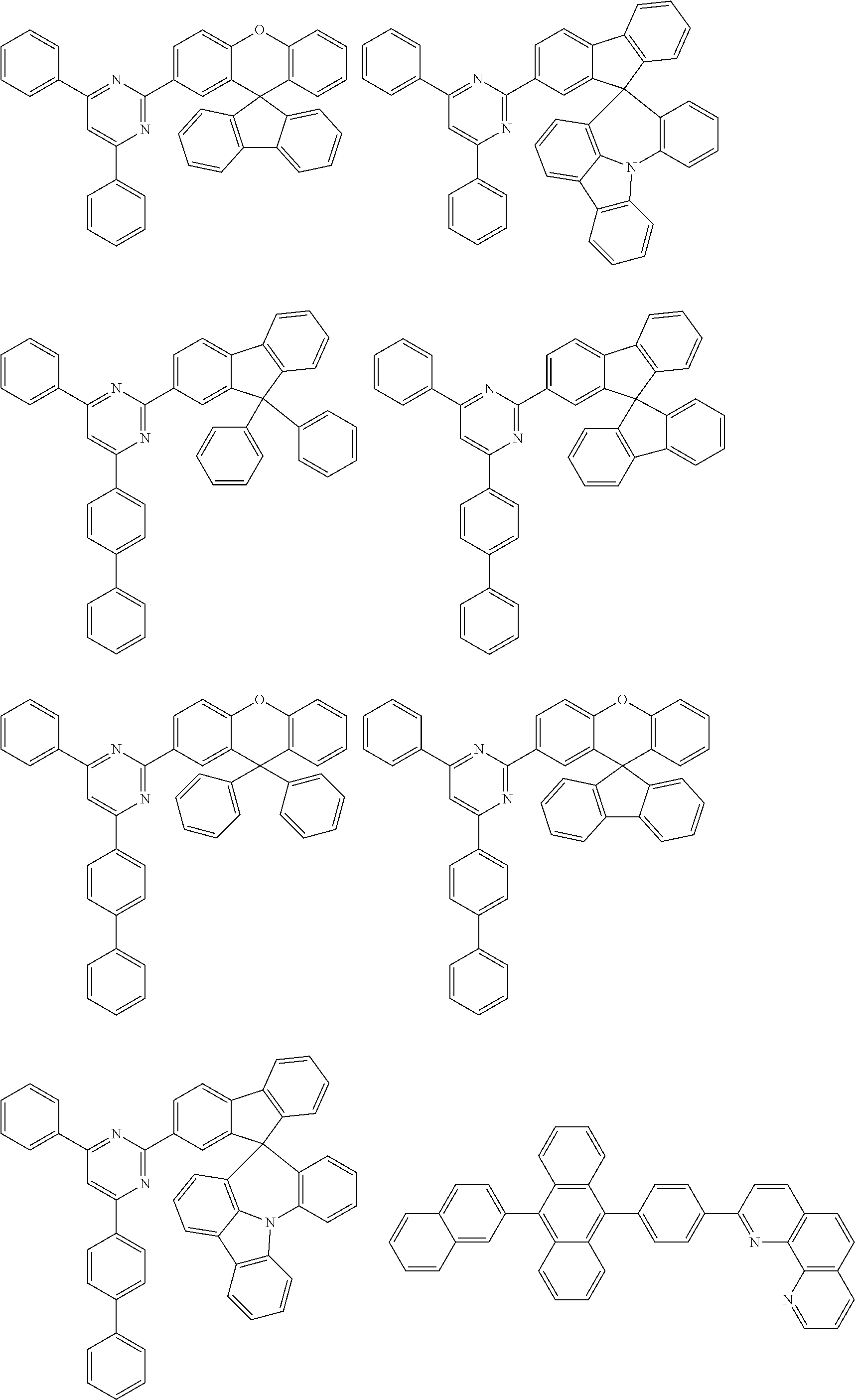

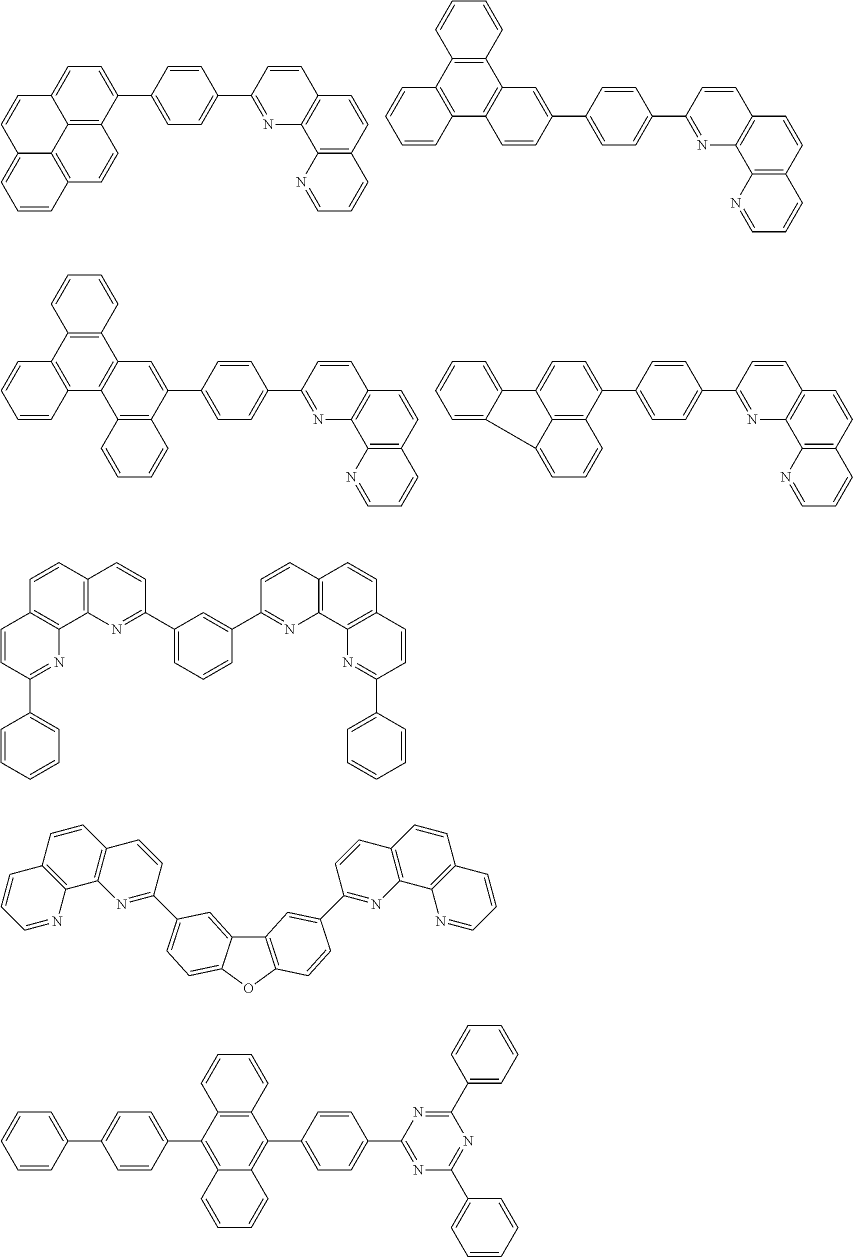

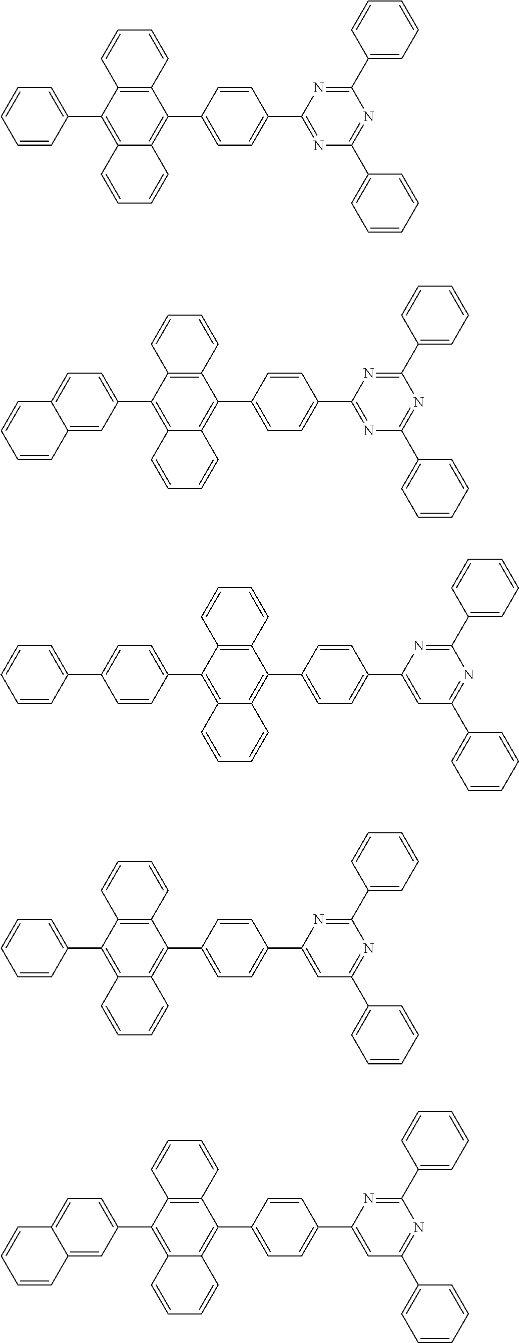

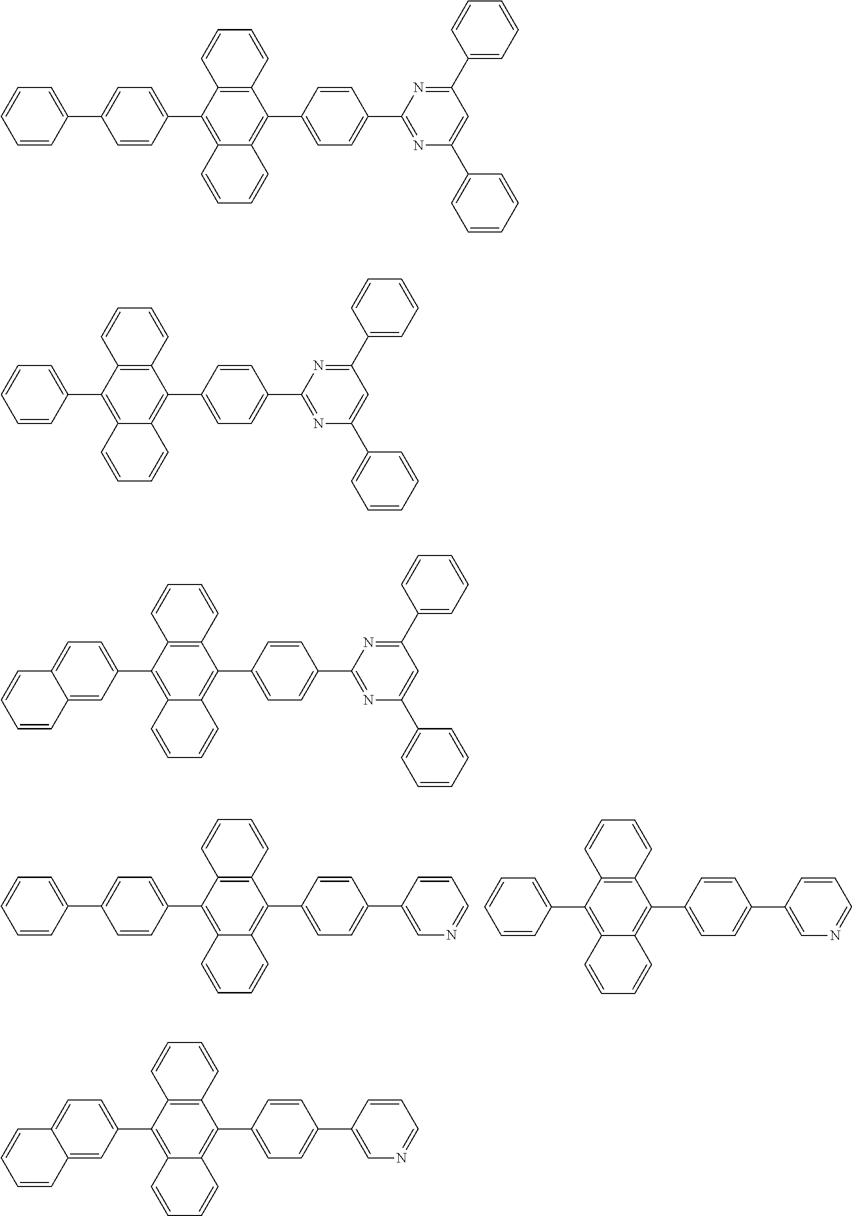

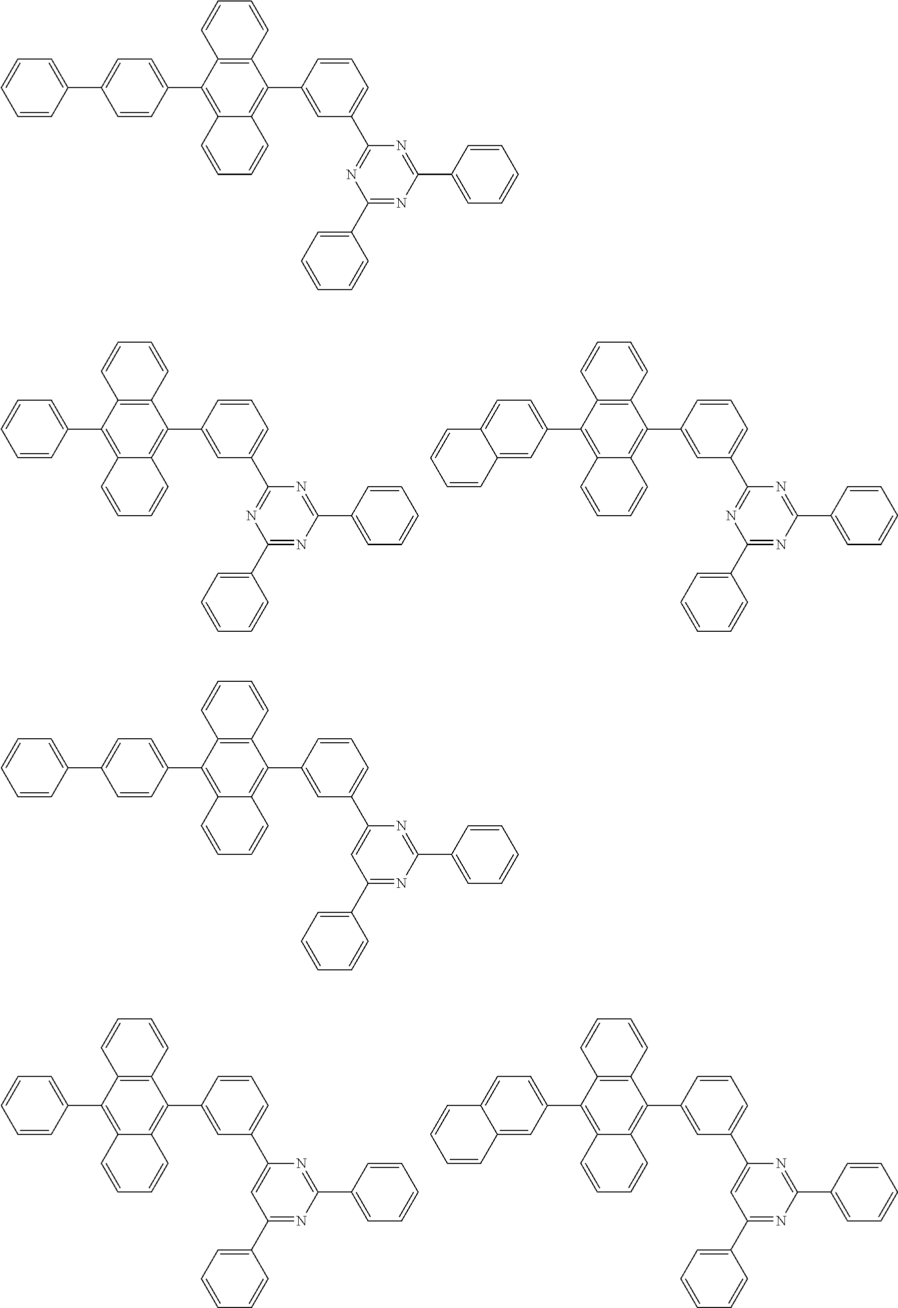

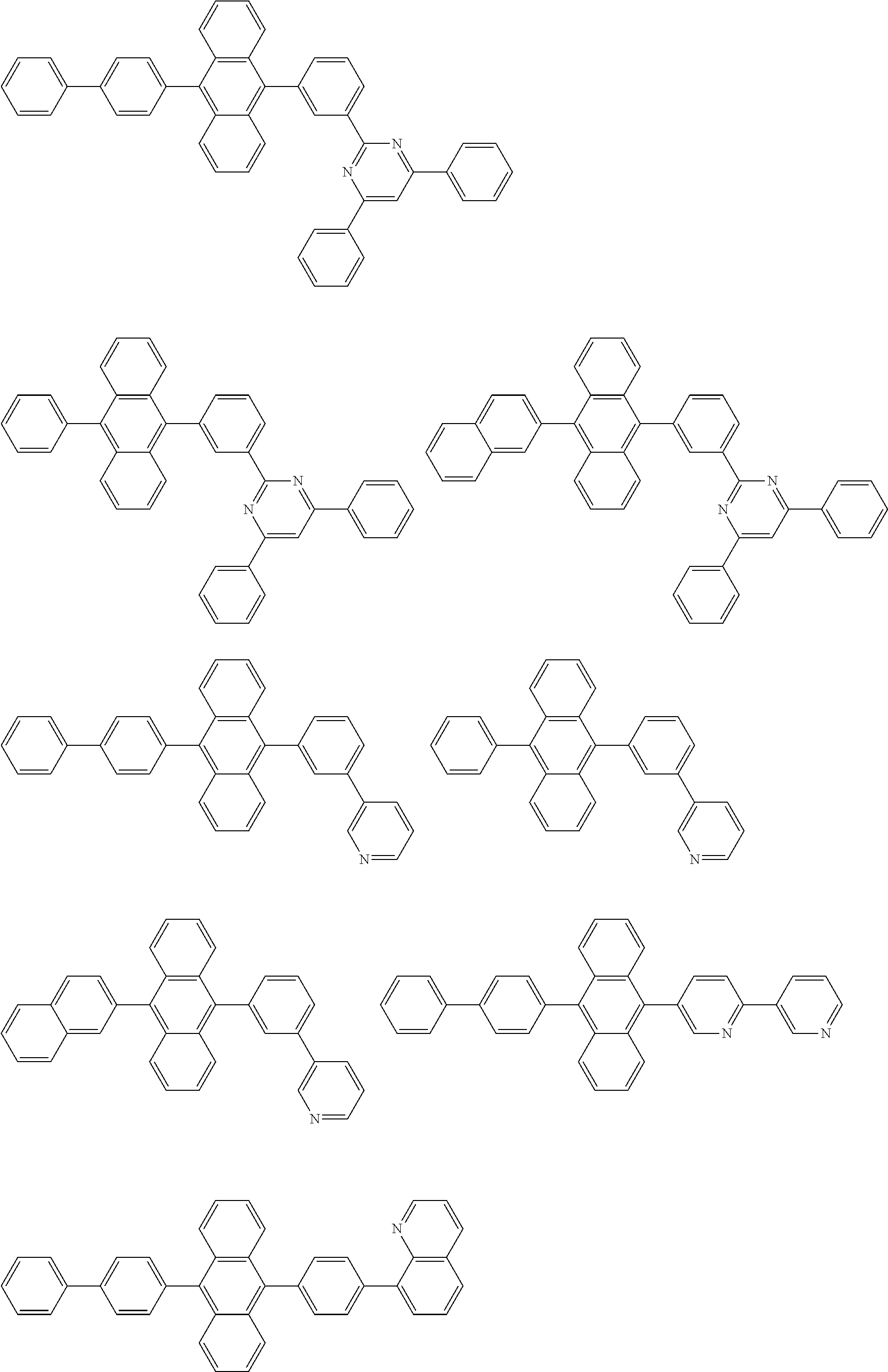

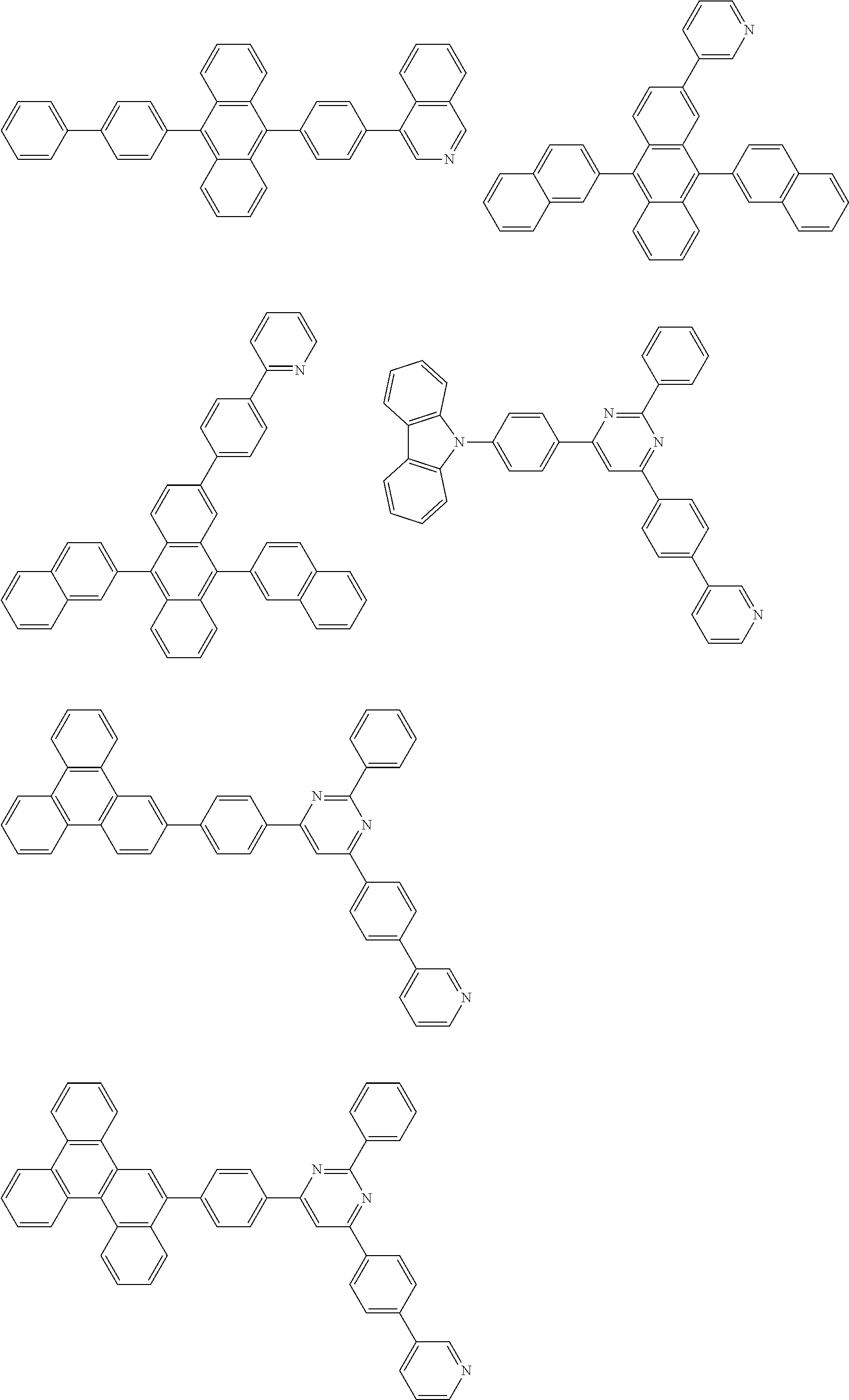 [SMILES: c1ccc(-c2ccc(-c3c4ccccc4c(-c4ccc(-c5cncc6ccccc56)cc4)c4ccccc34)cc2)cc1 ; c1cncc(-c2ccc3c(-c4ccc5ccccc5c4)c4ccccc4c(-c4ccc5ccccc5c4)c3c2)c1 ; c1ccc(-c2ccc(-c3ccc4c(-c5ccc6ccccc6c5)c5ccccc5c(-c5ccc6ccccc6c5)c4c3)cc2)nc1 ; c1ccc(-c2nc(-c3ccc(-c4cccnc4)cc3)cc(-c3ccc(-n4c5ccccc5c5ccccc54)cc3)n2)cc1 ; c1ccc(-c2nc(-c3ccc(-c4cccnc4)cc3)cc(-c3ccc(-c4ccc5c6ccccc6c6ccccc6c5c4)cc3)n2)cc1 ; c1ccc(-c2nc(-c3ccc(-c4cccnc4)cc3)cc(-c3ccc(-c4cc5c6ccccc6c6ccccc6c5c5ccccc45)cc3)n2)cc1]

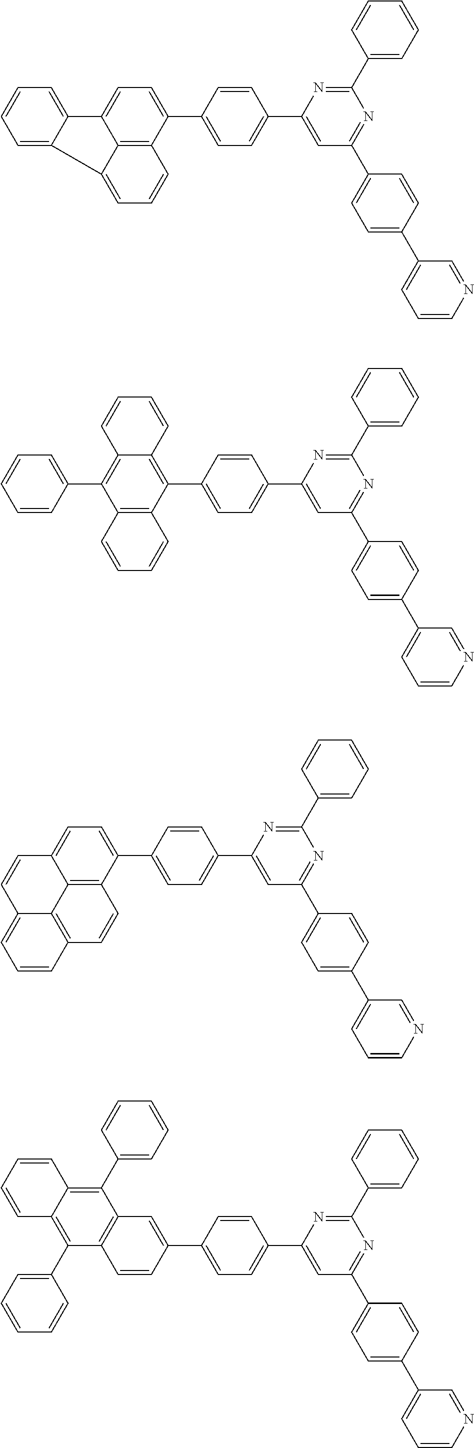 [SMILES: c1ccc(-c2nc(-c3ccc(-c4cccnc4)cc3)cc(-c3ccc(-c4ccc5c6c(cccc46)-c4ccccc4-5)cc3)n2)cc1 ; c1ccc(-c2nc(-c3ccc(-c4cccnc4)cc3)cc(-c3ccc(-c4c5ccccc5c(-c5ccccc5)c5ccccc45)cc3)n2)cc1 ; c1ccc(-c2nc(-c3ccc(-c4cccnc4)cc3)cc(-c3ccc(-c4ccc5ccc6cccc7ccc4c5c67)cc3)n2)cc1 ; c1ccc(-c2nc(-c3ccc(-c4cccnc4)cc3)cc(-c3ccc(-c4ccc5c(-c6ccccc6)c6ccccc6c(-c6ccccc6)c5c4)cc3)n2)cc1]

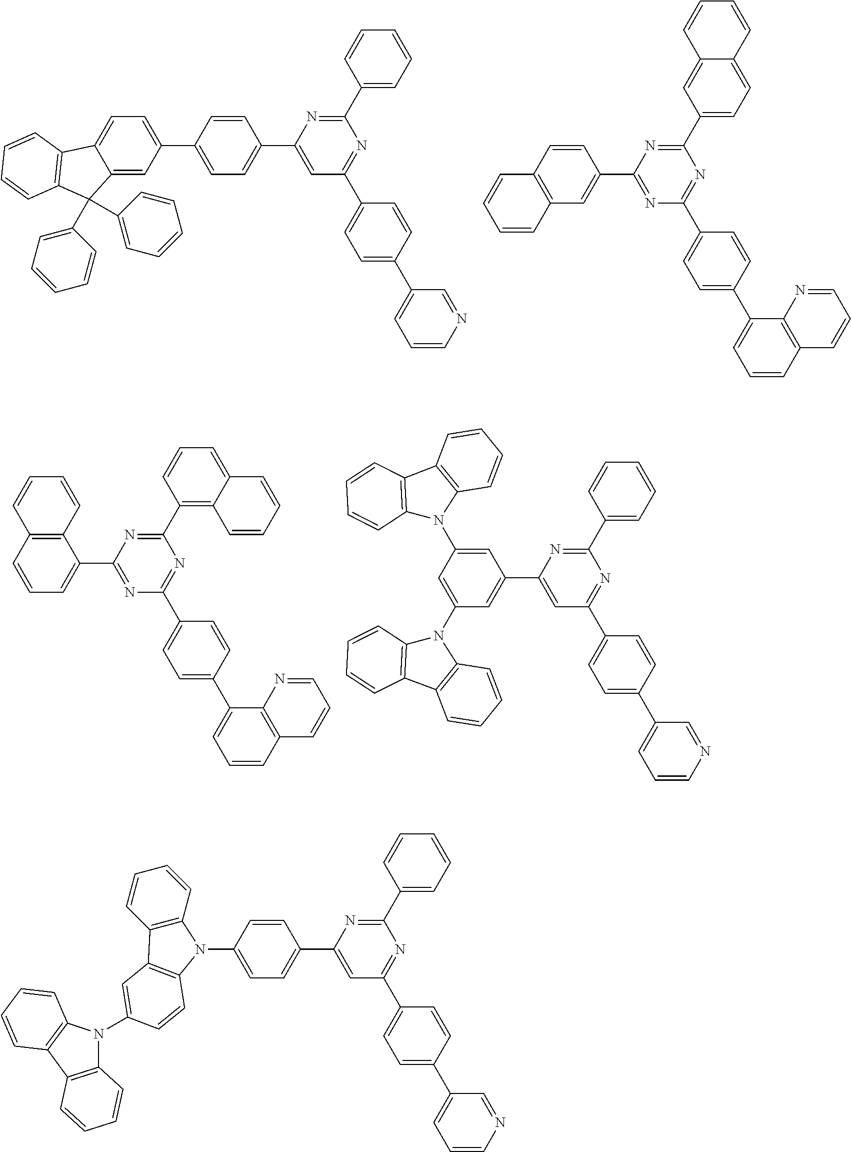

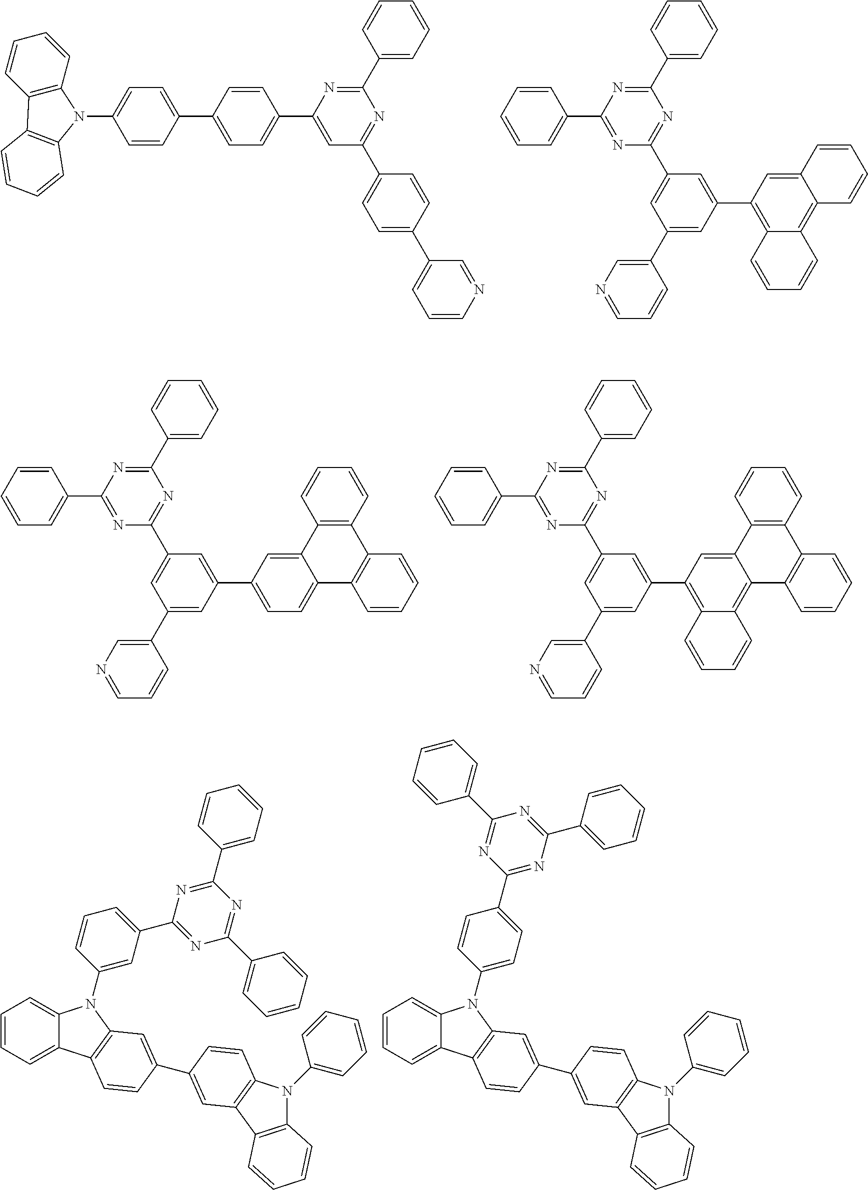

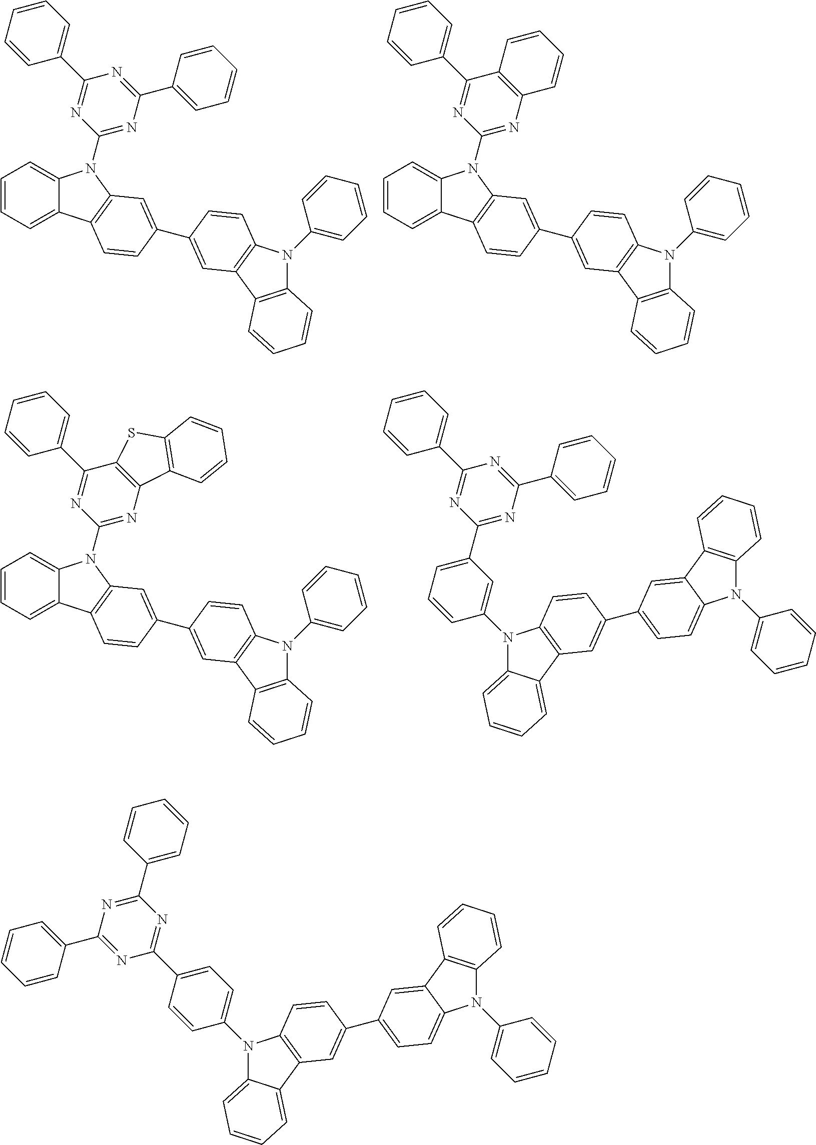

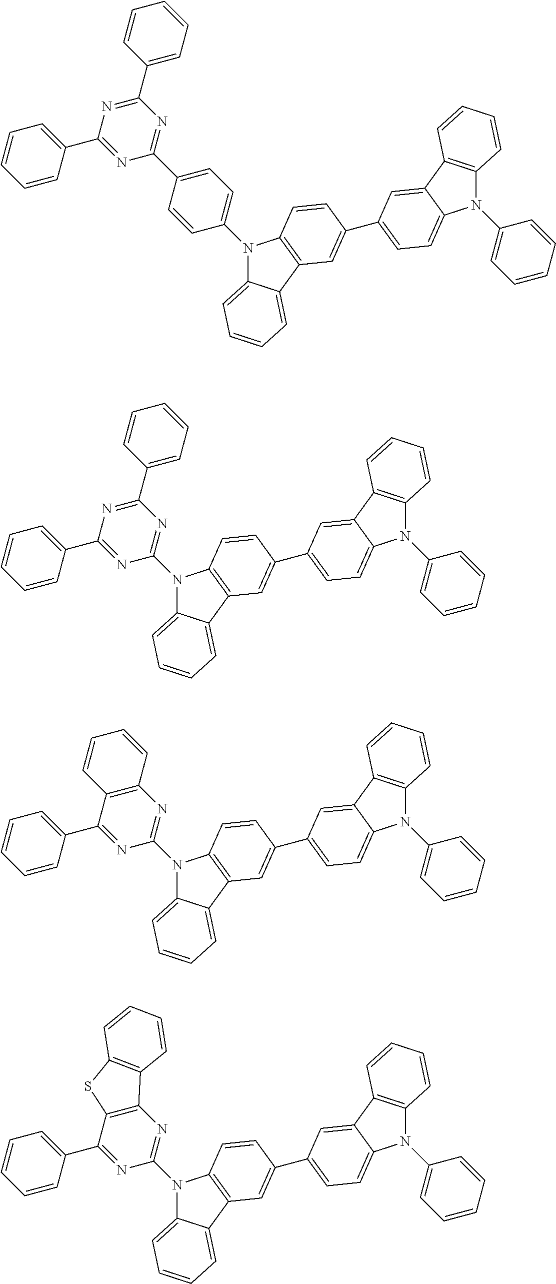 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccccc4c4cc(-c5ccc6c(c5)c5ccccc5n6-c5ccccc5)ccc43)nc3c2sc2ccccc23)cc1]

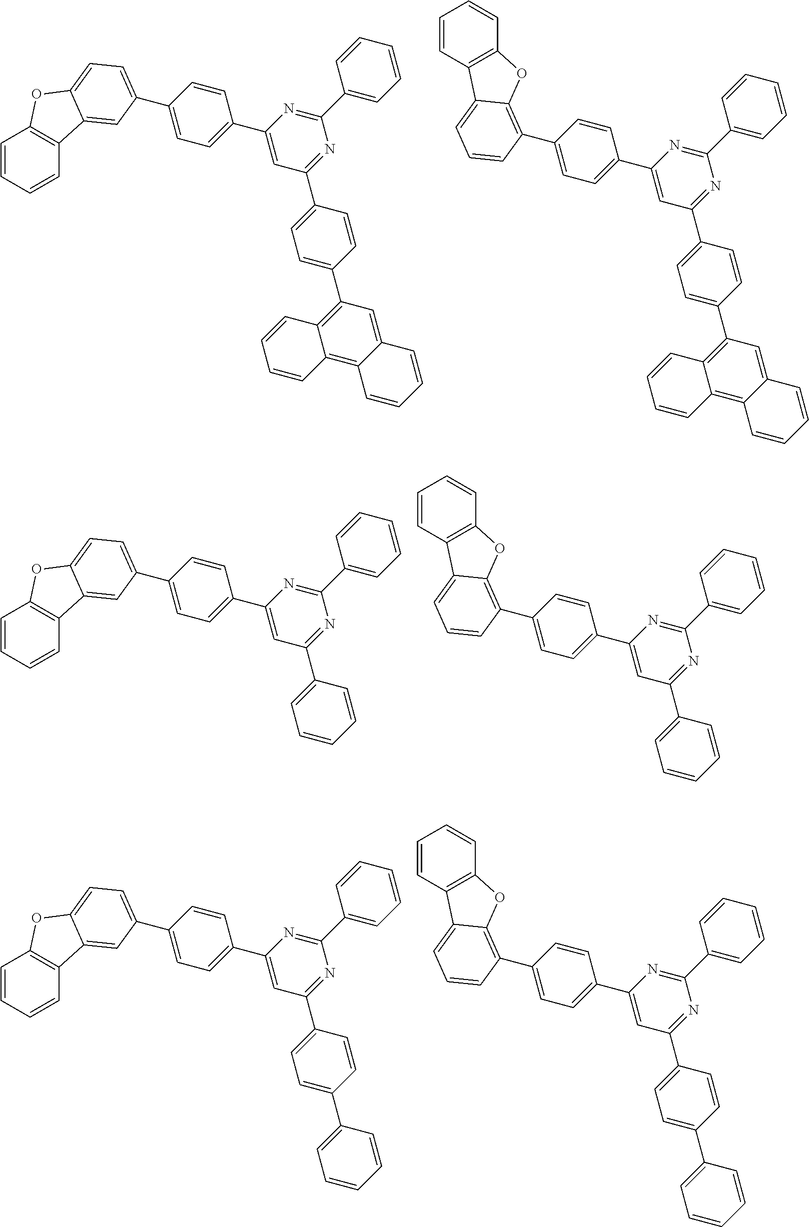

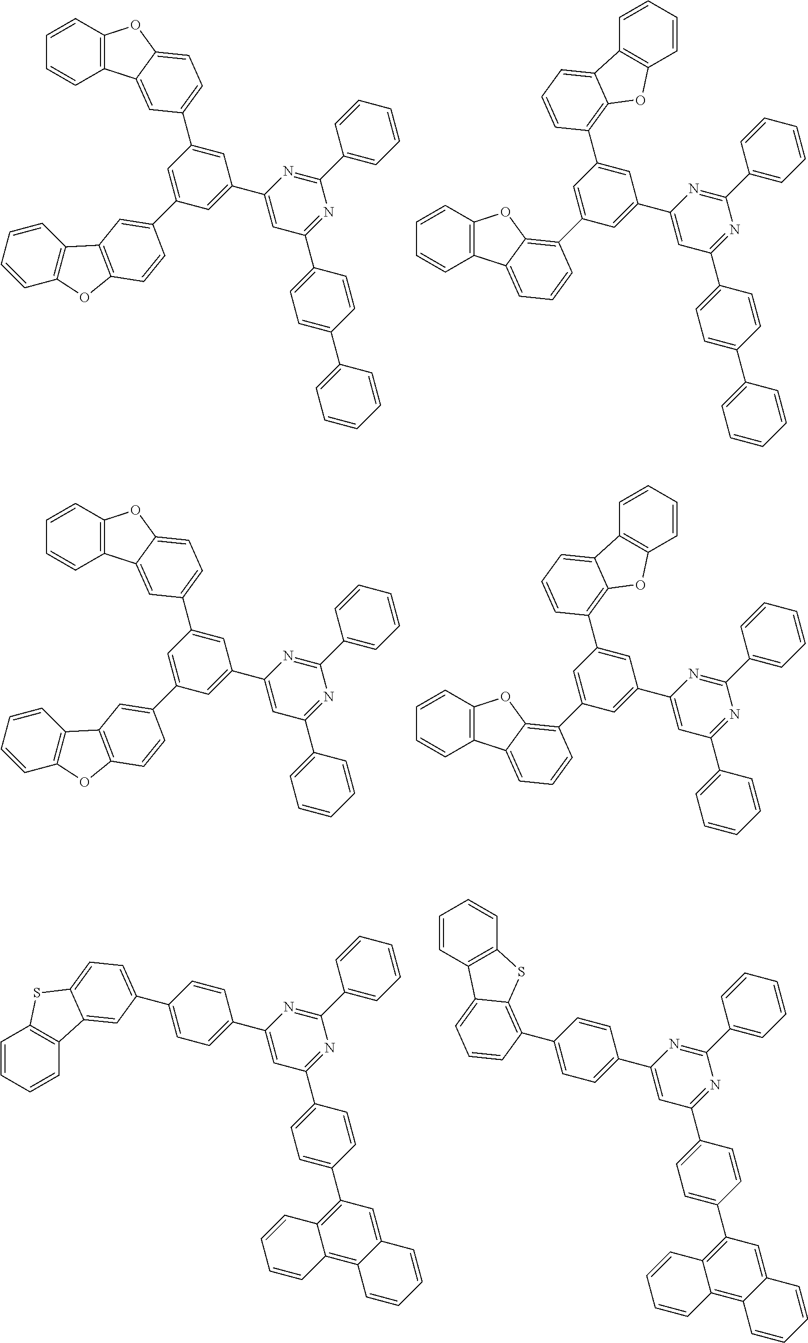

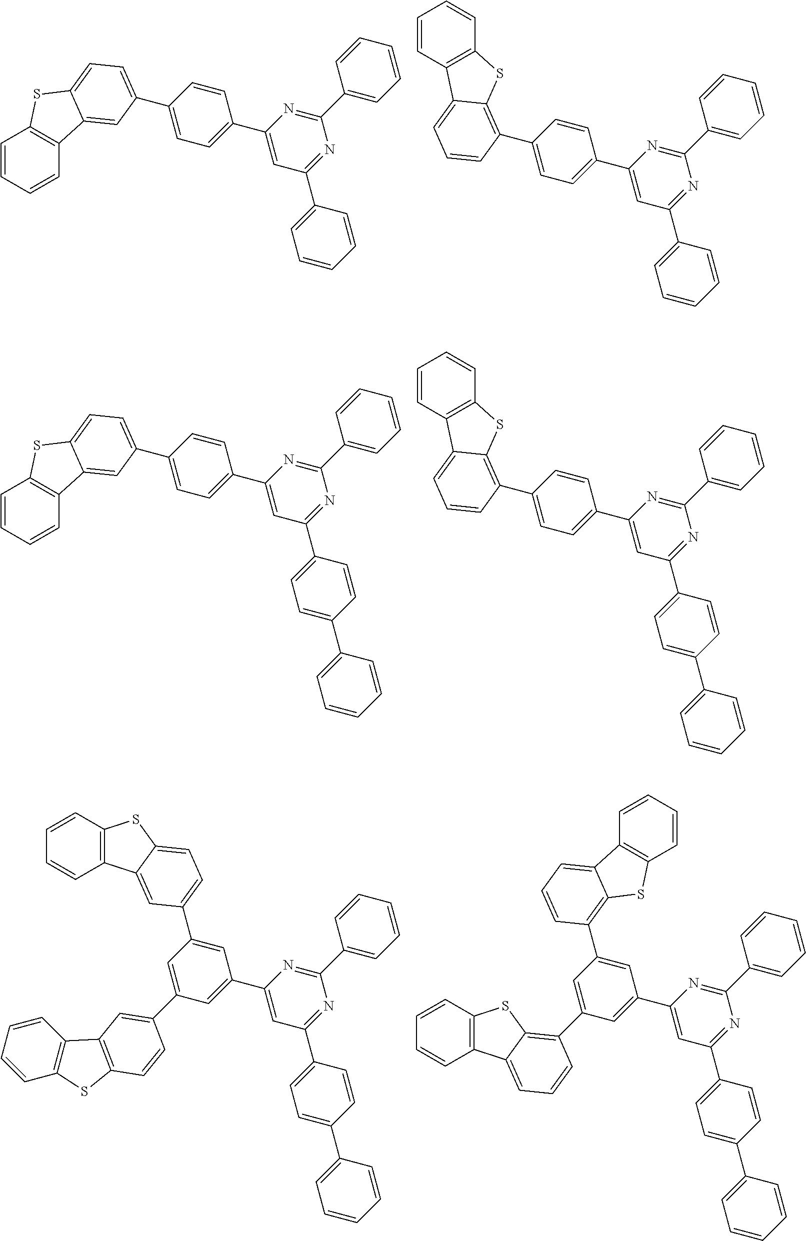

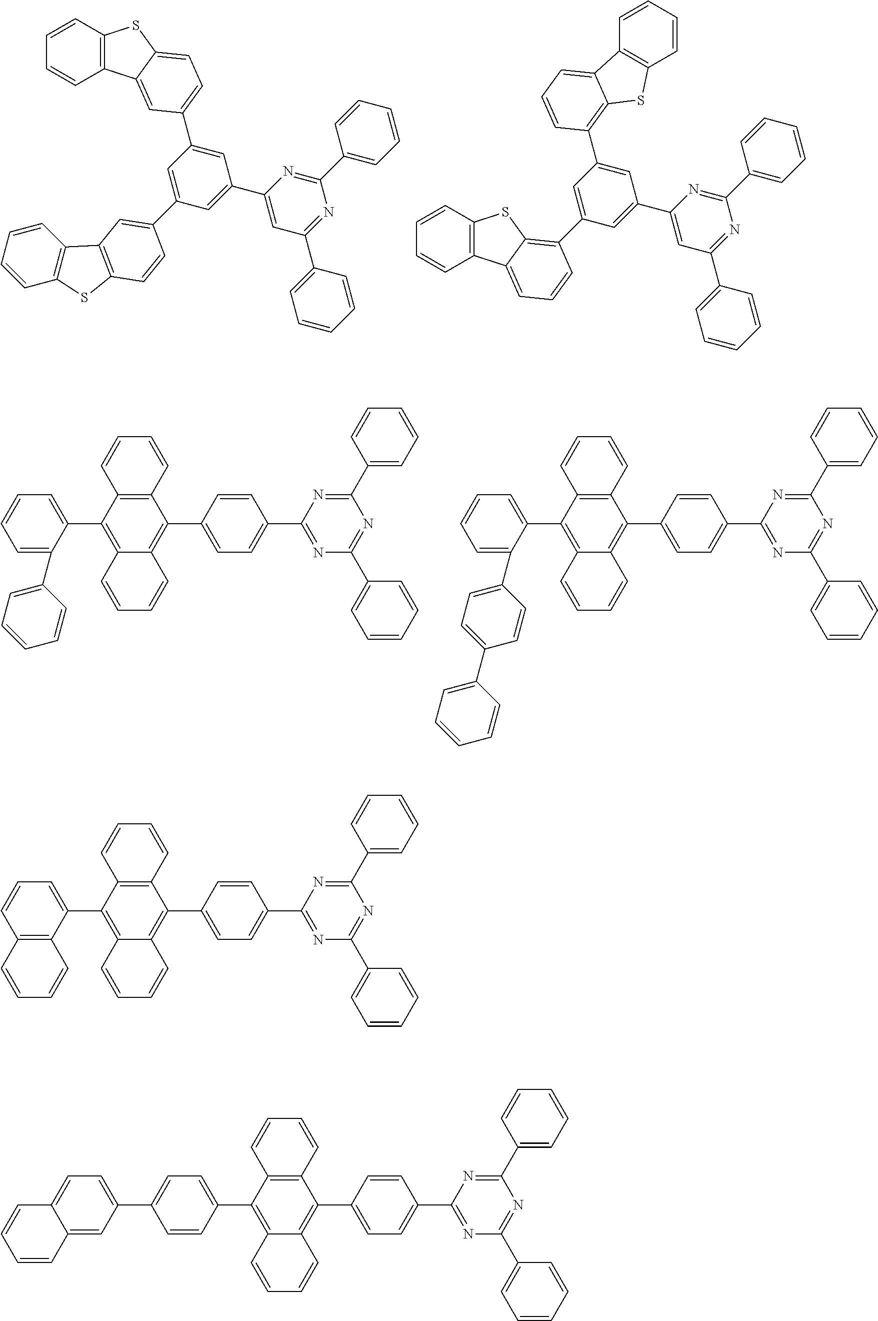

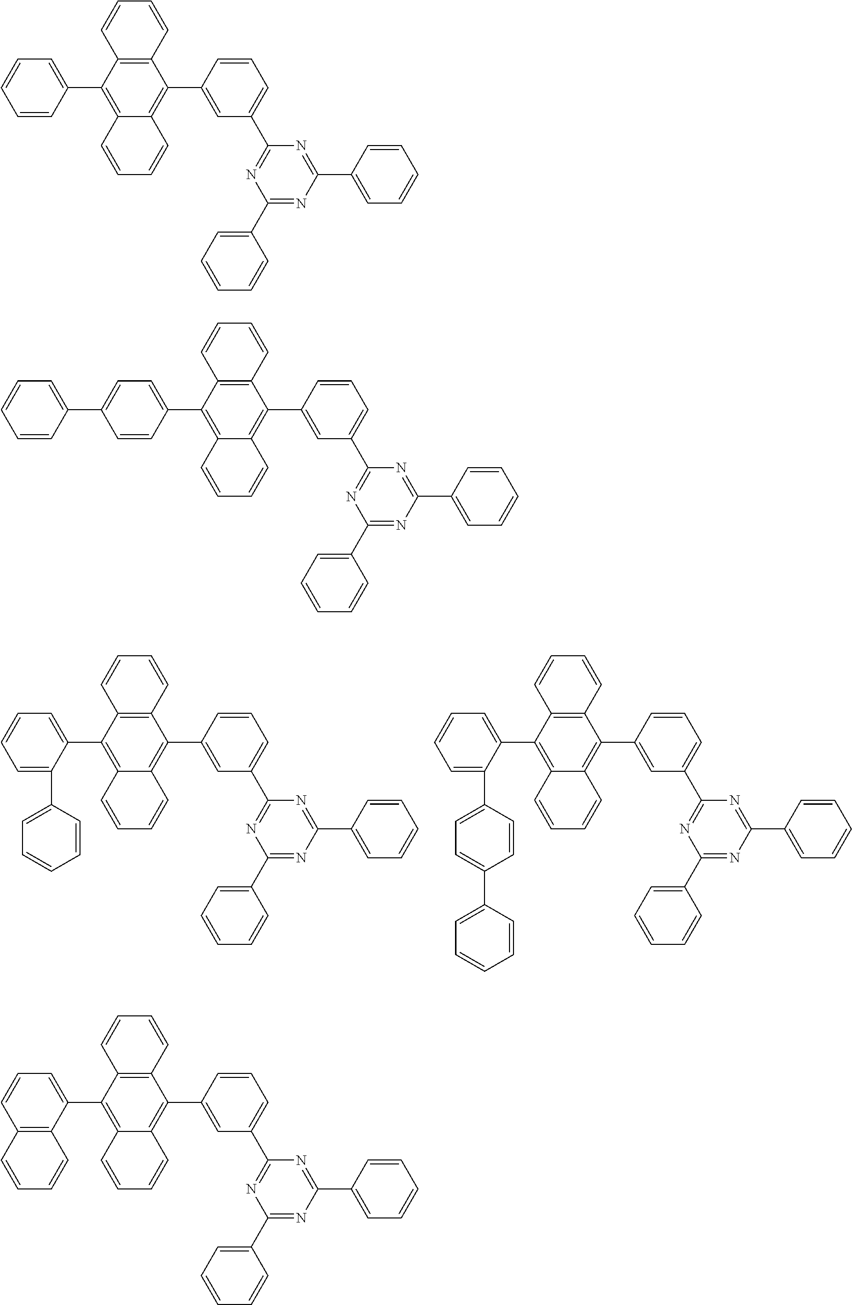

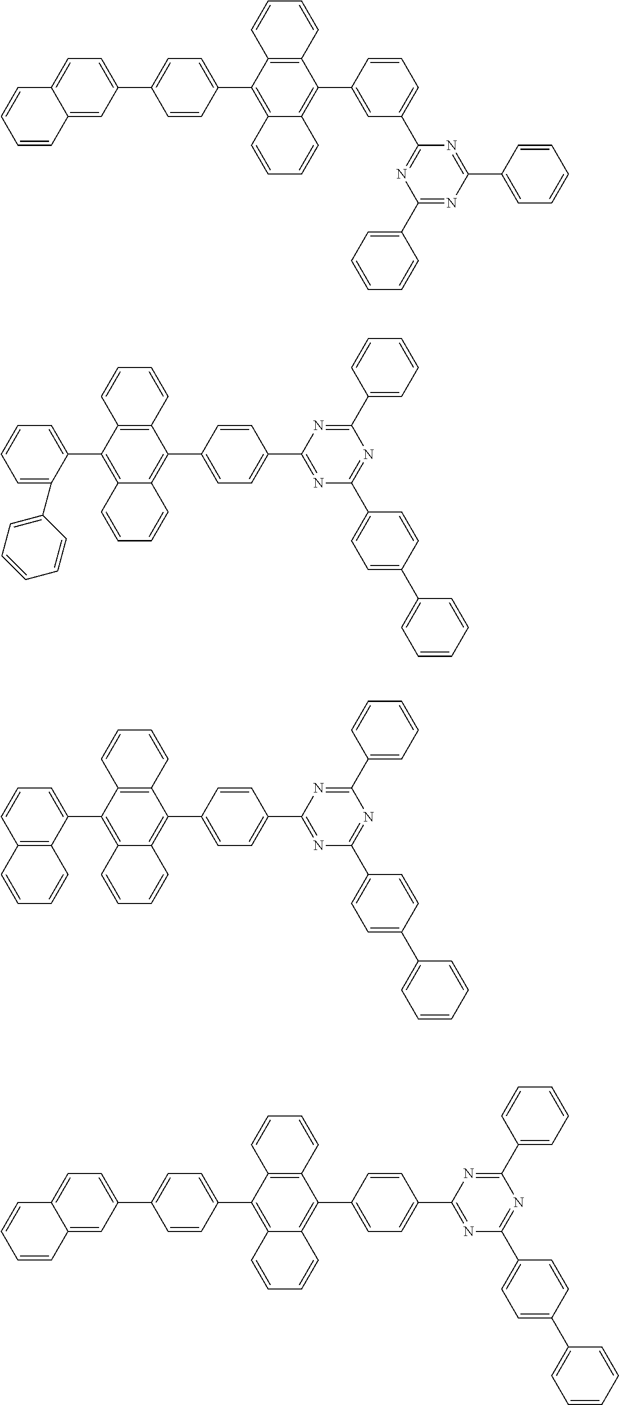 [SMILES: c1ccc(-c2nc(-c3ccccc3)nc(-c3cccc(-c4c5ccccc5c(-c5ccc(-c6ccc7ccccc7c6)cc5)c5ccccc45)c3)n2)cc1 ; c1ccc(-c2ccc(-c3nc(-c4ccccc4)nc(-c4ccc(-c5c6ccccc6c(-c6ccccc6-c6ccccc6)c6ccccc56)cc4)n3)cc2)cc1 ; c1ccc(-c2ccc(-c3nc(-c4ccccc4)nc(-c4ccc(-c5c6ccccc6c(-c6cccc7ccccc67)c6ccccc56)cc4)n3)cc2)cc1 ; c1ccc(-c2ccc(-c3nc(-c4ccccc4)nc(-c4ccc(-c5c6ccccc6c(-c6ccc(-c7ccc8ccccc8c7)cc6)c6ccccc56)cc4)n3)cc2)cc1]

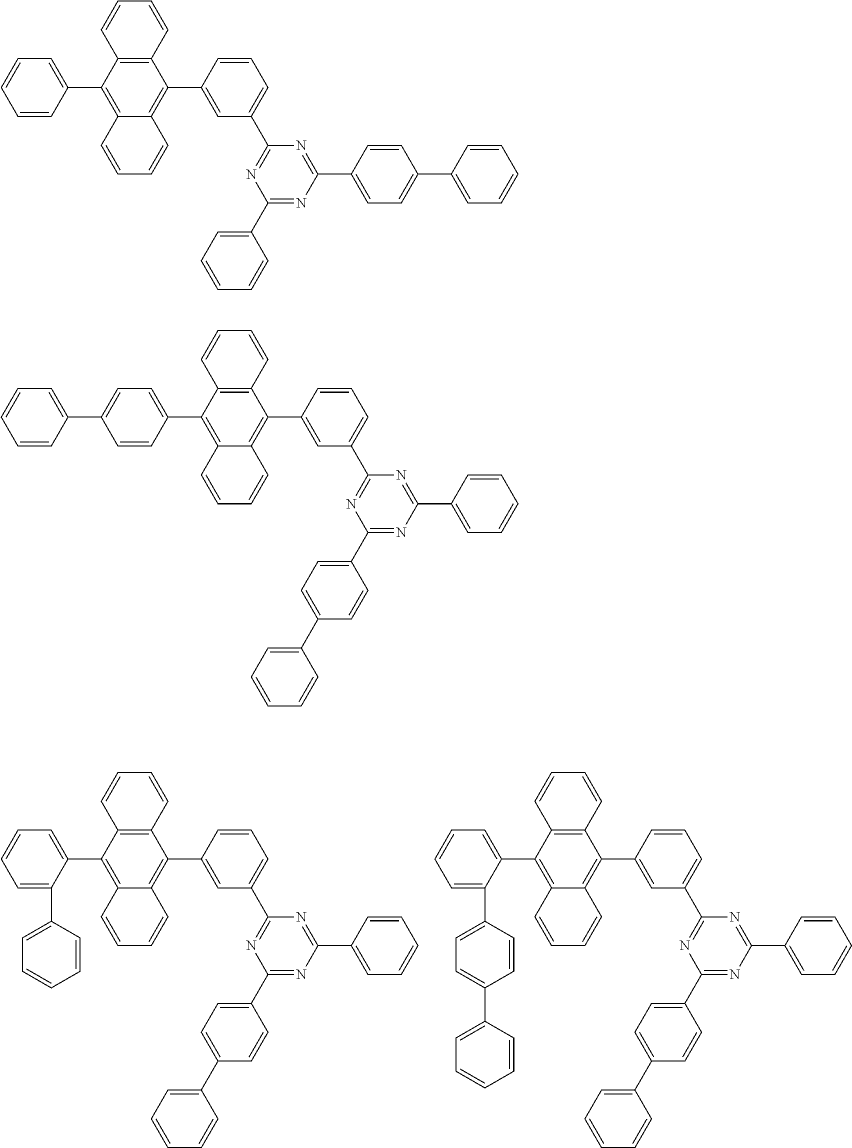

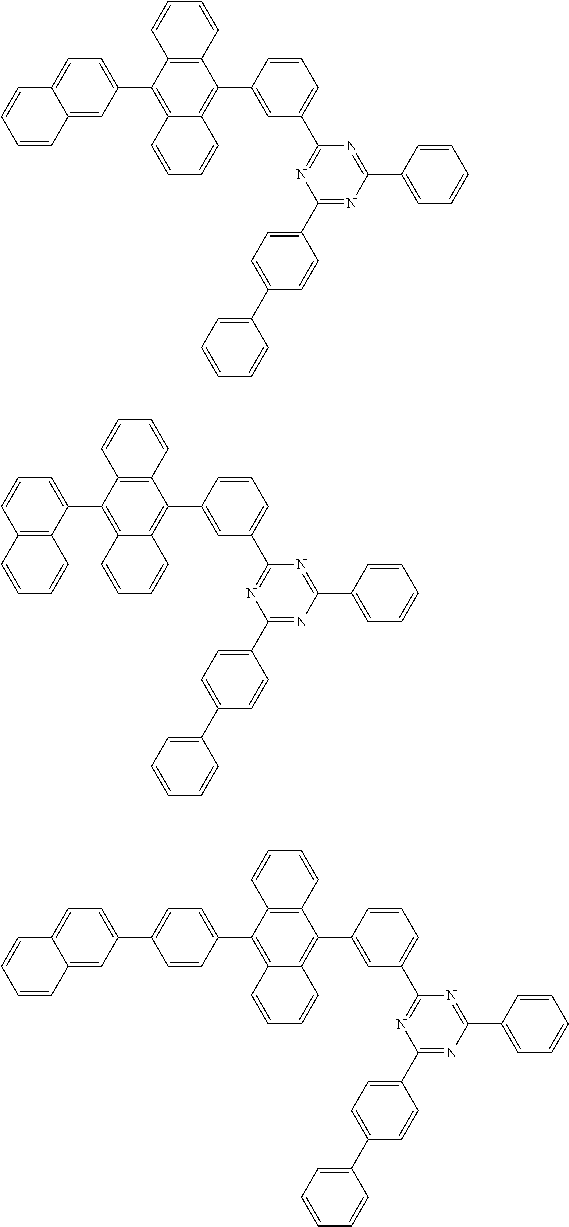 [SMILES: c1ccc(-c2ccc(-c3nc(-c4ccccc4)nc(-c4cccc(-c5c6ccccc6c(-c6ccc7ccccc7c6)c6ccccc56)c4)n3)cc2)cc1 ; c1ccc(-c2ccc(-c3nc(-c4ccccc4)nc(-c4cccc(-c5c6ccccc6c(-c6cccc7ccccc67)c6ccccc56)c4)n3)cc2)cc1 ; c1ccc(-c2ccc(-c3nc(-c4ccccc4)nc(-c4cccc(-c5c6ccccc6c(-c6ccc(-c7ccc8ccccc8c7)cc6)c6ccccc56)c4)n3)cc2)cc1]

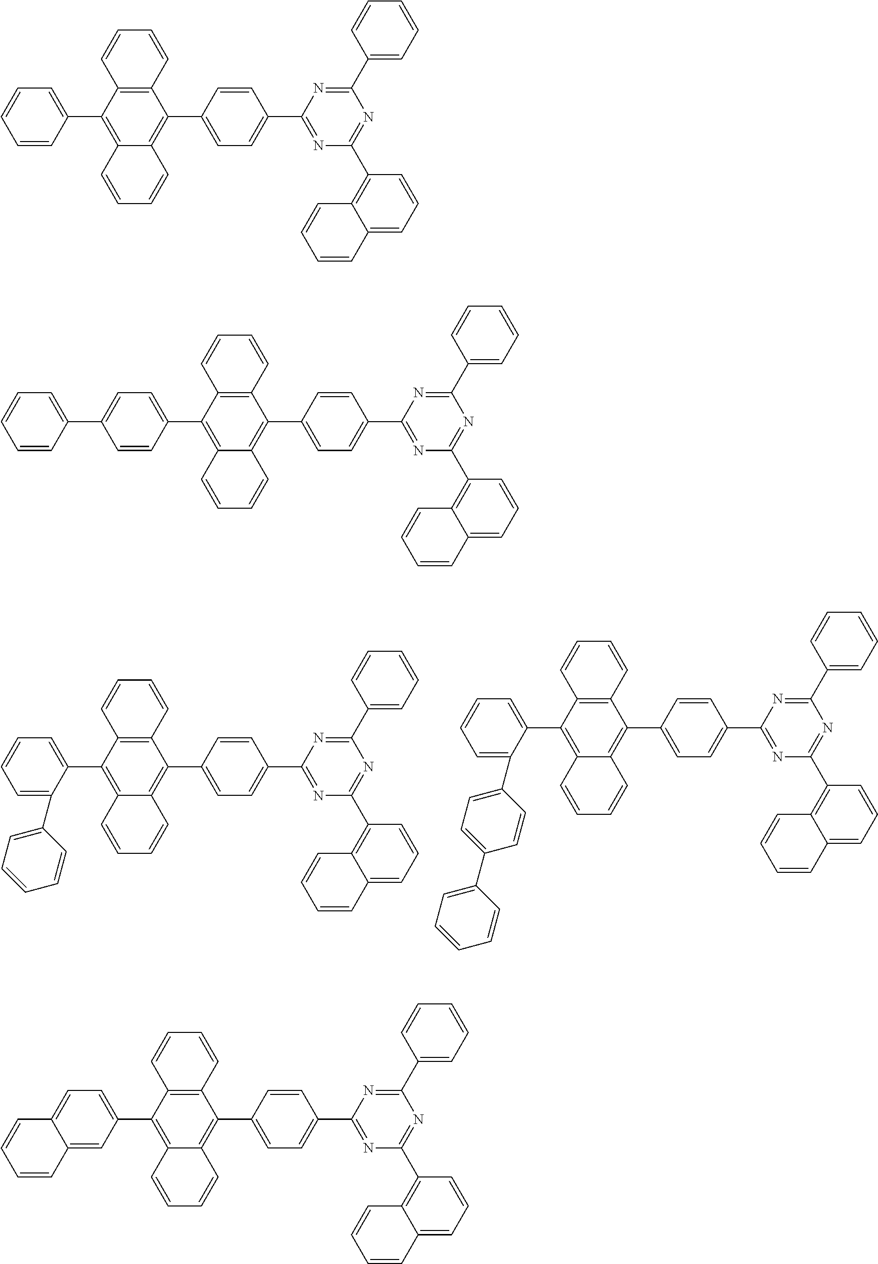

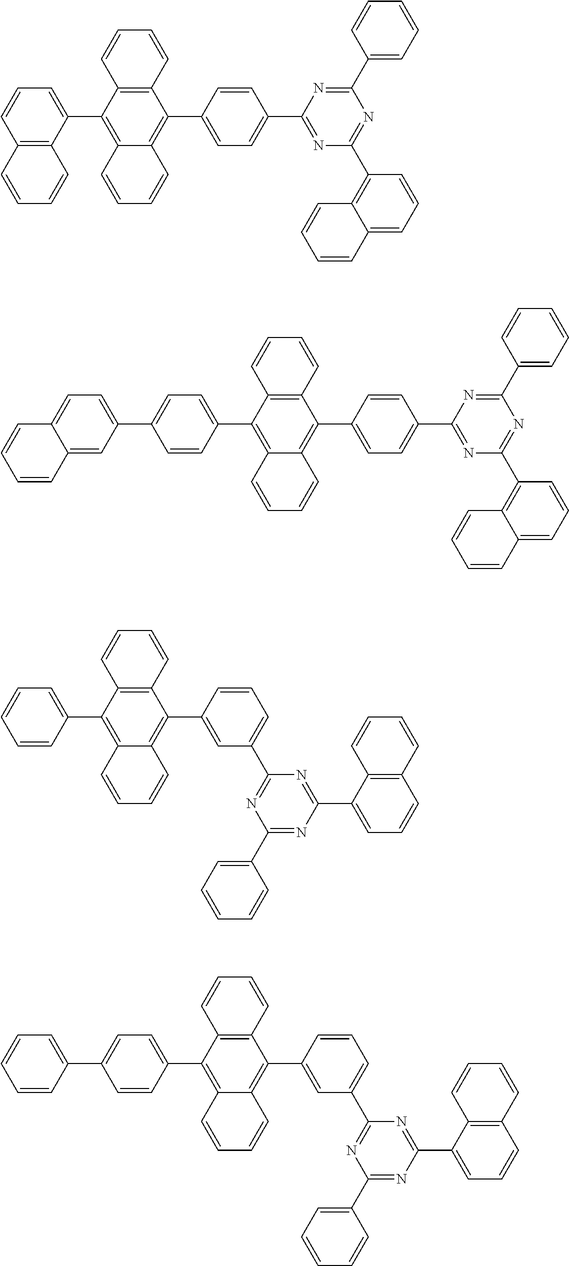 [SMILES: c1ccc(-c2nc(-c3ccc(-c4c5ccccc5c(-c5cccc6ccccc56)c5ccccc45)cc3)nc(-c3cccc4ccccc34)n2)cc1 ; c1ccc(-c2nc(-c3ccc(-c4c5ccccc5c(-c5ccc(-c6ccc7ccccc7c6)cc5)c5ccccc45)cc3)nc(-c3cccc4ccccc34)n2)cc1 ; c1ccc(-c2nc(-c3cccc(-c4c5ccccc5c(-c5ccccc5)c5ccccc45)c3)nc(-c3cccc4ccccc34)n2)cc1 ; c1ccc(-c2ccc(-c3c4ccccc4c(-c4cccc(-c5nc(-c6ccccc6)nc(-c6cccc7ccccc67)n5)c4)c4ccccc34)cc2)cc1]

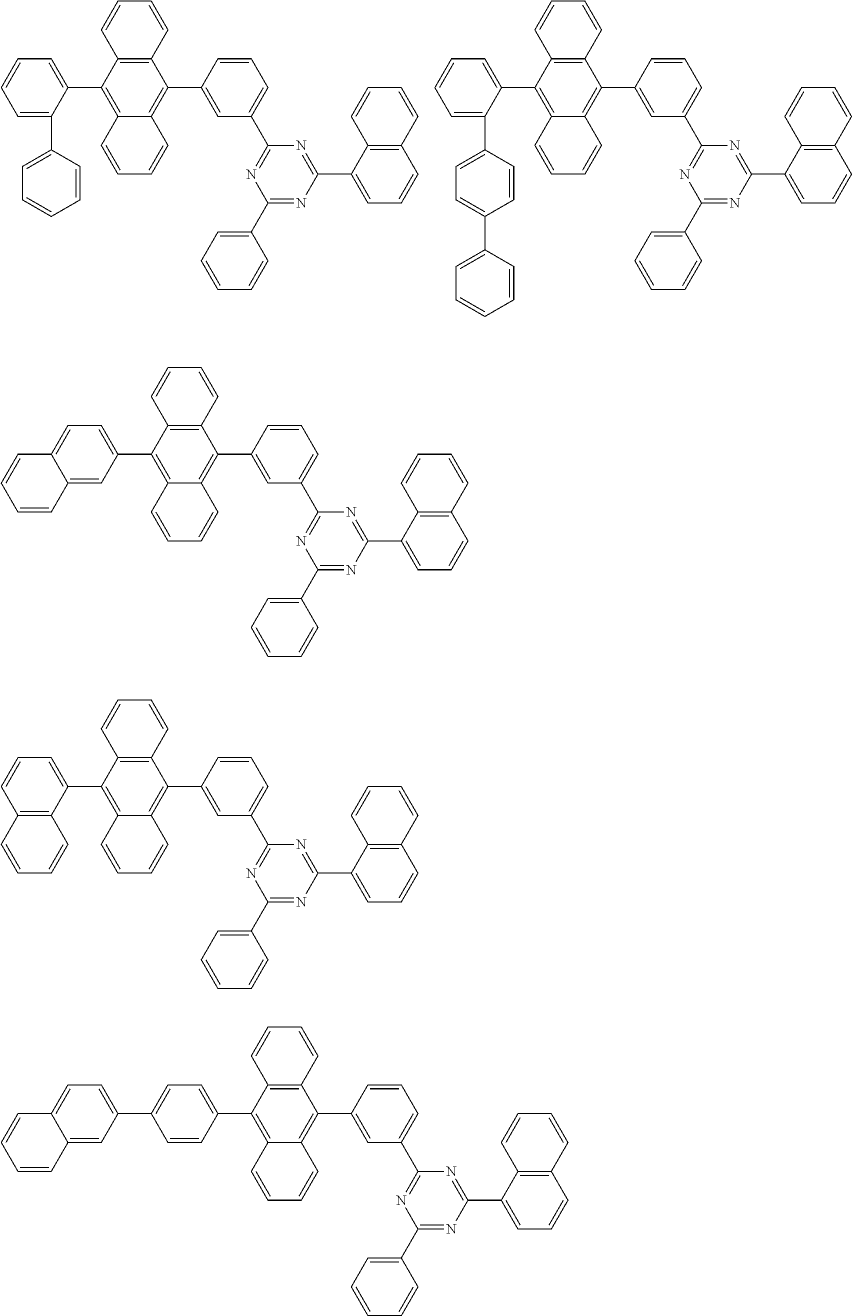

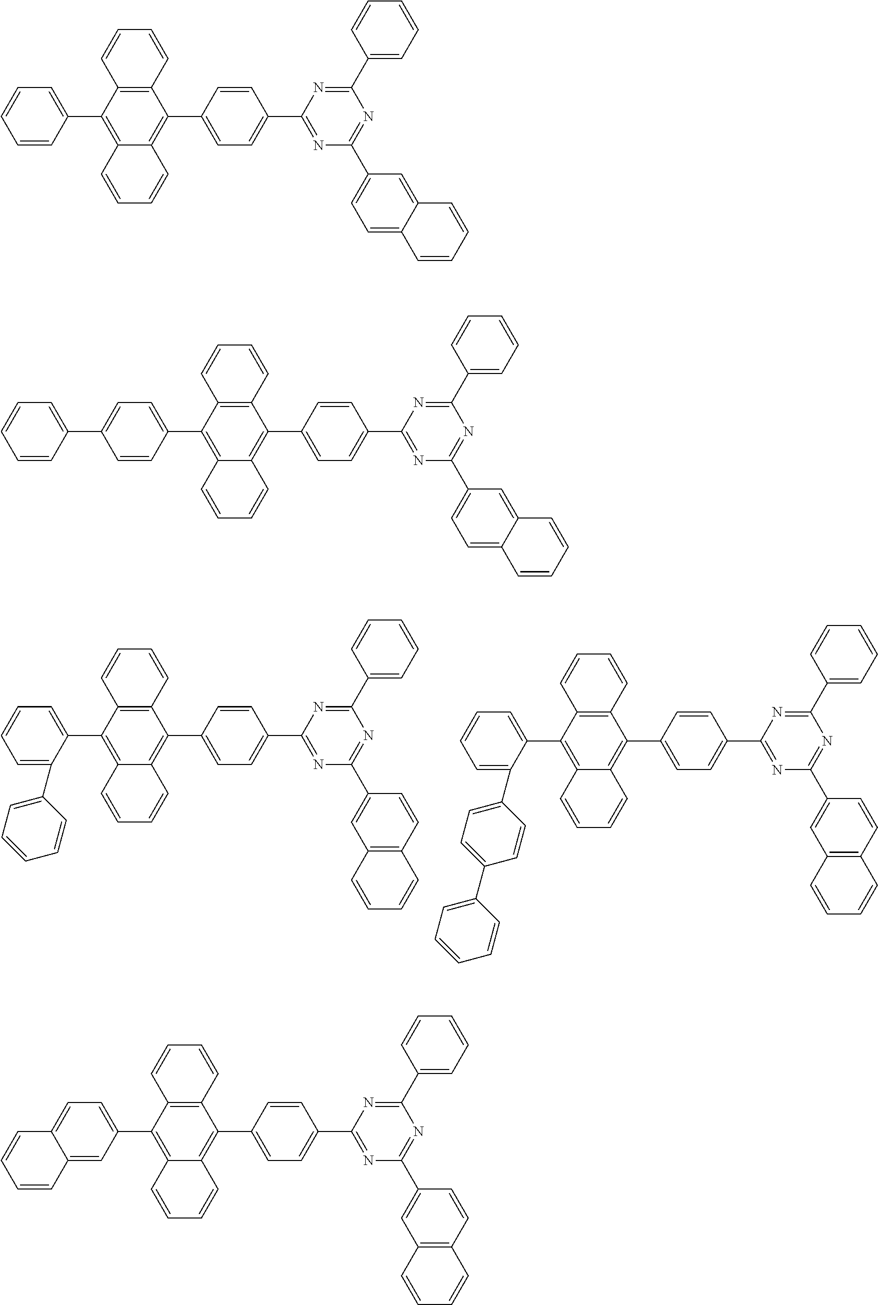

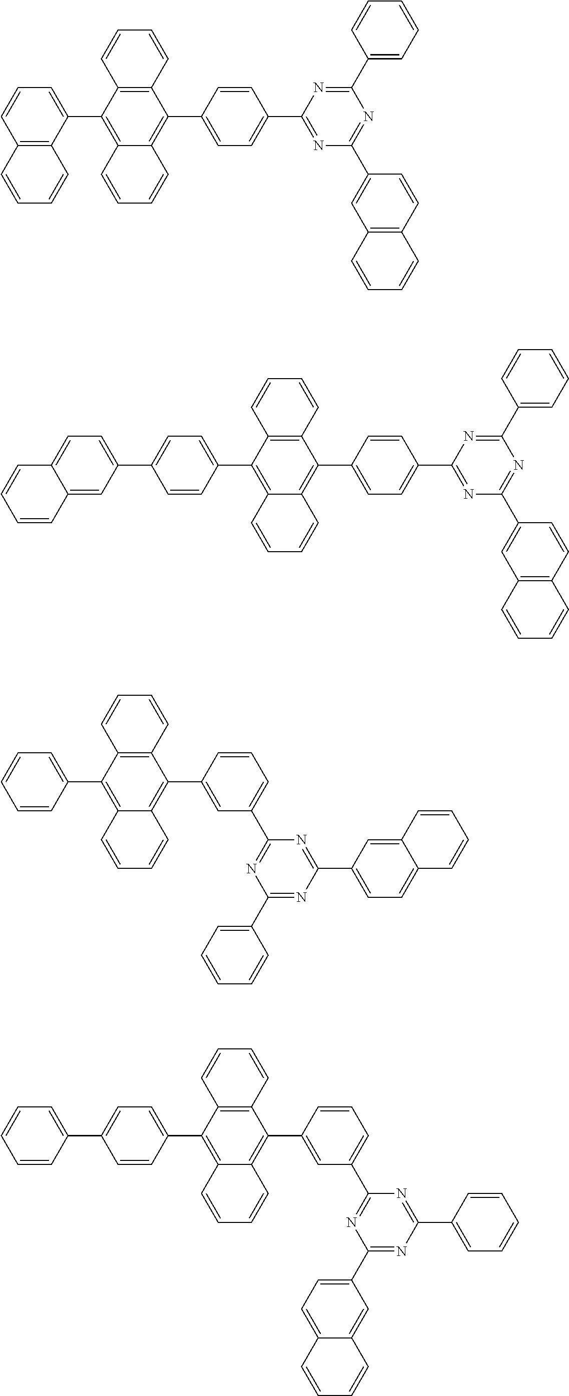 [SMILES: c1ccc(-c2nc(-c3ccc(-c4c5ccccc5c(-c5cccc6ccccc56)c5ccccc45)cc3)nc(-c3ccc4ccccc4c3)n2)cc1 ; c1ccc(-c2nc(-c3ccc(-c4c5ccccc5c(-c5ccc(-c6ccc7ccccc7c6)cc5)c5ccccc45)cc3)nc(-c3ccc4ccccc4c3)n2)cc1 ; c1ccc(-c2nc(-c3cccc(-c4c5ccccc5c(-c5ccccc5)c5ccccc45)c3)nc(-c3ccc4ccccc4c3)n2)cc1 ; c1ccc(-c2ccc(-c3c4ccccc4c(-c4cccc(-c5nc(-c6ccccc6)nc(-c6ccc7ccccc7c6)n5)c4)c4ccccc34)cc2)cc1]

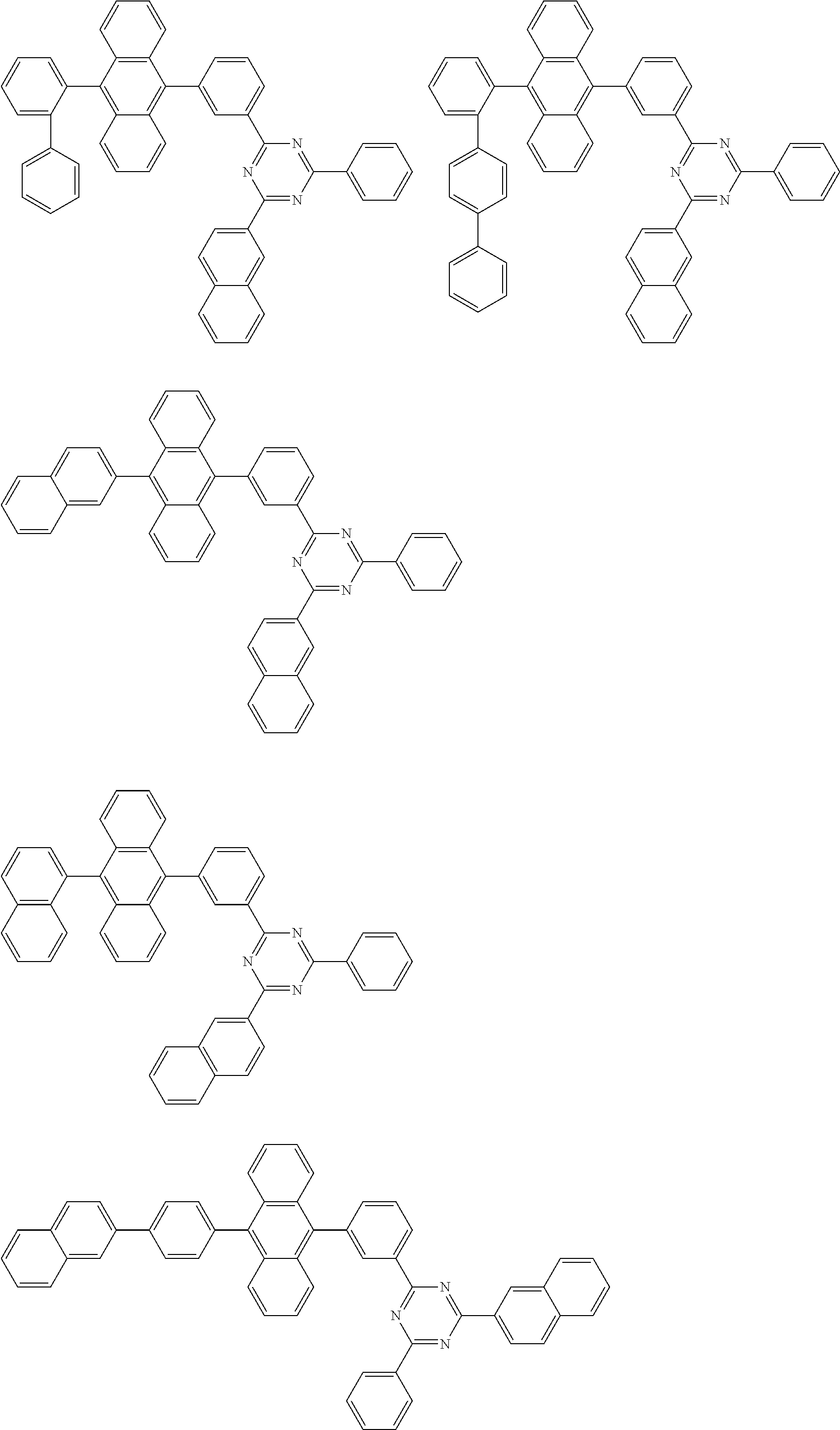

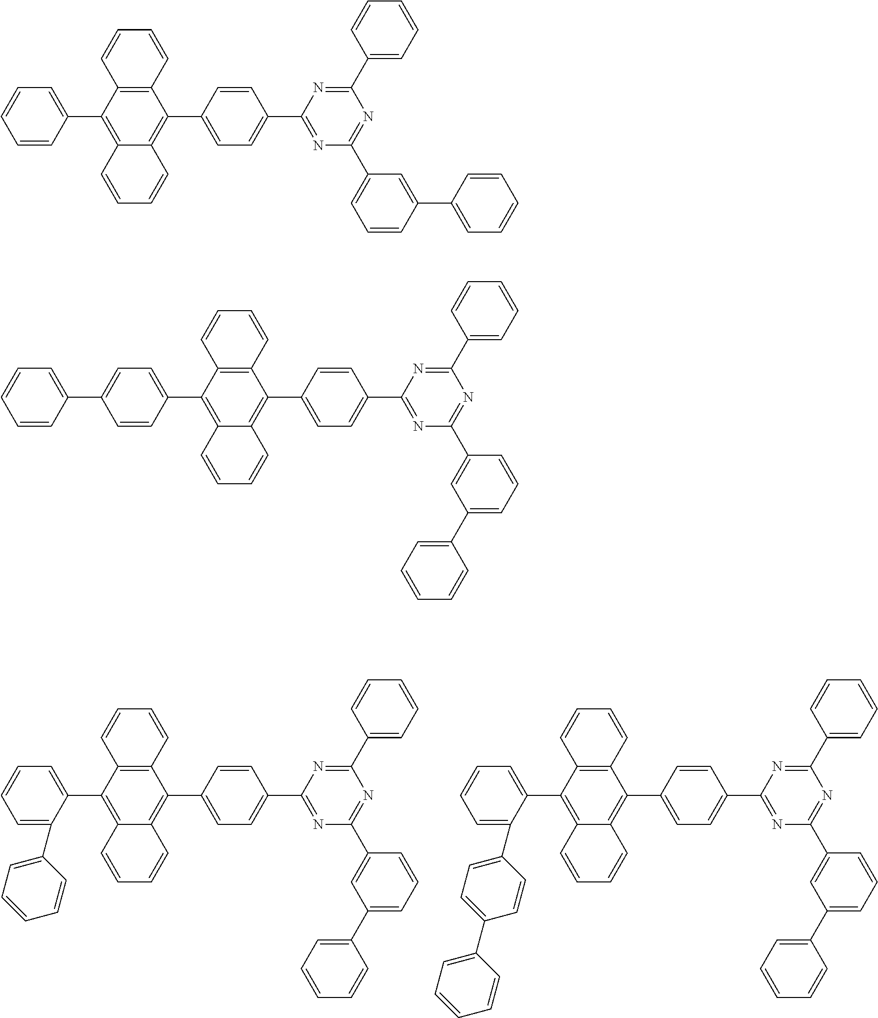

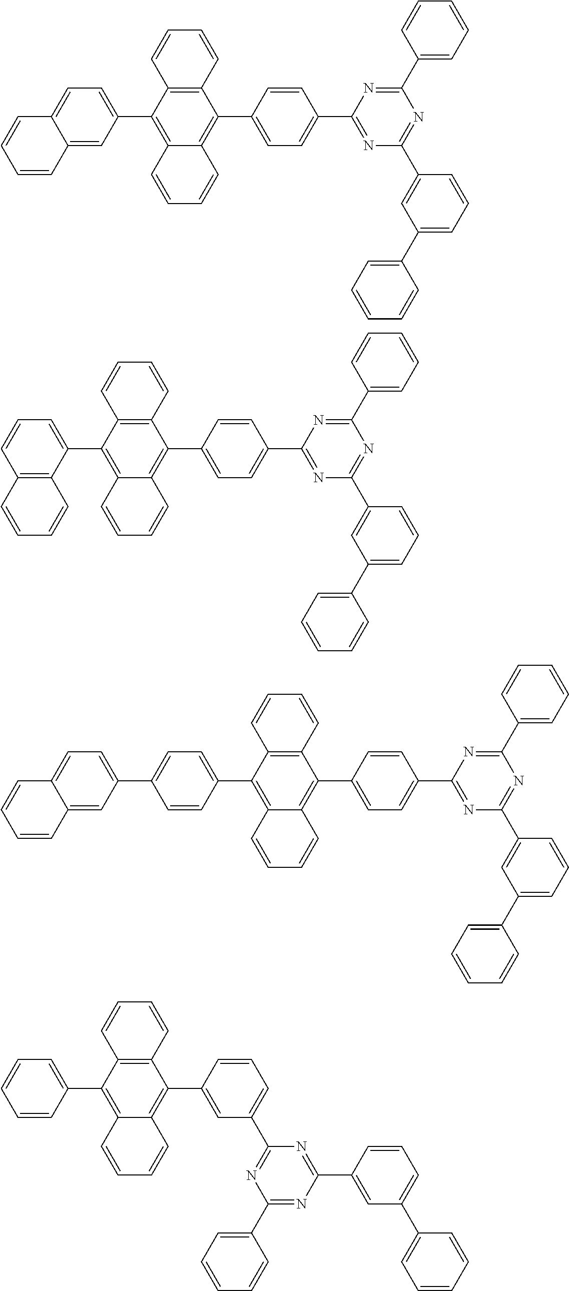

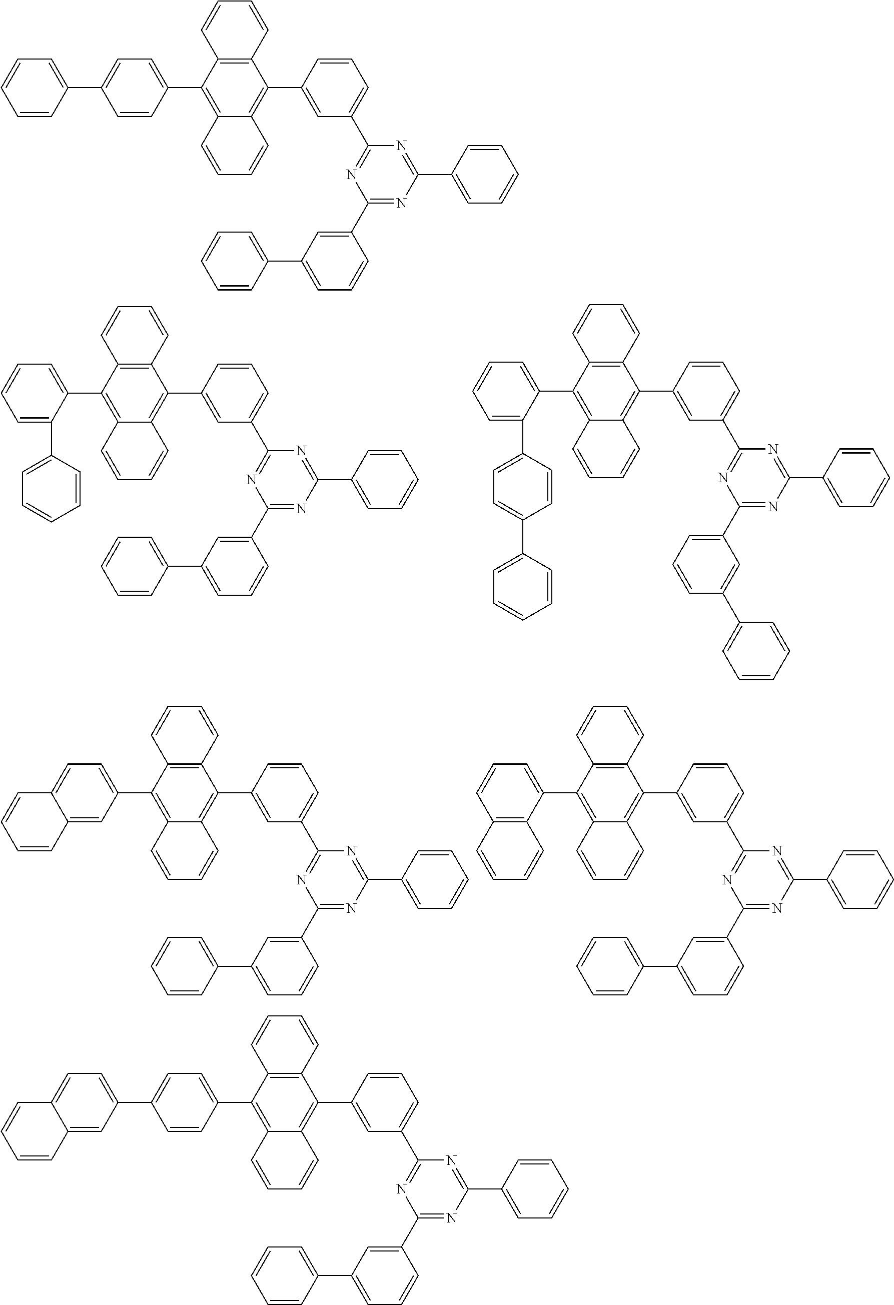

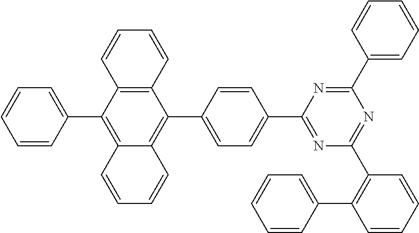 [SMILES: c1ccc(-c2nc(-c3ccc(-c4c5ccccc5c(-c5ccccc5)c5ccccc45)cc3)nc(-c3ccccc3-c3ccccc3)n2)cc1]

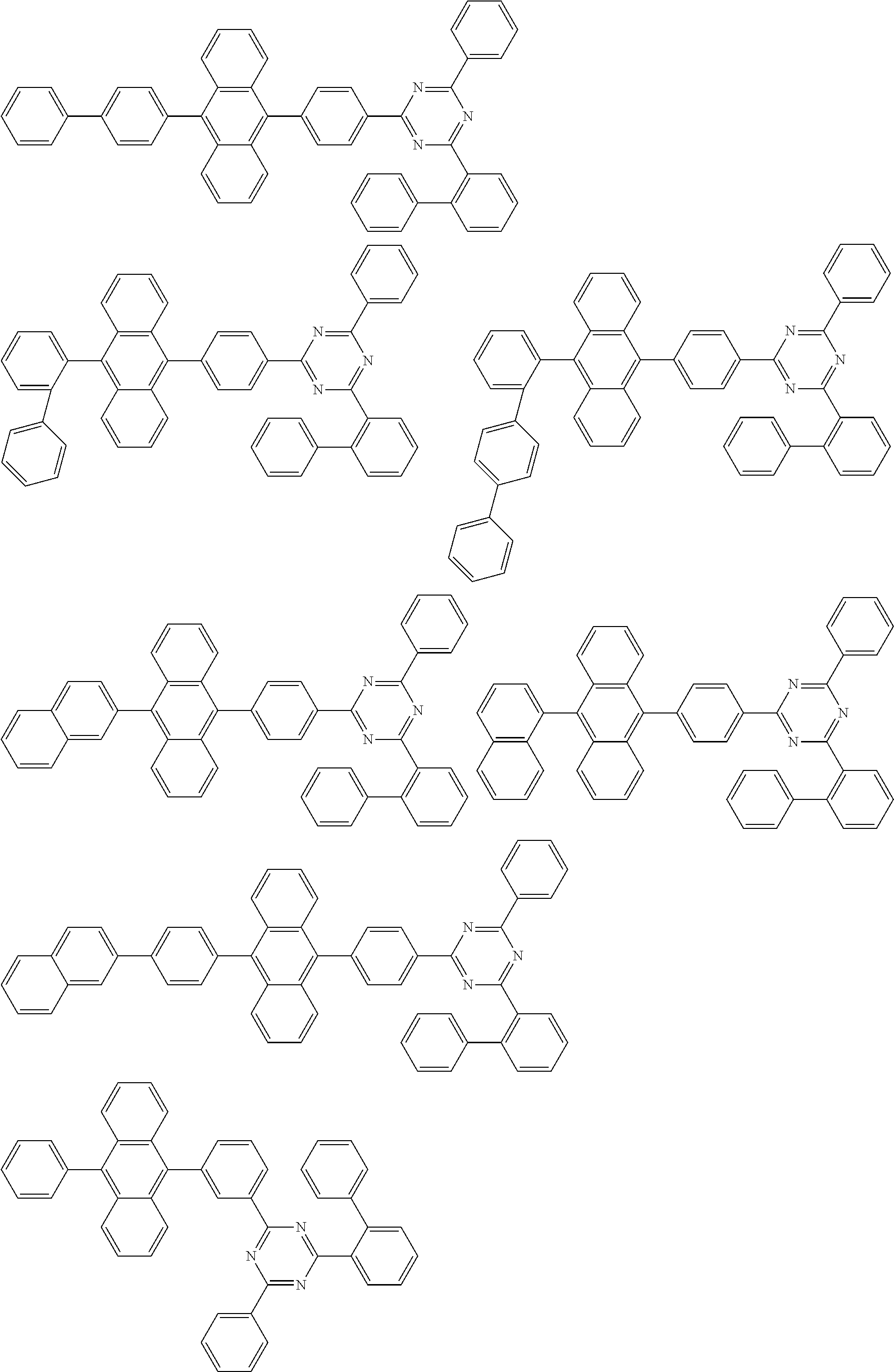

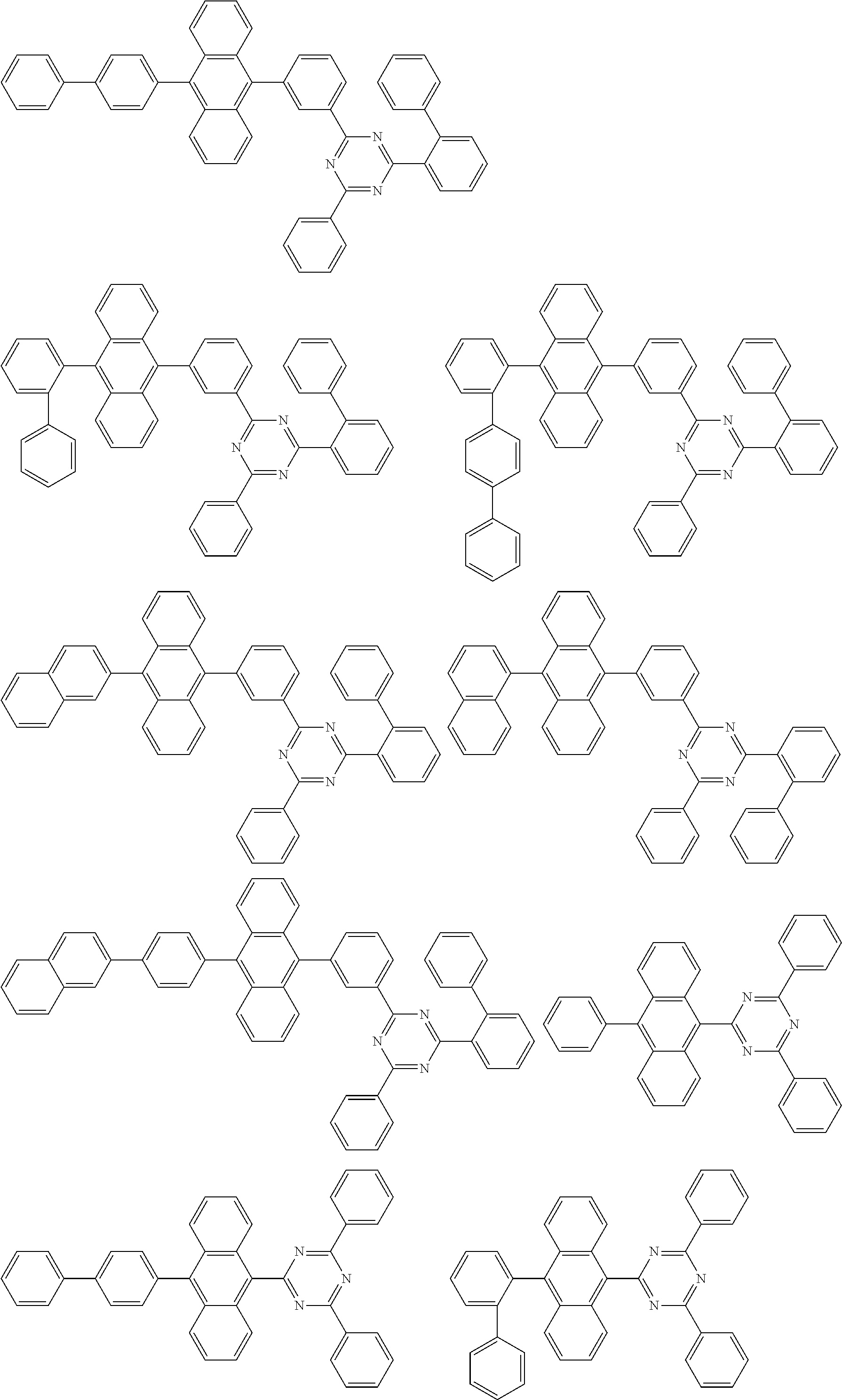

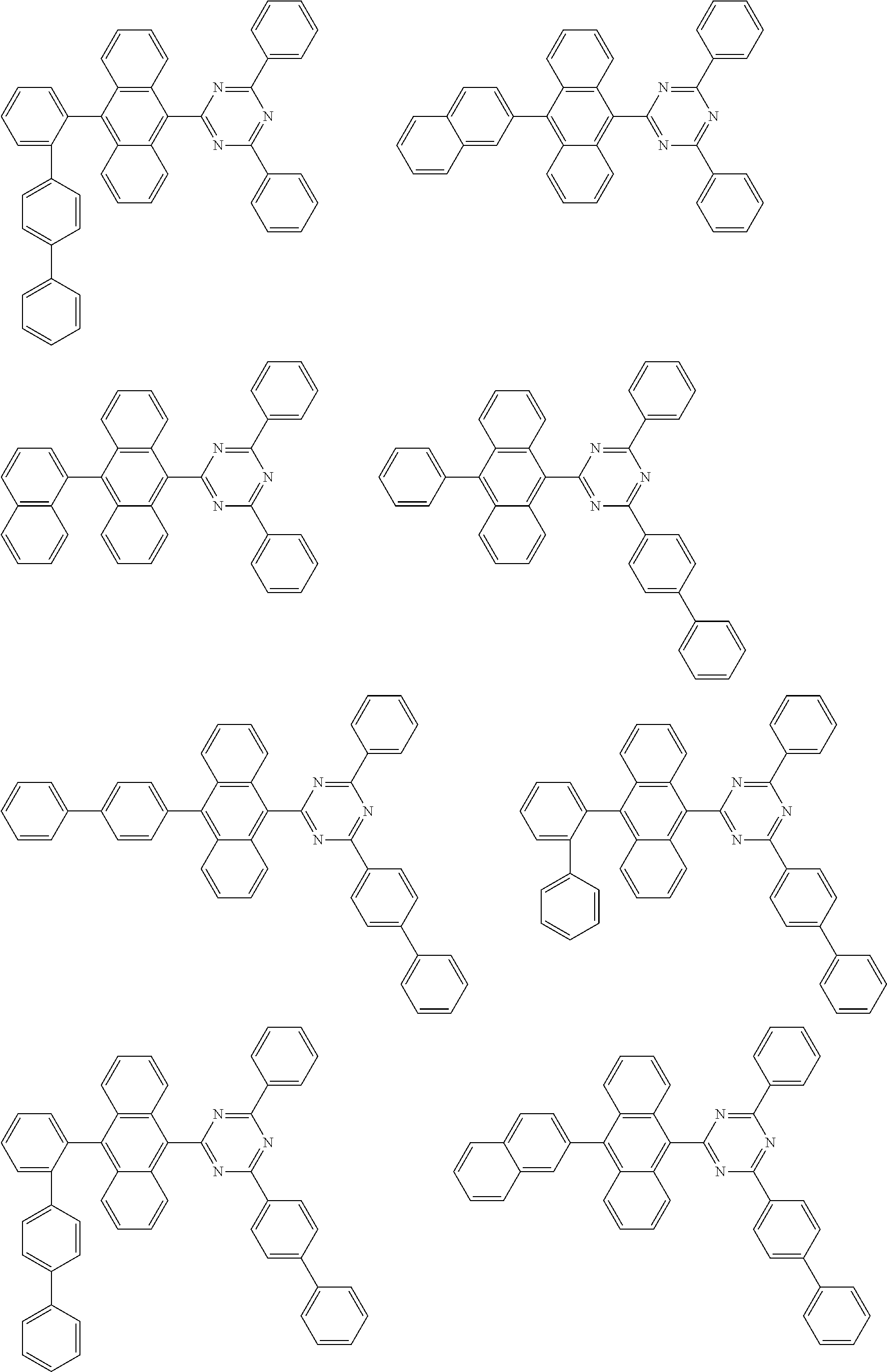

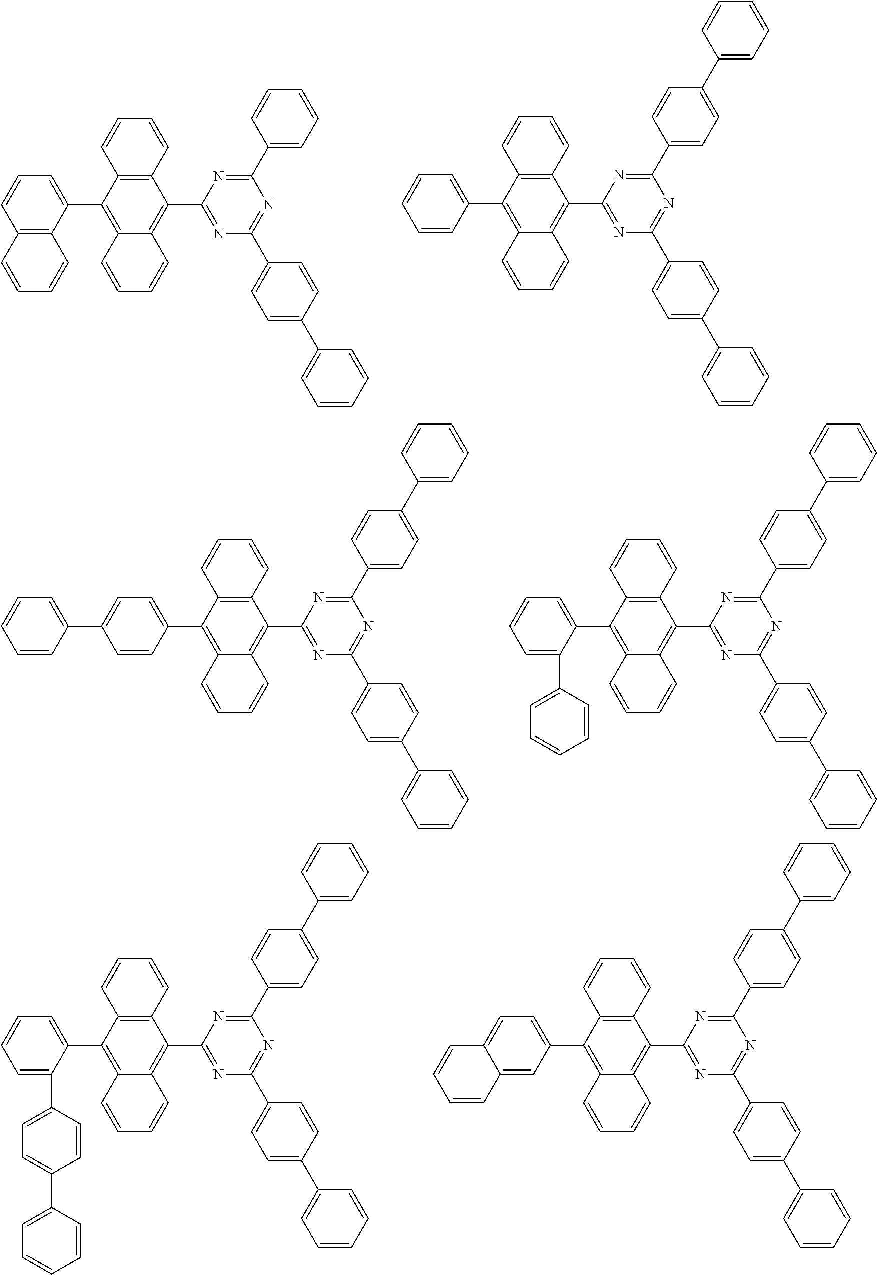

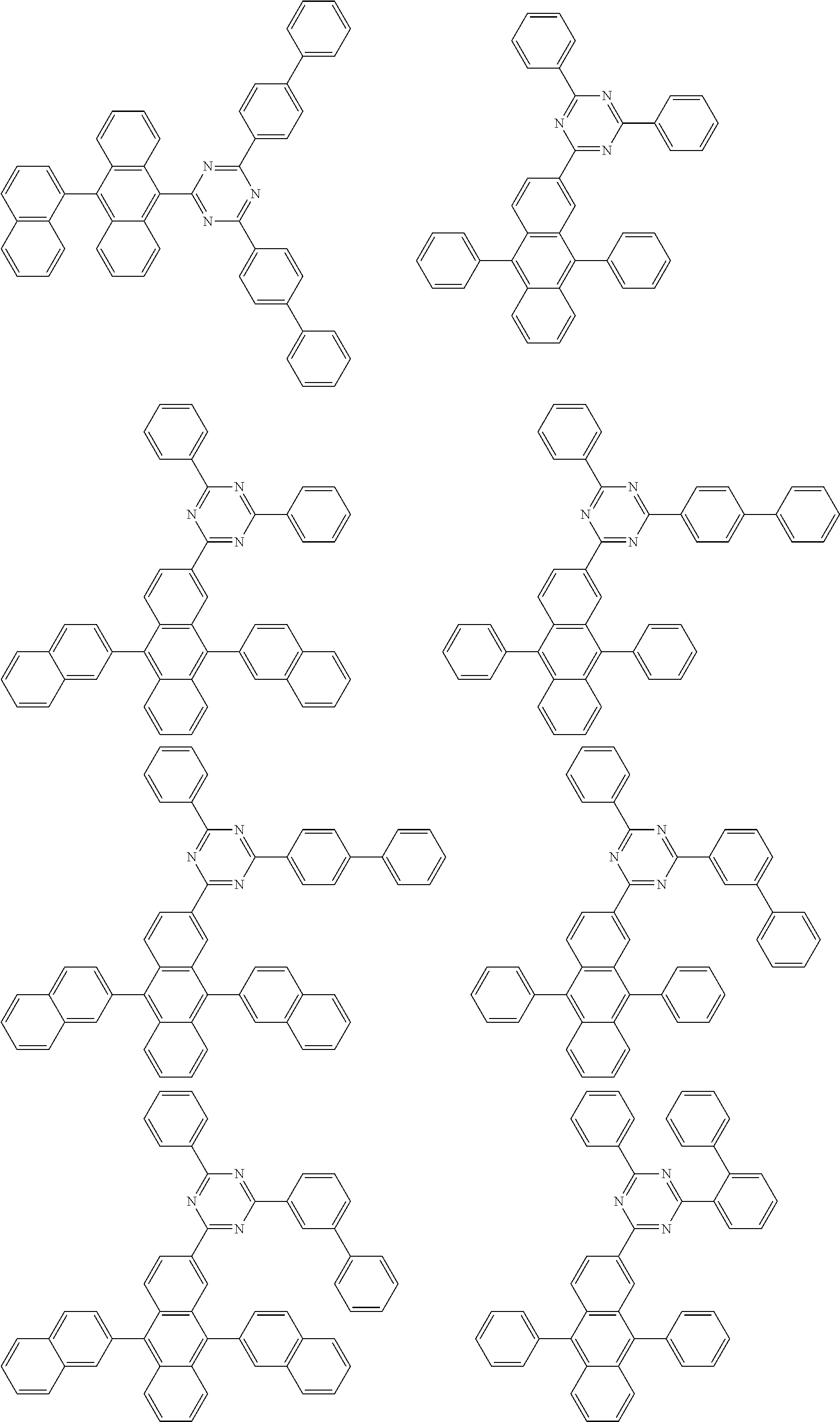

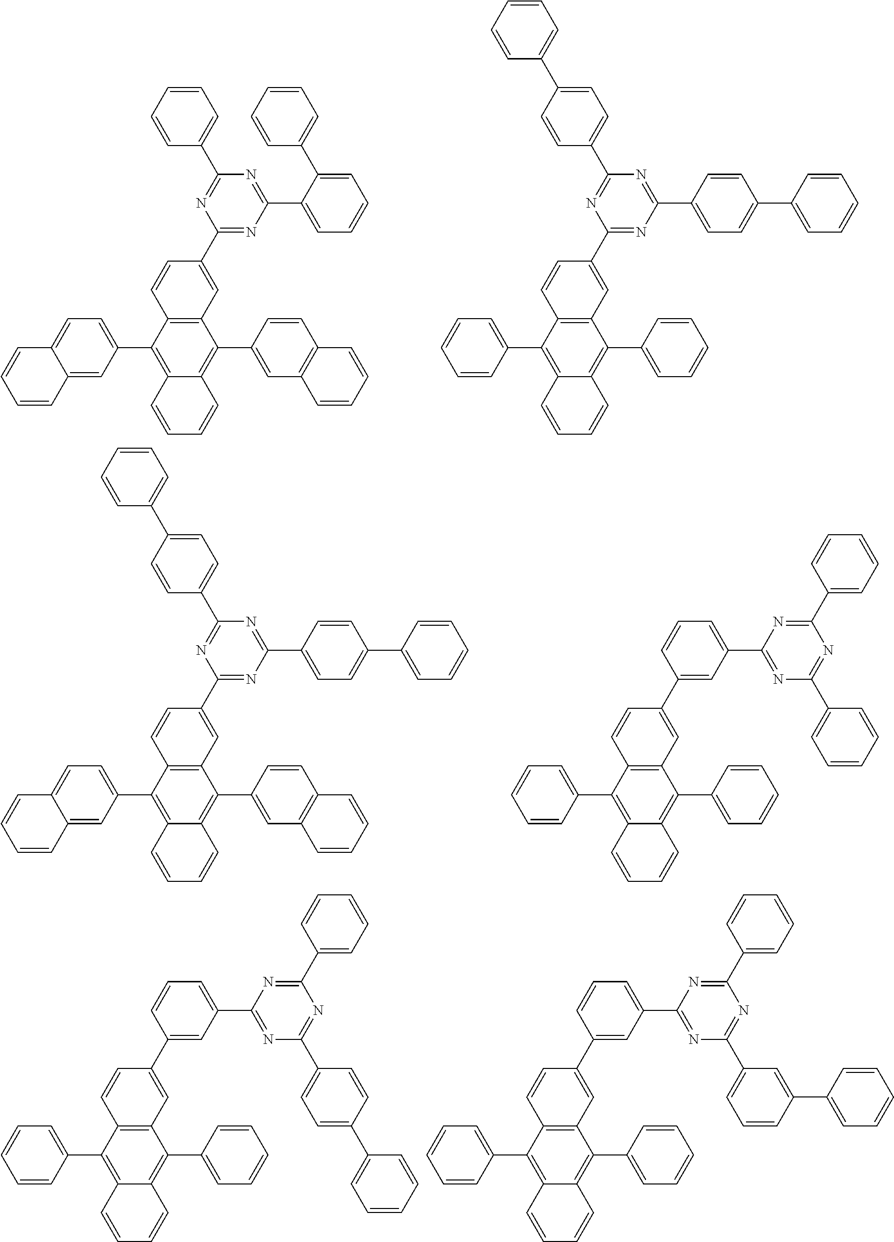

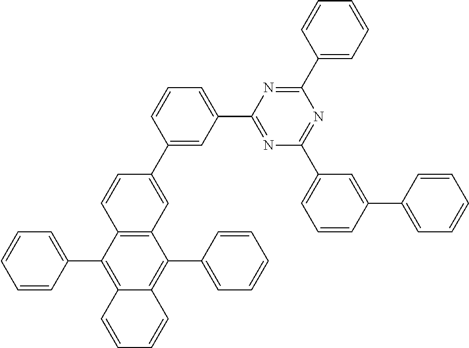 [SMILES: c1ccc(-c2cccc(-c3nc(-c4ccccc4)nc(-c4cccc(-c5ccc6c(-c7ccccc7)c7ccccc7c(-c7ccccc7)c6c5)c4)n3)c2)cc1]

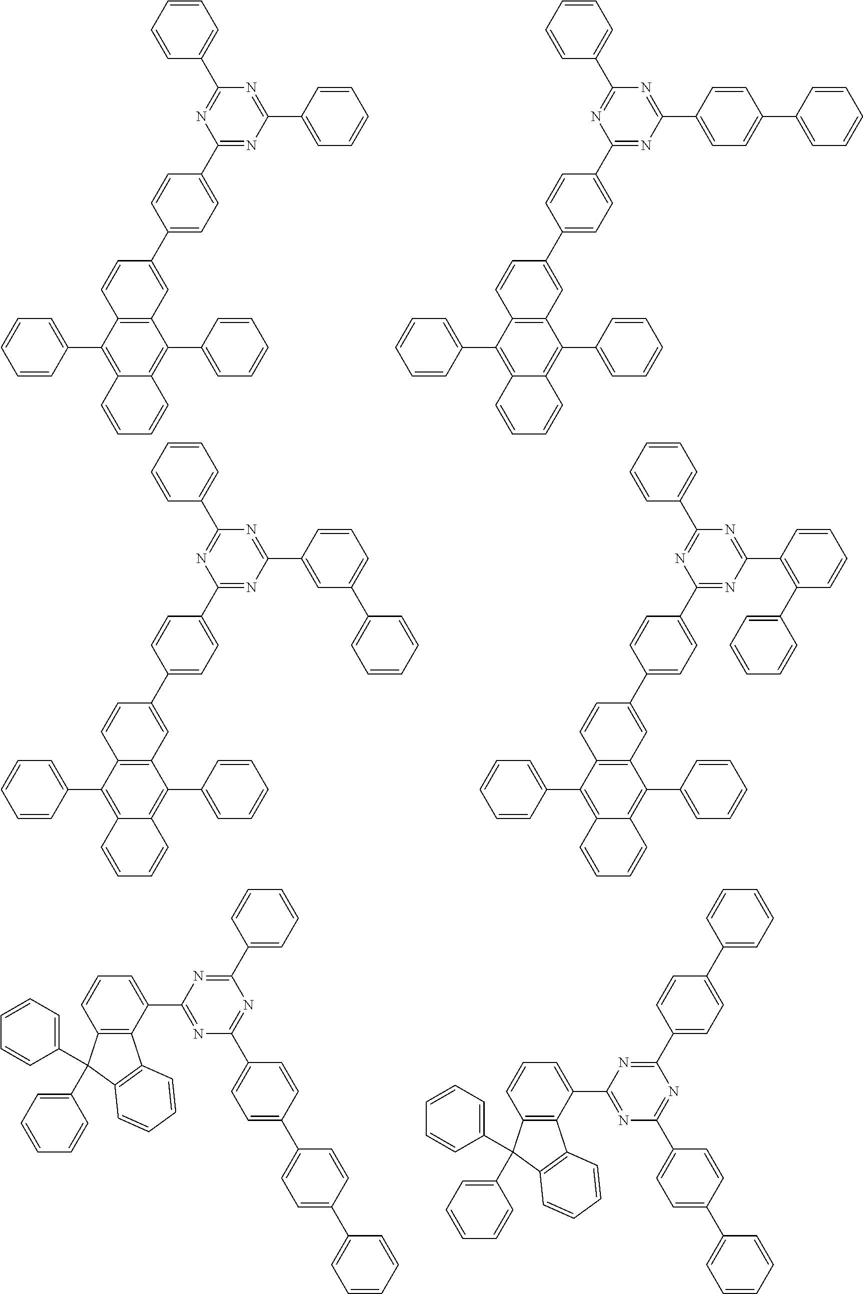

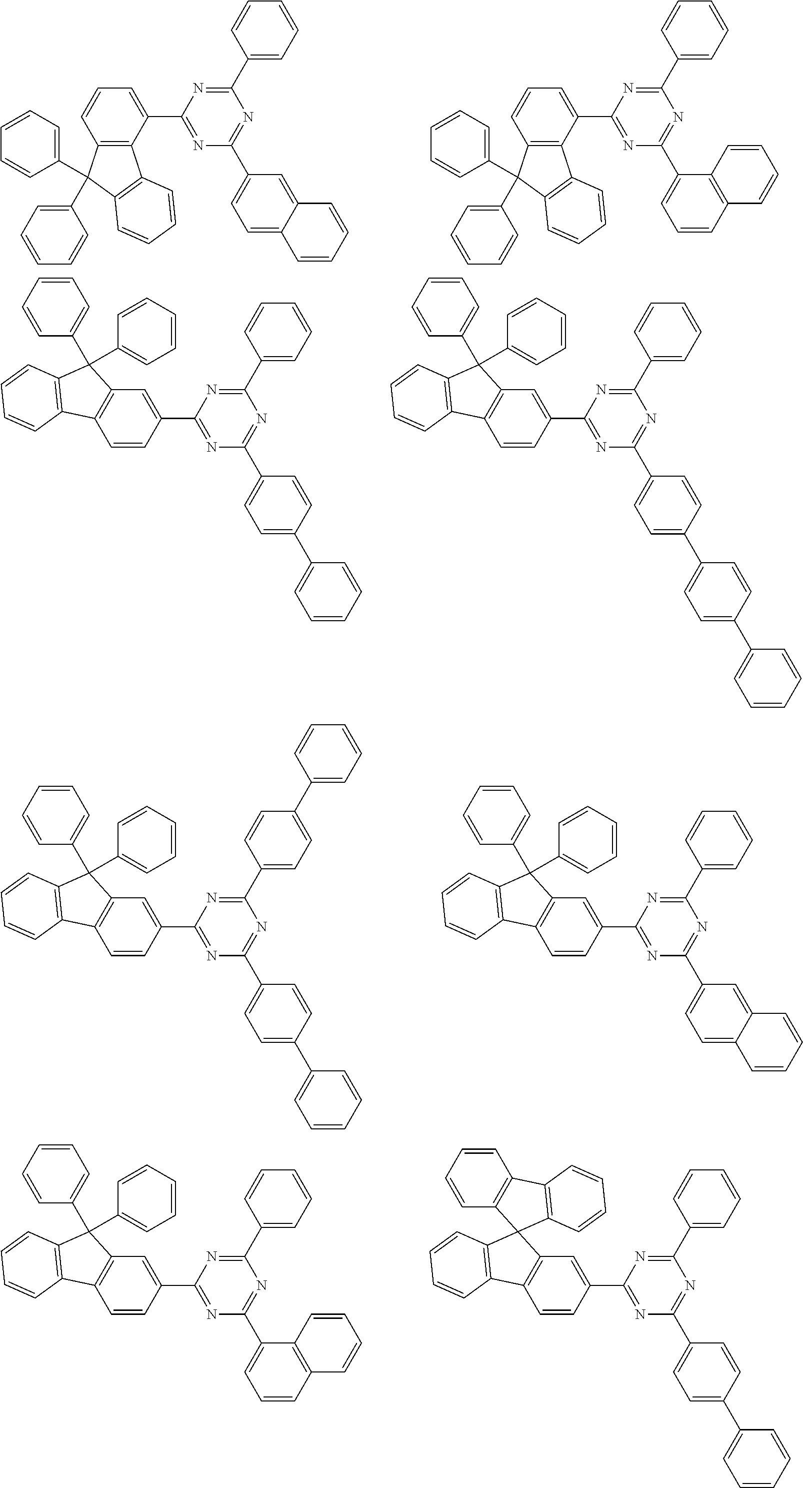

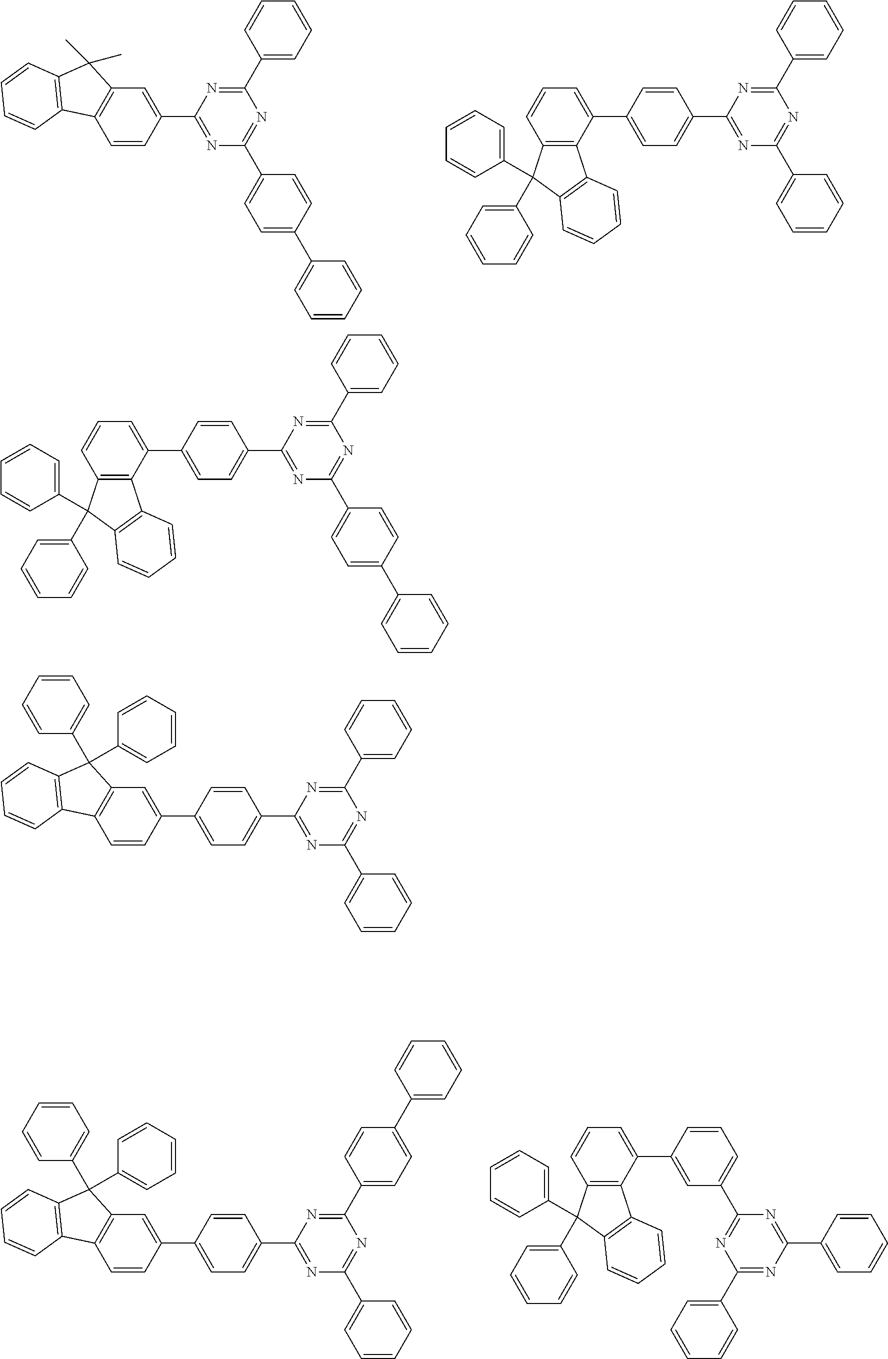

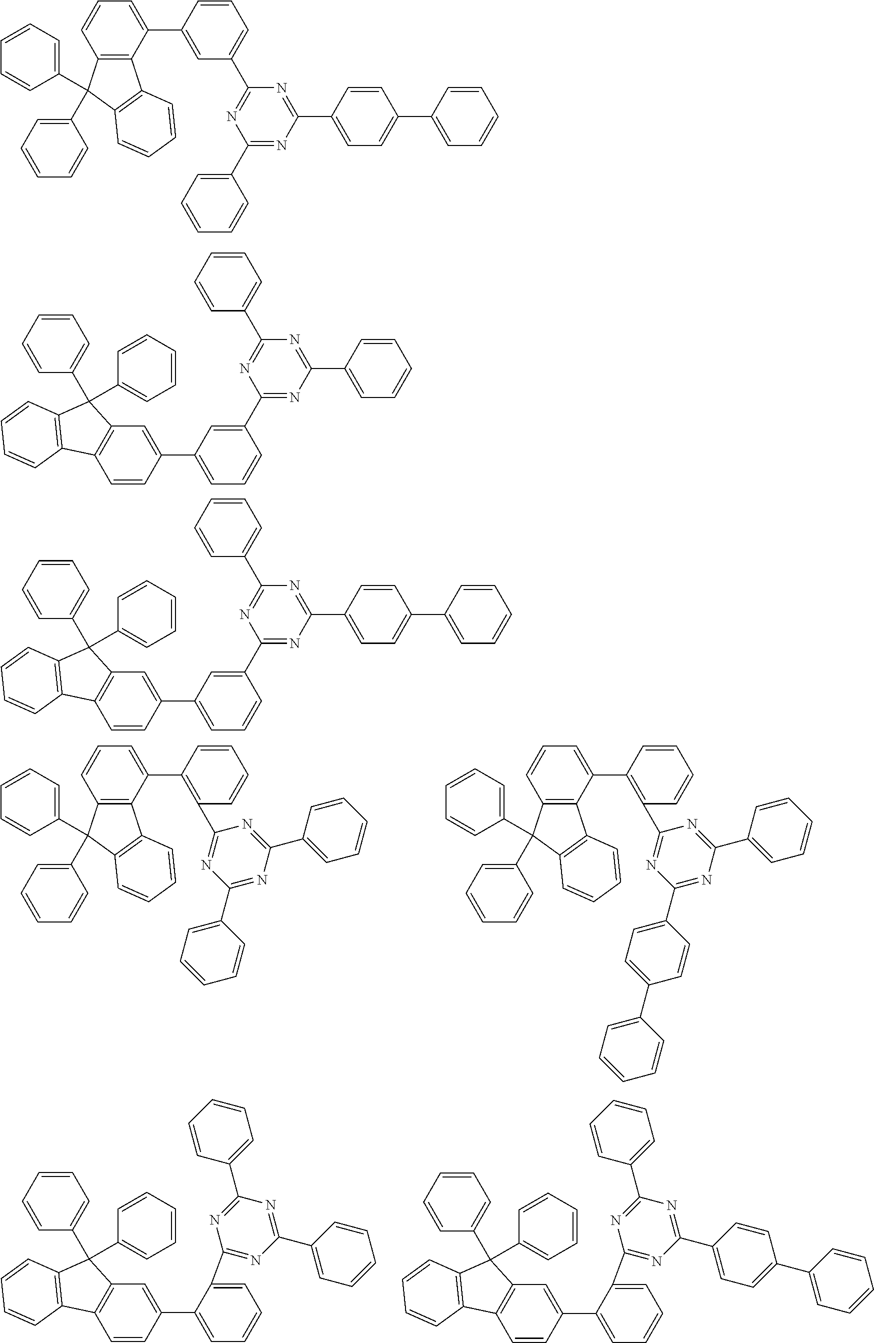

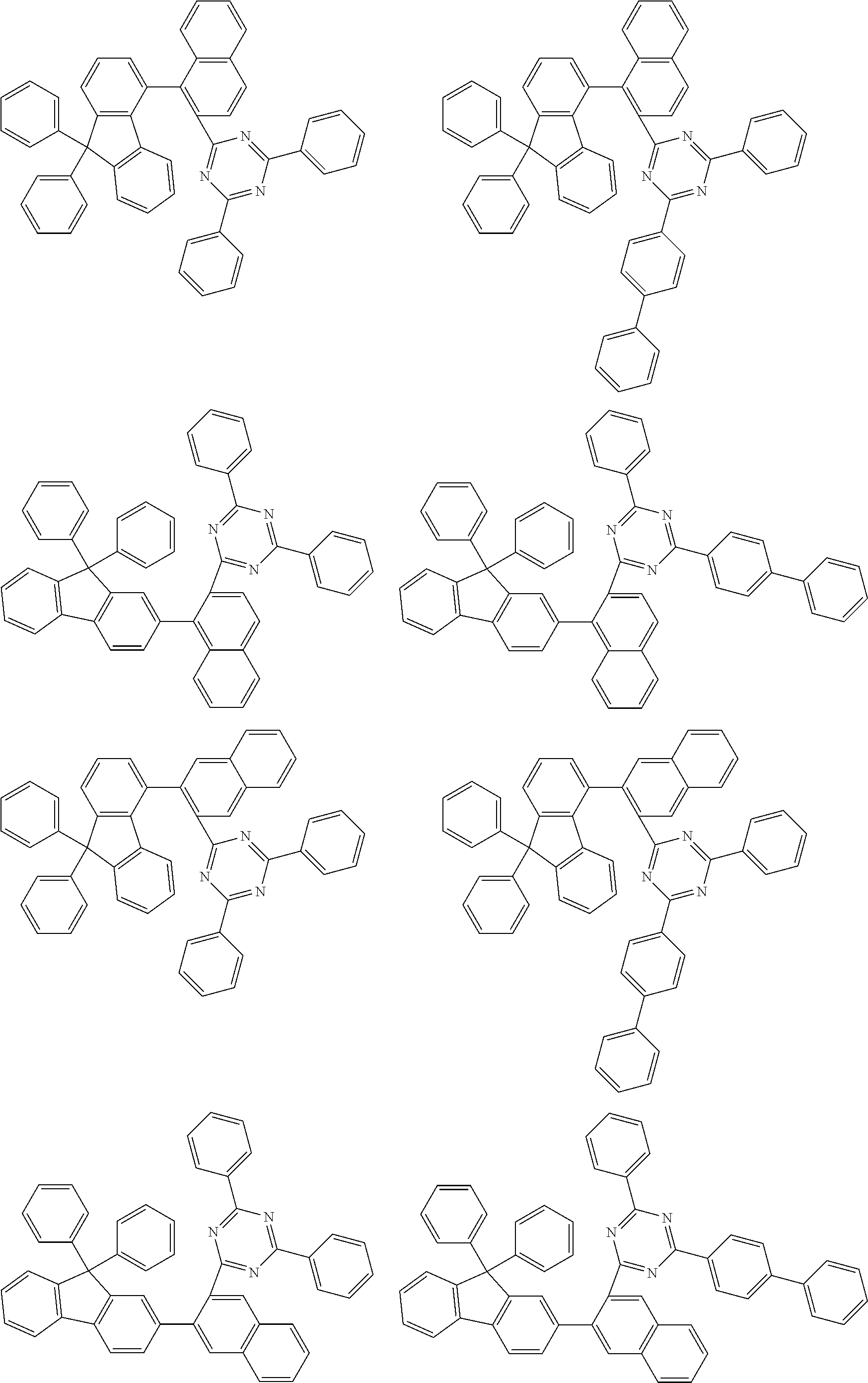

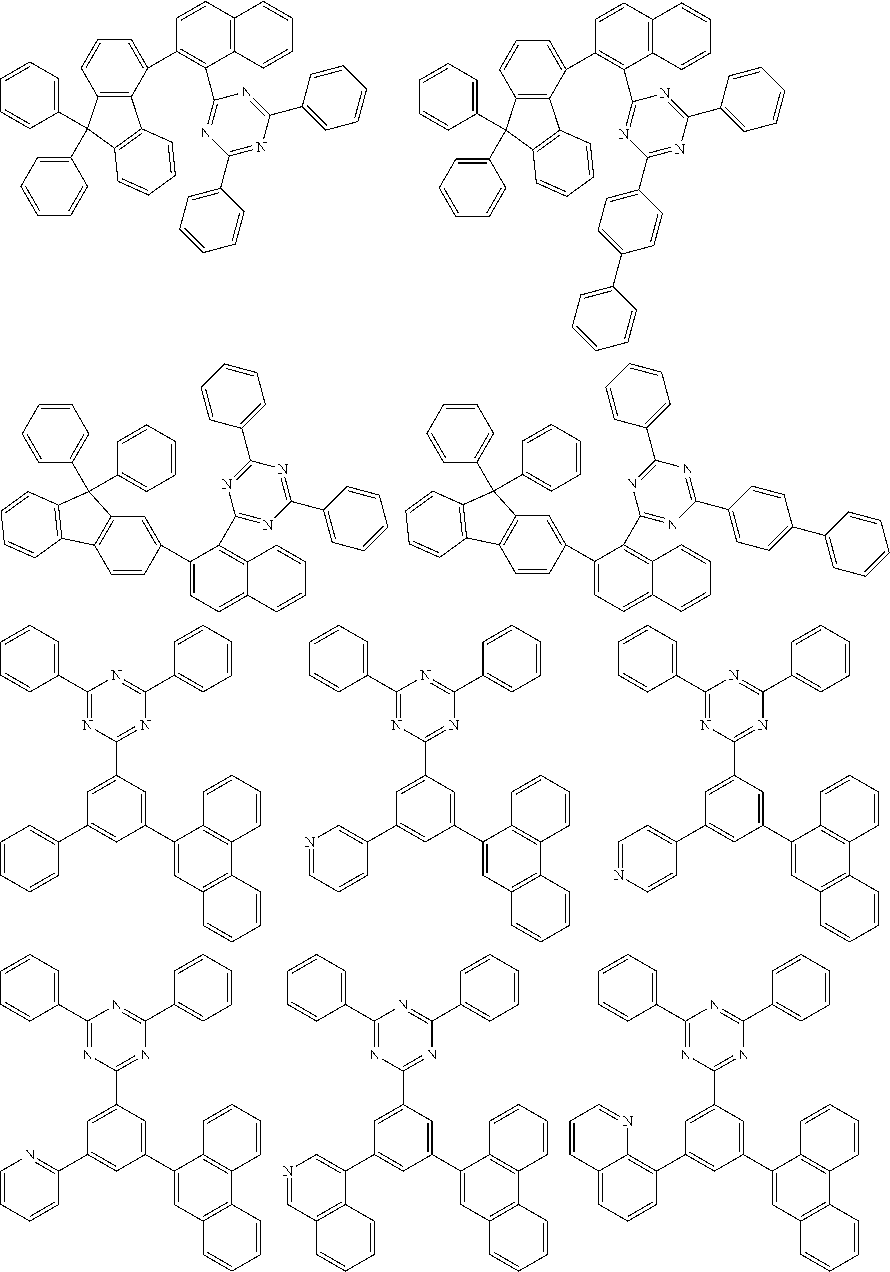

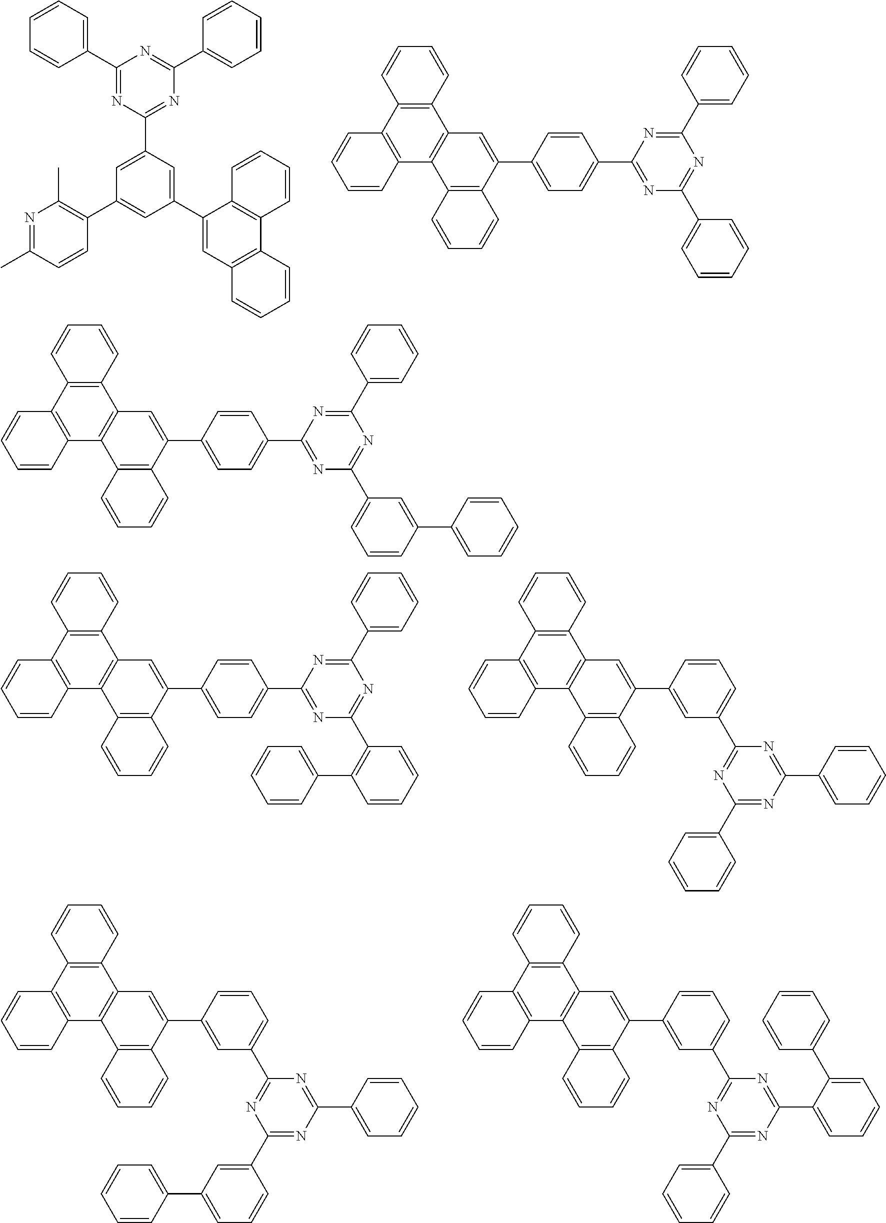

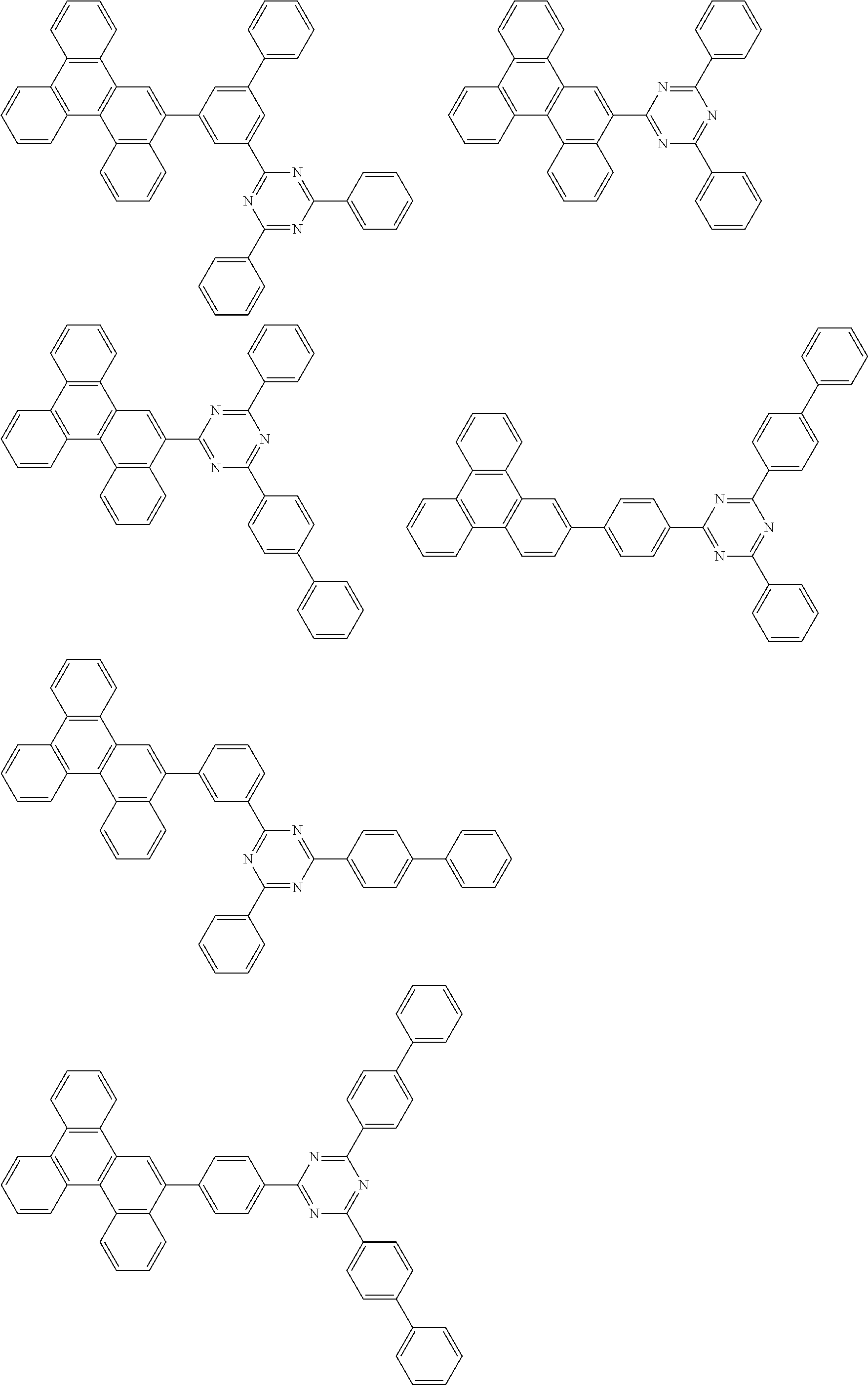

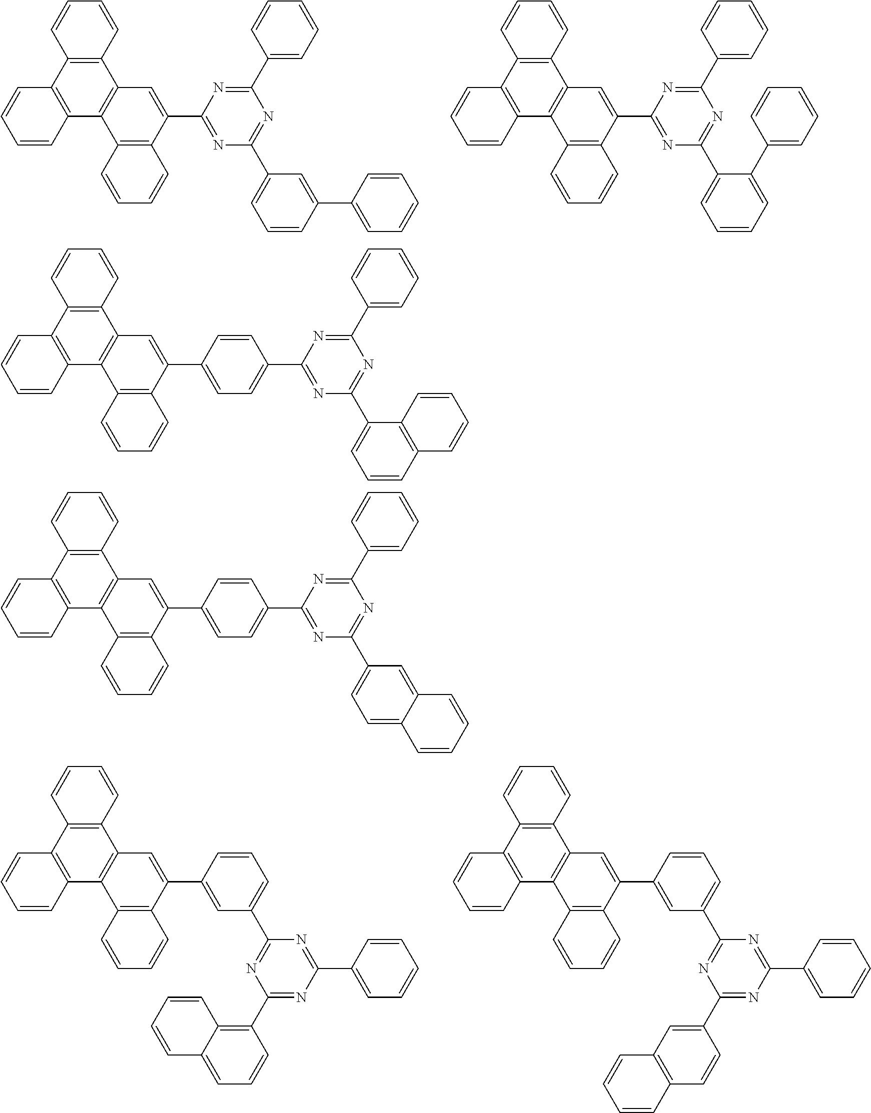

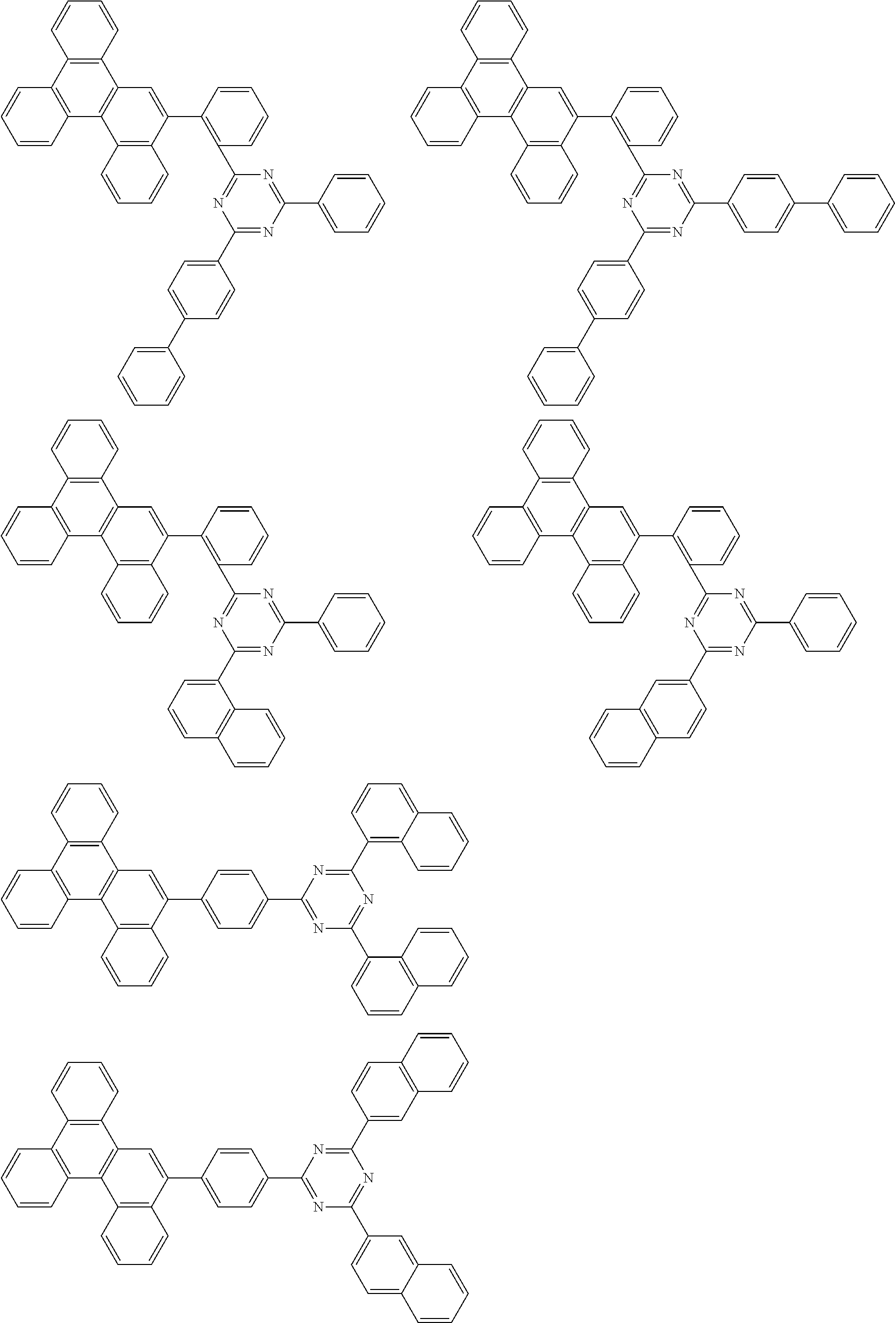

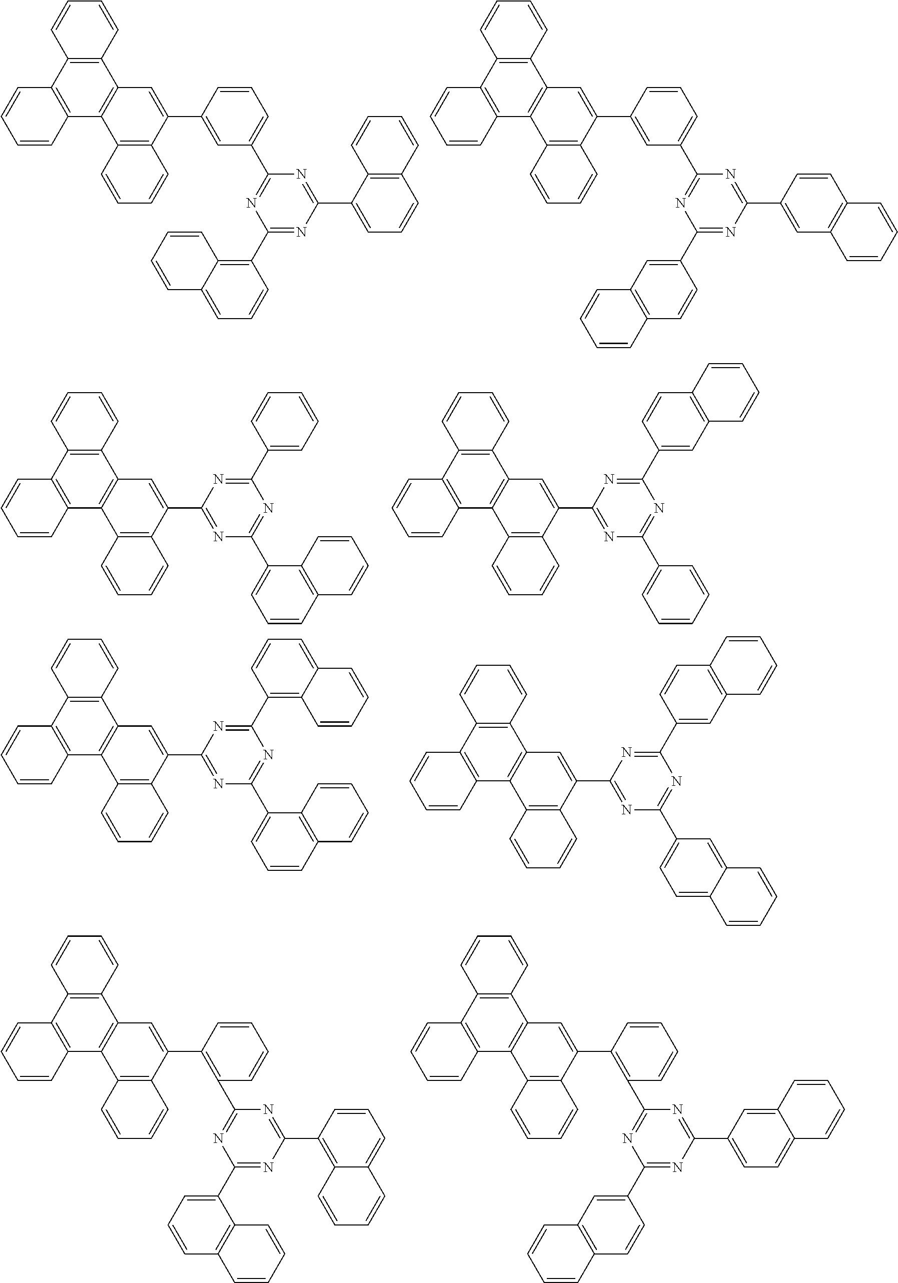

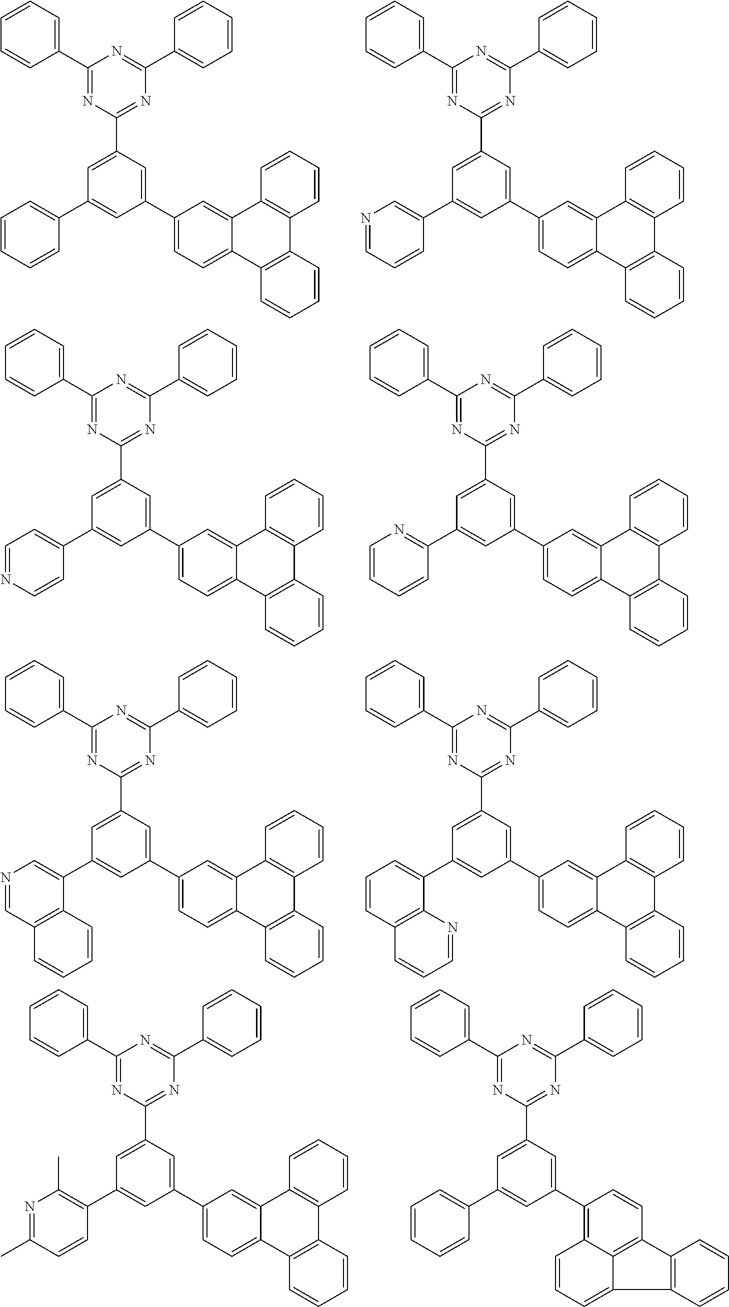

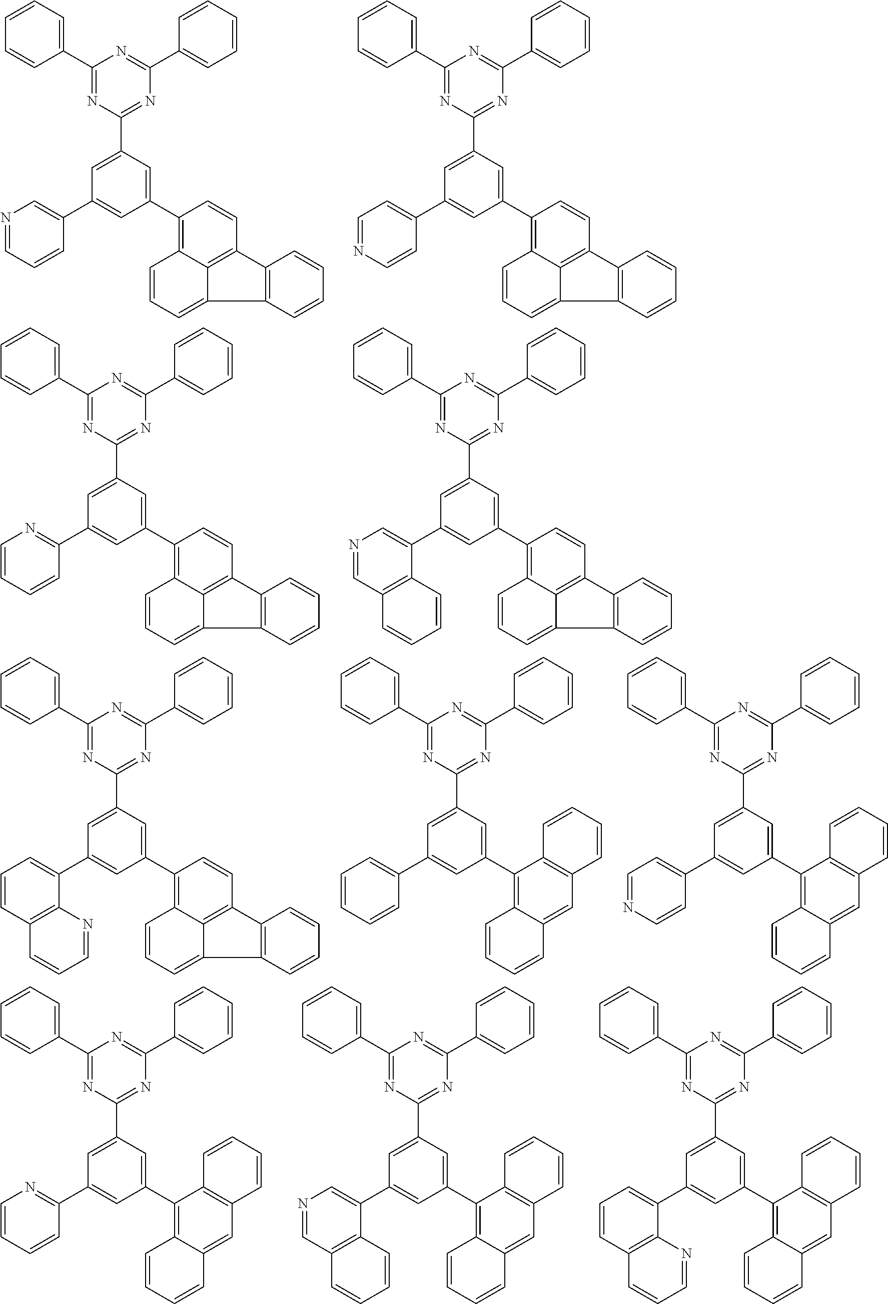

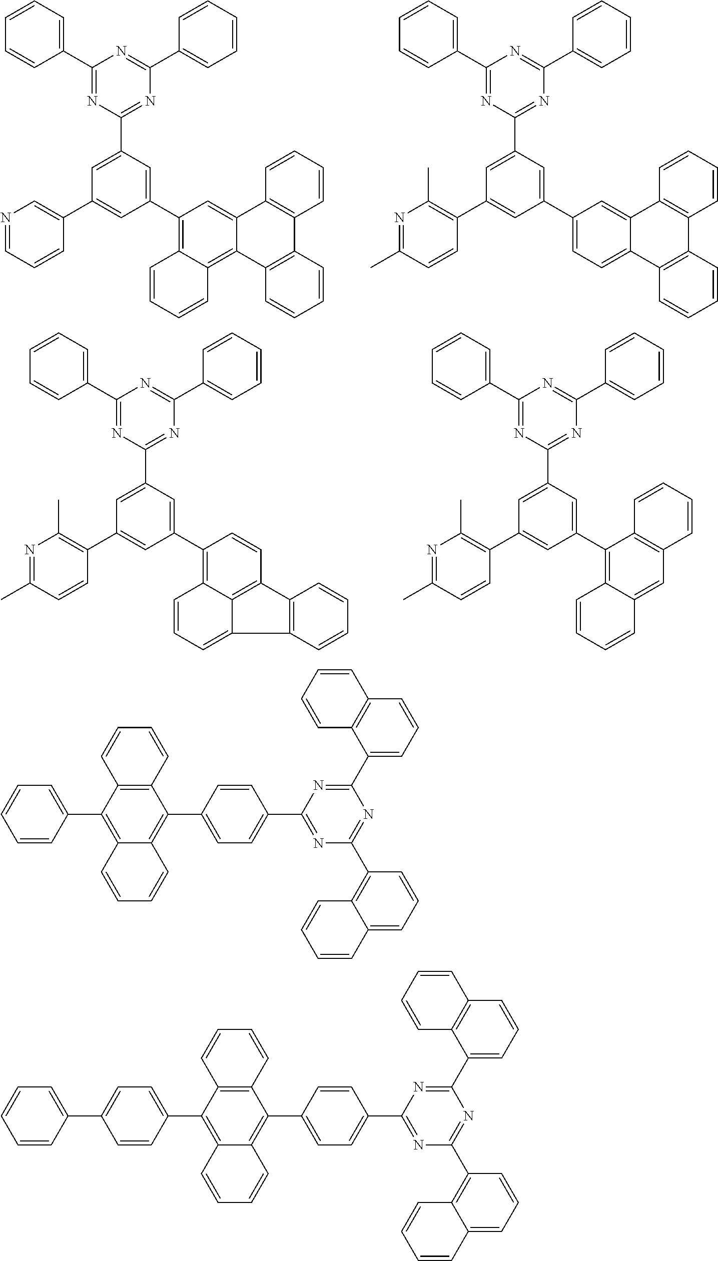

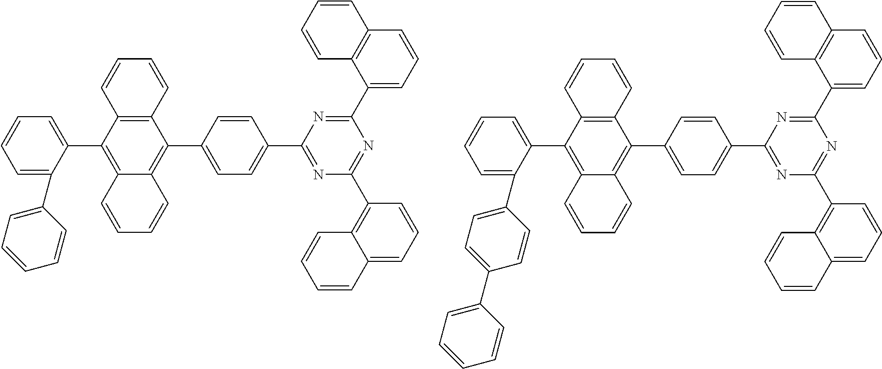 [SMILES: c1ccc(-c2ccccc2-c2c3ccccc3c(-c3ccc(-c4nc(-c5cccc6ccccc56)nc(-c5cccc6ccccc56)n4)cc3)c3ccccc23)cc1 ; c1ccc(-c2ccc(-c3ccccc3-c3c4ccccc4c(-c4ccc(-c5nc(-c6cccc7ccccc67)nc(-c6cccc7ccccc67)n5)cc4)c4ccccc34)cc2)cc1]

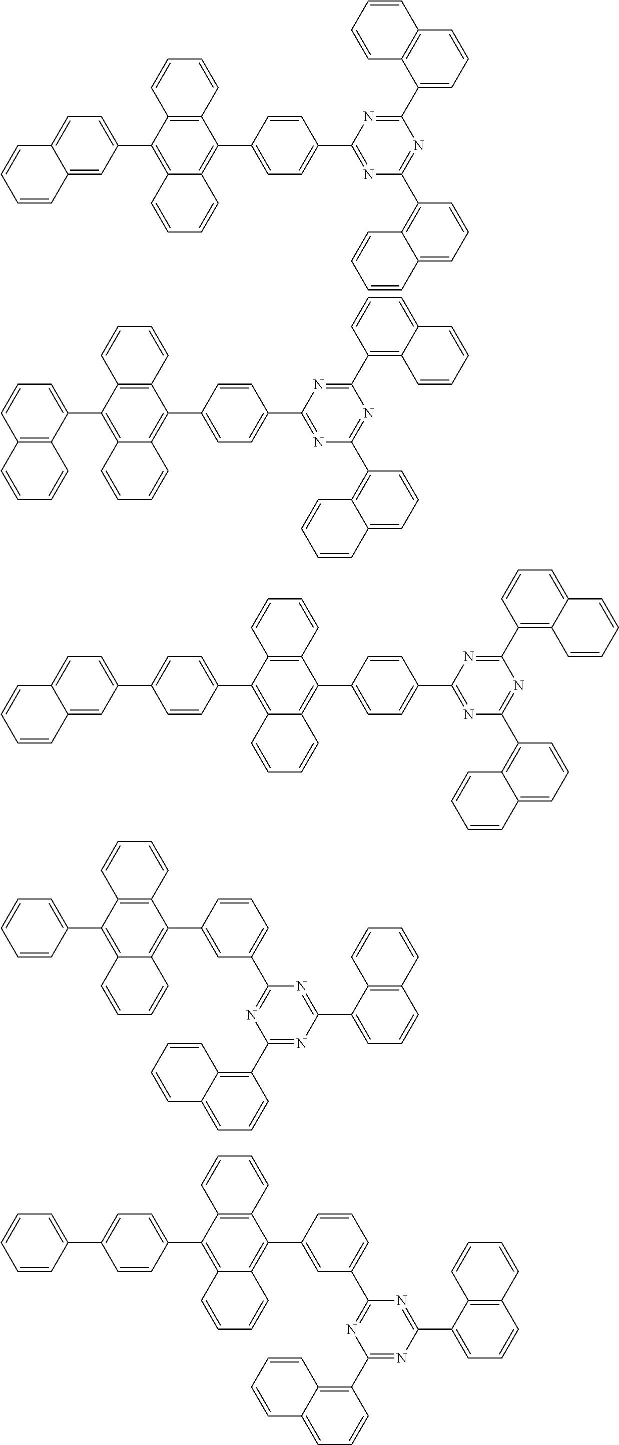

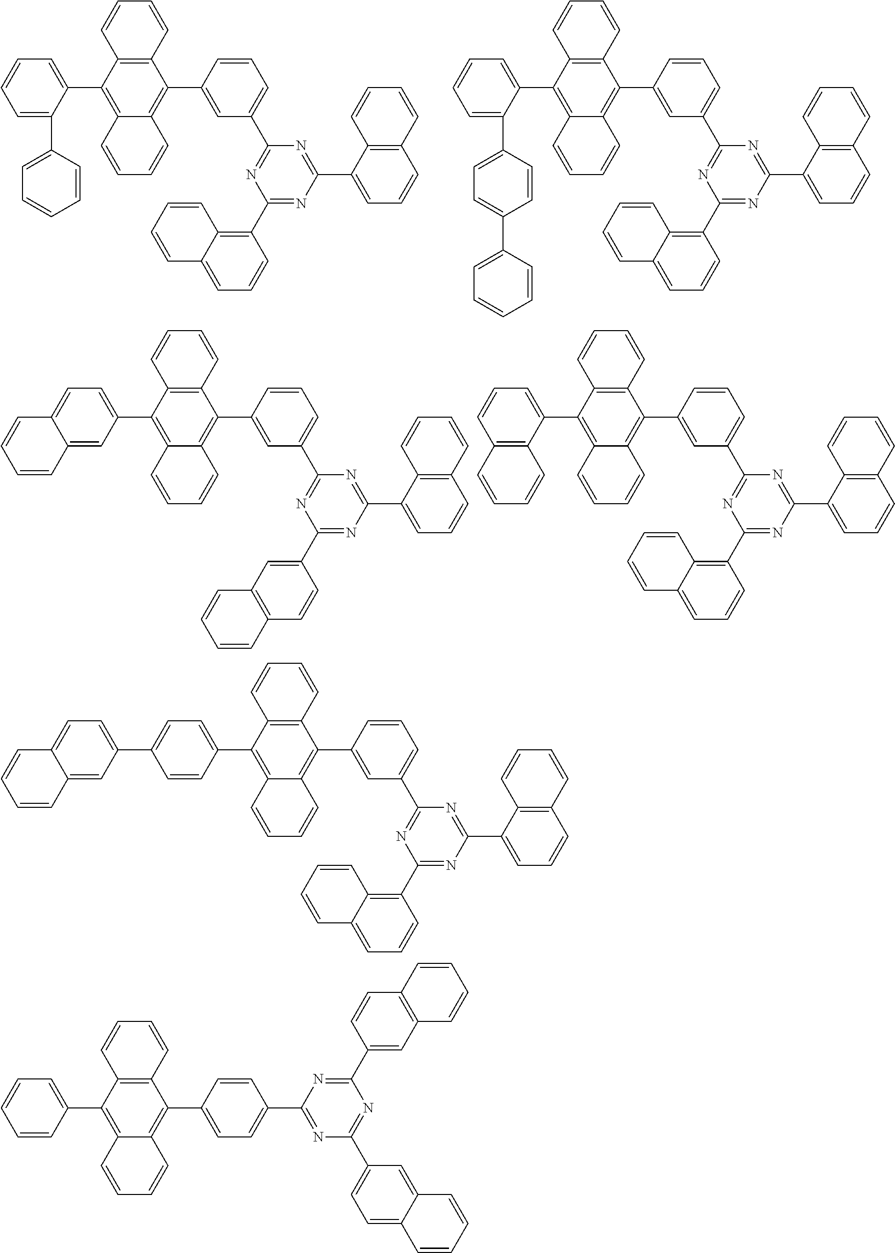

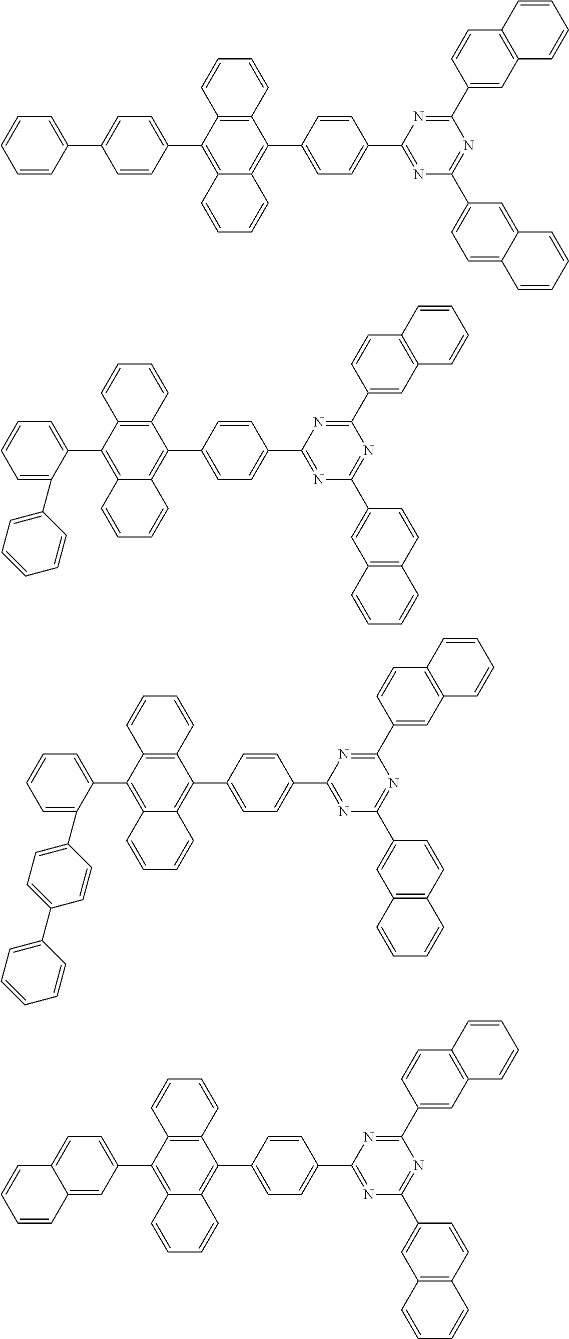

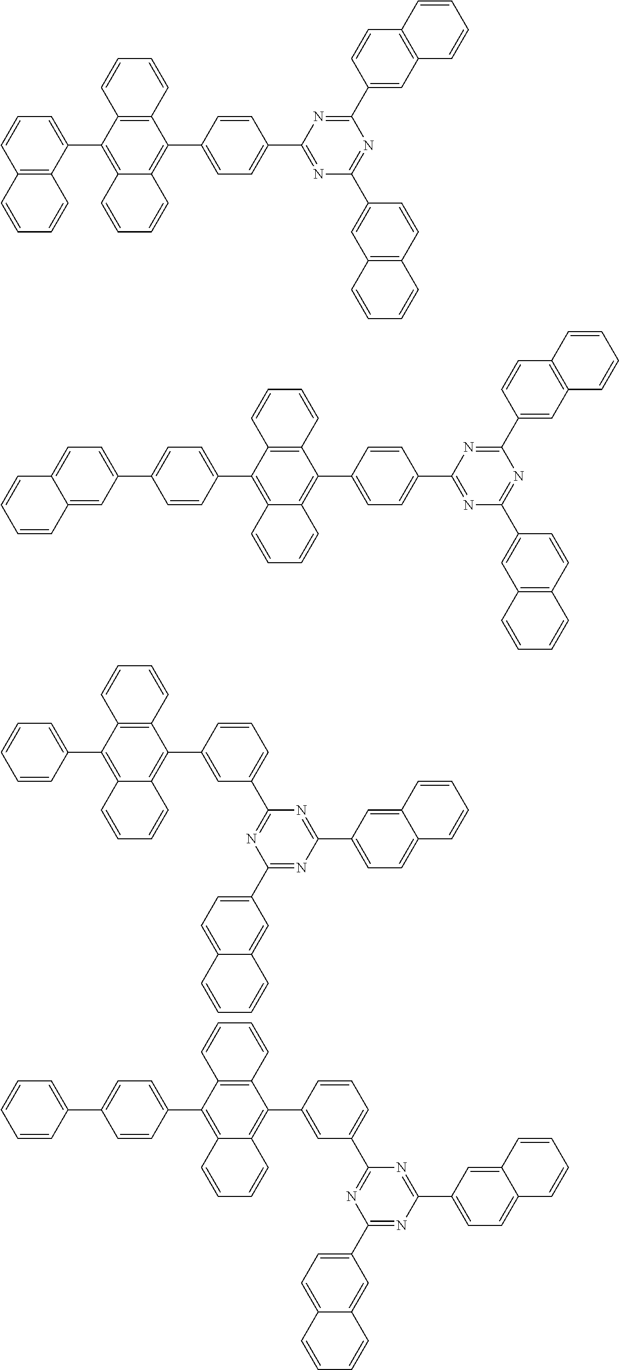

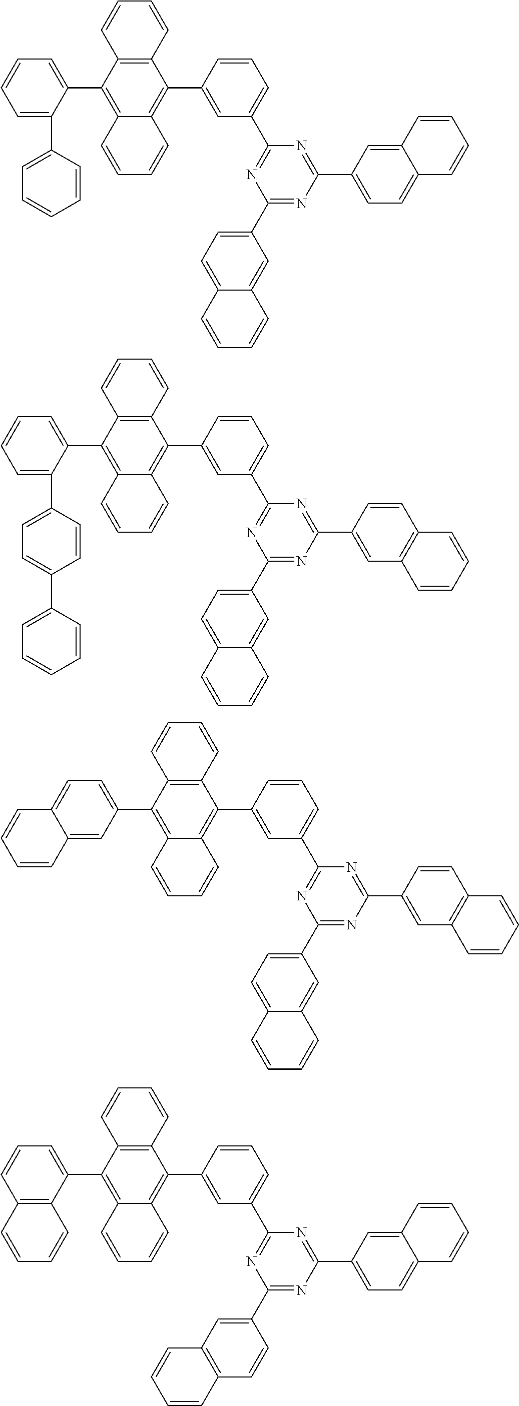

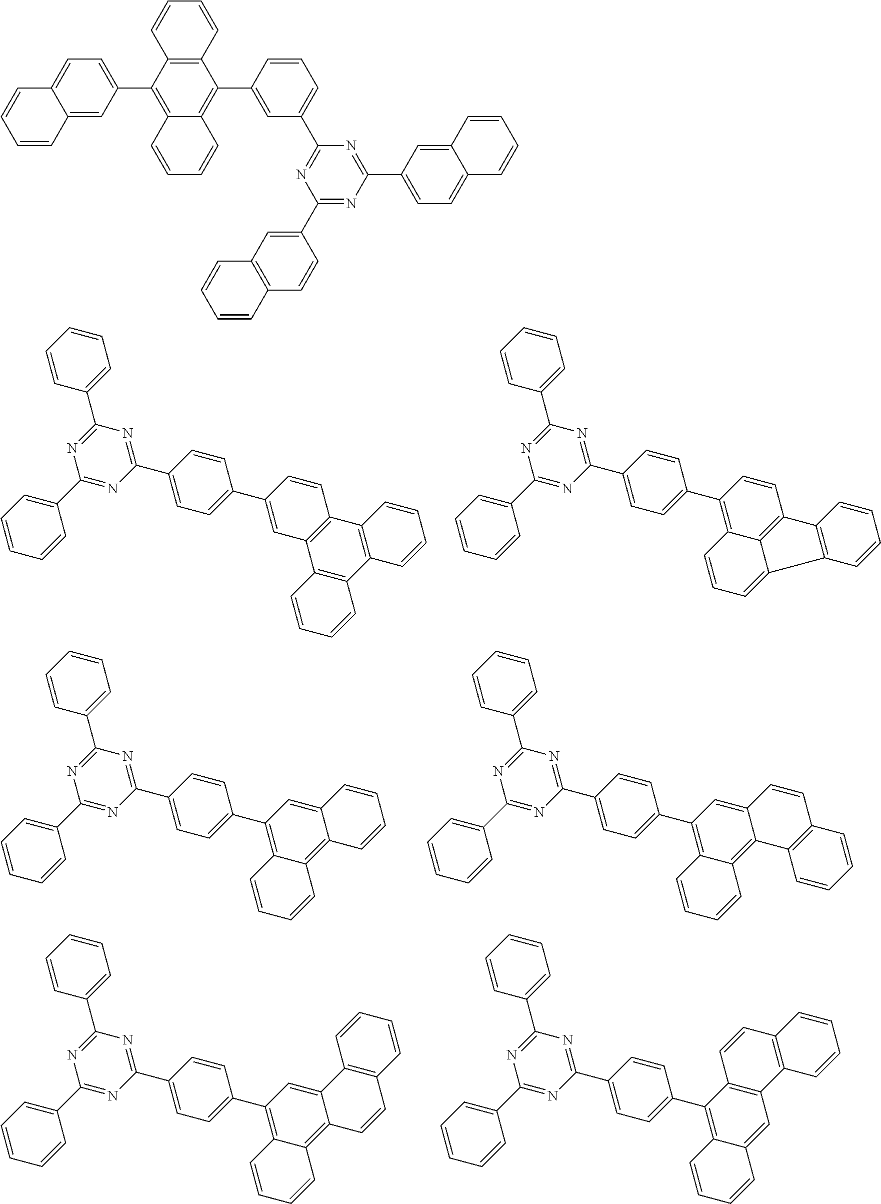

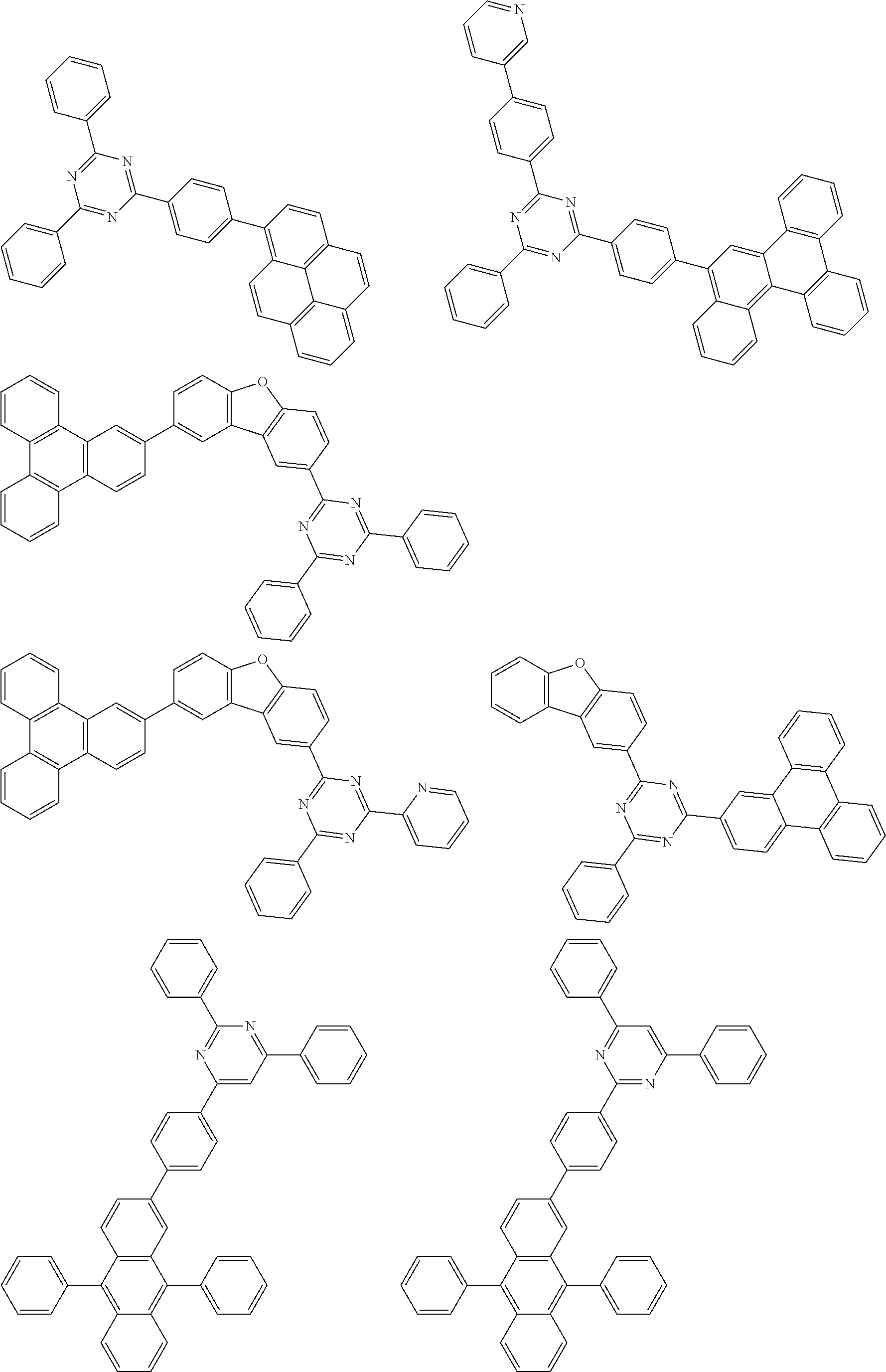

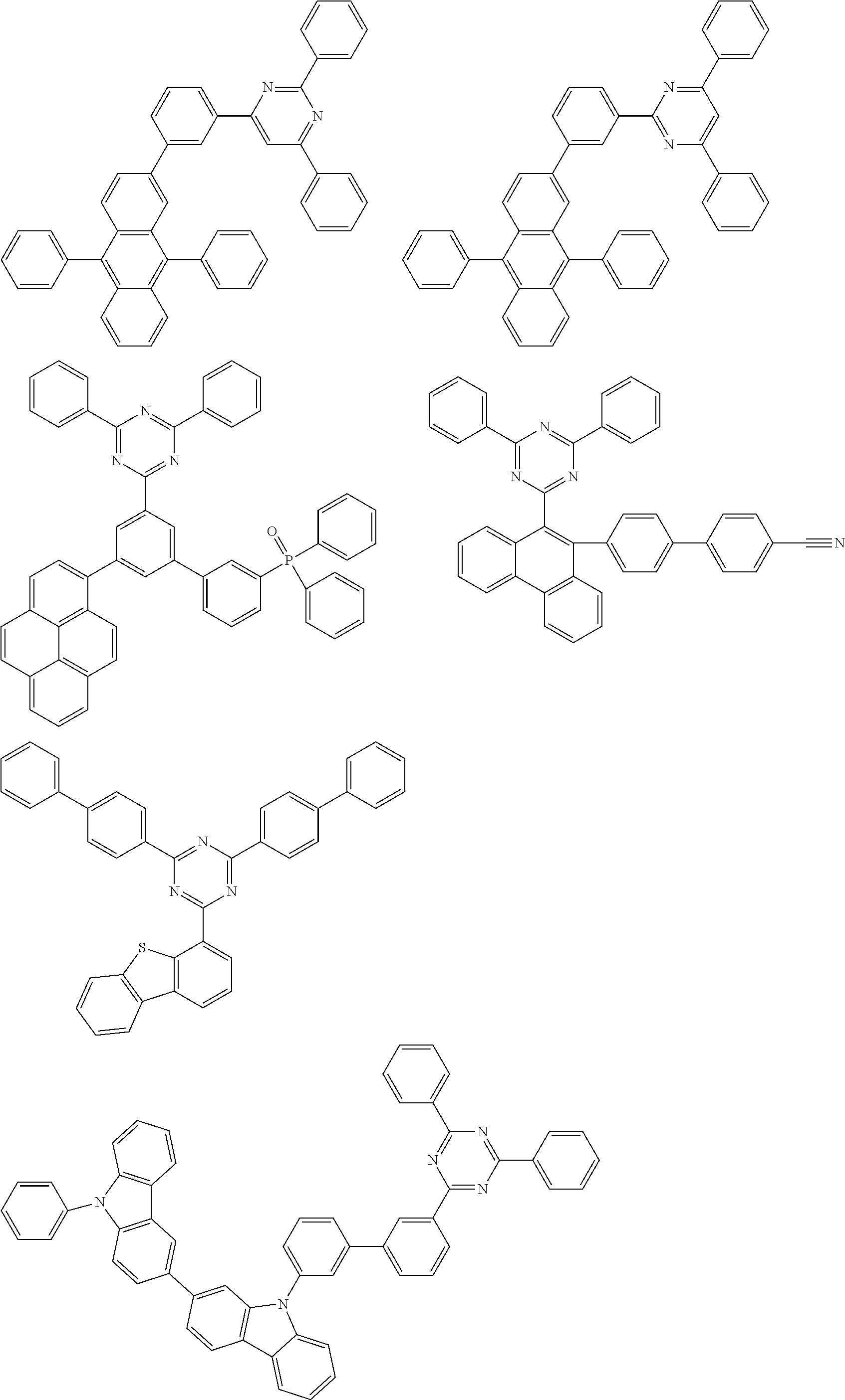

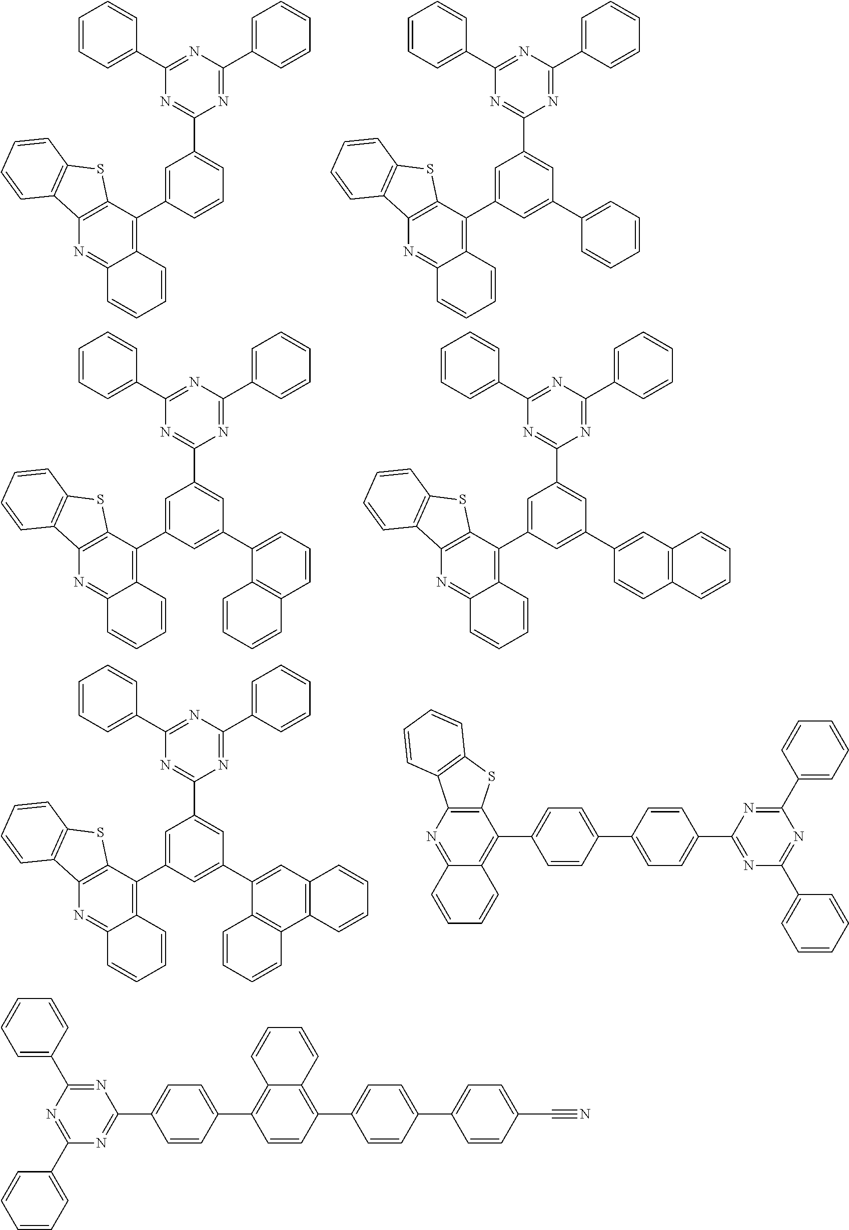

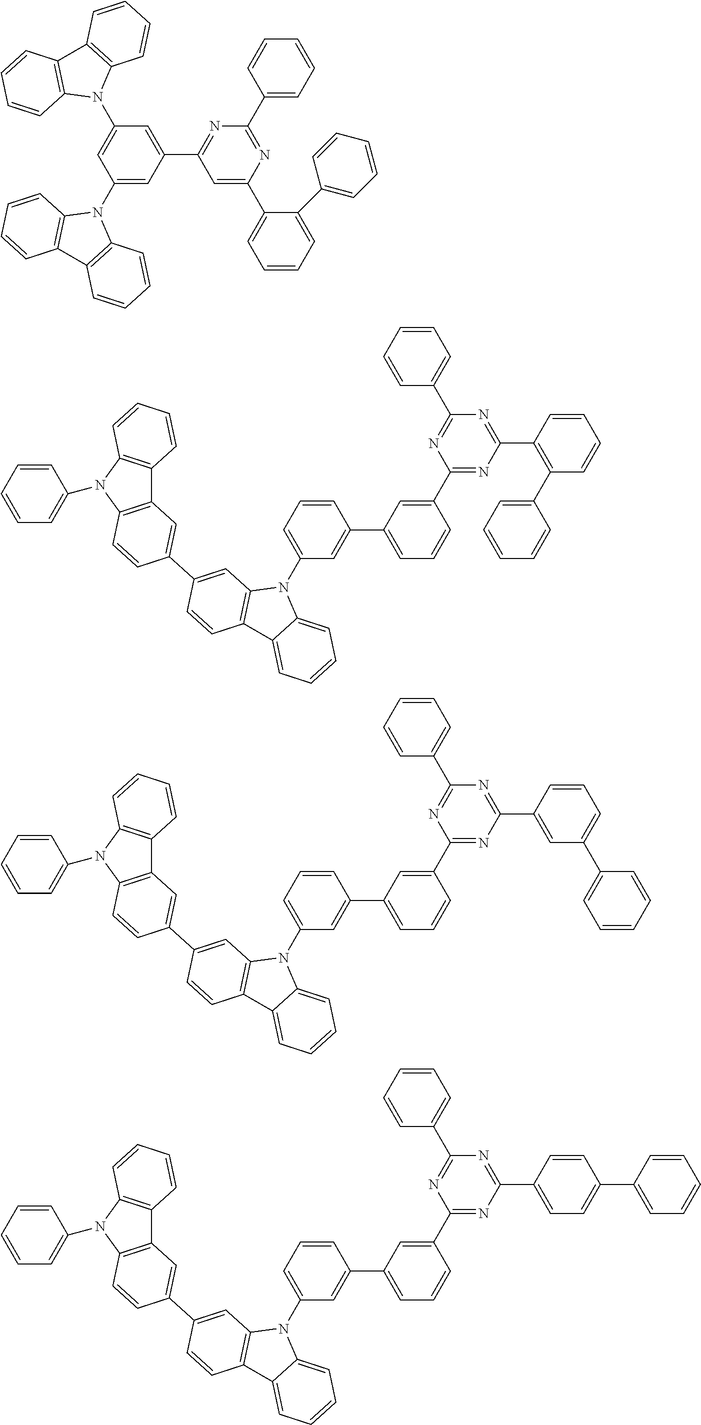 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; c1ccc(-c2nc(-c3cccc(-c4cccc(-n5c6ccccc6c6ccc(-c7ccc8c(c7)c7ccccc7n8-c7ccccc7)cc65)c4)c3)nc(-c3ccccc3-c3ccccc3)n2)cc1 ; c1ccc(-c2cccc(-c3nc(-c4ccccc4)nc(-c4cccc(-c5cccc(-n6c7ccccc7c7ccc(-c8ccc9c(c8)c8ccccc8n9-c8ccccc8)cc76)c5)c4)n3)c2)cc1 ; c1ccc(-c2ccc(-c3nc(-c4ccccc4)nc(-c4cccc(-c5cccc(-n6c7ccccc7c7ccc(-c8ccc9c(c8)c8ccccc8n9-c8ccccc8)cc76)c5)c4)n3)cc2)cc1]

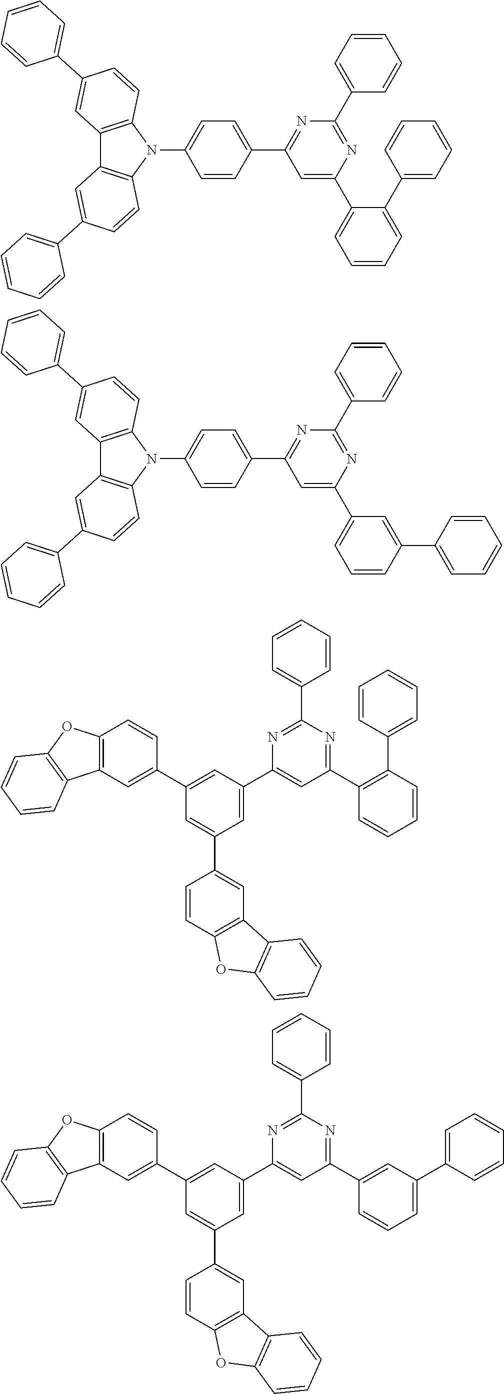

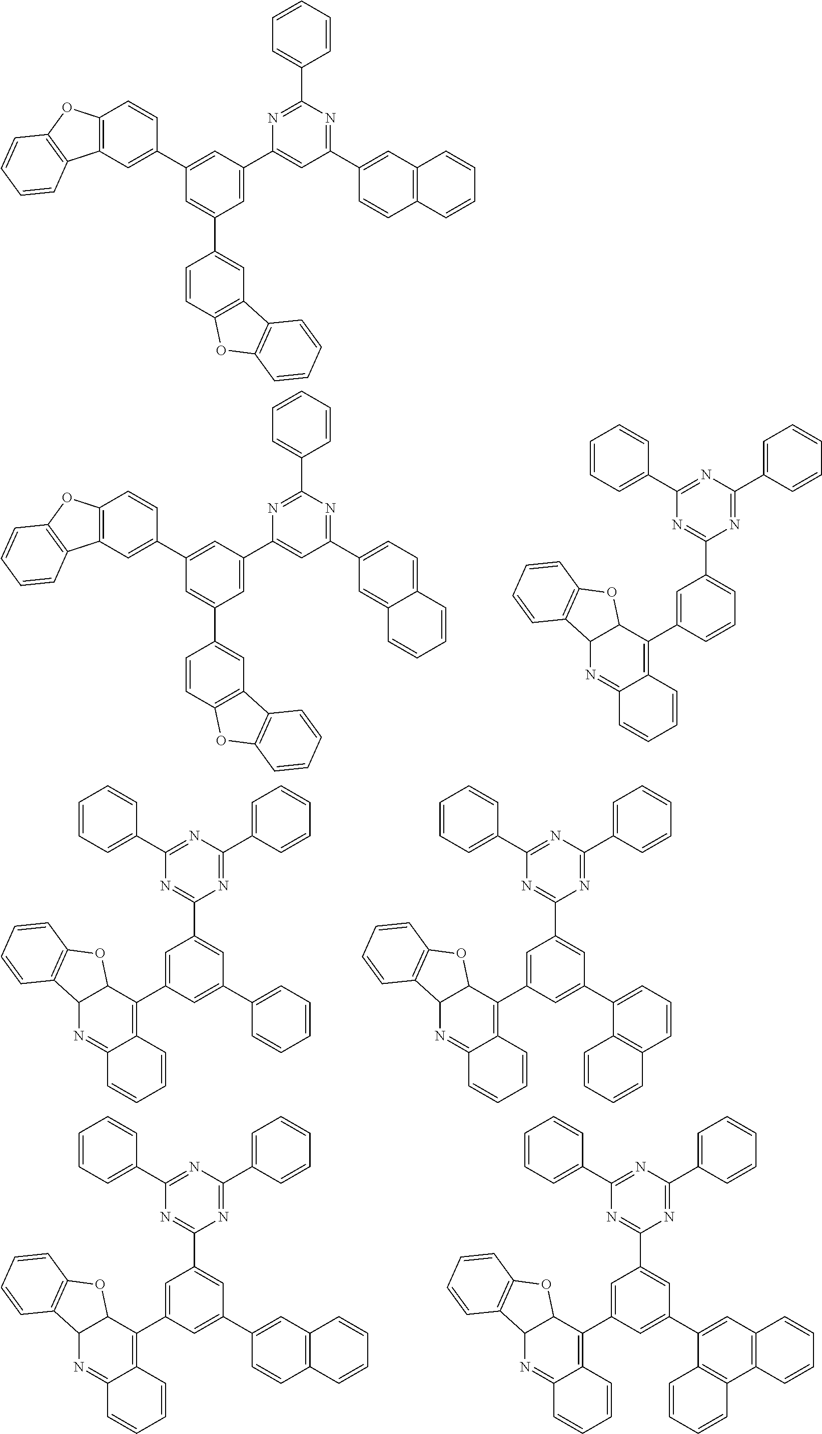

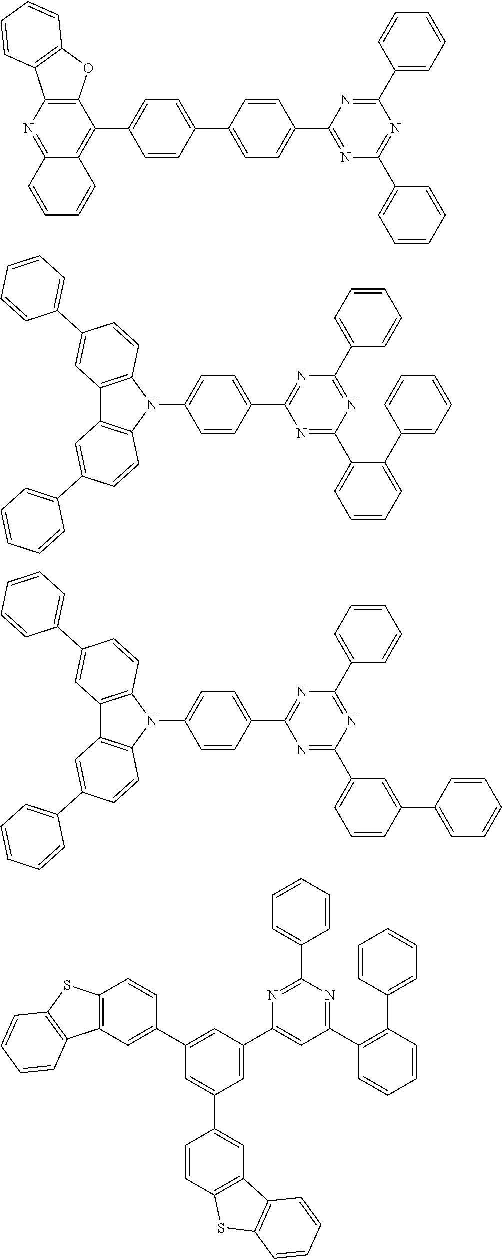

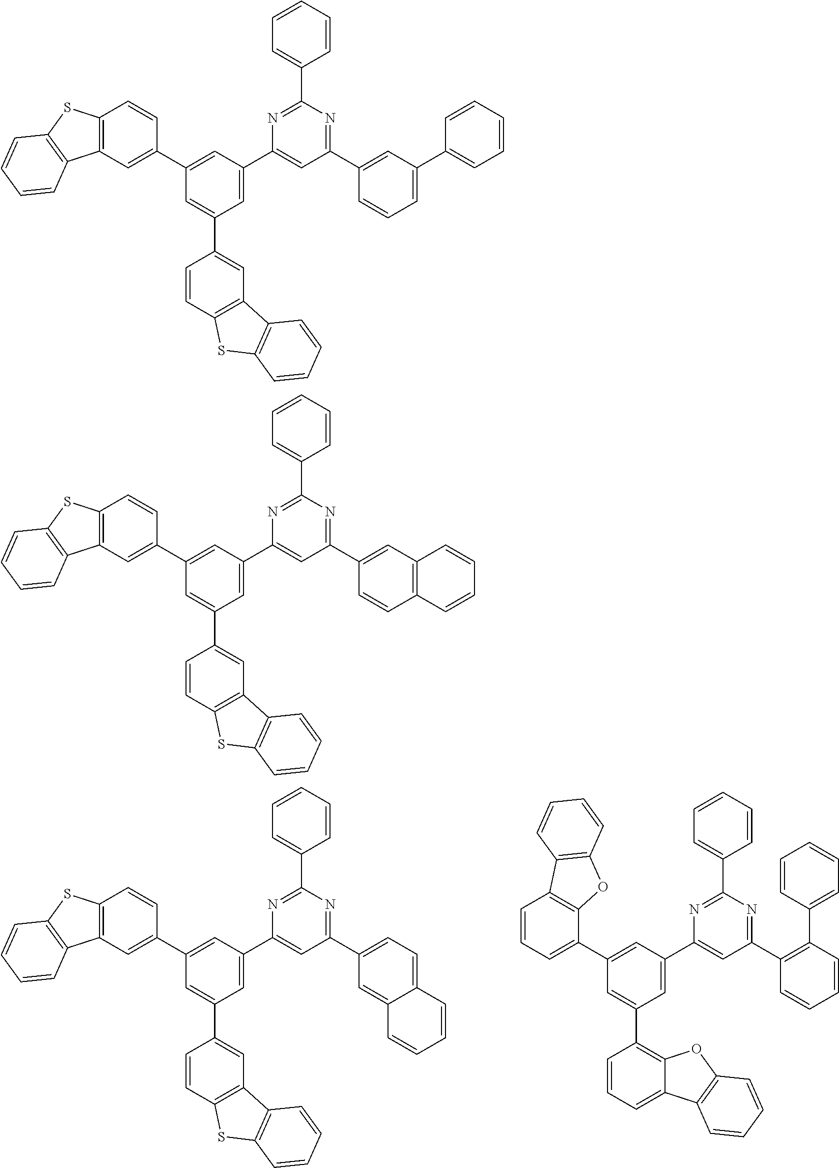

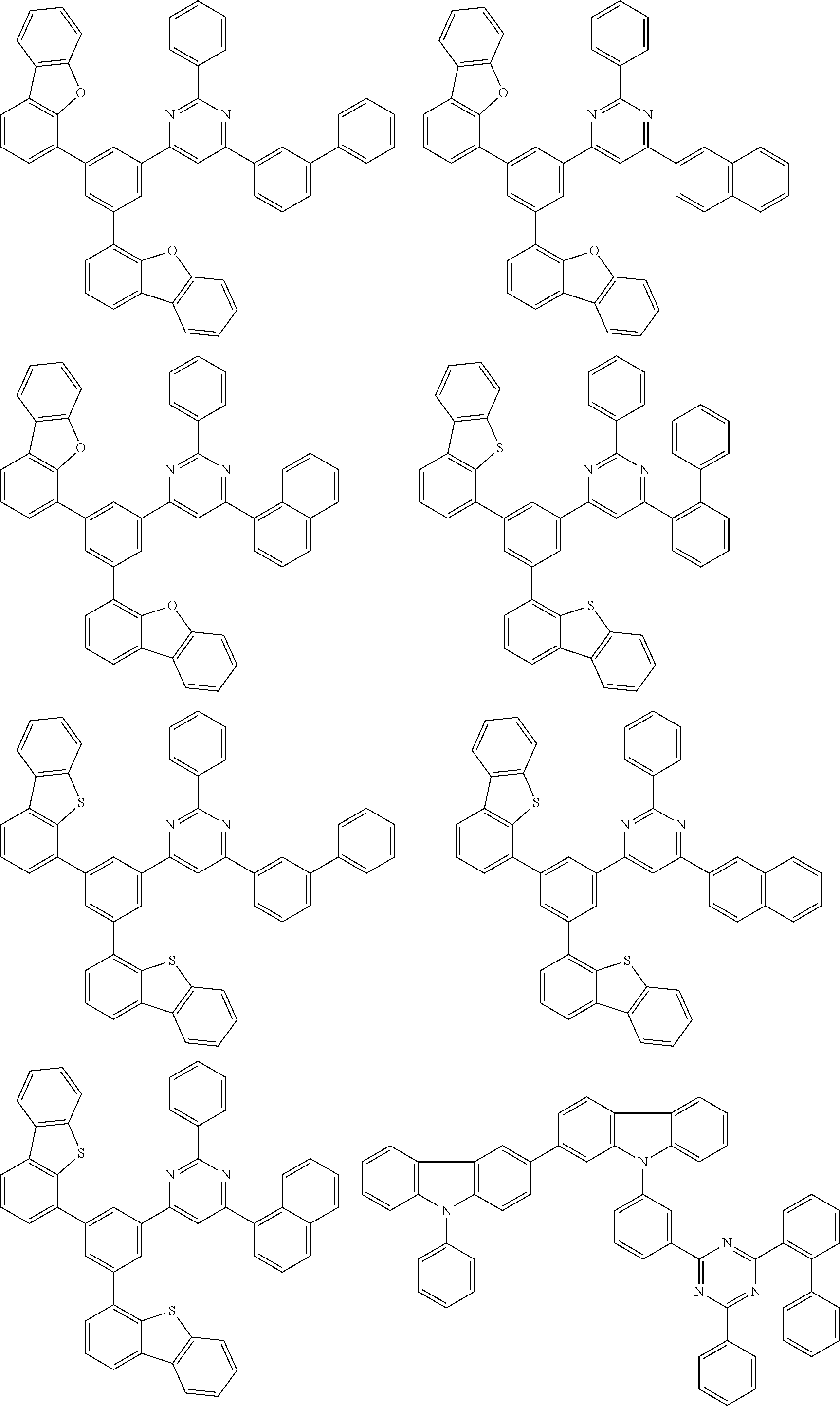

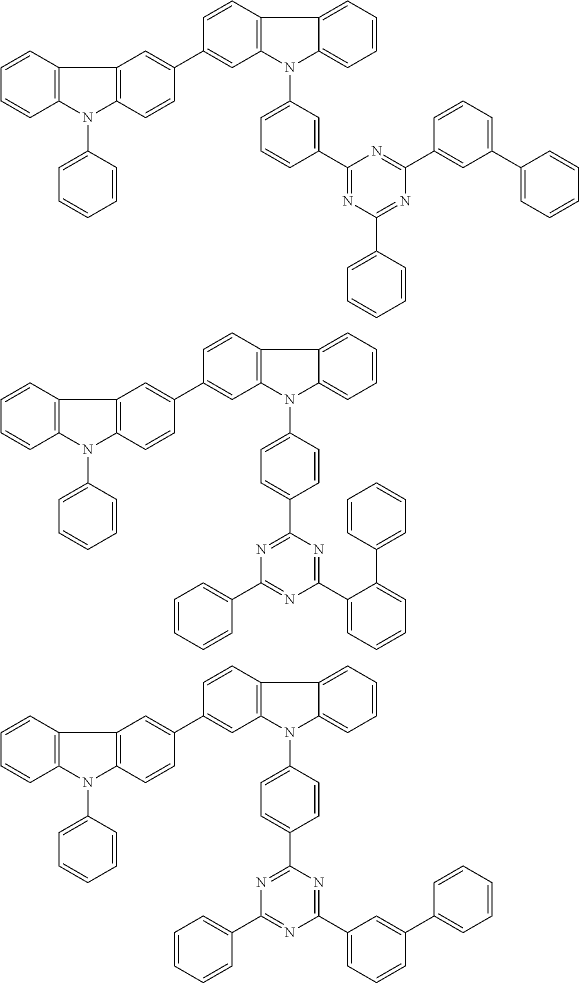

The substituent referred to by “substituent” and the optional substituent referred to by “substituted or unsubstituted” used herein is, unless otherwise noted, a group selected from an alkyl group having 1 to 25, preferably 1 to 18, more preferably 1 to 8 carbon atoms; a cycloalkyl group having 3 to 25, preferably 3 to 10, more preferably 3 to 8, still more preferably 5 or 6 ring carbon atoms; an aryl group (inclusive of a non-fused aryl group, a fused aryl group, and an aromatic ring assembly) having 6 to 30, preferably 6 to 25, more preferably 6 to 18 ring carbon atoms; a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; a non-aromatic heterocyclic ring group (inclusive of a non-fused heterocyclic ring group, a fused heterocyclic ring group, and a heterocyclic ring assembly) having 3 to 30, preferably 5 to 30, more preferably 5 to 24, still more preferably 5 to 13 ring atoms; an aralkyl group having 7 to 31, preferably 7 to 26, more preferably 7 to 20 carbon atoms including an aryl group having 6 to 30, preferably 6 to 25, more preferably 6 to 18 ring carbon atoms; an alkyl group having a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; an amino group; a mono- or di-substituted amino group having a substituent selected from an alkyl group having 1 to 25, preferably 1 to 18, more preferably 1 to 8 carbon atoms, an aryl group having 6 to 30, preferably 6 to 25, more preferably 6 to 18 ring carbon atoms, a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; an alkoxy group having an alkyl group having 1 to 25, preferably 1 to 18, more preferably 1 to 8 carbon atoms; an aryloxy group having an aryl group (inclusive of a non-fused aryl group, a fused aryl group, and an aromatic ring assembly) having 6 to 30, preferably 6 to 25, more preferably 6 to 18 ring carbon atoms; a heteroaryloxy group having a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; an alkylthio group having an alkyl group having 1 to 25, preferably 1 to 18, more preferably 1 to 8 carbon atoms; an arylthio group having an aryl group (inclusive of a non-fused aryl group, a fused aryl group, and an aromatic ring assembly) having 6 to 30, preferably 6 to 25, more preferably 6 to 18 ring carbon atoms; a heteroarylthio group having a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; an alkenyl group having 2 to 25, preferably 2 to 18, more preferably 2 to 8 carbon atoms; an alkynyl group having 2 to 25, preferably 2 to 18, more preferably 2 to 8 carbon atoms; a carbonyl group having a substituent selected from an alkyl group having 1 to 25, preferably 1 to 18, more preferably 1 to 8 carbon atoms, an aryl group having 6 to 30, preferably 6 to 25, more preferably 6 to 18 ring carbon atoms, and a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; a mono-, di- or tri-substituted silyl group having a substituent selected from an alkyl group having 1 to 25, preferably 1 to 18, more preferably 1 to 8 carbon atoms, an aryl group (inclusive of a non-fused aryl group, a fused aryl group, and an aromatic ring assembly) having 6 to 30, preferably 6 to 25, more preferably 6 to 18 ring carbon atoms, and a heteroaryl group (inclusive of a non-fused heterocyclic ring group, a fused heterocyclic ring group, and a heterocyclic ring assembly) 5 to 30, preferably 5 to 24, more preferably 5 to 13 ring atoms; a haloalkyl group having 1 to 25, preferably 1 to 18, more preferably 1 to 8 carbon atoms; a haloalkoxy group having a haloalkyl group having 1 to 25, preferably 1 to 18, more preferably 1 to 8 carbon atoms; a halogen atom; a cyano group; a mono- or di-substituted phosphoryl group having a substituent selected from an alkyl group having 1 to 25, preferably 1 to 18, more preferably 1 to 8 carbon atoms, an aryl group (inclusive of a non-fused aryl group, a fused aryl group, and an aromatic ring assembly) having 6 to 30, preferably 6 to 25, more preferably 6 to 18 ring carbon atom, and a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms and a nitro group.

The substituent and the optional substituent is more preferably selected from an alkyl group having 1 to 25, preferably 1 to 18, more preferably 1 to 8 carbon atoms; a cycloalkyl group having 3 to 25, preferably 3 to 10, more preferably 3 to 8, still more preferably 5 or 6 ring carbon atoms; an aryl group (inclusive of a non-fused aryl group, a fused aryl group, and an aromatic ring assembly) having 6 to 30, preferably 6 to 25, more preferably 6 to 18 ring carbon atoms; a heteroaryl group (inclusive of a non-fused aromatic heterocyclic ring group, a fused aromatic heterocyclic ring group, and an aromatic heterocyclic ring assembly) having 5 to 30, preferably 5 to 24, more preferably 5 to 13 ring atoms; a mono- or di-substituted amino group having a substituent selected from an alkyl group having 1 to 25, preferably 1 to 18, more preferably 1 to 8 carbon atoms, an aryl group (inclusive of a non-fused aryl group, a fused aryl group, and an aromatic ring assembly) having 6 to 30, preferably 6 to 25, more preferably 6 to 18 ring carbon atoms, and a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; a halogen atom; a mono- or di-substituted phosphoryl group having a substituent selected from an alkyl group having 1 to 25, preferably 1 to 18, more preferably 1 to 8 carbon atoms, an aryl group (inclusive of a non-fused aryl group, a fused aryl group, and an aromatic ring assembly) having 6 to 30, preferably 6 to 25, more preferably 6 to 18 ring carbon atoms, and a heteroaryl group (inclusive of a non-fused heterocyclic ring group, a fused heterocyclic ring group, and a heterocyclic ring assembly) having 5 to 30, preferably 5 to 24, more preferably 5 to 13 ring atoms; and a cyano group.

Examples of the alkyl group having 1 to 25 carbon atoms include a methyl group, an ethyl group, a n-propyl group, an isopropyl group, a n-butyl group, an isobutyl group, a s-butyl group, a t-butyl group, a pentyl group (inclusive of isomeric groups), a hexyl group (inclusive of isomeric groups), a heptyl group (inclusive of isomeric groups), an octyl group (inclusive of isomeric groups), a nonyl group (inclusive of isomeric groups), a decyl group (inclusive of isomeric groups), an undecyl group (inclusive of isomeric groups), and a dodecyl group (inclusive of isomeric groups). Preferred are a methyl group, an ethyl group, a n-propyl group, an isopropyl group, a n-butyl group, an isobutyl group, a s-butyl group, a t-butyl group, and a pentyl group (inclusive of isomeric groups). More preferred are a methyl group, an ethyl group, a n-propyl group, an isopropyl group, a n-butyl group, an isobutyl group, a s-butyl group, and a t-butyl group. Still more preferred are a methyl group and a t-butyl group.

Examples of the cycloalkyl group having 3 to 25 ring carbon atoms include a cyclopropyl group, a cyclobutyl group, a cryclopentyl group, a cyclohexyl group, and a cycloheptyl group.

Examples of the aryl group (inclusive of a non-fused aryl group, a fused aryl group, and an aromatic ring assembly) having 6 to 30 ring carbon atoms include a phenyl group, a biphenylyl group, a terphenylyl group, a biphenylenyl group, a naphthyl group, an acenaphthylenyl group, an anthryl group, a benzoanthryl group, an aceanthryl group, a phenanthryl group, a benzophenanthryl group, a phenalenyl group, a fluorenyl group, a spirofluorenyl group, a triphenylenyl group, a pentacenyl group, a picenyl group, a pentaphenyl group, a pyrenyl group, a chrysenyl group, a benzochrysenyl group, a s-indacenyl group, an as-indacenyl group, a fluoranthenyl group, a benzofluoranthenyl group, and a perylenyl group. Preferred are a phenyl group, a biphenylyl group, a terphenylyl group, and a naphthyl group, more preferred are a phenyl group, a biphenylyl group, and a naphthyl group, and still more preferred is a phenyl group.

The substituted aryl group is preferably a 9,9-dimethylfluorenyl group and a 9,9-diphenyffluorenyl group.

The heteroaryl group having 5 to 30 ring atoms comprises 1 to 5, preferably 1 to 3, and more preferably 1 to 2 ring heteroatoms, such as a nitrogen atom, a sulfur atom, and an oxygen atom.

Examples of the heteroaryl group having 5 to 30 ring atoms include a pyrrolyl group, a furyl group, a thienyl group, pyridyl group, a pyridazinyl group, a pyrimidinyl group, a pyrazinyl group, a triazinyl group, an imidazolyl group, an oxazolyl group, a thiazolyl group, a pyrazolyl group, an isoxazolyl group, an isothiazolyl group, an oxadiazolyl group, a thiadiazolyl group, a triazolyl group, an indolyl group, an isoindolyl group, a benzofuranyl group, an isobenzofuranyl group, a benzothiophenyl group (a benzothienyl group, the same applies below), an indolizinyl group, a quinolizinyl group, a quinolyl group, an isoquinolyl group, a cinnolyl group, a phthalazinyl group, a quinazolinyl group, a quinoxalinyl group, a benzimidazolyl group, a benzoxazolyl group, a benzothiazolyl group, an indazolyl group, a benzisoxazolyl group, a benzisothiazolyl group, a dibenzofuranyl group, a naphthobenzofuranyl group, a dibenzothiophenyl group (dibenzothienyl group, the same applies below), a naphthobenzotiophenyl group (a naphthobenzothienyl group), a carbazolyl group (a N-carbazolyl group and a C-carbazolyl group), a benzocarbazolyl group (a benzo-N-carbazolyl group and a benzo-C-carbazolyl group), a phenanthridinyl group, an acridinyl group, a phenanthrolinyl group, a phenazinyl group, a phenothiazinyl group, a phenoxazinyl group, a benzimidazolobenzimidazolyl group, and a xanthenyl group. Preferred are a furyl group, a thienyl group, pyridyl group, a pyridazinyl group, a pyrimidinyl group, a pyrazinyl group, a triazinyl group, a benzofuranyl group, a benzothiophenyl group, a dibenzofuranyl group, a naphthobenzofuranyl group, a dibenzothiophenyl group, a naphthobenzothiophenyl group, a carbazolyl group, and a benzocarbazolyl group, and more preferred are a thienyl group, a benzothiophenyl group, a dibenzofuranyl group, a naphthobenzofuranyl group, a dibenzothiophenyl group, a naphthobenzothiophenyl group, a carbazolyl group, and a benzocarbazolyl group. Preferred examples of the substituted heteroaryl group include a N-phenylcarbazolyl group, a N-biphenylylcarbazolyl group, a N-phenylphenylcarbazolyl group, a N-naphthylcarbazolyl group, a phenyldibenzofuranyl group, and a phenyldibenzothiophenyl group (a phenyldibenzothienyl group).

Examples of the non-aromatic heterocyclic ring group having 3 to 30 ring atoms include aliphatic rings derived from the heteroaryl groups mentioned above by partially or completely hydrogenating the aromatic rings.

The aryl group having 6 to 30 ring carbon atoms included in the aralkyl group having 7 to 31 carbon atoms are as described above with respect to the aryl group having 6 to 30 ring carbon atoms. The alkyl portion of the aralkyl group is selected from the alkyl group so as to have 7 to 31 carbon atoms. Examples of the aralkyl group having 7 to 31 carbon atoms include a benzyl group, a phenethyl group, and a phenylpropyl group, with a benzyl group being preferred.

The alkyl group having 1 to 25 carbon atoms, the aryl group having 6 to 30 ring carbon atoms (inclusive of a non-fused aryl group, a fused aryl group, and an aromatic ring assembly), the heteroaryl group having 5 to 30 ring atoms (inclusive of a non-fused heterocyclic ring group, a fused heterocyclic ring group, and a heterocyclic ring assembly) for the substituent of the mono- or di-substituted amino group are the same as those described above with respect to the alkyl group having 1 to 25 carbon atoms, the aryl group having 6 to 30 ring carbon atoms, and the heteroaryl group having 5 to 30 ring atoms. Examples of the mono- or di-substituted amino group include a dialkylamino group, a diarylamino group, a diheteroarylamino group, an alkylarylamino group, an alkylheteroarylamino group, and an arylheteroarylamino group.

The alkyl group having 1 to 25 carbon atoms of the alkoxy group is as defined above with respect to the alkyl group having 1 to 25 carbon atoms. The alkoxy group is preferably a t-butoxy group, a propoxy group, an ethoxy group, or a methoxy group, more preferably an ethoxy group or a methoxy group, and still more preferably a methoxy group.

The aryl group having 6 to 30 ring carbon atoms (inclusive of a non-fused aryl group, a fused aryl group, and an aromatic ring assembly) of the aryloxy group is as defined above with respect to the aryl group having 6 to 30 ring carbon atoms. The aryloxy group is preferably a terphenyloxy group, a biphenyloxy group, or a phenoxy group, more preferably a biphenyloxy group or a phenoxy group, and still more preferably a phenoxy group.

The heteroaryl group having 5 to 30 ring atoms (inclusive of a non-fused heterocyclic ring group, a fused heterocyclic ring group, and a heterocyclic ring assembly) of the heteroaryloxy group is as defined above with respect to the heteroaryl group having 5 to 30 ring atoms.

The alkyl group having 1 to 25 carbon atoms of the alkylthio group is as defined above with respect to the alkyl group having 1 to 25 carbon atoms. The alkylthio group is, for example, a methylthio group or an ethylthio group.

The aryl group having 6 to 30 ring carbon atoms (inclusive of a non-fused aryl group, a fused aryl group, and an aromatic ring assembly) of the arylthio group is as defined above with respect to the aryl group having 6 to 30 ring carbon atoms. The arylthio group is, for example, a phenylthio group.

The heteroaryl group having 5 to 30 ring atoms (inclusive of a non-fused heterocyclic ring group, a fused heterocyclic ring group, and a heterocyclic ring assembly) of the heteroarylthio group is as defined above with respect to the heteroaryl group having 5 to 30 ring atoms.

Examples of the alkenyl group include a vinyl group, a propenyl group, a butenyl group, a pentenyl group, a pentadienyl group, a hexenyl group, a hexadienyl group, a heptenyl group, an octenyl group, an octadienyl group, a 2-ethylhexenyl group, and a decenyl group.

The alkynyl group is, for example, an ethynyl group or a methylethynyl group.

The alkyl group having 1 to 25 carbon atoms, the aryl group having 6 to 30 ring carbon atoms (inclusive of a non-fused aryl group, a fused aryl group, and an aromatic ring assembly), and the heteroaryl group having 5 to 30 ring atoms (inclusive of a non-fused heterocyclic ring group, a fused heterocyclic ring group, and a heterocyclic ring assembly), which the carbonyl group may have, are as defined above with respect to the alkyl group having 1 to 25 carbon atoms, the aryl group having 6 to 30 ring carbon atoms, and the heteroaryl group having 5 to 30 ring atoms. The carbonyl group is, for example, a methylcarbonyl group or a phenylcarbonyl group.

The alkyl group having 1 to 25 carbon atoms, an aryl group having 6 to 30 ring carbon atoms (inclusive of a non-fused aryl group, a fused aryl group, and an aromatic ring assembly) and the heteroaryl group having 5 to 30 ring atoms (inclusive of a non-fused heterocyclic ring group, a fused heterocyclic ring group, and a heterocyclic ring assembly) each included in the mono-, di- or tri-substituted silyl group are as described above with respect to the alkyl group having 1 to 25 carbon atoms, the aryl group having 6 to 30 ring carbon atoms, and the heteroaryl group having 5 to 30 ring atoms. Preferred is a tri-substituted silyl group, for example, a trimethylsilyl group, a triethylsilyl group, a t-butyklimethylsilyl group, a propyldimethylsilyl group, an isopropyldimethylsilyl group, a triphenylsilyl group, a phenyklimethylsilyl group, a t-butykliphenylsilyl group, and a tritolylsilyl group.

The haloalkyl group having 1 to 25 carbon atoms is a group derived from the alkyl group having 1 to 25 carbon atoms mentioned above by replacing at least one, preferably 1 to 7 hydrogen atoms or all the hydrogen atoms with a halogen atom selected from a fluorine atom, a chlorine atom, a bromine atom, and an iodine atom, preferably a fluorine atom. Preferred is a fluoroalkyl group having 1 to 25, preferably 1 to 18, and more preferably 1 to 8 carbon atoms, with a heptafluoropropyl group (inclusive of isomers), a pentafluoroethyl group, a 2,2,2-trifluoroethyl group, and a trifluoromethyl group being more preferred, and a pentafluoroethyl group, a 2,2,2-trifluoroethyl group, a trifluoromethyl group being more preferred, and a trifluoromethyl group being particularly preferred.

The haloalkyl group having 1 to 25 carbon atoms included in the haloalkoxy group is as defined above with respect to the haloalkyl group having 1 to 25 carbon atoms. Preferred is a fluoroalkoxy group having 1 to 25, preferably 1 to 18, more preferably 1 to 8 carbon atoms, with a heptafluoropropoxy group (inclusive of isomers), a pentafluoroethoxy group, a 2,2,2-trifluoroethoxy group, and a trifluoromethoxy group being more preferred, pentafluoroethoxy group, a 2,2,2-trifluoroethoxy group and a trifluoromethoxy group being more preferred, and a trifluoromethoxy group being particularly preferred.

The halogen atom is a fluorine atom, a chlorine atom, a bromine atom, or an iodine atom, with a fluorine atom being preferred.

The alkyl group having 1 to 25 carbon atoms, the aryl group having 6 to 30 ring carbon atoms (inclusive of a non-fused aryl group, fused aryl group and an aromatic ring assembly), and the heteroaryl group having 5 to 30 ring atoms (inclusive of a non-fused heterocyclic ring group, a fused heterocyclic ring group, and a heterocyclic ring assembly) each included in the mono- or di-substituted phosphoryl group are as defined above with respect to the alkyl group having 1 to 25 carbon atoms, the aryl group having 6 to 30 ring carbon atoms, and the heteroaryl group having 5 to 30 ring atoms. Preferred is a di-substituted phosphoryl group, for example, a diarylphosphoryl group, a diheteroarylphosphoryl group, and an arylheteroarylphosphoryl group.

The method of producing the compound 1 and the compound 2 is not particularly limited. A person skilled in the art could easily produce these compounds by using or modifying known synthesis reactions with reference to the examples described below.

### Organic EL Device

The organic EL device of the invention will be described below.

The organic EL device comprises an organic layer between a cathode and an anode. The organic layer comprises a light emitting layer, a first electron transporting layer, and a second electron transporting layer in this order from the anode side. The first electron transporting layer comprises the compound 1 and the second electron transporting layer comprises the compound 2.

The organic EL device of the invention may be any of a fluorescent or phosphorescent single color emitting device, a white-emitting device of fluorescent-phosphorescent hybrid type, a simple-type emitting device having a single emission unit, and a tandem emitting device having two or more emission units, with a fluorescent emitting device being preferred. The “emission unit” referred to herein is the smallest unit for emitting light by the recombination of injected holes and injected electrons, which comprises an organic layer, wherein at least one layer is a light emitting layer.

Representative device structures of the simple-type organic EL device are shown below:

### (1) Anode/Emission Unit/Cathode

The emission unit may be a stacked unit comprising two or more layers selected from a phosphorescent light emitting layer and a fluorescent light emitting layer. A space layer may be disposed between the light emitting layers to prevent the diffusion of excitons generated in the phosphorescent light emitting layer into the fluorescent light emitting layer. Representative layered structures of the simple-type emission unit are shown below, with the layers in parentheses being optional:

(a) (Hole injecting layer/) Hole transporting layer/Fluorescent light emitting layer/First electron transporting layer/Second electron transporting layer;
(b) (Hole injecting layer/) Hole transporting layer/Phosphorescent light emitting layer/First electron transporting layer/Second electron transporting layer;
(c) (Hole injecting layer/) Hole transporting layer/First fluorescent light emitting layer/Second fluorescent light emitting layer/First electron transporting layer/Second electron transporting layer;
(d) (Hole injecting layer/) Hole transporting layer/First phosphorescent light emitting layer/Second phosphorescent light emitting layer/First electron transporting layer/Second electron transporting layer;
(e) (Hole injecting layer/) Hole transporting layer/Phosphorescent light emitting layer/Space layer/Fluorescent light emitting layer/First electron transporting layer/Second electron transporting layer;
(f) (Hole injecting layer/) Hole transporting layer/First phosphorescent light emitting layer/Second phosphorescent light emitting layer/Space layer/Fluorescent light emitting layer/First electron transporting layer/Second electron transporting layer;
(g) (Hole injecting layer/) Hole transporting layer/First phosphorescent light emitting layer/Space layer/Second phosphorescent light emitting layer/Space layer/Fluorescent light emitting layer/First electron transporting layer/Second electron transporting layer;
(h) (Hole injecting layer/) Hole transporting layer/Phosphorescent light emitting layer/Space layer/First fluorescent light emitting layer/Second fluorescent light emitting layer/First electron transporting layer/Second electron transporting layer;
(i) (Hole injecting layer/) Hole transporting layer/Electron blocking layer/Fluorescent light emitting layer/First electron transporting layer/Second electron transporting layer;
(j) (Hole injecting layer/) Hole transporting layer/Electron blocking layer/Phosphorescent light emitting layer/First electron transporting layer/Second electron transporting layer;
(k) (Hole injecting layer/) Hole transporting layer/Exciton blocking layer/Fluorescent light emitting layer/First electron transporting layer/Second electron transporting layer;
(l) (Hole injecting layer/) Hole transporting layer/Exciton blocking layer/Phosphorescent light emitting layer/First electron transporting layer/Second electron transporting layer;
(m) (Hole injecting layer/) First hole transporting layer/Second hole transporting layer/Fluorescent light emitting layer/First electron transporting layer/Second electron transporting layer;
(n) (Hole injecting layer/) First hole transporting layer/Second hole transporting layer/Phosphorescent light emitting layer/First electron transporting layer/Second electron transporting layer;
(o) (Hole injecting layer/) Hole transporting layer/Fluorescent light emitting layer/First electron transporting layer/Second electron transporting layer;
(p) (Hole injecting layer/) Hole transporting layer/Phosphorescent light emitting layer/First electron transporting layer/Second electron transporting layer;
(q) (Hole injecting layer/) Hole transporting layer/Fluorescent light emitting layer/Triplet blocking layer/First electron transporting layer/Second electron transporting layer; and
(r) (Hole injecting layer/) Hole transporting layer/Phosphorescent light emitting layer/Triplet blocking layer/First electron transporting layer/Second electron transporting layer.

The emission color of the fluorescent emitting layer and that of the phosphorescent emitting layer may be different. For example, the layered structure of the stacked emission unit (f) may be (Hole injecting layer/) Hole transporting layer/First phosphorescent emitting layer (red emission)/Second phosphorescent emitting layer (green emission)/Sp ace layer/Fluorescent emitting layer (blue emission)/First electron transporting layer/Second electron transporting layer.

An electron blocking layer may be disposed between each light emitting layer and a hole transporting layer or between a light emitting layer and a space layer, if necessary. With such an electron blocking layer, electrons or holes are confined in a light emitting layer to increase the charge recombination in a light emitting layer, thereby improving the emission efficiency.

Representative device structure of the tandem-type organic EL device is shown below:

### (2) Anode/First Emission Unit/Intermediate Layer/Second Emission Unit/Cathode.

The layered structure of the first emission unit and the second emission unit may be independently selected from, for example, those exemplified above.

Generally, the intermediate layer is also called an intermediate electrode, an intermediate conductive layer, a charge generation layer, an electron withdrawing layer, a connecting layer, or an intermediate insulating layer. The intermediate layer may be formed by known materials which can supply electrons to the first emission unit and holes to the second emission unit.

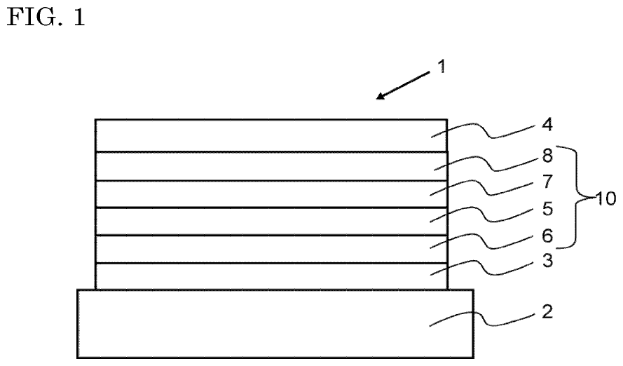

A schematic structure of an example of the organic EL device is shown in FIG. 1, wherein the organic EL device 1 comprises a substrate 2, an anode 3, a cathode 4, and an emission unit 10 disposed between the anode 3 and the cathode 4. The emission unit 10 comprises at least one light emitting layer 5. A hole injecting layer/a hole transporting layer 6 (anode-side organic layer) may be disposed between the light emitting layer 5 and the anode 3. A first electron transporting layer 7 and a second electron transporting layer 8 (cathode-side organic layer) are formed between the light emitting layer 5 and the cathode 4. An electron injecting layer may be formed between the electron transporting layer 8 and the cathode 4. An electron blocking layer (not shown) may be formed on the anode 3-side of the light emitting layer 5. With the electron blocking layer, electrons and holes are confined in the light emitting layer 5 to increase the exciton generation in the light emitting layer 5.

### Substrate

The substrate is a support for the emitting device and made of, for example, glass, quartz, and plastics. The substrate may be a flexible substrate, for example, a plastic substrate made of polycarbonate, polyarylate, polyether sulfone, polypropylene, polyester, polyvinyl fluoride, and polyvinyl chloride. An inorganic deposition film is also usable.

### Anode

The anode is formed on the substrate preferably from a metal, an alloy, an electrically conductive compound, and a mixture thereof, each having a large work function, for example, 4.5 eV or more. Examples of the material for the anode include indium oxide-tin oxide (ITO: indium tin oxide), indium oxide-tin oxide doped with silicon or silicon oxide, indium oxide-zinc oxide, indium oxide doped with tungsten oxide and zinc oxide, and graphene. In addition, gold (Au), platinum (Pt), nickel (Ni), tungsten (W), chromium (Cr), molybdenum (Mo), iron (Fe), cobalt (Co), copper (Cu), palladium (Pd), titanium (Ti), and a nitride of the above metal (for example, titanium nitride) are also usable.

These materials are made into a film generally by a sputtering method. For example, a film of indium oxide-zinc oxide is formed by sputtering an indium oxide target doped with 1 to 10 wt % of zinc oxide, and a film of indium oxide doped with tungsten oxide and zinc oxide is formed by sputtering an indium oxide target doped with 0.5 to 5 wt % of tungsten oxide and 0.1 to 1 wt % of zinc oxide. In addition, a vacuum vapor deposition method, a coating method, an inkjet method, and a spin coating method are usable.

A hole injecting layer to be optionally formed in contact with the anode is formed from a material which is capable of easily injecting holes independently of the work function of the anode. Therefore, the anode can be formed by a material generally known as an electrode material, for example, a metal, an alloy, an electroconductive compound, a mixture thereof, and a group 1 element and a group 2 element of the periodic table.

A material having a small work function, for example, the group 1 element and the group 2 element of the periodic table, i.e., an alkali metal, such as lithium (Li) and cesium (Cs), an alkaline earth metal, such as magnesium (Mg), calcium (Ca), and strontium (Sr), and an alloy thereof, such as MgAg and AlLi, are also usable. In addition, a rare earth metal, such as europium (Eu) and ytterbium (Yb), and an alloy thereof are also usable. The alkali metal, the alkaline earth metal, and the alloy thereof can be made into the anode by a vacuum vapor deposition or a sputtering method. When a silver paste, etc. is used, a coating method and an inkjet method are usable.

### Hole Injecting Layer

The hole injecting layer is provided to efficiently inject holes from the anode into the organic layer. Examples of the compound for use in the hole injecting layer include molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, an acceptor compound, and a macro molecular compound (an oligomer, a dendrimer, a polymer).

Preferred is an aromatic amine derivative or an acceptor compound, with an acceptor compound being more preferred. Preferred examples of the acceptor compound (an electron-accepting compound) include a heterocyclic derivative having an electron accepting group, a quinone derivative having an electron accepting group, an arylborane derivative, and a heteroarylborane derivative, for example, hexacyanohexaazatriphenylene, F₄TCNQ (2,3,5,6-tetrafluoro-7,7,8,8-tetracyanoquinodimethane), and 1,2,3-tris[(cyano)(4-cyano-2,3,5,6-tetrafluorophenyl)methylene]cyclopropane.

The layer comprising the acceptor compound preferably comprises a matrix material. The matrix material may be selected from a wide range of materials for organic EL devices. The matrix material to be combinedly used with the acceptor compound is preferably a donor compound and more preferably an aromatic amine compound.

### Hole Transporting Layer

The hole transporting layer comprises a highly hole transporting compound. An aromatic amine compound, a carbazole derivative, and an anthracene derivative may be used in the hole transporting layer. A macro molecular compound, such as poly(N-vinylcarbazole) (PVK) and poly(4-vinyltriphenylamine) (PVTPA), is also usable. A compound other than those mentioned above is also usable if its hole transporting ability is higher than its electron transporting ability. The hole transporting layer may be a single layer or a stacked layer of two or more layers each comprising the above compound. The material for hole transporting layer is preferably a compound represented by formula (H):

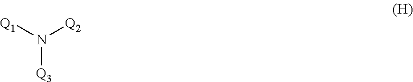

wherein, each of Q₁ to Q₃ is independently a substituted or unsubstituted aryl group having 6 to 50 ring carbon atoms, a substituted or unsubstituted heterocyclic group having 5 to 50 ring atoms, or a group wherein two or more selected from a substituted or unsubstituted aryl group having 6 to 50 ring carbon atoms and a substituted or unsubstituted heterocyclic group having 5 to 50 ring atoms are linked via a single bond. The aryl group is preferably a phenyl group, a biphenyl group, a terphenyl group, a fluorenyl group, a spirobifluorenyl group, an indenofluorenyl group, a naphthyl group, a phenanthryl group, an anthryl group, or a triphenylenyl group. The heterocyclic group is preferably a dibenzofuranyl group, a dibenzothiophenyl group, or a carbazolyl group. The group wherein two or more selected from an aryl group and a heterocyclic group are liked is preferably a dibenzofuran-substituted aryl group, a dibenzothiophene-substituted aryl group, or a carbazole-substituted aryl group, wherein the substituent may have a further substituent.

In an embodiment of the invention, at least one selected from Q₁ to Q₃ of formula (H) preferably has an arylamino substituent. Thus, the compound of formula (H) is preferably a diamine derivative, a triamine derivative or a tetramine derivative. The diamine derivative is preferably a tetraaryl-substituted benzidine and TPTE (4,4′-bis[N-phenyl-N-[4′-diphenylamino-1,1′-biphenyl-4-yl]amino]-1,1′-biphenyl).

### Light Emitting Layer

The light emitting layer comprises a highly light-emitting material (dopant material) and may be formed from a various kind of materials. The light emitting layer generally comprises a dopant material and a host material to cause an efficient emission of the dopant material. For example, a fluorescent compound and a phosphorescent compound are usable as the dopant material. The fluorescent compound is a compound which emits light from a singlet excited state, and the phosphorescent compound is a compound which emits light from a triplet excited state. A light emitting layer comprising a fluorescent compound is called a fluorescent emitting layer, and a light emitting layer comprising a phosphorescent compound is called a phosphorescent emitting layer. A light emitting layer may comprise more than one dopant material and more than one host material.

### Dopant Material of Light Emitting Layer

The dopant material of the fluorescent light emitting layer may be selected from a wide range of fluorescent compounds. Preferred are a fused polycyclic aromatic derivative, a styrylamine derivative, a fused ring amine derivative, a boron-containing compound, a pyrrole derivative, an indole derivative, and a carbazole derivative. More preferred are a fused ring amine derivative and a boron-containing compound. The fused ring amine derivative is preferably represented by formula (J):

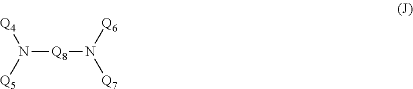

wherein each of Q₄ to Q₇ is independently a substituted or unsubstituted aryl group having 6 to 50 ring carbon atoms or a substituted or unsubstituted heteroaryl group having 5 to 50 ring atoms. The aryl group having 6 to 50 ring carbon atoms is preferably an aromatic hydrocarbon group having 6 to 12 ring carbon atoms and particularly preferably a phenyl group. The heteroaryl group having 5 to 50 ring atoms is a carbazolyl group, a dibenzofuranyl group, or a dibenzothiophenyl group, with a dibenzofuranyl group being preferred. Q₈ is a substituted or unsubstituted arylene group having 6 to 50 ring carbon atoms or a substituted or unsubstituted heteroarylene group having 5 to 50 ring atoms. The arylene group having 6 to 50 ring carbon atoms includes a pyrenylene group, a chrysenylene group, an anthracenylene group, and a fluorenylene group, with a pyrenylene group being preferred. A fluorenylene group having at least one benzofuro-fused skeleton is also preferable as the arylene group having 6 to 50 ring carbon atoms.

The boron-containing compound is, for example, a pyrromethene derivative and a triphenylborane derivative. The term, X derivative, used herein means a compound having a skeleton X as the main skeleton and includes a compound wherein a ring is fused to the main skeleton and a compound wherein substituents on the main skeleton form a ring. For example, the fused polycyclic aromatic derivative is a compound having a fused polycyclic aromatic skeleton as the main skeleton and includes a compound wherein a ring is fused to the fused polycyclic aromatic skeleton and a compound wherein substituents on the fused polycyclic aromatic skeleton form a ring.

Examples of the phosphorescent material (dopant material) for use in the phosphorescent emitting layer include a metal complex, such as an iridium complex, an osmium complex, and a platinum complex.

The metal complex is preferably an ortho-metalated complex of a metal selected from the group consisting of iridium, osmium, and platinum, and more preferably represented by formula (K):

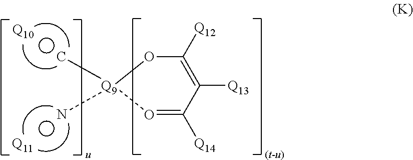

wherein:

Q₉ is at least one metal selected from the group consisting of osmium, iridium, and platinum, t is a valence of the metal, u is an integer of 1 or more;

a ring Q₁₀ is a substituted or unsubstituted aryl group having 6 to 24 ring carbon atoms or a heteroaryl group having 5 to 30 ring atoms, a ring Q₁₁ is a substituted or unsubstituted heteroaryl group having 5 to 30 ring atoms and having a nitrogen atom as the ring heteroatom;

each of Q₁₂ to Q₁₄ is a hydrogen atom or a substituent;

when u is 2 or more, the ring Q₁₀ and the ring Q₁₁ may be the same or different, respectively;

when t-u is 2 or more, Q₁₂ to Q₁₄ may be the same or different; and

when t-u is zero, formula (K) is represented by formula (G):

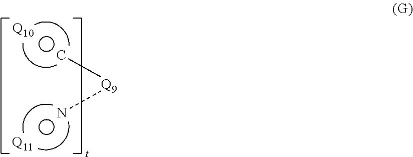

wherein Q₉, the ring Q₁₀, the ring Q₁₁, and t are as defined in formula (K).

A rare earth metal complex, such as tris(acetylacetonato) (monophenanthroline)terbium(III) (Tb(acac)₃(Phen)), tris (1,3-diphenyl-1,3-propanedionato)(monophenanthroline)europium(III) (Eu(DBM)₃(Phen)), and tris[1-(2-thenoyl)-3,3,3-trifluoroacetonato](monophenanthroline)europium(III) (Eu(TTA)₃(Phen)), emits light from the rare earth metal ion (electron transition between different multiple states), and therefore, usable as a phosphorescent compound.

### Host Material for Light Emitting Layer

The host material for use in the fluorescent emitting layer is preferably a compound having a fused polycyclic aromatic derivative as the main skeleton, and more preferably an anthracene derivative, a pyrene derivative, a chrysene derivative, and a naphthacene derivative. A host suitable as a blue host material (a host material combinedly used with a blue fluorescent material) and a green host material (a host material combinedly used with a green fluorescent material) is an anthracene derivative represented by formula (E):

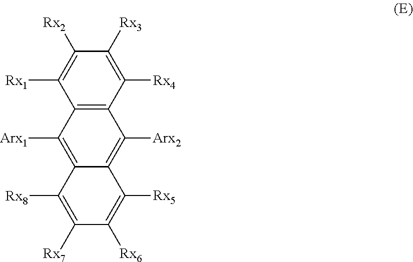

In formula (E), each of Ar_{X1} and Ar_{X2} is independently a substituted or unsubstituted aryl group having 6 to 50 ring carbon atoms or a substituted or unsubstituted heteroaryl group having 3 to 50 ring atoms, preferably a substituted or unsubstituted aryl group having 6 to 30 ring carbon atoms or a heteroaryl group having 5 to 30 ring atoms, and more preferably a phenyl group, a naphthyl group, biphenyl group, a phenanthryl group, a fluorenyl group, a dibenzofuranyl group, a naphthobenzofuranyl group, or a carbazolyl group, each optionally having a substituent. Each of R_{X1} to R_{X8} is a hydrogen atom or a substituent.

The host material for use in the phosphorescent emitting layer is preferably a compound having a triplet level higher than that of the phosphorescent dopant, and selected from a known phosphorescent host material, such as an aromatic derivative, a heterocyclic derivative, and a metal complex, preferably an aromatic derivative and a heterocyclic derivative. The aromatic derivative includes, for example, a naphthalene derivative, a triphenylene derivative, a phenanthrene derivative, and a fluoranthene derivative. The heterocyclic derivative includes, for example, an indole derivative, a carbazole derivative, a pyridine derivative, a pyrimidine derivative, a triazine derivative, a quinoline derivative, an isoquinoline derivative, a quinazoline derivative, a dibenzofuran derivative, and a dibenzothiophene derivative.

The host material to be combinedly used with the phosphorescent material is preferably a carbazole derivative having a carbazole substituent, a carbazole derivative having a benzo-fused skeleton, a carbazole derivative having an indeno-fused skeleton, a carbazole derivative having an indolo-fused skeleton, and a carbazole derivative having a benzofro-fused skeleton.

### Electron Transporting Layer

The electron transporting layer comprises a highly electron-transporting material (electron transporting material).

In the organic EL device of the invention, the electron transporting layer comprises a first electron transporting layer at the light emitting layer side and a second electron transporting layer at the cathode side. As described above, since the first electron transporting layer comprises the compound 1, the first electron transporting layer acts as a hole blocking layer. Since the second electron transporting layer comprises the compound 2, the EL device performance, for example, the emission efficiency is improved.

Another organic layer may be interposed between the light emitting layer and the first electron transporting layer and between the first electron transporting layer and the second electron transporting layer. Preferably, the light emitting layer and the first electron transporting layer are in direct contact with each other. Each electron transporting layer may comprise two or more compounds. Preferably, the first electron transporting layer is formed from only the compound 1. The first electron transporting layer and the second electron transporting layer are preferably free from the emitting material.

Further examples of the material for the electron transporting layer include a metal complex, such as an aluminum complex, a beryllium complex, and a zinc complex; a heterocyclic compound, such as an imidazole derivative, a benzimidazole derivative, an azine derivative, a carbazole derivative, and a phenanthroline derivative; a fused aromatic hydrocarbon derivative; and a macro molecular compound. Preferred are an imidazole derivative (for example, a benzimidazole derivative, an imidazopyridine derivative, and a benzimidazophenanthridine derivative), an azine derivative (for example, a pyrimidine derivative, a triazine derivative, a quinoline derivative, an isoquinoline derivative, and a phenanthroline derivative, each optionally having a phosphine oxide substituent), and an aromatic hydrocarbon derivative (for example, an anthracene derivative and a fluoranthene derivative).

In a preferred embodiment of the invention, the electron transporting layer may comprises at least one selected from the group consisting of an alkali metal (for example, Li and Cs), an alkaline earth metal (for example, Mg), an alloy comprising these metals, an alkali metal compound (for example, 8-quinolinolatolithium (Liq)), and an alkaline earth metal compound. When the electron transporting layer comprises at least one selected from the alkali metal, the alkaline earth metal, and the alloy of these metal, the content thereof in the electron transporting layer is, but not limited to, preferably 0.1 to 50% by mass, more preferably 0.1 to 20% by mass, and still more preferably 1 to 10% by mass. When the electron transporting layer comprises at least one selected from the alkali metal compound and the alkaline earth metal compound, the content thereof in the electron transporting layer is, but not limited to, preferably 1 to 99% by mass and more preferably 10 to 90% by mass.

In a preferred embodiment of the invention, the second electron transporting layer preferably comprises at least one selected from the group consisting of the alkali metal, the alkaline earth metal, the alloy of these metals, the alkali metal compound, and the alkaline earth metal compound, more preferably comprises 8-quinolinolatolithium (Liq). When the second electron transporting layer comprises at least one selected from the alkali metal, the alkaline earth metal, and the alloy of these metal, the content thereof in the second electron transporting layer is, but not limited to, preferably 0.1 to 50% by mass, more preferably 0.1 to 20% by mass, and still more preferably 1 to 10% by mass. When the second electron transporting layer comprises at least one selected from the alkali metal compound and the alkaline earth metal compound, the content thereof in the second electron transporting layer is, but not limited to, preferably 1 to 99% by mass and more preferably 10 to 90% by mass. The second electron transporting layer may be formed from only 8-quinolinolatolithium (Liq).

### Electron Injecting Layer

The electron injecting layer comprises a highly electron-injecting material, for example, an alkali metal, an alkaline earth metal, and a compound of these metals, such as lithium (Li), cesium (Cs), calcium (Ca), lithium fluoride (LiF), cesium fluoride (CsF), calcium fluoride(CaF₂), and lithium oxide (LiOx). In addition, an electron transporting material which is doped with an alkali metal, an alkaline earth metal or a compound thereof (for example, 8-quinolinolatolithium (Liq)), for example, Alq doped with magnesium (Mg), is also usable. By using such a material, electrons are efficiently injected from the cathode.

A composite material obtained by mixing an organic compound and an electron donor is also usable in the electron injecting layer. Such a composite material is excellent in the electron injecting ability and the electron transporting ability, because the organic compound receives electrons from the electron donor. The organic compound is preferably a material excellent in transporting the received electrons. Examples thereof are the materials for the electron transporting layer mentioned above, such as the metal complex and the aromatic heterocyclic compound. Any material capable of giving its electron to another organic compound is usable as the electron donor. Preferred examples thereof are an alkali metal, an alkaline earth metal, and a rare earth metal, such as lithium, cesium, magnesium, calcium, erbium, and ytterbium; an alkali metal oxide and an alkaline earth metal oxide, such as, lithium oxide, calcium oxide, and barium oxide; a Lewis base, such as magnesium oxide; and an organic compound, such as tetrathiafulvalene (TTF).

### Cathode

The cathode is formed preferably from a metal, an alloy, an electrically conductive compound, or a mixture thereof, each having a small work function, for example, a work function of 3.8 eV or less. Examples of the material for the cathode include a metal of the group 1 or 2 of the periodic table, for example, an alkali metal, such as lithium (Li) and cesium (Cs), an alkaline earth metal, such as magnesium (Mg), an alloy containing these metals (for example, MgAg and AlLi), a rare earth metal, such as europium (Eu) and ytterbium (Yb), and an alloy containing a rare earth metal.

The alkali metal, the alkaline earth metal, and the alloy thereof can be made into the cathode by a vacuum vapor deposition or a sputtering method. When a silver paste, etc. is used, a coating method and an inkjet method are usable.

When the electron injecting layer is formed, the material for the cathode can be selected independently from the work function and various electroconductive materials, such as Al, Ag, ITO, graphene, and indium oxide-tin oxide doped with silicon or silicon oxide, are usable. These electroconductive materials are made into films by a sputtering method, an inkjet method, and a spin coating method.

### Insulating Layer

Since electric field is applied to the ultra-thin films of organic EL devices, the pixel defects due to leak and short circuit tends to occur. To prevent the defects, an insulating thin film layer is preferably interposed between the pair of electrodes.

Examples of the material for the insulating layer include aluminum oxide, lithium fluoride, lithium oxide, cesium fluoride, cesium oxide, magnesium oxide, magnesium fluoride, calcium oxide, calcium fluoride, aluminum nitride, titanium oxide, silicon oxide, germanium oxide, silicon nitride, boron nitride, molybdenum oxide, ruthenium oxide, and vanadium oxide. These materials may be used in combination or may be made into stacked layers.

### Space Layer

For example, in an organic EL device wherein a fluorescent emitting layer and a phosphorescent emitting layer are stacked, a space layer is disposed between the fluorescent emitting layer and the phosphorescent emitting layer to prevent the diffusion of excitons generated in the phosphorescent emitting layer to the fluorescent emitting layer or to control the carrier balance. The space layer may be disposed between two or more phosphorescent emitting layers.

Since the space layer is disposed between the light emitting layers, a material combining the electron transporting ability and the hole transporting ability is preferably used for forming the space layer. To prevent the diffusion of triplet energy in the adjacent phosphorescent emitting layer, the triplet energy of the material for the space layer is preferably 2.6 eV or more. The materials described with respect to the hole transporting layer are usable as the material for the space layer.

### Blocking Layer

In the organic EL device, a blocking layer, such as an electron blocking layer, a hole blocking layer, and a triplet blocking layer, may be provided in the portion adjacent to the light emitting layer. The electron blocking layer is a layer which prevents the diffusion of electrons from the light emitting layer to the hole transporting layer. The hole blocking layer is a layer which prevents the diffusion of holes from the light emitting layer to the electron transporting layer. In the organic EL device of the invention, the first electron transporting layer acts as a hole blocking layer. The triplet blocking layer prevents the diffusion of excitons generated in the light emitting layer to adjacent layers and has a function of confining the excitons in the light emitting layer.

Each layer of the organic EL device can be formed by a known method, such as a vapor deposition method and a coating method. For example, each layer can be formed by a known vapor deposition method, such as a vacuum vapor deposition method and a molecular beam evaporation method (MBE method), and a known coating method using a solution of the compound for forming the layer, such as a dipping method, a spin coating method, a casting method, a bar coating method, and a roll coating method.

The thickness of each layer is not particularly limited and preferably 5 nm to 10 μm, more preferably 10 nm to 0.2 μm, because an excessively small thickness may cause defects such as pin holes and an excessively large thickness may require a high driving voltage to reduce the efficiency.

The organic EL device can be used in an electronic device, for example, as display parts, such as organic EL panel module, display devices of television sets, mobile phones, personal computer, etc., and light emitting sources of lighting equipment and vehicle lighting equipment.

### EXAMPLES

The present invention is described in more detail with reference to the examples. However, it should be noted that the scope of the present invention is not limited thereto.

### Example 1

A glass substrate of 25 mm×75 mm×1.1 mm thick having ITO transparent electrode (product of Geomatec Company) was ultrasonically cleaned in isopropyl alcohol for 5 min and then UV/ozone cleaned for 30 min. The thickness of ITO was 130 nm.

The cleaned glass substrate having the transparent electrode line was mounted to a substrate holder of a vacuum vapor deposition apparatus. First, the compound HI-1 was vapor-deposited so as to cover the transparent electrode line to form a hole injecting layer with a thickness of 5 nm.

On the hole injecting layer, the compound HT-1 was vapor-deposited to form a first hole transporting layer with a thickness of 95 nm.

On the first hole transporting layer, the compound HT-2 was vapor-deposited to form a second hole transporting layer with a thickness of 5 nm.

On the second hole transporting layer, the compound BH-1 (host material) and the compound BD-1 (dopant material) were vapor co-deposited to form a light emitting layer with a thickness of 20 nm. The concentration of the compound BH-1 and the compound BD-1 in the light emitting layer was 97% by mass and 3% by mass, respectively.

Successively after forming the light emitting layer, the compound HB-1 was vapor-deposited to form a first electron transporting layer with a thickness of 5 nm, and then, the compound ET-1 and 8-quinolinolatolithium (Liq) were vapor co-deposited in a ratio of 50:50 by mass to form a second electron transporting layer with a thickness of 20 nm.

On the second electron transporting layer, LiF was vapor-deposited to form an electron injecting layer with a thickness of 1 nm.

On the electron injecting layer, metallic Al was vapor-deposited to form a metallic cathode with a thickness of 80 nm, thereby producing an organic EL device.

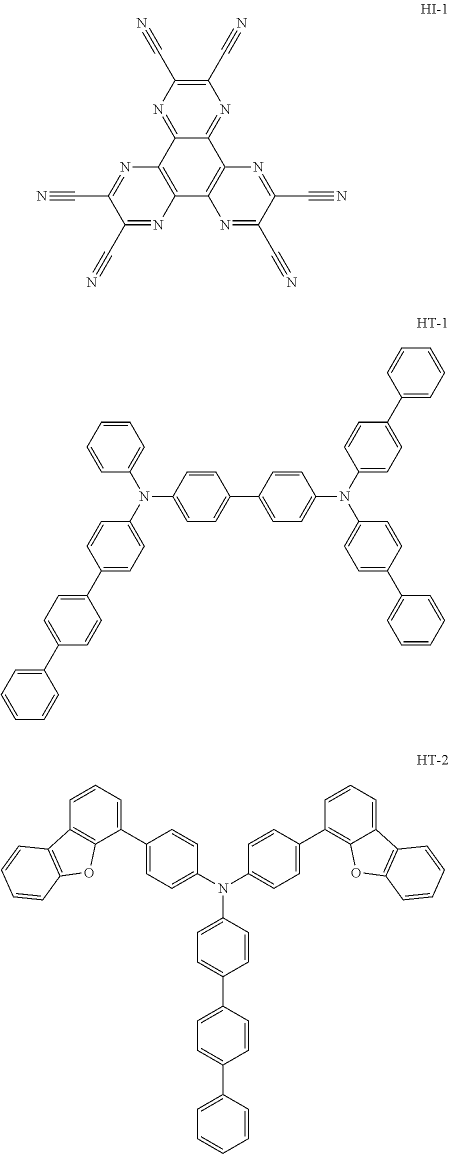 [SMILES: N#Cc1nc2c3nc(C#N)c(C#N)nc3c3nc(C#N)c(C#N)nc3c2nc1C#N ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

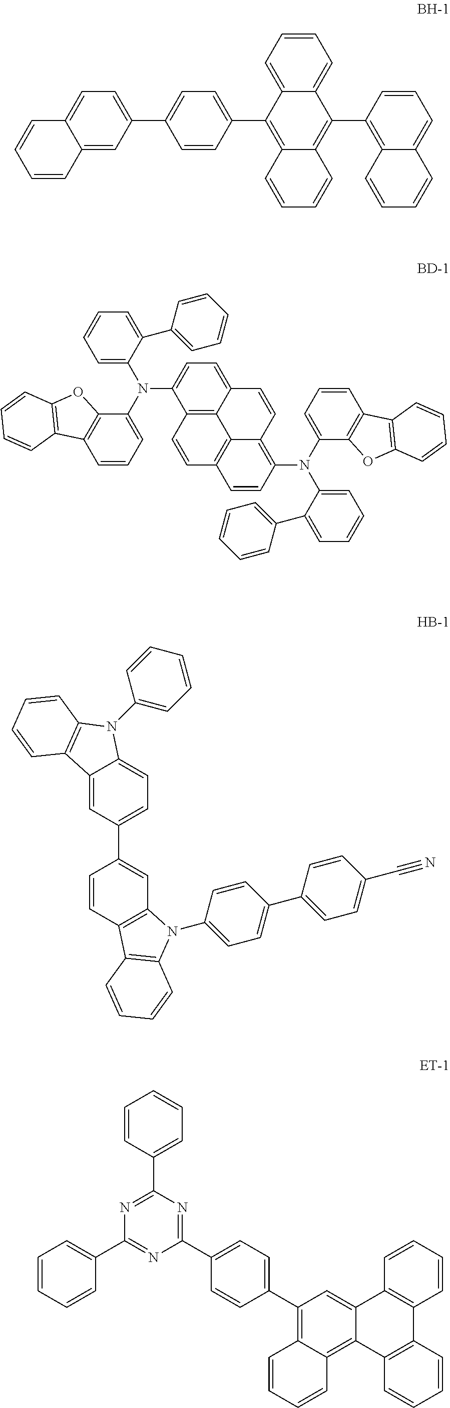

### Examples 2 to 11 and Comparative Examples 1 to 3

Each organic EL device was produced in the same manner as in Example 1 except for using the host material, the first electron transporting layer material, and the second electron transporting layer material, each described in Table 1.

### Evaluation of EL Device Performance

Each organic EL device thus produced was operated at a constant direct current to emit light, thereby determining the external quantum efficiency (EQE) at a current density of 10 mA/cm². The results are shown in Table 1.

TABLE 1

| | Materials | | | |
|---|---|---|---|---|
| | | First electron | Second electron | |
| | Host | transporting | transporting | EQE |
| | material | layer | layer | (%) |
| Example 1 | BH-1 | HB-1 | ET-1 | 9.8 |
| Example 2 | BH-2 | HB-1 | ET-1 | 10.0 |
| Example 3 | BH-1 | HB-1 | ET-2 | 9.9 |
| Example 4 | BH-2 | HB-1 | ET-2 | 10.1 |
| Example 5 | BH-1 | HB-1 | ET-3 | 9.2 |
| Example 6 | BH-2 | HB-1 | ET-3 | 9.8 |
| Example 7 | BH-2 | HB-2 | ET-1 | 8.5 |
| Example 8 | BH-2 | HB-2 | ET-2 | 8.6 |
| Example 9 | BH-2 | HB-2 | ET-3 | 8.4 |
| Example 10 | BH-3 | HB-1 | ET-1 | 9.9 |
| Example 11 | BH-4 | HB-1 | ET-1 | 9.9 |
| Comparative | BH-1 | HB-1 | ET-4 | 6.1 |
| example 1 | | | | |
| Comparative | BH-2 | HB-1 | ET-4 | 7.9 |
| example 2 | | | | |
| Comparative | BH-1 | HB-3 | ET-3 | 7.8 |
| example 3 | | | | |

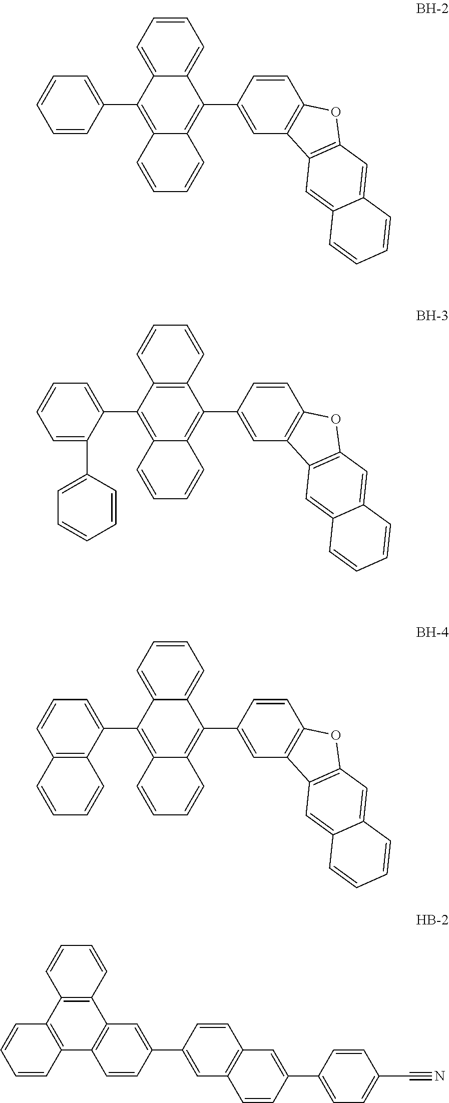 [SMILES: c1ccc(-c2c3ccccc3c(-c3ccc4oc5cc6ccccc6cc5c4c3)c3ccccc23)cc1 ; c1ccc(-c2ccccc2-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cccc5ccccc45)c4ccccc24)cc13 ; N#Cc1ccc(-c2ccc3cc(-c4ccc5c6ccccc6c6ccccc6c5c4)ccc3c2)cc1]

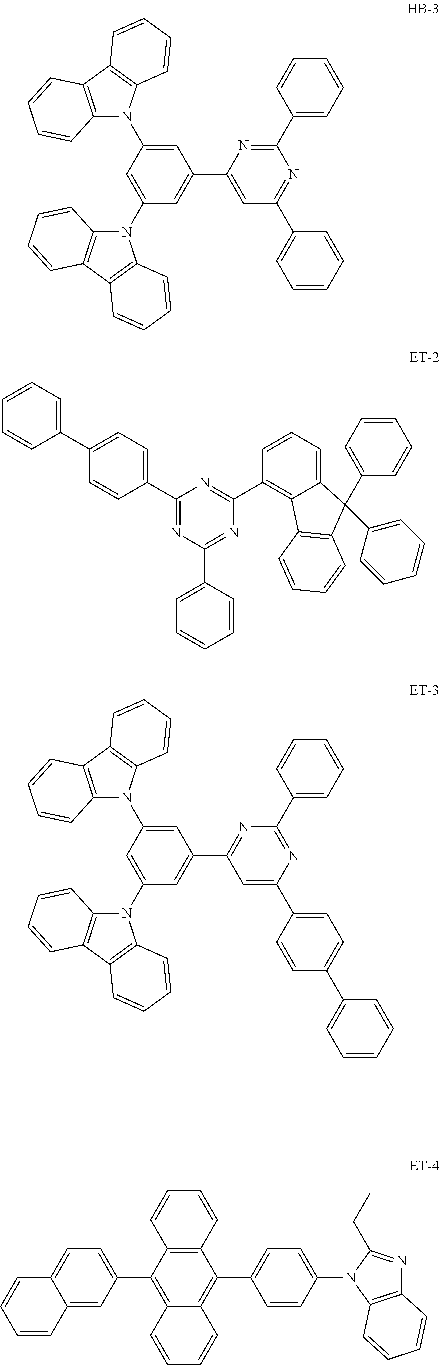 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2ccc(-c3nc(-c4ccccc4)nc(-c4cccc5c4-c4ccccc4C5(c4ccccc4)c4ccccc4)n3)cc2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; CCc1nc2ccccc2n1-c1ccc(-c2c3ccccc3c(-c3ccc4ccccc4c3)c3ccccc23)cc1]

In each of the organic EL devices in Examples of 1 to 11, the first electron transporting layer was formed from the compound of formula (1) and the second electron transporting layer was formed from the compound of formula (2). In each of the organic EL devices in Comparative Examples 1 and 2, the first electron transporting layer was formed from the compound of formula (1), but the second electron transporting layer was formed from the compound ET-4 having no nitrogen-containing six-membered ring. In the organic EL device of Comparative Example 3, the second electron transporting layer was formed from the compound of formula (2), but the first electron transporting layer was formed from the compound HB-3 containing no cyano group.

It can be seen from the results of Table 1 that an excellent emission efficiency (external quantum efficiency: EQE) was obtained only when the first electron transporting layer was formed from the compound of formula (1) and the second electron transporting layer was formed from the compound of formula (2).

### Examples 12 to 23

Each organic EL device was produced in the same manner as in Example 1 except for using the host material, the first electron transporting layer material, and the second electron transporting layer material described in Table 2. Each device thus produced was measured for the external quantum efficiency (EQE) in the same manner as describe above. The results are shown in Table 2.

TABLE 2

| | Materials | | | |
|---|---|---|---|---|
| | | First electron | Second electron | |
| | Host | transporting | transporting | EQE |
| | material | layer | layer | (%) |
| Example 12 | BH-2 | HB-4 | ET-1 | 9.4 |
| Example 13 | BH-1 | HB-5 | ET-1 | 8.9 |
| Example 14 | BH-1 | HB-6 | ET-1 | 8.4 |
| Example 15 | BH-1 | HB-7 | ET-1 | 8.7 |
| Example 16 | BH-1 | HB-8 | ET-1 | 9.1 |
| Example 17 | BH-3 | HB-1 | ET-5 | 10.0 |
| Example 18 | BH-2 | HB-1 | ET-6 | 9.0 |
| Example 19 | BH-2 | HB-1 | ET-7 | 9.3 |
| Example 20 | BH-1 | HB-1 | ET-8 | 9.7 |
| Example 21 | BH-1 | HB-1 | ET-9 | 9.5 |
| Example 22 | BH-3 | HB-4 | ET-5 | 9.3 |
| Example 23 | BH-1 | HB-5 | ET-2 | 9.6 |

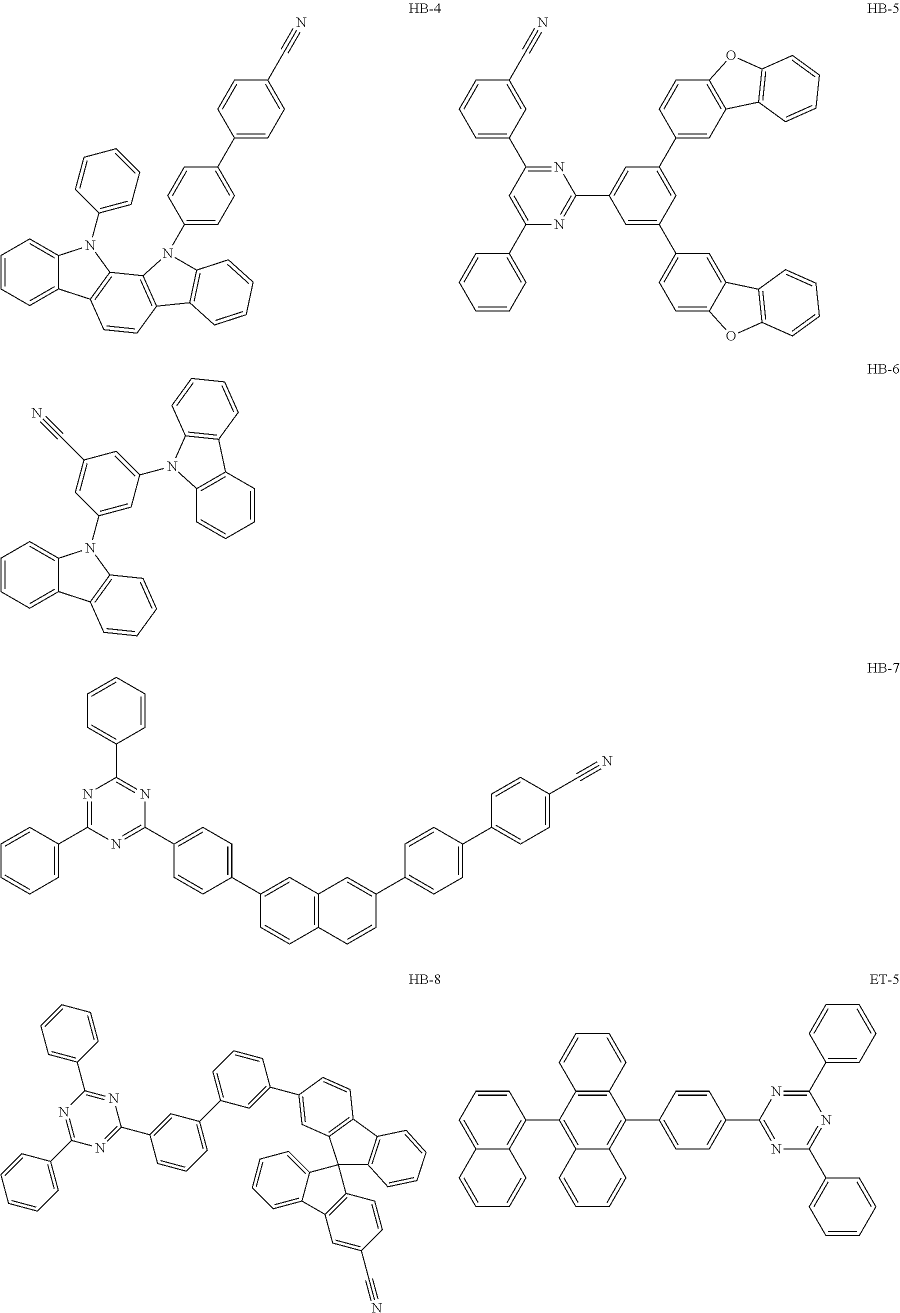

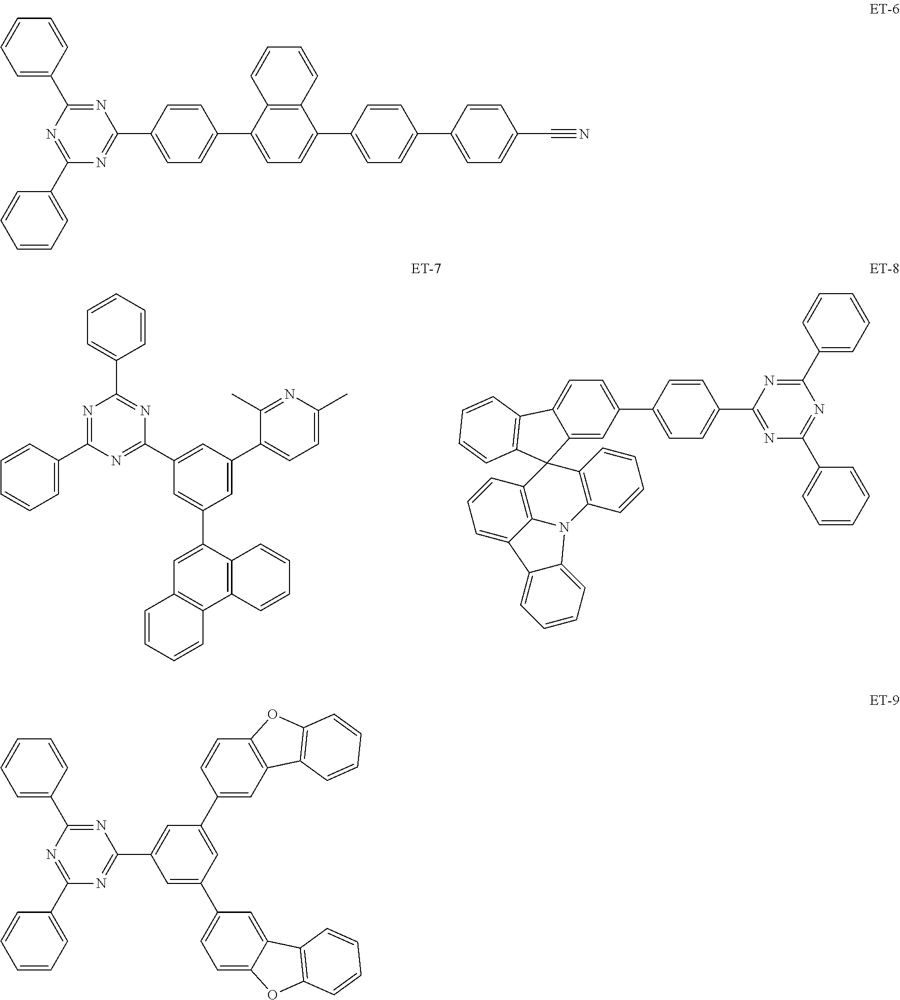 [SMILES: N#Cc1ccc(-c2ccc(-c3ccc(-c4ccc(-c5nc(-c6ccccc6)nc(-c6ccccc6)n5)cc4)c4ccccc34)cc2)cc1 ; Cc1ccc(-c2cc(-c3nc(-c4ccccc4)nc(-c4ccccc4)n3)cc(-c3cc4ccccc4c4ccccc34)c2)c(C)n1 ; c1ccc(-c2nc(-c3ccccc3)nc(-c3ccc(-c4ccc5c(c4)C4(c6ccccc6-5)c5ccccc5-n5c6ccccc6c6cccc4c65)cc3)n2)cc1 ; c1ccc(-c2nc(-c3ccccc3)nc(-c3cc(-c4ccc5oc6ccccc6c5c4)cc(-c4ccc5oc6ccccc6c5c4)c3)n2)cc1]

### REFERENCE SIGNS LIST

1: Organic EL device
2: Substrate
3: Anode
4: Cathode
5: Light emitting layer
6: Anode-side organic layer
7: Cathode-side organic layer (first electron transporting layer)
8: Cathode-side organic layer (second electron transporting layer)
10: Emission unit

1. An organic electroluminescence device comprising a cathode, an anode, and an organic layer between the cathode and the anode, wherein:
the organic layer comprises a light emitting layer, a first electron transporting layer, and a second electron transporting layer in this order from the anode toward the cathode;
the first electron transporting layer comprises a compound represented by formula (1); and
the second electron transporting layer comprises a compound represented by formula (2):
A-(L)ₙ-Ar—CN (1)
wherein
A is a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 30 ring atoms, or a substituted or unsubstituted non-fused heteroaryl group having 5 to 30 ring atoms;
L is a substituted or unsubstituted fused arylene group having 10 to 30 ring carbon atoms, a substituted or unsubstituted non-fused arylene group having 6 to 30 ring carbon atoms, a substituted or unsubstituted fused heteroarylene group having 9 to 30 ring atoms, or a substituted or unsubstituted non-fused heteroarylene group having 5 to 30 ring atoms;
n is 1 or 2;
when n is 2, two L's may be the same or different; and
Ar is a substituted or unsubstituted fused arylene group having 10 to 30 ring carbon atoms, a substituted or unsubstituted non-fused arylene group having 6 to 30 ring carbon atoms, a substituted or unsubstituted fused heteroarylene group having 9 to 30 ring atoms, or a substituted or unsubstituted non-fused heteroarylene group having 5 to 30 ring atoms;
provided that at least one of A and Ar is a group comprising a fused ring; 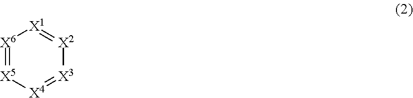
wherein
X¹ is a nitrogen atom or CR¹;
X² is a nitrogen atom or CR²;
X³ is a nitrogen atom or CR³;
X⁴ is a nitrogen atom or CR⁴;
X⁵ is a nitrogen atom or CR⁵;
X⁶ is a nitrogen atom or CR⁶;
at least one of X¹ to X⁶ is a nitrogen atom;
each of one to three selected from R¹ to R⁶ is independently a group represented by any of formulae (3) to (6), and the others of R¹ to R⁶ are each independently a hydrogen atom or a substituent;
adjacent two selected from R¹ to R⁶ are optionally bonded to each other to form a ring together with two ring carbon atoms to which the adjacent two are bonded, wherein the ring is a substituted or unsubstituted fused aromatic hydrocarbon ring having 10 to 30 ring carbon atoms, a substituted or unsubstituted non-fused aromatic hydrocarbon ring, a substituted or unsubstituted fused aromatic heterocyclic ring having 9 to 30 ring atoms, or a substituted or unsubstituted non-fused aromatic heterocyclic ring having 5 or 6 ring atoms; 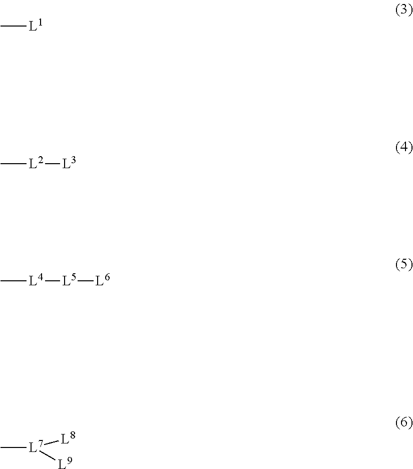
wherein
each of L¹, L³, L⁶, L⁸, and L⁹ is independently a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 32 ring atoms, or a substituted or unsubstituted non-fused heteroaryl group having 5 to 30 ring atoms;
each of L², L⁴, and L⁵ is independently a substituted or unsubstituted fused arylene group having 10 to 30 ring carbon atoms, a substituted or unsubstituted non-fused arylene group having 6 to 30 ring carbon atoms, a substituted or unsubstituted fused heteroarylene group having 9 to 30 ring atoms, or a substituted or unsubstituted non-fused heteroarylene group having 5 to 30 ring atoms;
L⁷ is a trivalent residue of a ring selected from a fused aromatic hydrocarbon ring having 10 to 30 ring carbon atoms, a non-fused aromatic hydrocarbon ring, a fused aromatic heterocyclic ring having 9 to 30 ring atoms, and a non-fused aromatic heterocyclic ring having 5 or 6 ring atoms, the trivalent residue being unsubstituted or having a substituent.

2. The organic electroluminescence device according to claim 1, wherein:
the fused aryl group of the substituted or unsubstituted fused aryl group having 10 to 30 ring carbon atoms for A is a monovalent residue of a fused aromatic hydrocarbon ring that is selected from naphthalene, acenaphthylene, anthracene, benzanthracene, aceanthrylene, phenanthrene, benzophenanthrene, phenalene, pentacene, picene, pentaphenylene, pyrene, chrysene, benzochrysene, s-indacene, as-indacene, fluoranthene, benzofluoranthene, perylene, and triphenylene;
the non-fused aryl group of the substituted or unsubstituted non-fused aryl group having 6 to 30 ring carbon atoms for A is a monovalent residue of benzene, biphenyl, terphenyl inclusive of isomers, or quaterphenyl inclusive of isomers;
the fused heteroaryl group of the substituted or unsubstituted fused heteroaryl group having 9 to 30 ring atoms for A is a monovalent residue derived from a fused heterocyclic ring by removing one hydrogen atom on a ring carbon atom or a ring nitrogen atom, wherein the fused heterocyclic ring is selected from indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, xanthene, di(benzimidazo)benzo[1,3,5]triazepine, (benzimidazo)benzimidazole, (benzimidazo)phenanthridine, and (benzindolo)benzoazepine; and
the non-fused heteroaryl group of the substituted or unsubstituted non-fused heteroaryl group having 5 to 30 ring atoms for A is a monovalent residue derived from a single ring or a ring assembly by removing one hydrogen atom on a carbon atom or a nitrogen atom, wherein the single ring and the ring assembly is selected from pyrrole, imidazole, pyrazole, triazole, furan, thiophene, thiazole, isothiazole, oxazole, oxazoline, isoxazole, oxadiazole, thiadiazole, pyridine, pyrazine, pyridazine, pyrimidine, triazine, bipyrrole, terpyrrole, bithiophene, terthiophene, bipyridine, and terpyridine.

3. The organic electroluminescence device according to claim 1, wherein a ring heteroatom of each of the substituted or unsubstituted non-fused heteroaryl group having 5 to 30 ring atoms for A and the substituted or unsubstituted fused heteroaryl group having 9 to 30 ring atoms for A is selected from a nitrogen atom, an oxygen atom, and a sulfur atom.

4. The organic electroluminescence device according to claim 1, wherein a ring heteroatom of each of the substituted or unsubstituted non-fused heteroaryl group having 5 to 30 ring atoms for A and the substituted or unsubstituted fused heteroaryl group having 9 to 30 ring atoms for A is a nitrogen atom.

5. The organic electroluminescence device according to claim 1, wherein the substituted or unsubstituted fused heteroaryl group having 9 to 30 ring atoms for A comprises an indole structure, a benzimidazole structure, a carbazole structure, a (benzimidazo)benzimidazole structure, or a di(benzimidazo)benzo[1,3,5]triazepine structure.

6. The organic electroluminescence device according to claim 1, wherein the substituted or unsubstituted fused heteroaryl group having 9 to 30 ring atoms for A comprises an indole structure or a carbazole structure.

7. The organic electroluminescence device according to claim 1, wherein the substituted or unsubstituted fused heteroaryl group having 9 to 30 ring atoms for A comprises a carbazole structure, and the carbazole structure is a biscarbazole structure or a fused carbazole structure.

8. The organic electroluminescence device according to claim 1, wherein the substituted or unsubstituted fused heteroaryl group having 9 to 30 ring atoms for A comprises a carbazole structure, and the carbazole structure is a biscarbazole structure.

9. The organic electroluminescence device according to claim 7, wherein the biscarbazole structure is represented by formula (7): 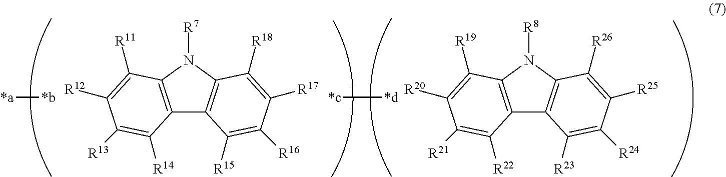
wherein
a is bonded to L of formula (1);
one selected from R⁷ and R¹¹ to R¹⁴ is a single bond bonded to *b;
one selected from R¹¹ to R¹⁸ is a single bond bonded to *c;
R⁷ not a single bond bonded to *b is a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 30 ring atoms, or a substituted or unsubstituted non-fused heteroaryl group having 5 to 30 ring atoms;
R¹¹ to R¹⁴ not a single bond bonded to *b and not a single bond bonded to *c, and R¹⁵ to R¹⁸ not a single bond bonded to *c are each independently a hydrogen atom or a substituent,
one selected from R⁸ and R¹⁹ to R²⁶ is a single bond bonded to *d;
R⁸ not a single bond bonded to *d is a substituted or unsubstituted fused aryl group having 10 to 30 ring carbon atoms, a substituted or unsubstituted non-fused aryl group having 6 to 30 ring carbon atoms, a substituted or unsubstituted fused heteroaryl group having 9 to 30 ring atoms, or a substituted or unsubstituted non-fused heteroaryl group having 5 to 30 ring atoms; and
R¹⁹ to R²² not a single bond bonded to *d are each independently a hydrogen atom or a substituent,
provided that when R¹⁶ is bonded to *c and R²¹ is bonded to *d, R¹⁵ and R²² together may represent an oxygen atom or a sulfur atom that crosslinks two carbazole structures.

10. The organic electroluminescence device according to claim 7, wherein the fused carbazole structure is represented by formula (8): 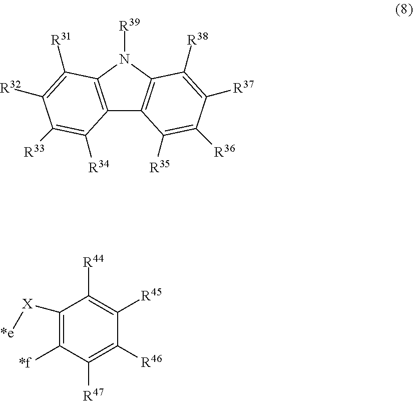
in formula (8):
one selected from R³⁹, R³¹ to R³⁸, and R⁴⁴ to R⁴⁷ is a single bond bonded to L of formula (1);
in at least one selected from R³¹ and R³², R³² and R³³, R³³ and R³⁴, R³⁵ and R³⁶, R³⁶ and R³⁷, and R³⁷ and R³⁸, one is a single bond bonded to *e and the other is a single bond bonded to *f;
R³⁹ not a single bond bonded to L of formula (1) is a substituent;
R³¹ to R³⁸ not a single bond bonded to L of formula (1), *e or *f is a hydrogen atom or a substituent;
X is an oxygen atom, a sulfur atom, NR⁴¹, or CR⁴²R⁴³;
R⁴¹ is a substituent;
each of R⁴² and R⁴³ is independently a hydrogen atom or a substituent;
R⁴⁴ to R⁴⁷ not a single bond bonded to L of formula (1) are each independently a hydrogen atom or a substituent;
or
in formula (8):
at least one selected from R³¹ and R³², R³² and R³³, R³³ and R³⁴, R³⁵ and R³⁶, R³⁶ and R³⁷, and R³⁷ and R³⁸, together with two ring carbon atoms to which they are bonded, form a substituted or unsubstituted fused or non-fused aromatic hydrocarbon ring having 6 to 30 ring carbon atoms;
one selected from R³⁹ and R³¹ to R³⁸ not forming the fused or non-fused aromatic hydrocarbon ring is a single bond bonded to L of formula (1), or one ring carbon atom of the fused or non-fused aromatic hydrocarbon ring is bonded to L of formula (1);
R³⁹ not a single bond bonded to L of formula (1) is a substituent; and
R³¹ to R³⁸ not a single bond bonded to L of formula (1) and not forming the ring are each a hydrogen atom or a substituent.

11. The organic electroluminescence device according to claim 1, wherein A is a substituted or unsubstituted fused heteroaryl group having 9 to 30 ring atoms.

12. The organic electroluminescence device according to claim 1, wherein the fused aryl group of the substituted or unsubstituted fused aryl group having 10 to 30 ring carbon atoms for A is a monovalent residue of a fused aromatic hydrocarbon ring selected from naphthalene, phenanthrene, pyrene, benzochrysene, fluoranthene, and triphenylene.

13. The organic electroluminescence device according to claim 1, wherein the fused aryl group of the substituted or unsubstituted fused aryl group having 10 to 30 ring carbon atoms for A is a monovalent residue of a fused aromatic hydrocarbon ring selected from pyrene, benzochrysene, fluoranthene, and triphenylene.

14. The organic electroluminescence device according to claim 1, wherein:
the fused arylene group of the substituted or unsubstituted fused arylene group having 10 to 30 ring carbon atoms for L and Ar is a divalent residue of a fused aromatic ring selected from naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, triphenylene, and spirofluorene;
the non-fused arylene group of the substituted or unsubstituted non-fused arylene group having 6 to 30 ring carbon atoms for L and Ar is a divalent residue of benzene, biphenyl, terphenyl inclusive of isomers, or quaterphenyl;
the fused heteroarylene group of the substituted or unsubstituted fused heteroarylene group having 9 to 30 ring atoms for L and Ar is a divalent residue derived from a fused heterocyclic ring by removing two hydrogen atoms on a ring carbon atom and/or a ring nitrogen atom, wherein the fused heterocyclic ring is selected from indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene; and
the non-fused heteroarylene group of the substituted or unsubstituted non-fused heteroarylene group having 5 to 30 ring atoms for L and Ar is a divalent residue derived from a heterocyclic ring by removing two hydrogen atoms on a carbon atom and/or a nitrogen atom, wherein the heterocyclic ring is selected from pyrrole, imidazole, pyrazole, triazole, furan, thiophene, thiazole, isothiazole, oxazole, oxazoline, isoxazole, oxadiazole, thiadiazole, pyridine, pyrazine, pyridazine, pyrimidine, triazine, bipyrrole, terpyrrole, bithiophene, terthiophene, bipyridine, and terpyridine.

15. The organic electroluminescence device according to claim 1, wherein Ar of —Ar—CN or -L-Ar—CN of formula (1) is a single benzene ring, a ring assembly comprising a benzene ring, an aromatic hydrocarbon ring comprising benzene rings, or a fused aromatic heterocyclic ring comprising a benzene ring, wherein the benzene ring has optionally a substituent, and the carbon atom forming the benzene ring is bonded to CN.

16. The organic electroluminescence device according to claim 15, wherein —Ar—CN or -L-Ar—CN is represented by any of the following formulae: 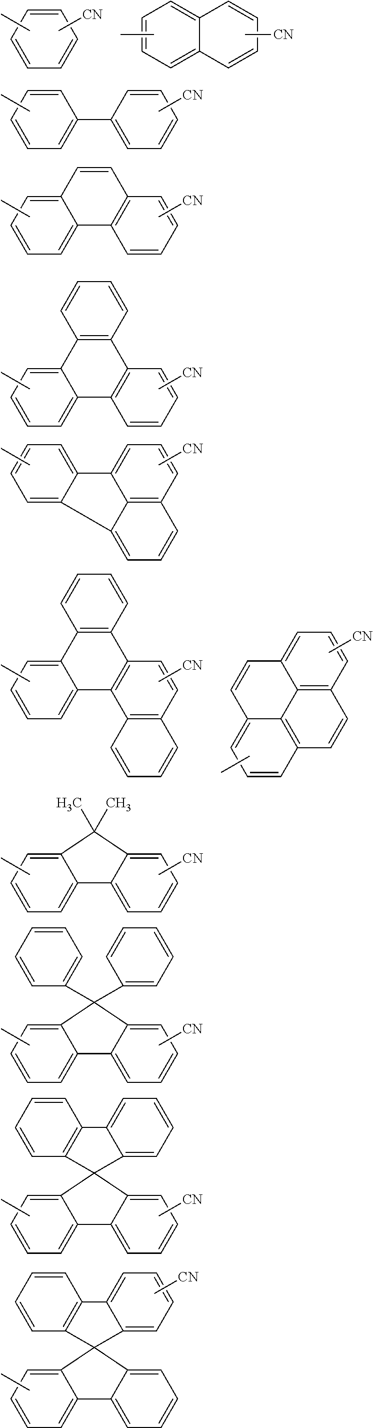 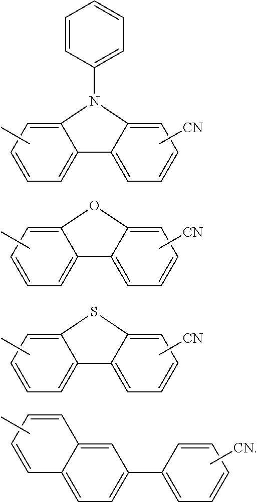
wherein each benzene ring optionally has a substituent.

17. The organic electroluminescence device according to claim 15, wherein —Ar—CN or -L-Ar—CN comprises a p-biphenylylcyano structure.

18. The organic electroluminescence device according to claim 17, wherein the p-biphenylylcyano structure does not comprise a heteroatom.

19. The organic electroluminescence device according to claim 1, wherein formula (2) is represented by formula (2a):

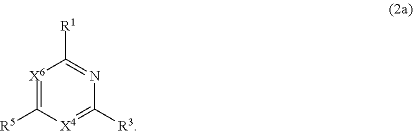

20. The organic electroluminescence device according to claim 1, wherein formula (2) is represented by formula (2b):

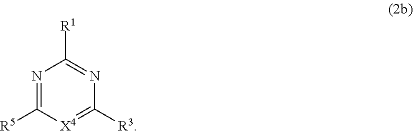

21. The organic electroluminescence device according to claim 1, wherein formula (2) is represented by formula (2c):

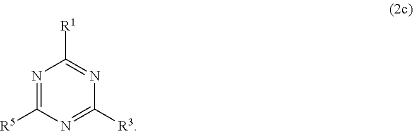

22. The organic electroluminescence device according to claim 1, wherein:
the fused aryl group of the substituted or unsubstituted fused aryl group having 10 to 30 ring carbon atoms for L¹, L³, L⁶, L⁸, and L⁹ is a monovalent residue of a fused aromatic ring selected from naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, triphenylene, and spirofluorene;
the non-fused aryl group of the substituted or unsubstituted non-fused aryl group having 6 to 30 ring carbon atoms for L¹, L³, L⁶, L⁸, and L⁹ is a monovalent residue of benzene, biphenyl, terphenyl inclusive of isomers, or quaterphenyl inclusive of isomers;
the fused heteroaryl group of the substituted or unsubstituted fused heteroaryl group having 9 to 32 ring atoms for L¹, L³, L⁶, L⁸, and L⁹ is a monovalent residue derived from a fused heterocyclic ring by removing one hydrogen atom on a ring carbon atom or a ring nitrogen atom, wherein the fused heterocyclic ring is selected from indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene; and
the non-fused heteroaryl group of the substituted or unsubstituted non-fused heteroaryl group having 5 to 30 ring atoms for L¹, L³, L⁶, L⁸, and L⁹ is a monovalent residue derived from a heterocyclic ring by removing one hydrogen atom on a carbon atom or a nitrogen atom, wherein the heterocyclic ring is selected from pyrrole, imidazole, imidazoline, pyrazole, triazole, furan, thiophene, thiazole, isothiazole, oxazole, isoxazole, oxadiazole, thiadiazole, pyridine, pyrazine, pyridazine, pyrimidine, triazine, bipyrrole, terpyrrole, bithiophene, terthiophene, bipyridine, and terpyridine.

23. The organic electroluminescence device according to claim 1, wherein:
the fused arylene group of the substituted or unsubstituted fused arylene group having 10 to 30 ring carbon atoms for L², L⁴, and L⁵ is a divalent residue of a fused aromatic ring selected from naphthalene, acenaphthylene, anthracene, benzanthracene, aceanthrylene, phenanthrene, benzophenanthrene, phenalene, fluorene, pentacene, picene, pentaphenylene, pyrene, chrysene, benzochrysene, s-indacene, as-indacene, fluoranthene, perylene, triphenylene, 9,9-dimethylfluorene, 9,9-diphenylfluorene, and spirofluorene;
the non-fused arylene group of the substituted or unsubstituted non-fused arylene group having 6 to 30 ring carbon atoms for L², L⁴, and L⁵ is a divalent residue of benzene, biphenyl, terphenyl inclusive of isomers, or quaterphenyl inclusive of isomers;
the fused heteroarylene group of the substituted or unsubstituted fused heteroarylene group having 9 to 30 ring atoms for L², L⁴, and L⁵ is a divalent residue derived from a fused heterocyclic ring by removing two hydrogen atoms on a ring carbon atom and/or a ring nitrogen atom, wherein the fused heterocyclic ring is selected from indole, isoindole, benzofuran, isobenzofuran, benzothiophene, indolizine, quinolizine, quinoline, isoquinoline, cinnoline, phthalazine, quinazoline, quinoxaline, benzimidazole, benzoxazole, benzothiazole, indazole, benzisoxazole, benzisothiazole, benzofuran, dibenzofuran, naphthobenzofuran, benzothiophene, dibenzothiophene, naphthobenzothiophene, carbazole, benzocarbazole, phenanthridine, acridine, phenanthroline, phenazine, phenothiazine, phenoxazine, and xanthene; and
the non-fused heteroarylene group of the substituted or unsubstituted non-fused heteroarylene group having 5 to 30 ring atoms for L², L⁴, and L⁵ is a divalent residue derived from a single ring or a ring assembly by removing two hydrogen atoms on a carbon atom and/or a nitrogen atom, wherein the single ring or the ring assembly is selected from pyrrole, imidazole, pyrazole, triazole, furan, thiophene, thiazole, isothiazole, oxazole, oxazoline, isoxazole, oxadiazole, thiadiazole, pyridine, pyrazine, pyridazine, pyrimidine, triazine, bipyrrole, terpyrrole, bithiophene, terthiophene, bipyridine, and terpyridine.

24. The organic electroluminescence device according to claim 1, wherein:
the fused aromatic hydrocarbon ring for L⁷ is selected from an indene ring, a naphthalene ring, and an anthracene ring;
the non-fused aromatic hydrocarbon ring is a benzene ring;
the fused aromatic heterocyclic ring is selected from a quinoline ring, a benzofuran ring, and a benzothiophene ring; and
the non-fused aromatic heterocyclic ring is selected from a pyrrole ring, an imidazole ring, a pyrazole ring, a triazole ring, a furan ring, a thiophene ring, a thiazole ring, an isothiazole ring, an oxazole ring, an isoxazole ring, an oxadiazole ring, a thiadiazole ring, a pyridine ring, a pyrazine ring, a pyridazine ring, a pyrimidine ring, and a triazine ring.

25. The organic electroluminescence device according to claim 1, wherein the light emitting layer and the first electron transporting layer are in direct contact with each other.

26. The organic electroluminescence device according to claim 1, wherein the light emitting layer comprises a host compound and a dopant compound.

27. The organic electroluminescence device according to claim 1, wherein the dopant compound is a phosphorescent dopant compound or a fluorescent dopant compound.

28. The organic electroluminescence device according to claim 1, wherein the second electron transporting layer comprises one or more selected from the group consisting of an alkali metal, an alkaline earth metal, a rare earth metal, an oxide of alkali metal, a halide of alkali metal, an oxide of alkaline earth metal, a halide of alkaline earth metal, an oxide of rare earth metal, a halide of rare earth metal, an organic complex comprising an alkali metal, an organic complex comprising an alkaline earth metal, and an organic complex comprising a rare earth metal.

29. An electronic device comprising the organic electroluminescence device according to claim 1.

30. The organic electroluminescence device according to claim 1, wherein n is 1.
